(19) United States
(12) Patent Application Publication
(10) Pub. No.: US 2024/0113138 A1
(43) Pub. Date: Apr. 4, 2024

(54) SEMICONDUCTOR DEVICE, METHOD FOR MANUFACTURING SEMICONDUCTOR DEVICE, AND ELECTRONIC APPARATUS

(71) Applicant: SEMICONDUCTOR ENERGY LABORATORY CO., LTD., Atsugi-shi (JP)

(72) Inventors: Hajime KIMURA, Atsugi (JP); Kentaro HAYASHI, Atsugi (JP); Shunpei YAMAZAKI, Tokyo (JP)

(21) Appl. No.: 18/473,750

(22) Filed: Sep. 25, 2023

(30) Foreign Application Priority Data
Sep. 30, 2022 (JP) 2022-157803
Oct. 14, 2022 (JP) 2022-165187

(51) Int. Cl. H01L 27/12

(52) U.S. Cl. CPC H01L 27/1255; H01L 27/1225; H01L 27/1259

(57) ABSTRACT

A semiconductor device that can be miniaturized or highly integrated is provided. The semiconductor device includes a capacitor, a transistor, and a first insulating layer. The capacitor includes first and second conductive layers and a second insulating layer. The second insulating layer is in contact with a side surface of the first conductive layer, and the second conductive layer covers at least part of the side surface of the first conductive layer with the second insulating layer therebetween. The transistor includes third to fifth conductive layers, a semiconductor layer, and a third insulating layer. The third conductive layer is in contact with a top surface of the first conductive layer. The first insulating layer is provided over the third conductive layer, and the fourth conductive layer is provided over the first insulating layer. The first insulating layer and the fourth conductive layer include an opening portion reaching the third conductive layer. The semiconductor layer is in contact with the third and fourth conductive layers. The semiconductor layer includes a region positioned inside the opening portion. Over the semiconductor layer, the third insulating layer and the fifth conductive layer are provided in this order so as to each include a region positioned inside the opening portion.

### BACKGROUND OF THE INVENTION

### 1. Field of the Invention

One embodiment of the present invention relates to a semiconductor device and a method for manufacturing the semiconductor device. One embodiment of the present invention relates to a memory device and a method for manufacturing the memory device. One embodiment of the present invention relates to a transistor and a method for manufacturing the transistor. One embodiment of the present invention relates to a capacitor and a method for manufacturing the capacitor. One embodiment of the present invention relates to an electronic apparatus.

Note that one embodiment of the present invention is not limited to the above technical field. Examples of the technical field of one embodiment of the present invention include a semiconductor device, a display apparatus, a light-emitting apparatus, a power storage device, a memory device, an electronic apparatus, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display apparatus, a light-emitting apparatus, a lighting device, and an electronic apparatus themselves are semiconductor devices and also include a semiconductor device.

### 2. Description of the Related Art

Recently, development of semiconductor devices has been proceeding, and large scale integration (LSI) circuits are used in the semiconductor devices. For example, central processing units (CPUs), memories, and the like are used in the semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of a CPU or a memory is mounted on a circuit board, for example, a printed wiring board, to be used as one of components of a variety of electronic apparatuses.

A technique by which a transistor is formed using a semiconductor thin film formed over a substrate having an insulating surface has been attracting attention. The transistor is applied to a wide range of electronic devices such as integrated circuits (ICs) or display apparatuses. A silicon-based semiconductor material is widely known as a material for a semiconductor thin film that can be used in a transistor. As another material, an oxide semiconductor has been attracting attention.

It is known that a transistor including an oxide semiconductor has an extremely low leakage current in a non-conducting state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic apparatuses. In addition, the productivity of a semiconductor device including an integrated circuit is desired to be improved. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

Furthermore, by employing vertical transistors, an integrated circuit with higher density can be achieved. For example, Patent Document 4 discloses a vertical transistor in which a side surface of an oxide semiconductor is covered with a gate electrode with a gate insulating layer therebetween.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

In a memory device, memory cells each including a transistor and a capacitor are provided in a matrix. When the area occupied by the transistor and the capacitor increases, the area per memory cell increases accordingly.

An object of one embodiment of the present invention is to provide a semiconductor device, memory device, or transistor that can be miniaturized or highly integrated. Another object of one embodiment of the present invention is to provide a highly reliable semiconductor device, memory device, or transistor. Another object of one embodiment of the present invention is to provide a semiconductor device or memory device which has high reading accuracy. Another object of one embodiment of the present invention is to provide a transistor with a high on-state current. Another object of one embodiment of the present invention is to provide a transistor with favorable electrical characteristics. Another object of one embodiment of the present invention is to provide a low-cost semiconductor device or memory device. Another object of one embodiment of the present invention is to provide a semiconductor device or memory device with low power consumption. Another object of one embodiment of the present invention is to provide a semiconductor device or memory device with a high operation speed. Another object of one embodiment of the present invention is to provide a novel semiconductor device, memory device or transistor.

Another object of one embodiment of the present invention is to provide a method for manufacturing a semiconductor device, memory device, or transistor that can be miniaturized or highly integrated. Another object of one embodiment of the present invention is to provide a method for manufacturing a highly reliable semiconductor device, memory device, or transistor. Another object of one embodiment of the present invention is to provide a method for manufacturing a semiconductor device or memory device which has high reading accuracy. Another object of one embodiment of the present invention is to provide a method for manufacturing a transistor with a high on-state current. Another object of one embodiment of the present invention is to provide a method for manufacturing a transistor with favorable electrical characteristics. Another object of one embodiment of the present invention is to provide a high-yield method for manufacturing a semiconductor device or memory device. Another object of one embodiment of the present invention is to provide a method for manufacturing a semiconductor device or memory device with low power consumption. Another object of one embodiment of the present invention is to provide a method for manufacturing a semiconductor device or memory device with a high operation speed. Another object of one embodiment of the present invention is to provide a method for manufacturing a novel semiconductor device, memory device or transistor.

Note that the description of these objects does not preclude the existence of other objects. One embodiment of the present invention does not need to achieve all of these objects. Other objects can be derived from the description of the specification, the drawings, and the claims.

One embodiment of the present invention is a semiconductor device including a capacitor, a first transistor, and a first insulating layer. The capacitor includes a first conductive layer, a second conductive layer, and a second insulating layer. The second insulating layer includes a region in contact with a side surface of the first conductive layer. The second conductive layer covers at least part of the side surface of the first conductive layer with the second insulating layer therebetween. The first transistor includes a third conductive layer, a fourth conductive layer, a fifth conductive layer, a first semiconductor layer, and a third insulating layer. The third conductive layer includes a region in contact with a top surface of the first conductive layer. The first insulating layer is over the third conductive layer. The fourth conductive layer is over the first insulating layer. The first insulating layer and the fourth conductive layer include a first opening portion reaching the third conductive layer. The first semiconductor layer includes a region in contact with the third conductive layer, a region in contact with the fourth conductive layer, and a region positioned inside the first opening portion. The third insulating layer is over the first semiconductor layer and includes a region positioned inside the first opening portion. The fifth conductive layer includes a region facing the first semiconductor layer with the third insulating layer therebetween, inside the first opening portion.

In the above-described embodiment, the semiconductor device may further include a second transistor, the second transistor may be under the capacitor, and the first conductive layer may be electrically connected to a gate electrode of the second transistor. In the above-described embodiment, the semiconductor device may further include a second transistor and a fourth insulating layer. The second transistor may include a sixth conductive layer, a seventh conductive layer, an eighth conductive layer, a second semiconductor layer, and a fifth insulating layer. The fourth insulating layer may be over the sixth conductive layer. The seventh conductive layer may be over the fourth insulating layer. The fourth insulating layer and the seventh conductive layer may include a second opening portion reaching the sixth conductive layer. The second semiconductor layer may include a region in contact with the sixth conductive layer, a region in contact with the seventh conductive layer, and a region positioned inside the second opening portion. The fifth insulating layer may be over the second semiconductor layer and include a region positioned inside the second opening portion. The eighth conductive layer may include a region facing the second semiconductor layer with the fifth insulating layer therebetween, inside the second opening portion. A top surface of the eighth conductive layer may include a region in contact with the first conductive layer.

In the above-described embodiment, the semiconductor device may further include a memory portion. The memory portion may include memory cells arranged in a matrix. Each of the memory cells may include the first transistor, the second transistor, and the capacitor. The sixth conductive layer and the seventh conductive layer may be shared by the memory cells arranged in a first direction.

In the above-described embodiment, a constant potential may be supplied to the seventh conductive layer.

In the above-described embodiment, the semiconductor device may further include a first driver circuit. The first driver circuit may be electrically connected to the sixth conductive layer. The first driver circuit may be configured to write data to the memory cells and read the data.

In the above-described embodiment, the second conductive layer may be shared by the memory cells arranged in a second direction that is perpendicular to the first direction.

In the above-described embodiment, the semiconductor device may further include a second driver circuit. The second driver circuit is electrically connected to the second conductive layer. The second driver circuit may be configured to supply a signal to the second conductive layer and thereby control reading of the data.

In the above-described embodiment, the second conductive layer may include a region extending in a first direction and a region extending in a second direction that is perpendicular to the first direction, and the second conductive layer may include a third opening portion in a region where the region extending in the first direction and the region extending in the second direction intersect with each other.

In the above-described embodiment, a constant potential is supplied to the second conductive layer.

In the above-described embodiment, the semiconductor device may further include a memory portion, a first driver circuit, and a second driver circuit. Memory cells may be arranged in a matrix in the memory portion. Each of the memory cells may include the first transistor, the second transistor, and the capacitor. The second conductive layer may include a region extending in a first direction and a region extending in a second direction that is perpendicular to the first direction. The second conductive layer may include a third opening portion in a region where the region extending in the first direction and the region extending in the second direction intersect with each other. A constant potential may be supplied to the second conductive layer. The sixth conductive layer may be electrically connected to the first driver circuit. The seventh conductive layer may be electrically connected to the second driver circuit. The first driver circuit may be configured to write data to the memory cells and read the data. The second driver circuit may be configured to supply a signal to the seventh conductive layer and thereby control reading of the data.

In the above-described embodiment, the first semiconductor layer and the second semiconductor layer may include a metal oxide. The metal oxide may contain one or more selected from indium, zinc, and an element M, and the element M may be one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

In the above-described embodiment, a capacitance of the capacitor may be more than or equal to double a capacitance of a capacitor formed by the seventh conductive layer, the fifth insulating layer, and the eighth conductive layer.

An electronic apparatus including the semiconductor device according to one embodiment of the present invention and a camera is also one embodiment of the present invention.

One embodiment of the present invention is a method for manufacturing a semiconductor device, including the steps of: forming a first conductive film; processing part of the first conductive film to form a first conductive layer including a first opening portion; forming a first insulating layer including a region in contact with, inside the first opening portion, a side surface of the first conductive layer; forming, in the first insulating layer, a second opening portion including a region overlapping with the first opening portion; forming a second conductive layer inside the second opening portion to form a capacitor including the first conductive layer, the second conductive layer, and the first insulating layer; forming a third conductive layer including a region in contact with a top surface of the second conductive layer; forming a second insulating layer over the third conductive layer; forming a second conductive film over the second insulating layer; forming a third opening portion in the second insulating layer and the second conductive film; forming a first semiconductor layer so as to include a region in contact with the third conductive layer and a region in contact with the second conductive film and so as to include a region positioned inside the third opening portion; processing part of the second conductive film to form a fourth conductive layer; forming a third insulating layer over the first semiconductor layer and the fourth conductive layer; and forming a fifth conductive layer so as to include a region facing the first semiconductor layer with the third insulating layer therebetween, inside the third opening portion, to form a first transistor including the third to fifth conductive layers and the third insulating layer. In the above-described embodiment, a second transistor may be formed before the first conductive film is formed, and the second conductive layer may be formed so as to be electrically connected to a gate electrode of the second transistor.

The method for manufacturing a semiconductor device of the above-described embodiment may further include the steps of: forming a sixth conductive layer before the first conductive film is formed; forming a fourth insulating layer over the sixth conductive layer; forming a third conductive film over the fourth insulating layer; forming a fourth opening portion in the fourth insulating layer and the third conductive film; forming a second semiconductor layer so as to include a region in contact with the sixth conductive layer and a region in contact with the third conductive film and so as to include a region positioned inside the fourth opening portion; processing part of the third conductive film to form a seventh conductive layer; forming a fifth insulating layer over the second semiconductor layer and the seventh conductive layer; forming an eighth conductive layer so as to include a region facing the second semiconductor layer with the fifth insulating layer therebetween, inside the fourth opening portion, to form a second transistor including the sixth to eighth conductive layers and the fifth insulating layer; forming a sixth insulating layer over the eighth conductive layer; forming the first conductive film over the sixth insulating layer; processing part of the first conductive film to form, over the sixth insulating layer, the first conductive layer including the first opening portion overlapping with at least part of the eighth conductive layer; forming the second opening portion in the sixth insulating layer after the first insulating layer is formed; and forming the second conductive layer including a region in contact with the eighth conductive layer.

The method for manufacturing a semiconductor device of the above-described embodiment may further include the steps of: forming an insulating film over the first conductive film; processing part of the insulating film to form a seventh insulating layer including the first opening portion; and forming the first insulating layer so as to cover at least part of the seventh insulating layer.

With one embodiment of the present invention, a semiconductor device, memory device, or transistor that can be miniaturized or highly integrated can be provided. With one embodiment of the present invention, a highly reliable semiconductor device, memory device, or transistor can be provided. With one embodiment of the present invention, a semiconductor device or memory device which has high reading accuracy can be provided. With one embodiment of the present invention, a transistor with a high on-state current can be provided. With one embodiment of the present invention, a transistor with favorable electrical characteristics can be provided. With one embodiment of the present invention, a low-cost semiconductor device or memory device can be provided. With one embodiment of the present invention, a semiconductor device or memory device with low power consumption can be provided. With one embodiment of the present invention, a semiconductor device or memory device with a high operation speed can be provided. With one embodiment of the present invention, a novel semiconductor device, memory device or transistor can be provided.

With one embodiment of the present invention, a method for manufacturing a semiconductor device, memory device, or transistor that can be miniaturized or highly integrated can be provided. With one embodiment of the present invention, a method for manufacturing a highly reliable semiconductor device, memory device, or transistor can be provided. With one embodiment of the present invention, a method for manufacturing a semiconductor device or memory device which has high reading accuracy can be provided. With one embodiment of the present invention, a method for manufacturing a transistor with a high on-state current can be provided. With one embodiment of the present invention, a method for manufacturing a transistor with favorable electrical characteristics can be provided. With one embodiment of the present invention, a high-yield method for manufacturing a semiconductor device or memory device can be provided. With one embodiment of the present invention, a method for manufacturing a semiconductor device or memory device with low power consumption can be provided. With one embodiment of the present invention, a method for manufacturing a semiconductor device or memory device with a high operation speed can be provided. With one embodiment of the present invention, a method for manufacturing a novel semiconductor device, memory device or transistor can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

In the accompanying drawings:

FIG. 1A is a block diagram illustrating a structure example of a semiconductor device and FIGS. 1B1 and 1B2 are circuit diagrams illustrating structure examples of a memory cell;

FIG. 2A is a plan view illustrating a structure example of a semiconductor device and FIGS. 2B and 2C are cross-sectional views illustrating the structure example of the semiconductor device;

FIGS. 3A1 to 3A3, FIGS. 3B1 and 3B2, and FIGS. 3C1 to 3C3 are plan views illustrating the structure example of the semiconductor device;

FIGS. 4A and 4B are cross-sectional views illustrating a structure example of a semiconductor device;

FIGS. 5A and 5B are cross-sectional views illustrating a structure example of a transistor;

FIGS. 6A1 to 6A3, FIGS. 6B1 and 6B2, and FIGS. 6C1 to 6C3 are plan views illustrating a structure example of the semiconductor device;

FIGS. 7A1 to 7A3, FIGS. 7B1 and 7B2, and FIGS. 7C1 to 7C3 are plan views illustrating a structure example of the semiconductor device;

FIG. 8A is a plan view illustrating a structure example of the semiconductor device and FIGS. 8B and 8C are cross-sectional views illustrating the structure example of the semiconductor device;

FIGS. 9A1 to 9A3, FIGS. 9B1 and 9B2, and FIGS. 9C1 to 9C3 are plan views illustrating a structure example of the semiconductor device;

FIGS. 10A1 to 10A3, FIGS. 10B1 and 10B2, and FIGS. 10C1 to 10C3 are plan views illustrating a structure example of the semiconductor device;

FIGS. 11A1 to 11A3, FIGS. 11B1 and 11B2, and FIGS. 11C1 to 11C3 are plan views illustrating a structure example of the semiconductor device;

FIG. 12A is a block diagram illustrating a structure example of the semiconductor device and FIG. 12B is a circuit diagram illustrating a structure example of a memory cell;

FIG. 13A is a plan view illustrating a structure example of the semiconductor device and FIGS. 13B and 13C are cross-sectional views illustrating the structure example of the semiconductor device;

FIG. 14A is a circuit diagram illustrating a structure example of the memory cell, FIG. 14B is a plan view illustrating a structure example of the semiconductor device, and FIGS. 14C and 14D are cross-sectional views illustrating the structure example of the semiconductor device;

FIG. 15A is a block diagram illustrating a structure example of a display apparatus, FIG. 15B is a plan view illustrating a structure example of a pixel, and FIGS. 15C and 15D are circuit diagrams illustrating structure examples of a subpixel;

FIGS. 16A and 16B are plan views illustrating a structure example of the semiconductor device;

FIGS. 17A and 17B are plan views illustrating structure examples of the semiconductor device;

FIG. 18 is a plan view illustrating a structure example of the semiconductor device;

FIGS. 19A and 19B are plan views illustrating a structure example of the semiconductor device;

FIGS. 20A and 20B are plan views illustrating a structure example of the semiconductor device;

FIGS. 21A and 21B are plan views illustrating structure examples of the semiconductor device;

FIGS. 22A and 22B are plan views illustrating a structure example of the semiconductor device;

FIGS. 23A and 23B are plan views illustrating a structure example of the semiconductor device;

FIGS. 24A and 24B are plan views illustrating a structure example of the semiconductor device;

FIGS. 25A and 25B are plan views illustrating a structure example of the semiconductor device;

FIGS. 26A and 26B are plan views illustrating a structure example of the semiconductor device;

FIGS. 27A and 27B are plan views illustrating a structure example of the semiconductor device;

FIGS. 28A and 28B are plan views illustrating a structure example of the semiconductor device;

FIGS. 29A and 29B are plan views illustrating a structure example of the semiconductor device;

FIGS. 30A and 30B are plan views illustrating a structure example of the semiconductor device;

FIGS. 31A and 31B are cross-sectional views illustrating a structure example of the semiconductor device;

FIGS. 32A and 32B are cross-sectional views illustrating a structure example of the semiconductor device;

FIG. 33A is a plan view illustrating a structure example of the semiconductor device and FIGS. 33B and 33C are cross-sectional views illustrating the structure example of the semiconductor device;

FIG. 34A is a plan view illustrating a structure example of the semiconductor device and FIGS. 34B and 34C are cross-sectional views illustrating the structure example of the semiconductor device;

FIG. 35A is a plan view illustrating a structure example of the semiconductor device and FIGS. 35B and 35C are cross-sectional views illustrating the structure example of the semiconductor device;

FIG. 36A is a plan view illustrating a structure example of the semiconductor device and FIGS. 36B and 36C are cross-sectional views illustrating the structure example of the semiconductor device;

FIG. 37A is a plan view illustrating a structure example of the semiconductor device and FIGS. 37B and 37C are cross-sectional views illustrating the structure example of the semiconductor device;

FIG. 38A is a plan view illustrating a structure example of the semiconductor device and FIGS. 38B and 38C are cross-sectional views illustrating the structure example of the semiconductor device;

FIGS. 39A to 39D are cross-sectional views illustrating structure examples in the semiconductor device;

FIG. 40A is a plan view illustrating a structure example of the semiconductor device and FIGS. 40B and 40C are cross-sectional views illustrating the structure example of the semiconductor device;

FIGS. 41A and 41B are cross-sectional views illustrating a structure example of the semiconductor device;

FIGS. 42A and 42B are cross-sectional views illustrating a structure example of the semiconductor device;

FIGS. 43A and 43B are cross-sectional views illustrating a structure example of the semiconductor device;

FIGS. 44A and 44B are plan views illustrating a structure example of the semiconductor device and FIGS. 44C and 44D are cross-sectional views illustrating the structure example of the semiconductor device;

FIGS. 45A and 45B are cross-sectional views illustrating a structure example of the semiconductor device;

FIG. 46A is a plan view illustrating a structure example of the semiconductor device and FIGS. 46B and 46C are cross-sectional views illustrating the structure example of the semiconductor device;

FIGS. 47A and 47B are plan views illustrating a structure example of the semiconductor device and FIGS. 47C and 47D are cross-sectional views illustrating the structure example of the semiconductor device;

FIG. 48A is a plan view illustrating a structure example of the semiconductor device and FIGS. 48B and 48C are cross-sectional views illustrating the structure example of the semiconductor device;

FIGS. 49A and 49B are plan views illustrating a structure example of the semiconductor device;

FIGS. 50A and 50B are plan views illustrating a structure example of the semiconductor device;

FIGS. 51A and 51B are plan views illustrating a structure example of the semiconductor device;

FIGS. 52A and 52B are plan views illustrating a structure example of the semiconductor device;

FIGS. 53A and 53B are plan views illustrating a structure example of the semiconductor device;

FIGS. 54A and 54B are plan views illustrating a structure example of the semiconductor device;

FIG. 55A is a plan view illustrating a structure example of the semiconductor device and FIGS. 55B and 55C are cross-sectional views illustrating the structure example of the semiconductor device;

FIG. 56A is a plan view illustrating a structure example of the semiconductor device and FIGS. 56B and 56C are cross-sectional views illustrating the structure example of the semiconductor device;

FIG. 57A is a plan view illustrating a structure example of the semiconductor device and FIGS. 57B and 57C are cross-sectional views illustrating the structure example of the semiconductor device;

FIG. 58A is a plan view illustrating a structure example of the semiconductor device and FIGS. 58B and 58C are cross-sectional views illustrating the structure example of the semiconductor device;

FIG. 59A is a plan view illustrating a structure example of the semiconductor device and FIGS. 59B and 59C are cross-sectional views illustrating the structure example of the semiconductor device;

FIGS. 60A and 60B are cross-sectional views illustrating structure examples of the semiconductor device;

FIG. 61A is a plan view illustrating a structure example of the semiconductor device and FIGS. 61B and 61C are cross-sectional views illustrating the structure example of the semiconductor device;

FIG. 62A is a plan view illustrating a structure example of the semiconductor device and FIGS. 62B and 62C are cross-sectional views illustrating the structure example of the semiconductor device;

FIG. 63A is a plan view illustrating a structure example of the semiconductor device and FIGS. 63B and 63C are cross-sectional views illustrating the structure example of the semiconductor device;

FIG. 64A is a plan view illustrating a structure example of the semiconductor device and FIGS. 64B and 64C are cross-sectional views illustrating the structure example of the semiconductor device;

FIGS. 65A and 65B are plan views illustrating a structure example of the semiconductor device and FIGS. 65C and 65D are cross-sectional views illustrating the structure example of the semiconductor device;

FIGS. 66A and 66B are plan views illustrating a structure example of the semiconductor device and FIGS. 66C and 66D are cross-sectional views illustrating the structure example of the semiconductor device;

FIG. 67A is a plan view illustrating a structure example of the semiconductor device and FIGS. 67B and 67C are cross-sectional views illustrating the structure example of the semiconductor device;

FIG. 68A is a plan view illustrating a structure example of the semiconductor device and FIGS. 68B and 68C are cross-sectional views illustrating the structure example of the semiconductor device;

FIGS. 69A and 69B are plan views illustrating structure examples of the semiconductor device and FIGS. 69C and 69D are cross-sectional views illustrating the structure examples of the semiconductor device;

FIG. 70A is a plan view illustrating a structure example of the semiconductor device and FIGS. 70B and 70C are cross-sectional views illustrating the structure example of the semiconductor device;

FIGS. 71A and 71B are plan views illustrating a structure example of the semiconductor device and FIGS. 71C and 71D are cross-sectional views illustrating the structure example of the semiconductor device;

FIG. 72A is a plan view illustrating a structure example of the semiconductor device and FIGS. 72B and 72C are cross-sectional views illustrating the structure example of the semiconductor device;

FIG. 73A is a plan view illustrating a structure example of the semiconductor device and FIGS. 73B and 73C are cross-sectional views illustrating the structure example of the semiconductor device;

FIG. 74A is a plan view illustrating a structure example of the semiconductor device and FIGS. 74B and 74C are cross-sectional views illustrating the structure example of the semiconductor device;

FIGS. 75A and 75B are plan views illustrating a structure example of the semiconductor device;

FIGS. 76A and 76B are plan views illustrating a structure example of the semiconductor device;

FIGS. 77A and 77B are plan views illustrating a structure example of the semiconductor device;

FIGS. 78A and 78B are plan views illustrating a structure example of the semiconductor device;

FIGS. 79A and 79B are plan views illustrating a structure example of the semiconductor device;

FIGS. 80A and 80B are plan views illustrating a structure example of the semiconductor device;

FIGS. 81A and 81B are plan views illustrating a structure example of the semiconductor device;

FIGS. 82A and 82B are plan views illustrating a structure example of the semiconductor device;

FIG. 83A is a plan view illustrating an example of a method for manufacturing a semiconductor device and FIGS. 83B and 83C are cross-sectional views illustrating the example of the method for manufacturing a semiconductor device;

FIG. 84A is a plan view illustrating the example of the method for manufacturing a semiconductor device and FIGS. 84B and 84C are cross-sectional views illustrating the example of the method for manufacturing a semiconductor device;

FIG. 85A is a plan view illustrating the example of the method for manufacturing a semiconductor device and FIGS. 85B and 85C are cross-sectional views illustrating the example of the method for manufacturing a semiconductor device;

FIG. 86A is a plan view illustrating the example of the method for manufacturing a semiconductor device and FIGS. 86B and 86C are cross-sectional views illustrating the example of the method for manufacturing a semiconductor device;

FIG. 87A is a plan view illustrating the example of the method for manufacturing a semiconductor device and FIGS. 87B and 87C are cross-sectional views illustrating the example of the method for manufacturing a semiconductor device;

FIG. 88A is a plan view illustrating the example of the method for manufacturing a semiconductor device and FIGS. 88B and 88C are cross-sectional views illustrating the example of the method for manufacturing a semiconductor device;

FIG. 89A is a plan view illustrating the example of the method for manufacturing a semiconductor device and FIGS. 89B and 89C are cross-sectional views illustrating the example of the method for manufacturing a semiconductor device;

FIG. 90A is a plan view illustrating the example of the method for manufacturing a semiconductor device and FIGS. 90B and 90C are cross-sectional views illustrating the example of the method for manufacturing a semiconductor device;

FIG. 91A is a plan view illustrating the example of the method for manufacturing a semiconductor device and FIGS. 91B and 91C are cross-sectional views illustrating the example of the method for manufacturing a semiconductor device;

FIG. 92A is a plan view illustrating the example of the method for manufacturing a semiconductor device and FIGS. 92B and 92C are cross-sectional views illustrating the example of the method for manufacturing a semiconductor device;

FIG. 93A is a plan view illustrating the example of the method for manufacturing a semiconductor device and FIGS. 93B and 93C are cross-sectional views illustrating the example of the method for manufacturing a semiconductor device;

FIG. 94A is a plan view illustrating the example of the method for manufacturing a semiconductor device and FIGS. 94B and 94C are cross-sectional views illustrating the example of the method for manufacturing a semiconductor device;

FIG. 95A is a plan view illustrating the example of the method for manufacturing a semiconductor device and FIGS. 95B and 95C are cross-sectional views illustrating the example of the method for manufacturing a semiconductor device;

FIG. 96A is a plan view illustrating the example of the method for manufacturing a semiconductor device and FIGS. 96B and 96C are cross-sectional views illustrating the example of the method for manufacturing a semiconductor device;

FIG. 97A is a plan view illustrating the example of the method for manufacturing a semiconductor device and FIGS. 97B and 97C are cross-sectional views illustrating the example of the method for manufacturing a semiconductor device;

FIG. 98A is a plan view illustrating the example of the method for manufacturing a semiconductor device and FIGS. 98B and 98C are cross-sectional views illustrating the example of the method for manufacturing a semiconductor device;

FIGS. 99A to 99C are cross-sectional views illustrating structure examples of the semiconductor device;

FIG. 100A is a plan view illustrating the example of the method for manufacturing a semiconductor device and FIGS. 100B and 100C are cross-sectional views illustrating the example of the method for manufacturing a semiconductor device;

FIG. 101A is a plan view illustrating the example of the method for manufacturing a semiconductor device and FIGS. 101B and 101C are cross-sectional views illustrating the example of the method for manufacturing a semiconductor device;

FIG. 102A is a plan view illustrating an example of a method for manufacturing a semiconductor device and FIGS. 102B and 102C are cross-sectional views illustrating the example of the method for manufacturing a semiconductor device;

FIG. 103A is a plan view illustrating the example of the method for manufacturing a semiconductor device and FIGS. 103B and 103C are cross-sectional views illustrating the example of the method for manufacturing a semiconductor device;

FIG. 104A is a plan view illustrating the example of the method for manufacturing a semiconductor device and FIGS. 104B and 104C are cross-sectional views illustrating the example of the method for manufacturing a semiconductor device;

FIG. 105A is a plan view illustrating the example of the method for manufacturing a semiconductor device and FIGS. 105B and 105C are cross-sectional views illustrating the example of the method for manufacturing a semiconductor device;

FIG. 106A is a plan view illustrating the example of the method for manufacturing a semiconductor device and FIGS. 106B and 106C are cross-sectional views illustrating the example of the method for manufacturing a semiconductor device;

FIG. 107A is a plan view illustrating the example of the method for manufacturing a semiconductor device and FIGS. 107B and 107C are cross-sectional views illustrating the example of the method for manufacturing a semiconductor device;

FIG. 108A is a plan view illustrating an example of a method for manufacturing a semiconductor device and FIGS. 108B and 108C are cross-sectional views illustrating the example of the method for manufacturing a semiconductor device;

FIG. 109A is a plan view illustrating the example of the method for manufacturing a semiconductor device and FIGS. 109B and 109C are cross-sectional views illustrating the example of the method for manufacturing a semiconductor device;

FIG. 110A is a plan view illustrating the example of the method for manufacturing a semiconductor device and FIGS. 110B and 110C are cross-sectional views illustrating the example of the method for manufacturing a semiconductor device;

FIG. 111A is a plan view illustrating the example of the method for manufacturing a semiconductor device and FIGS. 111B and 111C are cross-sectional views illustrating the example of the method for manufacturing a semiconductor device;

FIG. 112A is a plan view illustrating the example of the method for manufacturing a semiconductor device and FIGS. 112B and 112C are cross-sectional views illustrating the example of the method for manufacturing a semiconductor device;

FIG. 113A is a plan view illustrating the example of the method for manufacturing a semiconductor device and FIGS. 113B and 113C are cross-sectional views illustrating the example of the method for manufacturing a semiconductor device;

FIG. 114A is a plan view illustrating the example of the method for manufacturing a semiconductor device and FIGS. 114B and 114C are cross-sectional views illustrating the example of the method for manufacturing a semiconductor device;

FIG. 115A is a plan view illustrating the example of the method for manufacturing a semiconductor device and FIGS. 115B and 115C are cross-sectional views illustrating the example of the method for manufacturing a semiconductor device;

FIG. 116A is a plan view illustrating the example of the method for manufacturing a semiconductor device and FIGS. 116B and 116C are cross-sectional views illustrating the example of the method for manufacturing a semiconductor device;

FIG. 117A is a plan view illustrating the example of the method for manufacturing a semiconductor device and FIGS. 117B and 117C are cross-sectional views illustrating the example of the method for manufacturing a semiconductor device;

FIG. 118A is a plan view illustrating an example of a method for manufacturing a semiconductor device and FIGS. 118B and 118C are cross-sectional views illustrating the example of the method for manufacturing a semiconductor device;

FIG. 119A is a plan view illustrating the example of the method for manufacturing a semiconductor device and FIGS. 119B and 119C are cross-sectional views illustrating the example of the method for manufacturing a semiconductor device;

FIG. 120A is a plan view illustrating the example of the method for manufacturing a semiconductor device and FIGS. 120B and 120C are cross-sectional views illustrating the example of the method for manufacturing a semiconductor device;

FIG. 121A is a plan view illustrating the example of the method for manufacturing a semiconductor device and FIGS. 121B and 121C are cross-sectional views illustrating the example of the method for manufacturing a semiconductor device;

FIG. 122A is a plan view illustrating an example of a method for manufacturing a semiconductor device and FIGS. 122B and 122C are cross-sectional views illustrating the example of the method for manufacturing a semiconductor device;

FIG. 123A is a plan view illustrating the example of the method for manufacturing a semiconductor device and FIGS. 123B and 123C are cross-sectional views illustrating the example of the method for manufacturing a semiconductor device;

FIG. 124A is a plan view illustrating the example of the method for manufacturing a semiconductor device and FIGS. 124B and 124C are cross-sectional views illustrating the example of the method for manufacturing a semiconductor device;

FIG. 125A is a plan view illustrating the example of the method for manufacturing a semiconductor device and FIGS. 125B and 125C are cross-sectional views illustrating the example of the method for manufacturing a semiconductor device;

FIG. 126A is a plan view illustrating the example of the method for manufacturing a semiconductor device and FIGS. 126B and 126C are cross-sectional views illustrating the example of the method for manufacturing a semiconductor device;

FIG. 127A is a plan view illustrating the example of the method for manufacturing a semiconductor device and FIGS. 127B and 127C are cross-sectional views illustrating the example of the method for manufacturing a semiconductor device;

FIG. 128A is a plan view illustrating the example of the method for manufacturing a semiconductor device and FIGS. 128B and 128C are cross-sectional views illustrating the example of the method for manufacturing a semiconductor device;

FIG. 129A is a plan view illustrating an example of a method for manufacturing a semiconductor device and FIGS. 129B and 129C are cross-sectional views illustrating the example of the method for manufacturing a semiconductor device;

FIG. 130A is a plan view illustrating the example of the method for manufacturing a semiconductor device and FIGS. 130B and 130C are cross-sectional views illustrating the example of the method for manufacturing a semiconductor device;

FIG. 131A is a plan view illustrating the example of the method for manufacturing a semiconductor device and FIGS. 131B and 131C are cross-sectional views illustrating the example of the method for manufacturing a semiconductor device;

FIG. 132A is a plan view illustrating the example of the method for manufacturing a semiconductor device and FIGS. 132B and 132C are cross-sectional views illustrating the example of the method for manufacturing a semiconductor device;

FIG. 133A is a plan view illustrating the example of the method for manufacturing a semiconductor device and FIGS. 133B and 133C are cross-sectional views illustrating the example of the method for manufacturing a semiconductor device;

FIG. 134A is a plan view illustrating the example of the method for manufacturing a semiconductor device and FIGS. 134B and 134C are cross-sectional views illustrating the example of the method for manufacturing a semiconductor device;

FIG. 135A is a plan view illustrating an example of a method for manufacturing a semiconductor device and FIGS. 135B and 135C are cross-sectional views illustrating the example of the method for manufacturing a semiconductor device;

FIG. 136A is a plan view illustrating the example of the method for manufacturing a semiconductor device and FIGS. 136B and 136C are cross-sectional views illustrating the example of the method for manufacturing a semiconductor device;

FIG. 137A is a plan view illustrating the example of the method for manufacturing a semiconductor device and FIGS. 137B and 137C are cross-sectional views illustrating the example of the method for manufacturing a semiconductor device;

FIG. 138A is a plan view illustrating the example of the method for manufacturing a semiconductor device and FIGS. 138B and 138C are cross-sectional views illustrating the example of the method for manufacturing a semiconductor device;

FIG. 139A is a plan view illustrating an example of a method for manufacturing a semiconductor device and FIGS. 139B and 139C are cross-sectional views illustrating the example of the method for manufacturing a semiconductor device;

FIG. 140A is a plan view illustrating the example of the method for manufacturing a semiconductor device and FIGS. 140B and 140C are cross-sectional views illustrating the example of the method for manufacturing a semiconductor device;

FIG. 141A is a plan view illustrating the example of the method for manufacturing a semiconductor device and FIGS. 141B and 141C are cross-sectional views illustrating the example of the method for manufacturing a semiconductor device;

FIG. 142A is a plan view illustrating the example of the method for manufacturing a semiconductor device and FIGS. 142B and 142C are cross-sectional views illustrating the example of the method for manufacturing a semiconductor device;

FIG. 143A is a plan view illustrating an example of a method for manufacturing a semiconductor device and FIGS. 143B and 143C are cross-sectional views illustrating the example of the method for manufacturing a semiconductor device;

FIG. 144A is a plan view illustrating the example of the method for manufacturing a semiconductor device and FIGS. 144B and 144C are cross-sectional views illustrating the example of the method for manufacturing a semiconductor device;

FIG. 145A is a plan view illustrating the example of the method for manufacturing a semiconductor device and FIGS. 145B and 145C are cross-sectional views illustrating the example of the method for manufacturing a semiconductor device;

FIG. 146A is a plan view illustrating the example of the method for manufacturing a semiconductor device and FIGS. 146B and 146C are cross-sectional views illustrating the example of the method for manufacturing a semiconductor device;

FIG. 147A is a plan view illustrating the example of the method for manufacturing a semiconductor device and FIGS. 147B and 147C are cross-sectional views illustrating the example of the method for manufacturing a semiconductor device;

FIG. 148A is a plan view illustrating the example of the method for manufacturing a semiconductor device and FIGS. 148B and 148C are cross-sectional views illustrating the example of the method for manufacturing a semiconductor device;

FIG. 149A is a plan view illustrating the example of the method for manufacturing a semiconductor device and FIGS. 149B and 149C are cross-sectional views illustrating the example of the method for manufacturing a semiconductor device;

FIG. 150A is a plan view illustrating the example of the method for manufacturing a semiconductor device and FIGS. 150B and 150C are cross-sectional views illustrating the example of the method for manufacturing a semiconductor device;

FIG. 151A is a plan view illustrating the example of the method for manufacturing a semiconductor device and FIGS. 151B and 151C are cross-sectional views illustrating the example of the method for manufacturing a semiconductor device;

FIG. 152A is a plan view illustrating the example of the method for manufacturing a semiconductor device and FIGS. 152B and 152C are cross-sectional views illustrating the example of the method for manufacturing a semiconductor device;

FIG. 153A is a plan view illustrating an example of a method for manufacturing a semiconductor device and FIGS. 153B and 153C are cross-sectional views illustrating the example of the method for manufacturing a semiconductor device;

FIG. 154A is a plan view illustrating the example of the method for manufacturing a semiconductor device and FIGS. 154B and 154C are cross-sectional views illustrating the example of the method for manufacturing a semiconductor device;

FIG. 155A is a plan view illustrating the example of the method for manufacturing a semiconductor device and FIGS. 155B and 155C are cross-sectional views illustrating the example of the method for manufacturing a semiconductor device;

FIG. 156A is a plan view illustrating the example of the method for manufacturing a semiconductor device and FIGS. 156B and 156C are cross-sectional views illustrating the example of the method for manufacturing a semiconductor device;

FIG. 157A is a plan view illustrating the example of the method for manufacturing a semiconductor device and FIGS. 157B and 157C are cross-sectional views illustrating the example of the method for manufacturing a semiconductor device;

FIG. 158A is a plan view illustrating the example of the method for manufacturing a semiconductor device and FIGS. 158B and 158C are cross-sectional views illustrating the example of the method for manufacturing a semiconductor device;

FIG. 159A is a plan view illustrating an example of a method for manufacturing a semiconductor device and FIGS. 159B and 159C are cross-sectional views illustrating the example of the method for manufacturing a semiconductor device;

FIG. 160 is a perspective view illustrating a structure example of a semiconductor device;

FIG. 161 is a cross-sectional view illustrating a structure example of a semiconductor device;

FIG. 162 is a cross-sectional view illustrating a structure example of a semiconductor device;

FIGS. 163A and 163B illustrate examples of electronic components;

FIGS. 164A and 164B illustrate examples of electronic apparatuses and FIGS. 164C to 164E illustrate an example of a large computer;

FIG. 165 illustrates an example of a device for space;

FIG. 166 illustrates an example of a storage system that can be used in a data center; and

FIG. 167 is a graph according to Example.

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each structure illustrated in drawings is not accurately represented in some cases for easy understanding. Therefore, the disclosed invention is not necessarily limited to the position, size, range, or the like disclosed in the drawings. For example, in the actual manufacturing process, a layer, a resist mask, or the like might be unintentionally reduced in size by treatment such as etching, which is not illustrated in some cases for easy understanding.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor is an element having at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

Note that in this specification and the like, oxynitride refers to a material that contains more oxygen than nitrogen. Nitride oxide refers to a material that contains more nitrogen than oxygen.

The contents of elements such as hydrogen, oxygen, carbon, and nitrogen in a film can be analyzed by secondary ion mass spectrometry (SIMS) or X-ray photoelectron spectroscopy (XPS), for example. XPS is suitable when the content of a target element is high (e.g., 0.5 atomic % or more, or 1 atomic % or more). In contrast, SIMS is suitable when the content of a target element is low (e.g., 0.5 atomic % or less, or 1 atomic % or less). To compare the contents of elements, analysis with a combination of SIMS and XPS is preferably used.

In this specification and the like, the terms “film” and “layer” can be interchanged with each other depending on circumstances. For example, the term “conductive layer” can be changed into the term “conductive film” in some cases. The term “conductive film” can be changed into the term “conductive layer” in some cases, for example. For example, the term “insulating film” can be changed into the term “insulating layer” in some cases. The term “insulating layer” can be changed into the term “insulating film” in some cases, for example. For example, the term “semiconductor film” can be changed into the term “semiconductor layer” in some cases. The term “semiconductor layer” can be changed into the term “semiconductor film” in some cases, for example.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 60° and less than or equal to 120°.

In this specification and the like, the term “electrically connected” includes the case where components are connected to each other through an object having any electric action. There is no particular limitation on an “object having any electric function” as long as electric signals can be transmitted and received between components that are connected through the object. Examples of the “object having any electric function” are a switching element such as a transistor, a resistor, a coil, a capacitor, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V g s is lower than a threshold voltage Vth, and the off state of a p-channel transistor means that V g s is higher than Vth.

Note that in this specification and the like, a top surface shape of a component means the outline of the component in a plan view. A plan view means that the component is observed from a normal direction of a surface where the component is formed or from a normal direction of a surface of a support (e.g., a substrate) where the component is formed.

Note that in this specification and the like, a tapered shape refers to a shape such that at least part of a side surface of a component is inclined with respect to a substrate surface or a formation surface of the component. For example, a tapered shape preferably includes a region where the angle between the inclined side surface and the substrate surface or the formation surface (such an angle is also referred to as a taper angle) is less than 90°. Note that the side surface of the component, the substrate surface, and the formation surface are not necessarily completely flat and may be substantially flat with a slight curvature or with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, terms for describing arrangement, such as “over”, “above”, “under”, “below”, “left”, and “right”, are used for convenience in describing a positional relation between components with reference to drawings. The positional relation between components is changed as appropriate in accordance with the direction from which each component is described. Thus, the positional relation is not limited to that described with a term used in this specification and can be explained with other terms as appropriate depending on the situation.

In this specification and the like, a metal oxide means an oxide of metal in a broad sense. Metal oxides are classified into an oxide insulator, an oxide conductor (including a transparent oxide conductor), an oxide semiconductor (also simply referred to as OS), and the like. For example, a metal oxide used in a semiconductor layer of a transistor is referred to as an oxide semiconductor in some cases. That is, an OS transistor can also be referred to as a transistor including a metal oxide or an oxide semiconductor. Note that a metal oxide containing nitrogen is also called a metal oxide in some cases. In addition, a metal oxide containing nitrogen may be referred to as a metal oxynitride.

### Embodiment 1

In this embodiment, a semiconductor device of one embodiment of the present invention and a method for manufacturing the semiconductor device are described with reference to drawings. In this embodiment, the semiconductor device of one embodiment of the present invention is described taking a memory device as a main example.

One embodiment of the present invention relates to a memory device including a memory portion in which memory cells are arranged in a matrix. The memory cells each include a first transistor, a second transistor, and a capacitor.

The first transistor can be a transistor in which a semiconductor layer is provided inside an opening portion that is formed in an interlayer insulating layer over a substrate. With this structure, the channel length direction of the first transistor can be a direction that is along a side surface of the interlayer insulating layer in the opening portion. Thus, the channel length is not influenced by the performance of a light exposure apparatus used for manufacturing the first transistor and can be shorter than the resolution limit of the light exposure apparatus.

Here, a first conductive layer provided under the opening portion is used as one of a source electrode and a drain electrode of the first transistor. Specifically, the interlayer insulating layer is provided over the first conductive layer and an opening portion is provided in the interlayer insulating layer so as to reach the first conductive layer. Then, the semiconductor layer is provided so as to include a region in contact with the first conductive layer inside the opening portion. Furthermore, as the other of the source electrode and the drain electrode of the first transistor, a second conductive layer which is provided over the interlayer insulating layer and has an opening portion overlapping with the above-described opening portion is used. A gate insulating layer is provided over the semiconductor layer and the second conductive layer, and a third conductive layer functioning as a gate electrode of the first transistor is provided over the gate insulating layer.

The second transistor is provided over the first transistor. The second transistor can have a structure similar to that of the first transistor. Here, one of a source electrode and a drain electrode of the second transistor is a fourth conductive layer, the other of the source electrode and the drain electrode of the second transistor is a fifth conductive layer, and a gate electrode of the second transistor is a sixth conductive layer.

In the memory device of one embodiment of the present invention, a seventh conductive layer is provided between the third conductive layer included in the first transistor and the fourth conductive layer included in the second transistor, and the third conductive layer and the fourth conductive layer are electrically connected to each other by the seventh conductive layer. Here, a dielectric layer is provided so as to include a region in contact with a side surface of the seventh conductive layer, and an eighth conductive layer is provided so as to cover at least part of the side surface of the seventh conductive layer with the dielectric layer therebetween. For example, the eighth conductive layer is provided so as to include a region in contact with a side surface that is of the dielectric layer and opposite to a side surface which the seventh conductive layer is in contact with. In this manner, the capacitor including the seventh conductive layer, the dielectric layer, and the eighth conductive layer can be provided between the first transistor and the second transistor.

As described above, in the memory device of one embodiment of the present invention, the first transistor, the capacitor, and the second transistor are stacked in this order. Furthermore, the first and second transistors are each a transistor in which the semiconductor layer, the gate insulating layer, and the gate electrode are provided inside the opening portion formed in the interlayer insulating layer, one of the source electrode and the drain electrode is provided under the opening portion, and the other of the source electrode and the drain electrode is provided over the interlayer insulating layer. Thus, the area occupied by the memory cell in a plan view can be made small as compared with, for example, the case where the first and second transistors are planar transistors and the first transistor, the capacitor, and the second transistor are not stacked but provided in the same layer. Therefore, the memory cells can be miniaturized and highly integrated. Accordingly, with one embodiment of the present invention, a memory device capable of being miniaturized and highly integrated can be provided.

### <Structure Example 1 of Semiconductor Device>

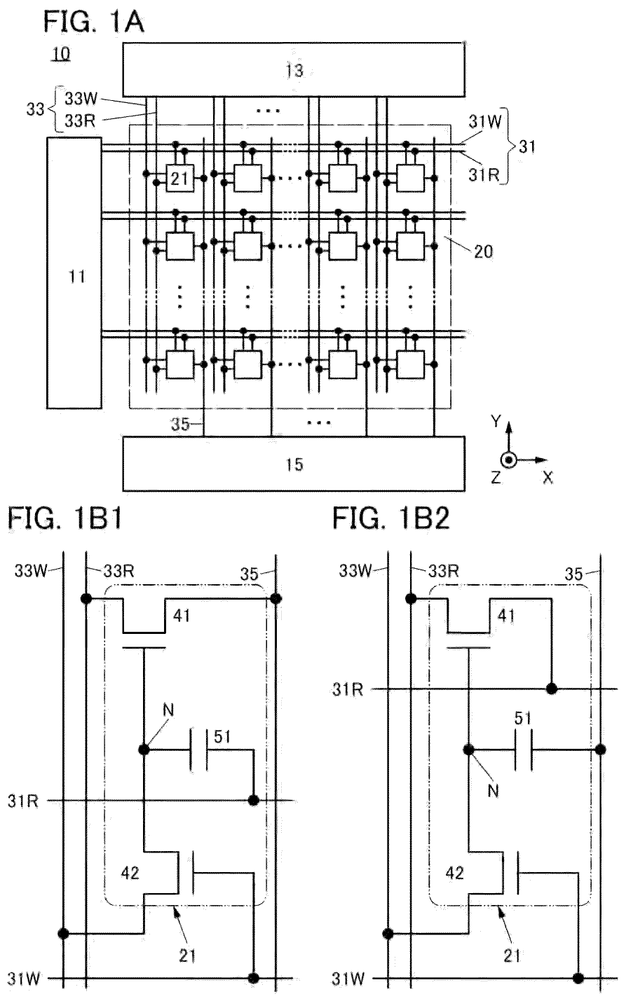

FIG. 1A is a block diagram illustrating a structure example of a semiconductor device 10. The semiconductor device 10 can be used as a memory device.

The semiconductor device 10 includes a memory portion 20, a word line driver circuit 11, a bit line driver circuit 13, and a power supply circuit 15. The memory portion 20 includes a plurality of memory cells 21 arranged in a matrix. Note that the power supply circuit 15 may be provided outside the semiconductor device 10.

The word line driver circuit 11 is electrically connected to the memory cells 21 through wirings 31. The wirings 31 extend in the row direction of the matrix, for example. The wirings 31 function as word lines. FIG. 1A illustrates a wiring 31W and a wiring 31R as the wirings 31.

The bit line driver circuit 13 is electrically connected to the memory cells 21 through wirings 33. The wirings 33 extend in the column direction of the matrix, for example. The wirings 33 function as bit lines. FIG. 1A illustrates a wiring 33W and a wiring 33R as the wirings 33.

In FIG. 1A, as shown by the coordinate axes, the direction in which the wirings 31 functioning as the word lines extend is the X direction and the direction in which the wirings 33 functioning as the bit lines extend is the Y direction. As described above, the wirings 31 extend in the row direction of the matrix, and the wirings 33 extend in the column direction of the matrix. Thus, the X direction can be the row direction and the Y direction can be the column direction. The X direction and the Y direction can intersect with each other and, specifically, can be perpendicular to each other. In addition, the direction intersecting with both of the X direction and the Y direction, specifically, the direction perpendicular to both of the X direction and the Y direction can be the Z direction. Note that in the following drawings, the X direction, Y direction, and Z direction are shown by the coordinate axes, and the definitions of the directions may be the same as or different from those in FIG. 1A. In FIG. 1A, the X direction, Y direction, and Z direction are shown by arrows; the forward direction and the reverse direction are not distinguished from each other unless otherwise specified. The same applies to the following drawings.

In this specification and the like, one of the X, Y, and Z directions may be referred to as a “first direction”. Another one of the directions may be referred to as a “second direction”. Furthermore, the remaining one of the directions may be referred to as a “third direction”.

The power supply circuit 15 is electrically connected to the memory cells 21 through a wiring 35. FIG. 1A illustrates an example in which the wiring 35 extends in the column direction of the matrix. The wiring 35 functions as a power supply line. In FIG. 1A, the wirings 31, the wirings 33, and the wiring 35 are shown by straight lines; however, one straight line does not necessarily mean one wiring and may represent a plurality of wirings in some cases. In the following block diagrams, circuit diagrams, and the like, a plurality of wirings may be represented by one straight line. As for wirings other than the wirings 31, the wirings 33, and the wiring 35, a plurality of wirings may be represented by one straight line.

The word line driver circuit 11 has a function of selecting, row by row, the memory cells 21 to which data is to be written. The word line driver circuit 11 has a function of selecting, row by row, the memory cells 21 from which data is to be read, specifically, the memory cells 21 from which data is to be output to the wirings 33. The word line driver circuit 11 has a function of selecting the memory cells 21 to which data is to be written or the memory cells 21 from which data is to be read by supplying signals to the wirings 31. Specifically, the word line driver circuit 11 has a function of selecting the memory cells 21 to which data is to be written by supplying a signal to the wiring 31W. The word line driver circuit 11 has a function of selecting the memory cells 21 from which data is to be read, specifically, the memory cells 21 from which data is to be output to the wiring 33R by supplying a signal to the wiring 31R. Here, the wiring 31W is also referred to as a write word line, and the wiring 31R is also referred to as a read word line. Furthermore, the signal supplied to the wiring 31W by the word line driver circuit 11 is also referred to as a write signal. Furthermore, the signal supplied to the wiring 31R is also referred to as a read signal.

In the above-described manner, the word line driver circuit 11 has a function of controlling writing of data to the memory cells 21 by supplying the write signal to the wiring 31W. The word line driver circuit 11 has a function of controlling reading of data from the memory cells 21 by supplying the read signal to the wiring 31R. The write signal and the read signal can be pulse signals.

In this specification and the like, the pulse signal refers to a signal whose potential changes over time.

The bit line driver circuit 13 has a function of writing data through the wiring 33 to the memory cell 21 selected by the word line driver circuit 11. The bit line driver circuit 13 has a function of reading data retained in the memory cell 21 by amplifying data output from the memory cell 21 to the wiring 33 and outputting the amplified data to, for example, the outside of the semiconductor device 10. Furthermore, the bit line driver circuit 13 has a function of precharging the wiring 33 before data is read from the memory cell 21.

Specifically, the bit line driver circuit 13 has a function of writing data through the wiring 33W to the memory cell 21 selected by the word line driver circuit 11 with the write signal. The bit line driver circuit 13 has a function of reading data retained in the memory cell 21 by amplifying data output from the memory cell 21 to the wiring 33R and outputting the amplified data to, for example, the outside of the semiconductor device 10. Furthermore, the bit line driver circuit 13 has a function of precharging the wiring 33R before data is read from the memory cell 21. Here, the wiring 33W is also referred to as a write bit line, and the wiring 33R is also referred to as a read bit line.

In the above-described manner, the bit line driver circuit 13 has a function of writing data to the memory cell 21 through the wiring 33W. In addition, the bit line driver circuit 13 has a function of reading the data through the wiring 33R.

The power supply circuit 15 has a function of supplying a power supply potential to the wiring 35, specifically, a function of supplying a constant potential to the wiring 35. The power supply circuit 15 has a function of generating, for example, a high potential or a low potential and supplying it to the wiring 35. Note that the power supply circuit 15 may have a function of supplying a power supply potential to one or both of the word line driver circuit 11 and the bit line driver circuit 13.

FIG. 1B1 is a circuit diagram illustrating a structure example of the memory cell 21. The memory cell 21 includes a transistor 41, a transistor 42, and a capacitor 51.

One of a source and a drain of the transistor 41 is electrically connected to the wiring 33R. The other of the source and the drain of the transistor 41 is electrically connected to the wiring 35. A gate of the transistor 41 is electrically connected to one of a source and a drain of the transistor 42. The one of the source and the drain of the transistor 42 is electrically connected to one electrode of the capacitor 51. The other of the source and the drain of the transistor 42 is electrically connected to the wiring 33W. A gate of the transistor 42 is electrically connected to the wiring 31W. The other electrode of the capacitor 51 is electrically connected to the wiring 31R. Here, a node N refers to a node where the gate of the transistor 41, the one of the source and the drain of the transistor 42, and the one electrode of the capacitor 51 are electrically connected to each other.

The transistor 42 has a function of a switch. For example, in the case where the transistor 42 is an n-channel transistor, the transistor 42 can be turned on by setting the potential of the wiring 31W high. In addition, the transistor 42 can be turned off by setting the potential of the wiring 31W low. The transistor 42 has a function of controlling conduction/non-conduction between the wiring 33W and the node N, on the basis of the potential of the wiring 31W. When the transistor 42 is turned on, data is written to the memory cell 21 through the wiring 33W, and when the transistor 42 is turned off, the written data is retained. Specifically, when the transistor 42 is turned on, charge corresponding to data is accumulated in the node N, and when the transistor 42 is turned off, the charge in the node N is retained. Here, in writing data to the memory cell 21, the potential of the wiring 31R is set low, for example.

Description is given below assuming that the transistor 41 and the transistor 42 are n-channel transistors. However, the following description can apply to the case where one or both of the transistor 41 and the transistor 42 are p-channel transistors by appropriately inverting the potential levels, for example.

The transistor 41 has a function of controlling reading of data retained in the memory cell 21. A method for reading data retained in the memory cell 21 is described below. In the memory cell 21, binary data representing “0” or “1” is retained as the potential of the node N; “1” is represented by a potential higher than that for “0”.

To read data retained in the memory cell 21, first, the wiring 33R is precharged to a high potential. In addition, the potential of the wiring 35 is set low. Furthermore, the potential of the wiring 31R is set low. In this state, it is assumed that a difference between the gate potential and the source potential of the transistor 41, specifically, a difference in potential between the node N and the wiring 35 is lower than, for example, the threshold voltage of the transistor 41 regardless of the value (“0” or “1”) of data retained in the memory cell 21.

Then, the potential of the wiring 31R is set high. Accordingly, the potential of the node N is increased by capacitive coupling. Here, in the case where data retained in the memory cell 21 is “0”, even by setting the potential of the wiring 31R high, a difference between the gate potential and the source potential of the transistor 41 is lower than the threshold voltage of the transistor 41. In the case where data retained in the memory cell 21 is “1”, by setting the potential of the wiring 31R high, the difference between the gate potential and the source potential of the transistor 41 is higher than the threshold voltage of the transistor 41. In this case, in the case where data retained in the memory cell 21 is “0”, a current does not flow from the wiring 33R to the wiring 35; and in the case where data retained in the memory cell 21 is “1”, a current flows from the wiring 33R to the wiring 35. Thus, the bit line driver circuit 13 can read data retained in the memory cell 21 from the current flowing through the wiring 33R or the potential of the wiring 33R. Note that in the case where the potential of the wiring 31R is high, the difference between the gate potential and the source potential of the transistor 41 may be higher than the threshold voltage of the transistor 41 regardless of the value (“0” or “1”) of data retained in the memory cell 21. Also in this case, the bit line driver circuit 13 can read data retained in the memory cell 21 by reading the amount of current flowing through the wiring 33R, for example.

FIG. 1B2 illustrates a modification example of the memory cell 21 illustrated in FIG. 1B1, where the wiring 31R is electrically connected to the other of the source and the drain of the transistor 41, and the wiring 35 is electrically connected to the other electrode of the capacitor 51. Data writing and data reading in the memory cell 21 illustrated in FIG. 1B2 can be performed by a method similar to that for the memory cell 21 illustrated in FIG. 1B1. In order to write data to the memory cell 21 illustrated in FIG. 1B2, the potential of the wiring 31R is set high, for example. By changing the potential of the wiring 31R from a high potential to a low potential, data retained in the memory cell 21 illustrated in FIG. 1B2 can be read.

For example, OS transistors are preferably used as the transistor 41 and the transistor 42. Specifically, examples of a metal oxide included in channel formation regions of the OS transistors include indium oxide, gallium oxide, and zinc oxide. A structure of the memory cell 21 using the OS transistors as the transistor 41 and the transistor 42 is referred to as a nonvolatile oxide semiconductor random access memory (NOSRAM (registered trademark)).

Transistors other than the OS transistors may be used as the transistor 41 and the transistor 42. For example, transistors including silicon in their channel formation regions (hereinafter referred to as Si transistors) can be used as the transistor 41 and the transistor 42. As the silicon, single crystal silicon, amorphous silicon (sometimes referred to as hydrogenated amorphous silicon), microcrystalline silicon, or polycrystalline silicon (including low-temperature polycrystalline silicon) can be used, for example.

As the transistor 41 and the transistor 42, transistors having the same structure or different structures may be used. For example, the transistor 41 and the transistor 42 may each be an OS transistor, or the transistor 41 may be a Si transistor and the transistor 42 may be an OS transistor.

An OS transistor has an extremely low leakage current (also referred to as off-state current) between a source and a drain in an off state. Thus, by using an OS transistor as the transistor 42, charge accumulated in the node N can be retained for a long period. Accordingly, data written to the memory cell 21 can be retained for a long period and therefore the frequency of the refresh operation (rewriting data to the memory cell 21) can be reduced. As a result, power consumption of the semiconductor device can be reduced.

The on-state current of a Si transistor may be higher than that of the OS transistor. In that case, the use of the Si transistor as the transistor 41 enables high-speed reading of data retained in the memory cell 21.

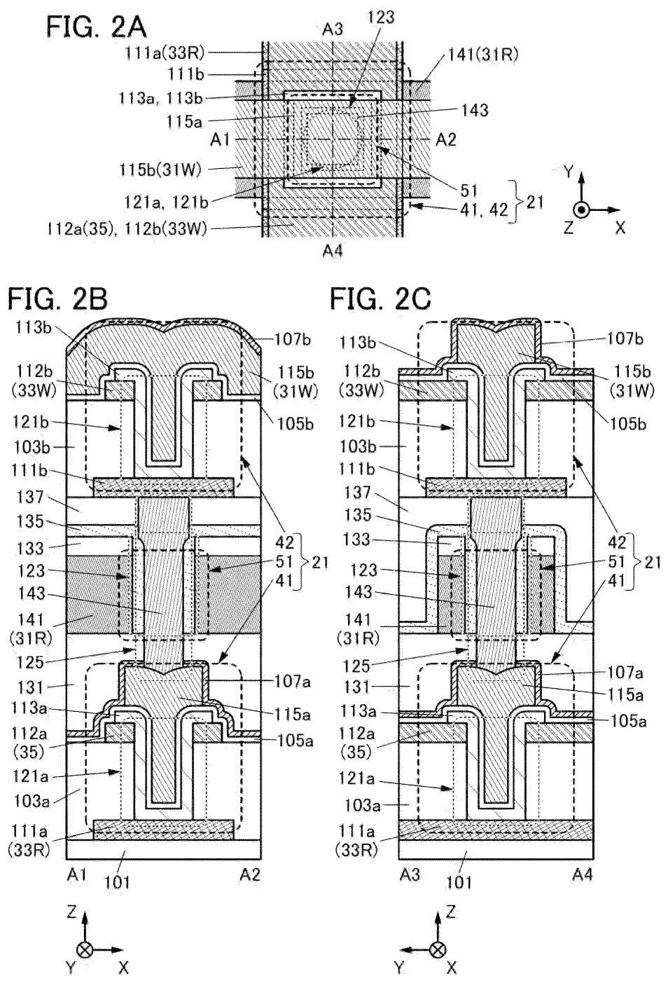

FIG. 2A is a plan view illustrating a structure example of part of the semiconductor device 10 that is the semiconductor device of one embodiment of the present invention. FIG. 2A illustrates the structure example of the memory cell 21 illustrated in FIG. 1B1. For clarity of the drawing, some components such as an insulating layer are omitted in FIG. 2A. Some components are omitted also in the following plan views. FIG. 2B is a cross-sectional view taken along dashed-dotted line A1-A2 in FIG. 2A. FIG. 2C is a cross-sectional view taken along dashed-dotted line A3-A4 in FIG. 2A.

The semiconductor device of one embodiment of the present invention includes an insulating layer 101 over a substrate (not illustrated) and the memory cell 21 over the insulating layer 101. The memory cell 21 includes the transistor 41, the capacitor 51 over the transistor 41, and the transistor 42 over the capacitor 51. In other words, the memory cell 21 includes the transistor 42, the capacitor 51 under the transistor 42, and the transistor 41 under the capacitor 51.

The semiconductor device of one embodiment of the present invention includes an insulating layer 103a over the insulating layer 101, an insulating layer 107a over the transistor 41 and the insulating layer 103a, an insulating layer 131 over the insulating layer 107a, the capacitor 51 over the transistor 41 and the insulating layer 131, an insulating layer 133 over the capacitor 51 and the insulating layer 131, an insulating layer 137 over the insulating layer 131 and the insulating layer 133, the transistor 42 and an insulating layer 103b over the capacitor 51 and the insulating layer 137, and an insulating layer 107b over the transistor 42 and the insulating layer 103b. Here, the insulating layer 101, the insulating layer 103a, the insulating layer 131, the insulating layer 137, and the insulating layer 103b function as interlayer insulating layers. It is preferable that layers functioning as interlayer insulating layers including these insulating layers be planarized. Note that the layers functioning as the interlayer insulating layers are not necessarily planarized.

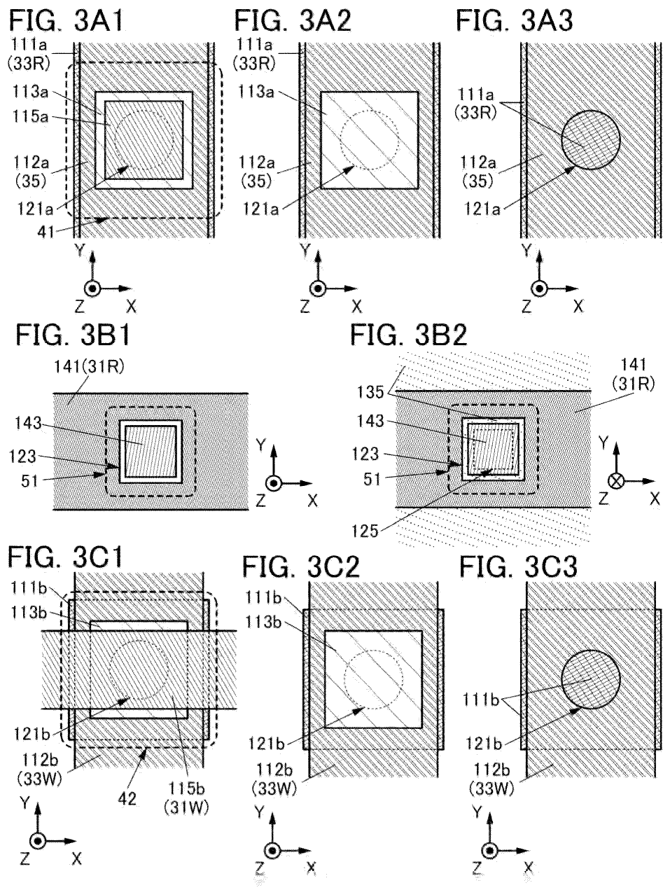

The transistor 41 includes a conductive layer 111a, a conductive layer 112a, a semiconductor layer 113a, an insulating layer 105a, and a conductive layer 115a. Here, a plan view of the transistor 41 extracted from FIG. 2A is illustrated in FIG. 3A1. A plan view omitting the conductive layer 115a from FIG. 3A1 is illustrated in FIG. 3A2. Furthermore, a plan view omitting the semiconductor layer 113a from FIG. 3A2 is illustrated in FIG. 3A3.

The conductive layer 111a functions as one of a source electrode and a drain electrode of the transistor 41 and functions as the wiring 33R. The conductive layer 112a functions as the other of the source electrode and the drain electrode of the transistor 41 and functions as the wiring 35. The insulating layer 105a functions as a gate insulating layer of the transistor 41. The conductive layer 115a functions as a gate electrode of the transistor 41. The conductive layer 111a functioning as the wiring 33R and the conductive layer 112a functioning as the wiring 35 each include a region extending in the Y direction.

The conductive layer 111a is provided over the insulating layer 101, the insulating layer 103a is provided over the insulating layer 101 and the conductive layer 111a, and the conductive layer 112a is provided over the insulating layer 103a. A region where the conductive layers 111a and 112a overlap with each other with the insulating layer 103a therebetween can be included.

An opening portion 121a reaching the conductive layer 111a is provided in the insulating layer 103a and the conductive layer 112a. FIG. 2A and FIGS. 3A1 to 3A3 illustrate an example in which the shape of the opening portion 121a is circular in the plan view. When the shape in the plan view (planar shape) of the opening portion 121a is circular, the processing accuracy in forming the opening portion 121a can be increased and the opening portion 121a with a fine size can be formed. Note that in this specification and the like, “circular” is not limited to “perfectly circular”. For example, the planar shapes of the opening portion 121a may be elliptical.

The bottom of the opening portion 121a includes a top surface of the conductive layer 111a. A sidewall of the opening portion 121a includes a side surface of the insulating layer 103a and a side surface of the conductive layer 112a. The opening portion 121a includes an opening portion included in the insulating layer 103a and an opening portion included in the conductive layer 112a. In other words, the opening portion of the insulating layer 103a and the opening portion of the conductive layer 112a which are provided in a region overlapping with the conductive layer 111a are each part of the opening portion 121a. The shape and the size of the opening portion 121a in the plan view may differ from layer to layer. When the shape of the opening portion 121a is circular in the plan view, the opening portions included in the layers may or may not be concentric with each other.

In the example illustrated in FIGS. 2A and 2B, in the X direction, a side end portion of the conductive layer 111a is positioned on the outer side of a side end portion that is of the conductive layer 112a and does not face the opening portion 121a; in other words, the side end portion that is of the conductive layer 112a and does not face the opening portion 121a overlaps with the conductive layer 111a and the side end portion of the conductive layer 111a does not overlap with the conductive layer 112a; however, one embodiment of the present invention is not limited thereto. For example, the side end portion of the conductive layer 111a may be positioned on the inner side of the side end portion that is of the conductive layer 112a and does not face the opening portion 121a.

The semiconductor layer 113a is provided so as to cover the opening portion 121a and include a region positioned inside the opening portion 121a. The semiconductor layer 113a can have a shape along the shapes of top and side surfaces of the conductive layer 112a, the side surface of the insulating layer 103a, and a top surface of the conductive layer 111a. Thus, the semiconductor layer 113a has a depressed portion in a position overlapping with the opening portion 121a. The semiconductor layer 113a can include a region in contact with the top surface of the conductive layer 112a, a region in contact with the side surface of the conductive layer 112a, a region in contact with the side surface of the insulating layer 103a, and a region in contact with the top surface of the conductive layer 111a.

The semiconductor layer 113a preferably covers a side end portion of the conductive layer 112a on the opening portion 121a side. For example, in FIGS. 2B and 2C, a side end portion of the semiconductor layer 113a is positioned over the conductive layer 112a. In other words, the lower end portion of the semiconductor layer 113a is in contact with the top surface of the conductive layer 112a. In the example illustrated in FIGS. 2A to 2C, the side end portion of the semiconductor layer 113a is positioned on the inner side of the side end portion that is of the conductive layer 112a and does not face the opening portion 121a; in other words, the semiconductor layer 113a entirely overlaps with either the conductive layer 112a or the opening portion 121a. Furthermore, in the example illustrated in FIGS. 2A to 2C, the side end portion of the semiconductor layer 113a is positioned on the inner side of the side end portion of the conductive layer 111a; in other words, the semiconductor layer 113a entirely overlaps with the conductive layer 111a.

Although the semiconductor layer 113a has a single-layer structure in FIGS. 2B and 2C and the like, one embodiment of the present invention is not limited thereto. The semiconductor layer 113a may have a stacked-layer structure of two or more layers. The insulating layer 105a functioning as the gate insulating layer of the transistor 41 is provided so as to cover the opening portion 121a and include a region positioned inside the opening portion 121a. The insulating layer 105a is provided over the semiconductor layer 113a, the conductive layer 112a, and the insulating layer 103a. The insulating layer 105a can have a shape along the shapes of top and side surfaces of the semiconductor layer 113a, the top and side surfaces of the conductive layer 112a, and a top surface of the insulating layer 103a. Accordingly, the insulating layer 105a has a depressed portion in a position overlapping with the opening portion 121a. The insulating layer 105a can include a region in contact with the top surface of the semiconductor layer 113a, a region in contact with the side surface of the semiconductor layer 113a, a region in contact with the top surface of the conductive layer 112a, a region in contact with the side surface of the conductive layer 112a, and a region in contact with the top surface of the insulating layer 103a.

The conductive layer 115a functioning as the gate electrode of the transistor 41 can be provided over the insulating layer 105a and include a region in contact with a top surface of the insulating layer 105a. The conductive layer 115a is provided so as to include a region positioned inside the opening portion 121a and a region facing the semiconductor layer 113a with the insulating layer 105a therebetween. Here, a structure in which the semiconductor layer 113a covers a side surface and a bottom surface of the conductive layer 115a with the insulating layer 105a therebetween inside the opening portion 121a is possible. For example, inside the opening portion 121a, the insulating layer 105a can include a region in contact with the side surface of the semiconductor layer 113a, a region in contact with a top surface of the depressed portion of the semiconductor layer 113a, a region in contact with a side surface of the conductive layer 115a, and a region in contact with a bottom surface of the conductive layer 115a.

As described above, the transistor 41 illustrated in FIGS. 2B and 2C is a transistor in which the semiconductor layer, the gate insulating layer, and the gate electrode are provided inside the opening portion formed in the interlayer insulating layer. Thus, the channel length direction of the transistor 41 can be a direction that is along the side surface of the insulating layer 103a in the opening portion 121a. Thus, the channel length is not influenced by the performance of a light exposure apparatus used for manufacturing the transistor 41 and can be shorter than the resolution limit of the light exposure apparatus. Although the opening portion 121a entirely includes a region overlapping with the conductive layer 111a, the semiconductor layer 113a, and the conductive layer 115a in the example illustrated in FIG. 2A, for example, it is allowable that part of the opening portion 121a does not overlap with at least one of the conductive layer 111a, the semiconductor layer 113a, and the conductive layer 115a.

Here, the distance between the conductive layer 115a and the conductive layer 112a outside the opening portion 121a is shorter than the distance between the conductive layer 115a and the conductive layer 111a outside the opening portion 121a. Accordingly, parasitic capacitance formed by the conductive layer 115a and the conductive layer 112a is larger than parasitic capacitance formed by the conductive layer 115a and the conductive layer 111a. In the memory cell 21 illustrated in FIG. 1B1, the potential of the wiring 33R changes, and a constant potential is supplied to the wiring 35. As described above, in the case where the conductive layer 111a functions as the wiring 33R and the conductive layer 112a functions as the wiring 35, noise to the node N illustrated in FIG. 1B1 due to the parasitic capacitance can be reduced as compared with the case where the conductive layer 112a functions as the wiring 33R and the conductive layer 111a functions as the wiring 35. This can inhibit the data retained in the memory cell 21 from being incorrectly read, for example. Therefore, a memory cell and a semiconductor device which have high reading accuracy can be provided.

The transistor 41 is a so-called top-gate transistor, in which the gate electrode is positioned above the semiconductor layer 113a. Furthermore, since a bottom surface of the semiconductor layer 113a includes a region in contact with the source electrode and the drain electrode, the transistor 41 can be referred to as a top-gate bottom-contact (TGBC) transistor.

The insulating layer 103a and the conductive layer 112a do not necessarily include the opening portion 121a. In this case, the conductive layer 111a functioning as the one of the source electrode and the drain electrode of the transistor 41 and the conductive layer 112a functioning as the other of the source electrode and the drain electrode of the transistor 41 are provided in the same layer. For example, the conductive layer 111a as well as the conductive layer 112a is provided over the insulating layer 103a, and the conductive layer 111a and the conductive layer 112a are provided in positions facing each other with the conductive layer 115a therebetween. In addition, the channel length of the transistor 41 is in a direction along the top surface of the insulating layer 103a. The transistor with this structure can be referred to as a planar transistor.

As illustrated in FIGS. 2B and 2C and the like, part of the insulating layer 105a is positioned outside the opening portion 121a, that is, over the conductive layer 112a and the insulating layer 103a. In that case, the insulating layer 105a preferably covers the side end portions of the semiconductor layer 113a. Accordingly, a short circuit between the conductive layer 115a and the semiconductor layer 113a can be prevented. The insulating layer 105a preferably covers the side end portions of the conductive layer 112a. This can prevent a short circuit between the conductive layer 115a and the conductive layer 112a.

Furthermore, as illustrated in FIGS. 2B and 2C and the like, part of the conductive layer 115a is positioned outside the opening portion 121a, that is, over the conductive layer 112a and the insulating layer 103a. In that case, as illustrated in FIGS. 2B and 2C and the like, a side end portion of the conductive layer 115a is preferably positioned on the inner side of the side end portion of the semiconductor layer 113a. This can prevent a short circuit between the conductive layer 115a and the conductive layer 112a, for example.

The insulating layer 107a is provided over the conductive layer 115a and the insulating layer 105a. The insulating layer 107a can be provided so as to cover a top surface and a side surface of the conductive layer 115a. The insulating layer 131 is provided over the insulating layer 107a as described above.

The insulating layer 107a has a function of inhibiting entry of impurities into the transistor 41, for example, a function of inhibiting entry of impurities into the semiconductor layer 113a. The insulating layer 131 functions as an interlayer insulating layer as described above.

The capacitor 51 includes a conductive layer 141, a conductive layer 143, and an insulating layer 135. Here, a plan view of the capacitor 51 extracted from FIG. 2A is illustrated in FIG. 3B1. A plan view of the capacitor 51 seen from the reverse side of FIG. 3B1 in the Z direction is illustrated in FIG. 3B2. In FIG. 3B2, the insulating layer 135 is illustrated in addition to the conductive layer 141 and the conductive layer 143. Note that, in the case where FIG. 3B1 is referred to as atop view, for example, FIG. 3B2 can be referred to as a bottom view.

The conductive layer 143 functions as one electrode of the capacitor 51. The conductive layer 141 functions as the other electrode of the capacitor 51 and functions as the wiring 31R. The insulating layer 135 functions as a dielectric layer of the capacitor 51. The conductive layer 141 functioning as the wiring 31R includes a region extending in the X direction.

The conductive layer 141 includes an opening portion 123, and the insulating layer 135 and the conductive layer 143 are provided so as to include regions positioned inside the opening portion 123. Specifically, inside the opening portion 123, the insulating layer 135 is provided so as to cover a side surface of the conductive layer 141, and the conductive layer 143 is provided on the inner side of the insulating layer 135 so as to, for example, fill the opening portion 123. Thus, the conductive layer 141 is provided so as to cover at least part of a side surface of the conductive layer 143 with the insulating layer 135 therebetween. The insulating layer 135 includes, inside the opening portion 123, a region in contact with a side surface of the conductive layer 141 and a region in contact with the side surface of the conductive layer 143, for example. In that case, as illustrated in FIGS. 2B and 2C, for example, the conductive layer 141 can include a region in contact with a side surface that is of the insulating layer 135 and opposite to a side surface which the conductive layer 143 is in contact with.

The insulating layer 133 is provided over the conductive layer 141. The conductive layer 141 and the insulating layer 133 can have the same shape in a plan view and both include the opening portion 123. In other words, the opening portion of the conductive layer 141 and the opening portion of the insulating layer 133 are each part of the opening portion 123. The shape and the size of the opening portion 123 in the plan view may differ from layer to layer. When the shape of the opening portion 123 is circular in the plan view, the opening portions of the layers may or may not be concentric with each other.

In an example of a method for forming the conductive layer 141 and the insulating layer 133, first, a conductive film to be the conductive layer 141 and an insulating film to be the insulating layer 133 are deposited in this order. Next, a pattern is formed by a photolithography method. Then, the insulating film and the conductive film are processed by an etching method in accordance with the pattern. In the above-described manner, the insulating layer 133 and the conductive layer 141 including the opening portion 123 can be formed.

FIG. 2A and FIGS. 3B1 and 3B2 each illustrate an example in which the shape of the opening portion 123 is quadrangular in the plan view. FIG. 3B2 illustrates an example in which the shape of an opening portion 125 is quadrangular in the plan view. Although the shape of the opening portion 123 is square in the plan views of FIG. 2A and FIGS. 3B1 and 3B2 and the shape of the opening portion 125 is square in the plan view of FIG. 3B2, the shapes of the opening portion 123 and the opening portion 125 are not limited thereto. The shapes of the opening portion 123 and the opening portion 125 may be each, for example, a rectangle, a rhombus, or a parallelogram in the plan view. Furthermore, the shapes of the opening portion 123 and the opening portion 125 may be each, for example, a triangle, a polygon with five or more sides such as a pentagon, or a star shape in the plan view. The planar shape of the conductive layer 143 is quadrangular as in the opening portion 123 in the example illustrated in FIG. 2A and FIGS. 3B1 and 3B2 but can be similar to the planar shape that the opening portion 123 can have. The kind of planar shape of the opening portion 123 may be different from that of planar shape of the conductive layer 143. Furthermore, the planar shape of the opening portion 125 may be different from the planar shape of the opening portion 123.

The insulating layer 135 is provided over the insulating layer 133. Specifically, the insulating layer 135 is provided so as to cover a top surface and a side surface of the insulating layer 133. The insulating layer 137 is provided over the insulating layer 135.

The opening portion 125 is provided in the insulating layer 107a, the insulating layer 131, the insulating layer 135, and the insulating layer 137. The opening portion 125 is provided so as to include a region overlapping with the opening portion 123 and reach the conductive layer 115a.

The bottom of the opening portion 125 includes the top surface of the conductive layer 115a. A sidewall of the opening portion 125 includes a side surface of the insulating layer 107a, a side surface of the insulating layer 131, a side surface of the insulating layer 135, and a side surface of the insulating layer 137. The opening portion 125 includes an opening portion included in the insulating layer 107a, an opening portion included in the insulating layer 131, an opening portion included in the insulating layer 135, and an opening portion included in the insulating layer 137. In other words, the opening portion of the insulating layer 107a, the opening portion of the insulating layer 131, the opening portion of the insulating layer 135, and the opening portion of the insulating layer 137 which are provided in a region overlapping with the conductive layer 115a are each part of the opening portion 125. The shape and the size of the opening portion 125 in the plan view may differ from layer to layer. When the shape of the opening portion 125 is circular in the plan view, the opening portions included in the layers may or may not be concentric with each other.

The conductive layer 143 is provided so as to include a region positioned inside the opening portion 123 and the opening portion 125. For example, the conductive layer 143 is provided so as to fill the opening portion 125. By providing the conductive layer 143 so as to include a region positioned in the opening portion 125, the top surface of the conductive layer 115a can be in contact with a bottom surface of the conductive layer 143, for example. Thus, the conductive layer 115a functioning as the gate electrode of the transistor 41 and the conductive layer 143 functioning as the one electrode of the capacitor 51 can be electrically connected to each other.

Here, in the case where the insulating layer 133 is not provided over the conductive layer 141, in the step of forming the opening portion 125, a region where the thickness of the insulating layer 135 is small might be formed between the conductive layer 141 and the conductive layer 143. In other words, a region where the distance between the conductive layer 141 and the conductive layer 143 is short might be formed. In that case, for example, a short circuit might occur between the conductive layer 141 and the conductive layer 143. Providing the insulating layer 133 over the conductive layer 141 can inhibit formation of the region where the distance between the conductive layer 141 and the conductive layer 143 is short. Accordingly, the reliability of the memory cell 21 can be improved, and a highly reliable semiconductor device can be provided. Furthermore, a semiconductor device can be provided with high manufacturing yield at low cost. Note that the insulating layer 133 is not necessarily provided as long as a short circuit between the conductive layer 141 and the conductive layer 143 does not occur, for example. In that case, the manufacturing process of the semiconductor device can be simplified.

The transistor 42 includes a conductive layer 111b, a conductive layer 112b, a semiconductor layer 113b, an insulating layer 105b, and a conductive layer 115b. Here, a plan view of the transistor 42 extracted from FIG. 2A is illustrated in FIG. 3C1. A plan view omitting the conductive layer 115b from FIG. 3C1 is illustrated in FIG. 3C2. Furthermore, a plan view omitting the semiconductor layer 113b from FIG. 3C2 is illustrated in FIG. 3C3.

The conductive layer 111b functions as one of a source electrode and a drain electrode of the transistor 42. The conductive layer 112b functions as the other of the source electrode and the drain electrode of the transistor 42 and functions as the wiring 33W. The insulating layer 105b functions as a gate insulating layer of the transistor 42. The conductive layer 115b functions as a gate electrode of the transistor 42 and functions as the wiring 31W. The conductive layer 115b functioning as the wiring 31W includes a region extending in the X direction. The conductive layer 112b functioning as the wiring 33W includes a region extending in the Y direction.

The conductive layer 111b is provided over the conductive layer 143 and the insulating layer 137, the insulating layer 103b is provided over the insulating layer 137 and the conductive layer 111b, and the conductive layer 112b is provided over the insulating layer 103b. A region where the conductive layers 111b and 112b overlap with each other with the insulating layer 103b therebetween can be included.

An opening portion 121b reaching the conductive layer 111b is provided in the insulating layer 103b and the conductive layer 112b. FIG. 2A and FIGS. 3C1 to 3C3 illustrate an example in which the shape of the opening portion 121b is circular in the plan view. Note that the shape of the opening portion 121b can be similar to the shape that the opening portion 121a can have.

The transistor 42 can have a structure similar to the above-described structure of the transistor 41. The description of the structure of the transistor 41 can be referred to for the description of the structure of the transistor 42 by replacing the transistor 41, the insulating layer 103a, the insulating layer 105a, the conductive layer 111a, the conductive layer 112a, the semiconductor layer 113a, the conductive layer 115a, and the opening portion 121a with the transistor 42, the insulating layer 103b, the insulating layer 105b, the conductive layer 111b, the conductive layer 112b, the semiconductor layer 113b, the conductive layer 115b, and the opening portion 121b, respectively, and appropriately replacing words or sentences as necessary.

In this specification and the like, the insulating layer 103a and the insulating layer 103b are collectively referred to as an insulating layer 103, the insulating layer 105a and the insulating layer 105b are collectively referred to as an insulating layer 105, the insulating layer 107a and the insulating layer 107b are collectively referred to as an insulating layer 107, the conductive layer 111a and the conductive layer 111b are collectively referred to as a conductive layer 111, the conductive layer 112a and the conductive layer 112b are collectively referred to as a conductive layer 112, the semiconductor layer 113a and the semiconductor layer 113b are collectively referred to as a semiconductor layer 113, the conductive layer 115a and the conductive layer 115b are collectively referred to as a conductive layer 115, and the opening portion 121a and the opening portion 121b are collectively referred to as an opening portion 121.

The conductive layer 111b can include a region in contact with the conductive layer 143. For example, a bottom surface of the conductive layer 111b can include a region in contact with a top surface of the conductive layer 143. Thus, the conductive layer 111b functioning as the one of the source electrode and the drain electrode of the transistor 42 and the conductive layer 143 functioning as the one electrode of the capacitor 51 can be electrically connected to each other. As described above, the conductive layer 143 is electrically connected to the conductive layer 115a functioning as the gate electrode of the transistor 41. In this way, the gate electrode of the transistor 41, the one of the source electrode and the drain electrode of the transistor 42, and the one electrode of the capacitor 51 are electrically connected to one another.

The insulating layer 107b is provided over the conductive layer 115b and the insulating layer 105b. The insulating layer 107b can be provided so as to cover a top surface and a side surface of the conductive layer 115b. The insulating layer 107b has a function of inhibiting entry of impurities into the transistor 42, for example, a function of inhibiting entry of impurities into the semiconductor layer 113b.

As described above, in the semiconductor device of one embodiment of the present invention, the transistor 41, the capacitor 51, and the transistor 42 are stacked in this order. Furthermore, the transistor 41 and the transistor 42 are each a transistor in which the semiconductor layer, the gate insulating layer, and the gate electrode are provided inside the opening portion formed in the interlayer insulating layer, one of the source electrode and the drain electrode is provided under the opening portion, and the other of the source electrode and the drain electrode is provided over the interlayer insulating layer. Thus, the area occupied by the memory cell 21 in a plan view can be made small as compared with, for example, the case where the transistors 41 and 42 are planar transistors and the transistor 41, the capacitor 51, and the transistor 42 are not stacked but provided in the same layer. Therefore, the memory cells can be miniaturized and highly integrated. Accordingly, with one embodiment of the present invention, a semiconductor device capable of being miniaturized and highly integrated can be provided.

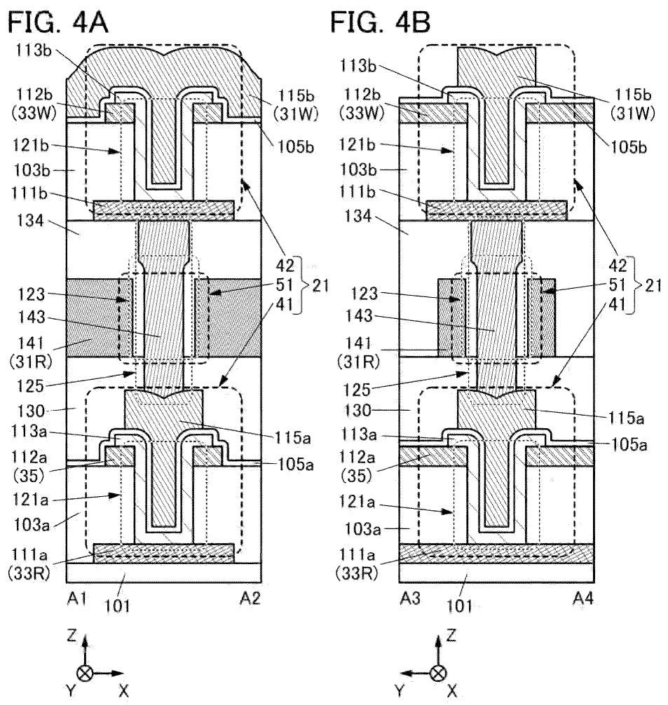

In the cross-sectional views in FIGS. 2B and 2C, boundaries cannot be clearly recognized in some cases. For example, a boundary between two insulating layers which are in contact with each other cannot be clearly recognized in some cases. Furthermore, a boundary between two conductive layers which are in contact with each other cannot be clearly recognized in some cases. Moreover, a boundary between two semiconductor layers which are in contact with each other cannot be clearly recognized in some cases. FIGS. 4A and 4B illustrate an example in which the insulating layer 107a and the insulating layer 131 illustrated in FIGS. 2B and 2C are changed to an insulating layer 130 and the insulating layer 133, the insulating layer 135, and the insulating layer 137 illustrated in FIGS. 2B and 2C are changed to an insulating layer 134. Note that the insulating layer 107b is not illustrated in FIGS. 4A and 4B.

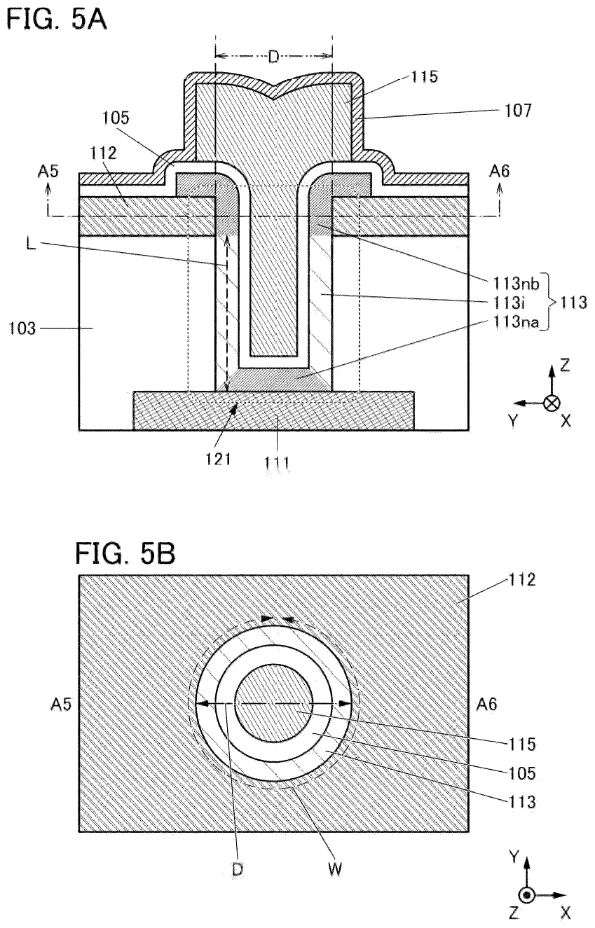

FIG. 5A is an enlarged view of the transistor 42 and its vicinity illustrated in FIG. 2C. FIG. 5B is a cross-sectional view taken along dashed-dotted line A5-A6 of the transistor illustrated in FIG. 5A. FIG. 5B can be regarded as a cross-sectional view along the X-Y plane or a plan view. Note that the conductive layer 111 is not illustrated in FIG. 5B. The structure illustrated in FIGS. 5A and 5B can be applied to not only the transistor 42 but also the transistor 41.

As illustrated in FIG. 5A, the semiconductor layer 113 includes a region 113i and a region 113na and a region 113nb that are provided with the region 113i sandwiched therebetween.

The region 113na is a region in contact with the conductive layer 111 in the semiconductor layer 113. At least part of the region 113na functions as one of a source region and a drain region of the transistor. The region 113nb is a region in contact with the conductive layer 112 in the semiconductor layer 113. At least part of the region 113nb functions as the other of the source region and the drain region of the transistor. As illustrated in FIG. 5B, the conductive layer 112 is in contact with all the perimeter of the semiconductor layer 113. Thus, the other of the source region and the drain region of the transistor can be formed along all the perimeter of a region formed in the same layer as the conductive layer 112 in the semiconductor layer 113.

The region 113i is a region between the region 113na and the region 113na in the semiconductor layer 113. At least part of the region 113i functions as the channel formation region of the transistor. That is, the channel formation region of the transistor is positioned in a region between the conductive layer 111 and the conductive layer 112 in the semiconductor layer 113. In other words, the channel formation region of the transistor is positioned in a region in contact with the insulating layer 103 or a region in the vicinity thereof in the semiconductor layer 113.

The channel length of the transistor is a distance between the source region and the drain region. That is, the channel length of the transistor is determined by the thickness of the insulating layer 103 over the conductive layer 111. In FIG. 5A, a channel length L of the transistor is indicated by a dashed double-headed arrow. In a cross-sectional view, the channel length L is a distance between an end portion of the region in contact with the conductive layer 111 of the semiconductor layer 113 and an end portion of the region in contact with the conductive layer 112 of the semiconductor layer 113. That is, the channel length L corresponds to the length of a side surface of the insulating layer 103 on the opening portion 121 side in the cross-sectional view.

In a planar transistor, the channel length is determined by the light exposure limit of photolithography, for example. In the present invention, the channel length can be determined by the thickness of the insulating layer 103. Thus, the channel length of the transistor can be less than or equal to the light exposure limit of photolithography allowing a quite minute structure (e.g., greater than or equal to 1 nm and less than or equal to 60 nm, greater than or equal to 1 nm and less than or equal to 50 nm, greater than or equal to 1 nm and less than or equal to 40 nm, greater than or equal to 5 nm and less than or equal to 30 nm, greater than or equal to 5 nm and less than or equal to 20 nm, or greater than or equal to 5 nm and less than or equal to 10 nm). Accordingly, the transistor can have a higher on-state current and higher frequency characteristics. Accordingly, the read speed and the write speed of the memory cell can be increased, whereby a semiconductor device with a high operation speed can be provided.

Here, although the details are described later, an OS transistor has a higher resistance against a short-channel effect than a Si transistor. Furthermore, as described above, the transistor having the structure illustrated in FIGS. 5A and 5B, for example, can have a shorter channel length than a planar transistor. Thus, in the case where the transistor has the structure illustrated in FIGS. 5A and 5B, for example, a metal oxide is preferably used for the semiconductor layer 113. Note that a material other than a metal oxide, such as silicon, may be used for the semiconductor layer 113.

In addition, as described above, the channel formation region, the source region, and the drain region can be formed in the opening portion 121. Thus, the area occupied by the transistor can be reduced as compared with a planar transistor in which the channel formation region, the source region, and the drain region are provided separately on the X-Y plane. This allows high integration of the semiconductor device; therefore, the memory capacity per unit area can be increased.

In addition, as illustrated in FIG. 5B, the semiconductor layer 113, the insulating layer 105, and the conductive layer 115 are provided concentrically on the X-Y plane including the channel formation region of the semiconductor layer 113. Thus, the side surface of the conductive layer 115 which is provided at the center faces the side surface of the semiconductor layer 113 with the insulating layer 105 therebetween. That is, in the plan view, all the perimeter of the semiconductor layer 113 serves as the channel formation region. In this case, for example, the channel width of the transistor is determined by the length of the perimeter of the semiconductor layer 113. In other words, the channel width of the transistor is determined by the maximum width of the opening portion 121 (the diameter in the case where the opening portion 121 is circular in the plan view). In FIGS. 5A and 5B, a maximum width D of the opening portion 121 is indicated by a dashed double-dotted double-headed arrow. In FIG. 5B, a channel width W of the transistor is indicated by a dashed-dotted double-headed arrow. By increasing the maximum width D of the opening portion 121, the channel width per unit area can be increased and the on-state current can be increased.

The maximum width D of the opening portion 121 is preferably, for example, greater than or equal to 5 nm and less than or equal to 100 nm, greater than or equal to 5 nm and less than or equal to 60 nm, greater than or equal to 10 nm and less than or equal to 50 nm, greater than or equal to 20 nm and less than or equal to 40 nm, or greater than or equal to 20 nm and less than or equal to 30 nm. In the case where the opening portion 121 is circular in the plan view, the maximum width D of the opening portion 121 corresponds to the diameter of the opening portion 121, and the channel width W can be “D×π”.

In the semiconductor device of one embodiment of the present invention, the channel length L of the transistor is preferably shorter than at least the channel width W of the transistor. The channel length L of the transistor in one embodiment of the present invention is greater than or equal to 0.1 times and less than or equal to 0.99 times, preferably greater than or equal to 0.5 times and less than or equal to 0.8 times the channel width W of the transistor. This structure enables a transistor with favorable electrical characteristics and high reliability.

By providing the semiconductor layer 113, the insulating layer 105, and the conductive layer 115 concentrically, the distance between the conductive layer 115 and the semiconductor layer 113 becomes substantially uniform. Thus, a gate electric field can be substantially uniformly applied to the semiconductor layer 113.

The sidewall of the opening portion 121 is preferably perpendicular to the top surface of the conductive layer 111, for example. This structure enables miniaturization and high integration of the semiconductor device. Note that the sidewall of the opening portion 121 may be tapered.

The components of the transistors and the capacitor included in the memory cell 21 will be described below.

### [Transistor]

As the semiconductor layer 113, a single layer or stacked layers including any of the metal oxides described in [Metal oxide] below can be used. As the semiconductor layer 113, a single layer or stacked layers containing any of the materials, such as silicon, described in [Other semiconductor materials] below can be used.

In the case of using a metal oxide for the semiconductor layer 113, a metal oxide having an atomic ratio of In:M:Zn=1:3:2 or a neighborhood thereof, In:M:Zn=1:3:4 or a neighborhood thereof, In:M:Zn=1:1:0.5 or a neighborhood thereof, In:M:Zn=1:1:1 or a neighborhood thereof, In:M:Zn=1:1:1.2 or a neighborhood thereof, In:M:Zn=1:1:2 or a neighborhood thereof, or In:M:Zn=4:2:3 or a neighborhood thereof can be specifically used for the semiconductor layer 113. Note that the neighborhood of an atomic ratio includes ±30% of an intended atomic ratio. Gallium is preferably used as the element M.

When the metal oxide is deposited by a sputtering method, the above atomic ratio is not limited to the atomic ratio of the deposited metal oxide and may be the atomic ratio of a sputtering target used for depositing the metal oxide.

Analysis of the composition of the metal oxide used for the semiconductor layer 113 can be performed by energy dispersive X-ray spectrometry (EDX), XPS, inductively coupled plasma-mass spectrometry (ICP-MS), inductively coupled plasma-atomic emission spectrometry (ICP-AES), or the like. Alternatively, any of these methods may be combined with each other for the analysis. Note that as for an element whose content is low, the actual content may be different from the content obtained by analysis because of the influence of the analysis accuracy. In the case where the content of the element M is low, for example, the content of the element M obtained by analysis may be lower than the actual content.

For the formation of a metal oxide, an atomic layer deposition (ALD) method can be suitably used.

Alternatively, a metal oxide may be formed by a sputtering method or a chemical vapor deposition (CVD) method.

Note that in the case where the metal oxide is formed by a sputtering method, the atomic ratio of the deposited metal oxide may be different from the atomic ratio of a sputtering target. In particular, the zinc content of the deposited metal oxide may be reduced to approximately 50% of that of the sputtering target.

The metal oxide used for the semiconductor layer 113 preferably has crystallinity. Examples of an oxide semiconductor having crystallinity include a c-axis aligned crystalline oxide semiconductor (CAAC-OS), a nanocrystalline oxide semiconductor (nc-OS), a polycrystalline oxide semiconductor, and a single-crystal oxide semiconductor. For the semiconductor layer 113, CAAC-OS or nc-OS is preferably used, and CAAC-OS is particularly preferably used.

CAAC-OS preferably includes a plurality of layered crystal regions and a c-axis is preferably aligned in a normal direction of a surface where the CAAC-OS is deposited. For example, the semiconductor layer 113 preferably includes a layered crystal that is substantially parallel to the sidewall of the opening portion 121, particularly a side surface of the insulating layer 103. With this structure, the layered crystal of the semiconductor layer 113 is formed substantially parallel to the channel length direction of the transistor, so that the on-state current of the transistor can be increased.

The CAAC-OS is a metal oxide having a dense structure with high crystallinity and a low amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

In the CAAC-OS, a reduction in electron mobility due to a crystal grain boundary is less likely to occur because it is difficult to observe a clear crystal grain boundary. Thus, a metal oxide including the CAAC-OS is physically stable.

Accordingly, the metal oxide including the CAAC-OS is resistant to heat and has high reliability.

When an oxide having crystallinity, such as CAAC-OS, is used for the semiconductor layer 113, oxygen extraction from the semiconductor layer 113 by the source or drain electrodes can be inhibited. In this case, extraction of oxygen from the semiconductor layer 113 can be inhibited even when heat treatment is performed; hence, the transistor is stable against high temperatures in the manufacturing process (i.e., thermal budget).

The crystallinity of the semiconductor layer 113 can be analyzed with X-ray diffraction (XRD), a transmission electron microscope (TEM), or electron diffraction (ED), for example. Alternatively, any of these methods may be combined with each other for the analysis.

The thickness of the semiconductor layer 113 is preferably greater than or equal to 1 nm and less than or equal to 20 nm, greater than or equal to 1 nm and less than or equal to 15 nm, greater than or equal to 3 nm and less than or equal to 12 nm, or greater than or equal to 5 nm and less than or equal to 10 nm.

Although the semiconductor layer 113 has a single-layer structure in FIGS. 2B and 2C and FIG. 5A, the present invention is not limited thereto. The semiconductor layer 113 may have a stacked-layer structure of a plurality of oxide layers with different chemical compositions. For example, a structure in which a plurality of kinds of metal oxides selected from the above-described metal oxides are stacked as appropriate may be used.

For the insulating layer 105 functioning as the gate insulating layer, a single layer or stacked layers of any of the insulators described in [Insulator] below can be used. For example, silicon oxide or silicon oxynitride can be used for the insulating layer 105. Silicon oxide or silicon oxynitride is preferable because of being thermally stable.

For the insulating layer 105, any of materials with high dielectric constants, that is, high-k materials, described in [Insulator] below may be used. For example, hafnium oxide, aluminum oxide, or the like may be used.

The thickness of the insulating layer 105 is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. It is preferable that the insulating layer 105 at least partly include a region with the above-described thickness.

The concentration of impurities such as water and hydrogen in the insulating layer 105 is preferably reduced. This can inhibit entry of impurities such as water and hydrogen into the channel formation region of the semiconductor layer 113.

Although the insulating layer 105 has a single-layer structure in FIGS. 2B and 2C and FIG. 5A, the present invention is not limited thereto. The insulating layer 105 may have a stacked-layer structure.

For the conductive layer 115 functioning as the gate electrode, a single layer or stacked layers of any of the conductors described in [Conductor] below can be used. For example, a conductive material with high conductivity, such as tungsten, aluminum, or copper, can be used for the conductive layer 115.

A conductive material that is unlikely to be oxidized, a conductive material having a function of inhibiting diffusion of oxygen, or the like is preferably used for the conductive layer 115. Examples of the conductive material include a conductive material containing nitrogen (e.g., titanium nitride or tantalum nitride) and a conductive material containing oxygen (e.g., ruthenium oxide). This can inhibit a decrease in the conductivity of the conductive layer 115. A semiconductor having high electrical conductivity, typified by polycrystalline silicon containing an impurity element such as phosphorus, or silicide such as nickel silicide may be used for the conductive layer 115.

Although the conductive layer 115 has a single-layer structure in FIGS. 2B and 2C and FIG. 5A, the present invention is not limited thereto. The conductive layer 115 may have a stacked-layer structure.

For the conductive layer 111, a single layer or stacked layers of any of the conductors described in [Conductor] below can be used. A conductive material that is unlikely to be oxidized, a conductive material having a function of inhibiting diffusion of oxygen, or the like is preferably used for the conductive layer 111. For example, titanium nitride, tantalum nitride, or the like can be used. For example, a structure in which tantalum nitride is stacked over titanium nitride may be used. In that case, titanium nitride is in contact with the insulating layer 101 and tantalum nitride is in contact with the semiconductor layer 113. With such a structure, the conductive layer 111 can be inhibited from being excessively oxidized by the semiconductor layer 113. In the case of using an oxide insulator for the insulating layer 101, the conductive layer 111 can be inhibited from being excessively oxidized by the insulating layer 101. Alternatively, the conductive layer 111 may have a structure in which tungsten is stacked over titanium nitride, for example.

Since the conductive layer 111 includes the region in contact with the semiconductor layer 113, any of the conductive materials containing oxygen described in [Conductor] below is preferably used for the conductive layer 111. When the conductive material containing oxygen is used for the conductive layer 111, the conductive layer 111 can maintain its conductivity even when absorbing oxygen. As the conductive layer 111, a single layer or stacked layers of indium tin oxide (also referred to as ITO), indium tin oxide to which silicon is added (also referred to as ITSO), indium zinc oxide (IZO (registered trademark)), or the like can be used, for example.

Although the top surface the conductive layer 111 is flat in FIGS. 2B and 2C and FIG. 5A, the present invention is not limited thereto. For example, the top surface of the conductive layer 111 may have a depressed portion overlapping with the opening portion 121. When at least part of the semiconductor layer 113, at least part of the insulating layer 105, and at least part of the conductive layer 115 are formed so as to fill the depressed portion, a gate electric field of the conductive layer 115 can be easily applied to a portion of the semiconductor layer 113 near the conductive layer 111.

For the conductive layer 112, a single layer or stacked layers of any of the conductors described in [Conductor] below can be used. For example, a conductive material with high conductivity, such as tungsten, aluminum, or copper, can be used for the conductive layer 112.

Also for the conductive layer 112, as in the conductive layer 115, a conductive material that is unlikely to be oxidized, a conductive material having a function of inhibiting diffusion of oxygen, or the like is preferably used. For example, titanium nitride, tantalum nitride, or the like can be used. With such a structure, the conductive layer 112 can be inhibited from being excessively oxidized by the semiconductor layer 113. Also for the conductive layer 112, as in the conductive layer 115, a semiconductor having high electrical conductivity, typified by polycrystalline silicon containing an impurity element such as phosphorus, or silicide such as nickel silicide may be used.

Alternatively, a structure in which tungsten is stacked over titanium nitride may be used, for example. When tungsten is stacked in this manner, the conductivity of the conductive layer 112 can be improved.

In the case where the conductive layer 112 has a stacked-layer structure of a first conductive layer and a second conductive layer, the first conductive layer may be formed using a conductive material with high conductivity and the second conductive layer may be formed using a conductive material containing oxygen, for example. By using the conductive material containing oxygen for the second conductive layer whose region in contact with the insulating layer 105 is larger in area than that of the first conductive layer, oxygen contained in the insulating layer 105 can be inhibited from diffusing into the first conductive layer of the conductive layer 112. For example, tungsten is preferably used as the first conductive layer of the conductive layer 112, and indium tin oxide to which silicon is added is preferably used as the second conductive layer of the conductive layer 112.

When the semiconductor layer 113 is in contact with the conductive layer 111, a metal compound or oxygen vacancies are formed, and the resistance of the region 113na in the semiconductor layer 113 is decreased. The decrease in the resistance of the semiconductor layer 113 in contact with the conductive layer 111 can decrease the contact resistance between the semiconductor layer 113 and the conductive layer 111. Similarly, when the semiconductor layer 113 is in contact with the conductive layer 112, the resistance of the region 113nb in the semiconductor layer 113 is decreased. Accordingly, the contact resistance between the semiconductor layer 113 and the conductive layer 112 can be decreased.

The insulating layer 101, the insulating layer 103, the insulating layer 131, and the insulating layer 137 functioning as the interlayer insulating layers each preferably have a low dielectric constant. In the case where a material with a low dielectric constant is used for an interlayer insulating film, parasitic capacitance between wirings can be reduced. For the insulating layer 101, the insulating layer 103, the insulating layer 131, and the insulating layer 137, a single layer or stacked layers of an insulator containing any of the materials with low dielectric constants described in [Insulator] below can be used. In particular, silicon oxide and silicon oxynitride, which have thermal stability, are preferable.

The concentration of impurities such as water and hydrogen in the insulating layer 101, the insulating layer 103, the insulating layer 131, and the insulating layer 137 is preferably reduced. This can inhibit entry of impurities such as water and hydrogen into the channel formation region of the semiconductor layer 113.

The insulating layer 103 provided in the vicinity of the channel formation region of the semiconductor layer 113 preferably contains oxygen that is released by heating (hereinafter also referred to as excess oxygen). When heat treatment is performed on the insulating layer 103 containing excess oxygen, oxygen is supplied from the insulating layer 103 to the channel formation region of the semiconductor layer 113, so that oxygen vacancies or defects that are oxygen vacancies into which hydrogen enters (also referred to as VoH) can be reduced. Thus, electrical characteristics of the transistor can be stabilized and the reliability can be improved.

For the insulating layer 103, any of the insulators having a function of capturing or fixing hydrogen described in [Insulator] below may be used. With this structure, hydrogen in the semiconductor layer 113 can be captured or fixed, whereby the hydrogen concentration in the semiconductor layer 113 can be reduced. For the insulating layer 103, magnesium oxide, aluminum oxide, or the like can be used.

Although the insulating layer 103 has a single-layer structure in FIGS. 2B and 2C and FIG. 5A, the present invention is not limited thereto. The insulating layer 103 may have a stacked-layer structure.

For the insulating layer 107, any of the insulators having a barrier property against hydrogen described in [Insulator] below is preferably used. In that case, hydrogen can be inhibited from being diffused from outside of the transistor to the semiconductor layer 113 through the insulating layer 105. A silicon nitride film and a silicon nitride oxide film can be suitably used for the insulating layer 107 because they release few impurities (e.g., water and hydrogen) and are unlikely to transmit oxygen and hydrogen.

For the insulating layer 107, any of the insulators having a function of capturing or fixing hydrogen described in [Insulator] below is preferably used. With this structure, diffusion of hydrogen into the semiconductor layer 113 from above the insulating layer 107 can be inhibited, and hydrogen in the semiconductor layer 113 can be captured or fixed, whereby the hydrogen concentration in the semiconductor layer 113 can be reduced. For the insulating layer 107, magnesium oxide, aluminum oxide, hafnium oxide, or the like can be used. Alternatively, for example, a stacked-layer film of aluminum oxide and silicon nitride over the aluminum oxide may be used for the insulating layer 107.

Although the insulating layer 107 is formed over the top surface of the transistor in the structure illustrated in FIGS. 2B and 2C and FIG. 5A, the structure is not limited thereto. For example, the insulating layer 107 or an insulating layer that has a similar function or contains a similar material to the insulating layer 107 may be formed on the side surface and the bottom surface of the transistor so that the transistor can be surrounded by the insulating layer 107. Alternatively, the insulating layer 107 may be formed on the top, side, and bottom surfaces of the transistor 41, the transistor 42, and the capacitor 51, so that the transistor 41, the transistor 42, and the capacitor 51 can be surrounded by the insulating layer 107. This structure can inhibit entry of impurities (e.g., water and hydrogen) into the transistor 41, the transistor 42, and the capacitor 51.

### [Capacitor 51]

For the conductive layer 141 and the conductive layer 143, a single layer or stacked layers of any of the conductors described in [Conductor] below can be used. For example, a conductive material with high conductivity, such as tungsten, aluminum, or copper, can be used for the conductive layer 141 and the conductive layer 143. By using a conductive material with high conductivity in this manner, conductivity of the conductive layer 141 and the conductive layer 143 can be improved.

For the conductive layer 141 and the conductive layer 143, a single layer or stacked layers of the conductive material that is unlikely to be oxidized, the conductive material having a function of inhibiting diffusion of oxygen, or the like is preferably used. For example, titanium nitride, indium tin oxide to which silicon is added, or the like may be used. Alternatively, a structure in which titanium nitride is stacked over tungsten may be used, for example. Alternatively, for example, a structure in which tungsten is stacked over first titanium nitride and second titanium nitride is stacked over the tungsten may be used. With such a structure, when an oxide insulator is used for the insulating layer 135, oxidation of the conductive layer 141 and the conductive layer 143 can be inhibited by the insulating layer 135. In the case of using an oxide insulator for the insulating layer 133, the conductive layer 141 can be inhibited from being oxidized by the insulating layer 133. A semiconductor having high electrical conductivity, typified by polycrystalline silicon containing an impurity element such as phosphorus, or silicide such as nickel silicide may be used for the conductive layer 141 and the conductive layer 143.

For the insulating layer 135, any of materials with high dielectric constants, that is, high-k materials, described in [Insulator] below may be used. Using such a high-k material for the insulating layer 135 allows the insulating layer 135 to be thick enough to inhibit a leakage current and a sufficiently high capacitance of the capacitor 51 to be ensured.

The insulating layer 135 preferably has a stacked-layer structure using an insulator that includes a high-k material. A stacked-layer structure including a high dielectric constant (high-k) material and a material having higher dielectric strength than the high-k material is preferably used. For example, as the insulating layer 135, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor 51.

Alternatively, a material that can show ferroelectricity may be used for the insulating layer 135. Examples of the material that can show ferroelectricity include metal oxides such as hafnium oxide, zirconium oxide, and HfZrO_{X} (X is a real number greater than 0). Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulating layer 135 can have a stacked-layer structure of a plurality of materials selected from the above-listed materials. Since the above-listed materials may change their crystal structures (characteristics) according to a variety of processes as well as deposition conditions, a material that exhibits ferroelectricity is referred to not only as a ferroelectric but also as a material that can show ferroelectricity or a material that shows ferroelectricity in this specification and the like.

A metal oxide containing one or both of hafnium and zirconium is preferable because the metal oxide can show ferroelectricity even when being processed into a thin film of several nanometers. Here, the thickness of the insulating layer 135 can be less than or equal to 100 nm, preferably less than or equal to 50 nm, further preferably less than or equal to 20 nm, still further preferably less than or equal to 10 nm (typically greater than or equal to 2 nm and less than or equal to 9 nm). For example, the thickness is preferably greater than or equal to 8 nm and less than or equal to 12 nm. With the use of the ferroelectric layer that can have a small thickness, the capacitor 51 can be combined with a scaled-down semiconductor element such as a transistor to fabricate a semiconductor device. Note that in this specification and the like, the material that can show ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can show ferroelectricity even with a minute area. For example, a ferroelectric layer can show ferroelectricity even with an area (occupied area) less than or equal to 100 μm², less than or equal to 10 μm², less than or equal to 1 μm², or less than or equal to 0.1 μm² in a plan view. Furthermore, even with an area of less than or equal to 10000 μm² or less than or equal to 1000 μm², a ferroelectric layer can show ferroelectricity in some cases. With a small-area ferroelectric layer, the area occupied by the capacitor 51 can be reduced.

The ferroelectric refers to an insulator having a property of causing internal polarization by application of an electric field from the outside and maintaining the polarization even after the electric field is made zero. Thus, with the use of a capacitor that includes this material as a dielectric (hereinafter, such a capacitor is sometimes referred to as a ferroelectric capacitor), a nonvolatile memory element can be formed. A nonvolatile memory element including a ferroelectric capacitor is sometimes also referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 51, the semiconductor device described in this embodiment functions as a ferroelectric memory.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer 135 can exhibit ferroelectricity, the insulating layer 135 needs to include a crystal. It is particularly preferable that the insulating layer 135 include a crystal having an orthorhombic crystal structure to exhibit ferroelectricity. A crystal included in the insulating layer 135 may have one or more of crystal structures selected from cubic, tetragonal, orthorhombic, monoclinic, and hexagonal crystal structures. Alternatively, the insulating layer 135 may have an amorphous structure. In that case, the insulating layer 135 may have a composite structure including an amorphous structure and a crystal structure.

The insulating layer 133 preferably has a low dielectric constant. In that case, parasitic capacitance between wirings can be reduced. For the insulating layer 133, a single layer or stacked layers of an insulator containing any of the materials with low dielectric constants described in [Insulator] below can be used. In particular, silicon oxide and silicon oxynitride, which have thermal stability, are preferable.

Although the insulating layer 133 has a single-layer structure in FIGS. 2B and 2C, the present invention is not limited thereto. The insulating layer 133 may have a stacked-layer structure.

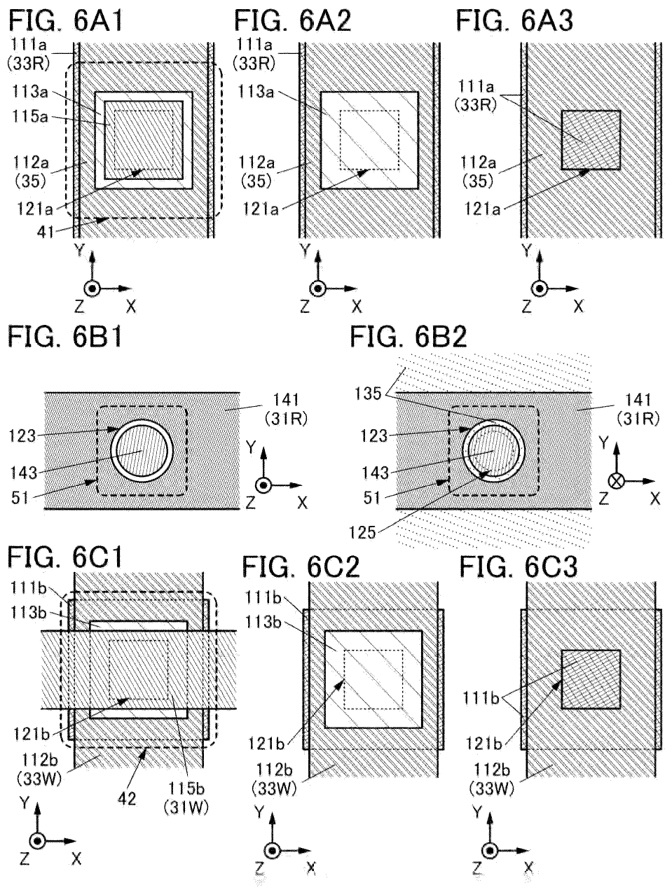

FIG. 6A1, FIG. 6A2, FIG. 6A3, FIG. 6B1, FIG. 6B2, FIG. 6C1, FIG. 6C2, and FIG. 6C3 illustrate modification examples of the structures illustrated in FIG. 3A1, FIG. 3A2, FIG. 3A3, FIG. 3B1, FIG. 3B2, FIG. 3C1, FIG. 3C2, and FIG. 3C3, respectively. FIGS. 6A1, 6A2, and 6A3 illustrate an example in which the shape of the opening portion 121a is quadrangular in the plan view, and FIGS. 6C1, 6C2, and 6C3 illustrate an example in which the shape of the opening portion 121b is quadrangular in the plan view. In FIGS. 6A1 to 6A3 and FIGS. 6C1 to 6C3, the side surface of the insulating layer 103 and the side surface of the conductive layer 112 in the opening portion 121 each include a region that is not curved but flat. Thus, the coverage with the semiconductor layer 113, the insulating layer 105, and the conductive layer 115 can be increased inside the opening portion 121, in some cases. Although the shape of the opening portion 121 is square in the plan views of FIGS. 6A1 to 6A3 and FIGS. 6C1 to 6C3, the shape of the opening portion 121 is not limited thereto and may be, for example, a rectangle, a rhombus, or a parallelogram in the plan views. Furthermore, the shape of the opening portion 121 may be, for example, a triangle, a polygon with five or more sides such as a pentagon, or a star shape in the plan views.

FIGS. 6B1 and 6B2 illustrate an example in which the shapes of the opening portion 123 and the conductive layer 143 are circular in the plan view. FIG. 6B2 illustrates an example in which the shape of the opening portion 125 is circular in the plan view. Note that the planar shape of the opening portion 123 and the planar shape of the opening portion 125 may be elliptical, for example.

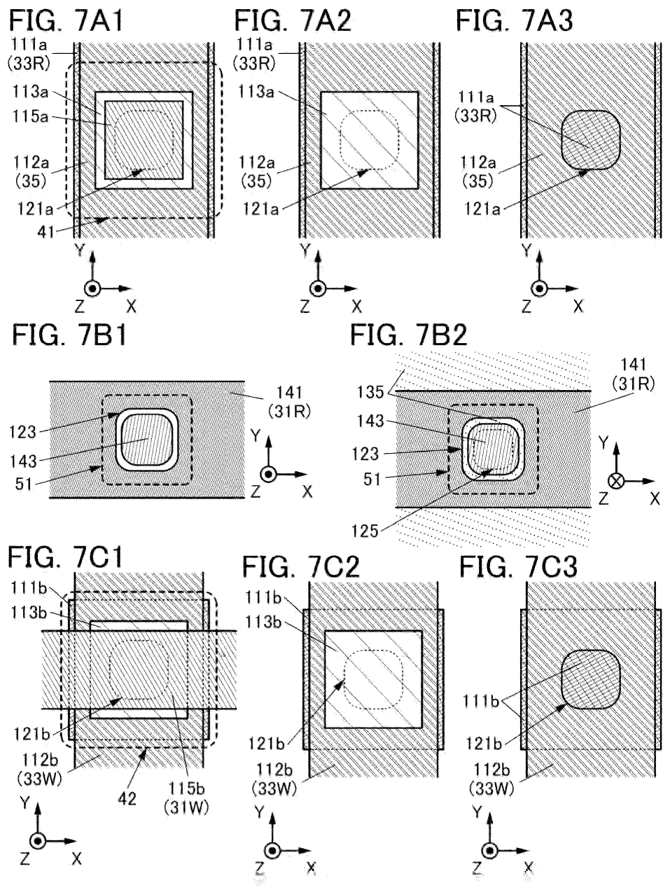

FIG. 7A1, FIG. 7A2, FIG. 7A3, FIG. 7B1, FIG. 7B2, FIG. 7C1, FIG. 7C2, and FIG. 7C3 illustrate modification examples of the structures illustrated in FIG. 3A1, FIG. 3A2, FIG. 3A3, FIG. 3B1, FIG. 3B2, FIG. 3C1, FIG. 3C2, and FIG. 3C3, respectively. FIGS. 7A1, 7A2, and 7A3 illustrate an example in which the shape of the opening portion 121a is quadrangular with rounded corners in the plan view. FIGS. 7B1 and 7B2 illustrate an example in which the shapes of the opening portion 123 and the conductive layer 143 are quadrangular with rounded corners in the plan view. FIG. 7B2 illustrates an example in which the shape of the opening portion 125 is quadrangular with rounded corners in the plan view. FIGS. 7C1, 7C2, and 7C3 illustrate an example in which the shape of the opening portion 121b is quadrangular with rounded corners in the plan view.

Although the shapes of the opening portion 121, the opening portion 123, the opening portion 125, and the conductive layer 143 are quadrangular with rounded corners in the plan views of FIGS. 7A1 to 7C3, the shapes of the opening portion 121, the opening portion 123, the opening portion 125, and the conductive layer 143 are not limited thereto. The shapes in the plan view may each be a rectangle with rounded corners, a triangle with rounded corners, a polygon with five or more sides, such as a pentagon, and with rounded corners, or a star shape with rounded corners, for example.

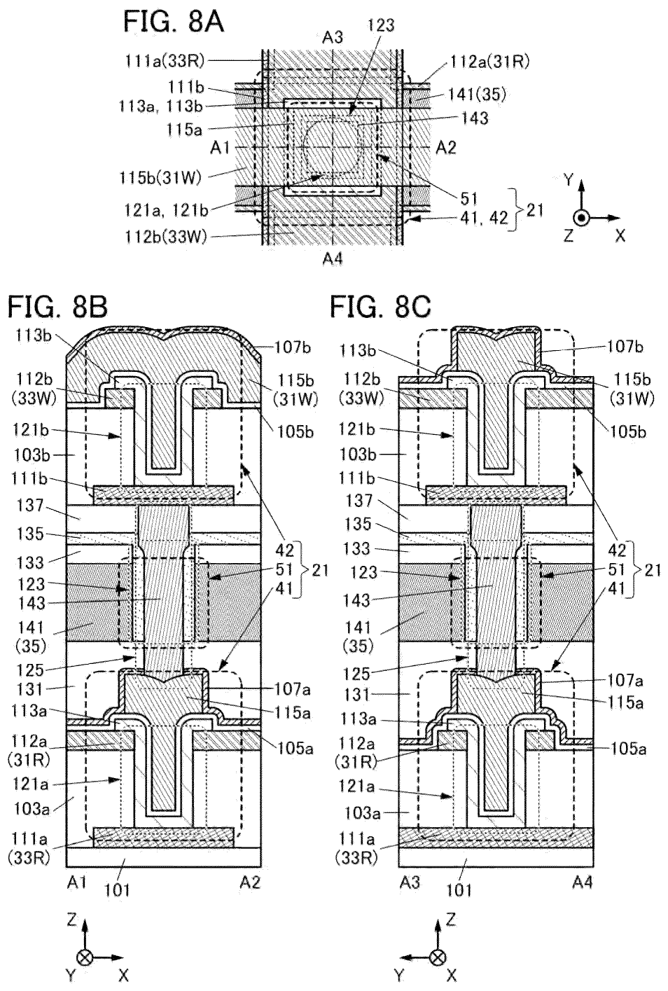

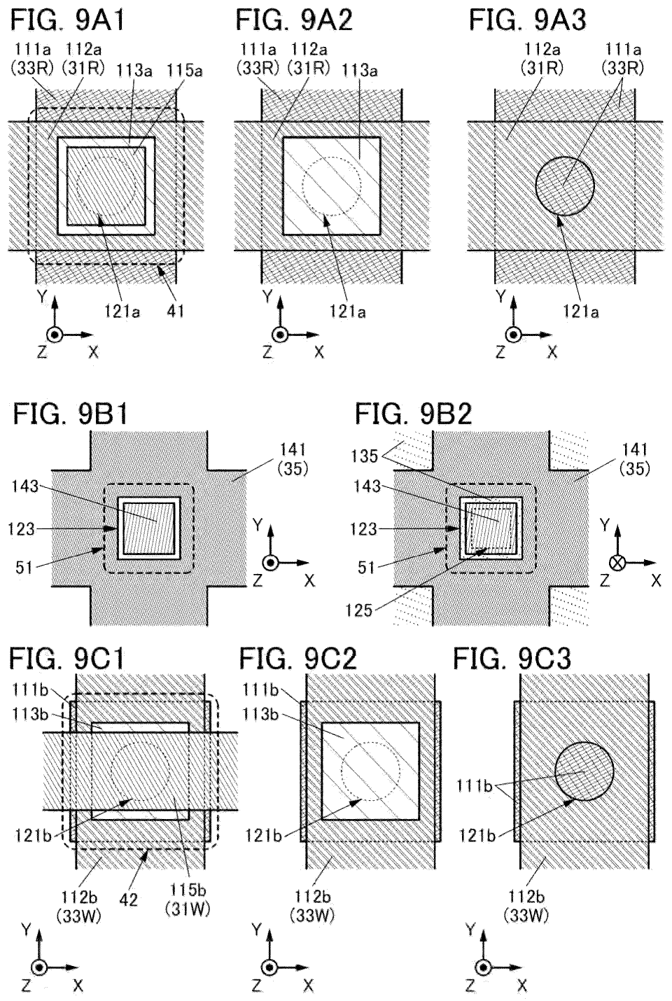

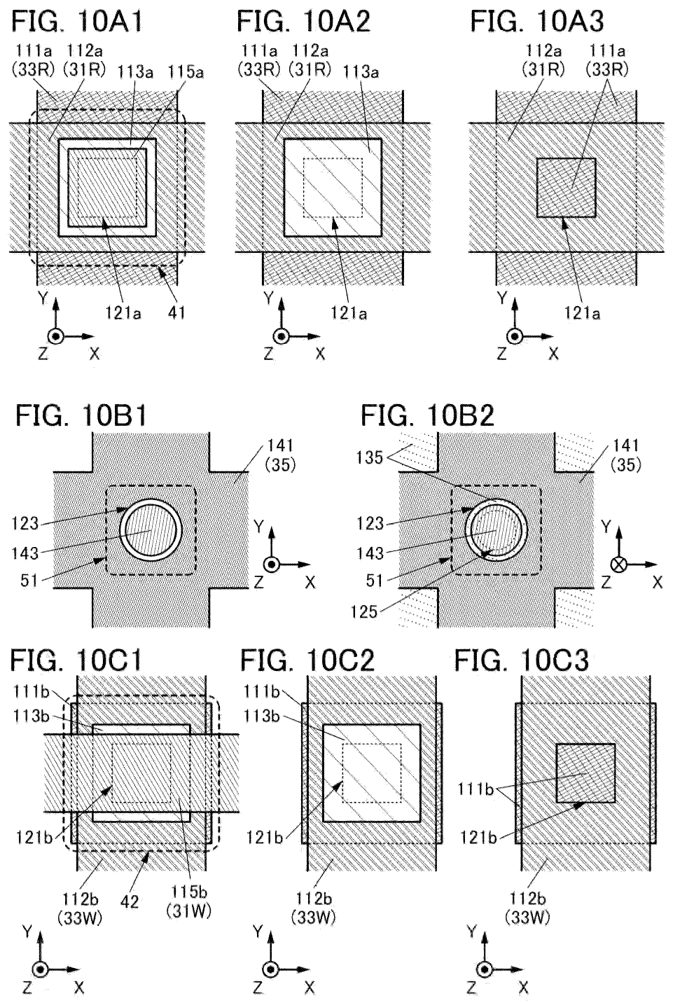

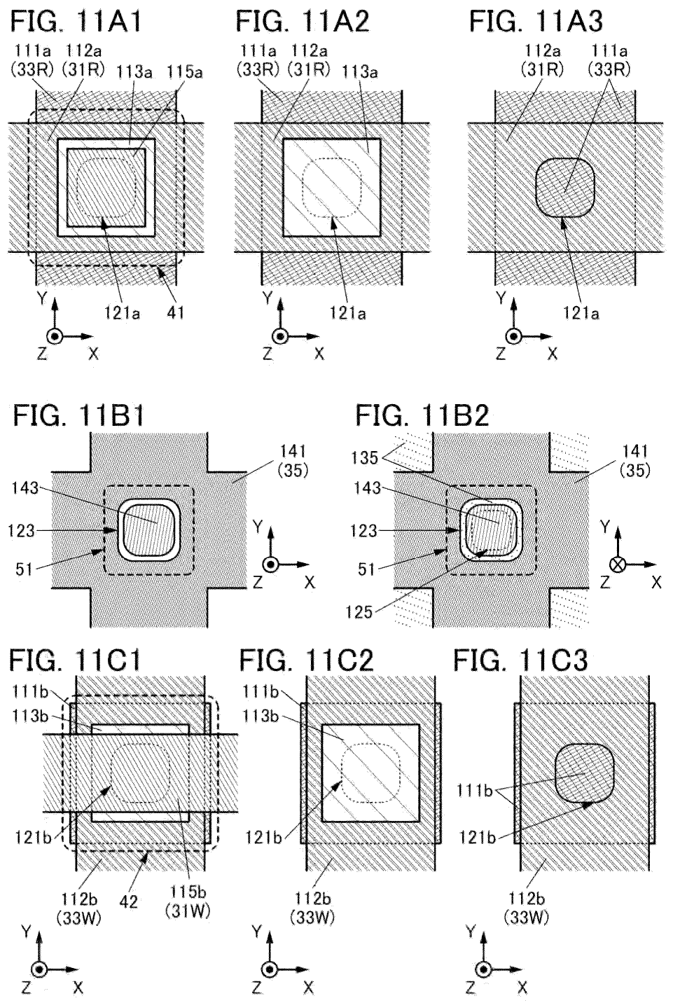

FIG. 8A, FIG. 8B, FIG. 8C, FIG. 9A1, FIG. 9A2, FIG. 9A3, FIG. 9B1, FIG. 9B2, FIG. 9C1, FIG. 9C2, FIG. 9C3, FIG. 10A1, FIG. 10A2, FIG. 10A3, FIG. 10B1, FIG. 10B2, FIG. 10C1, FIG. 10C2, FIG. 10C3, FIG. 11A1, FIG. 11A2, FIG. 11A3, FIG. 11B1, FIG. 11B2, FIG. 11C1, FIG. 11C2, and FIG. 11C3 illustrate modification examples of the structures illustrated in FIG. 2A, FIG. 2B, FIG. 2C, FIG. 3A1, FIG. 3A2, FIG. 3A3, FIG. 3B1, FIG. 3B2, FIG. 3C1, FIG. 3C2, FIG. 3C3, FIG. 6A1, FIG. 6A2, FIG. 6A3, FIG. 6B1, FIG. 6B2, FIG. 6C1, FIG. 6C2, FIG. 6C3, FIG. 7A1, FIG. 7A2, FIG. 7A3, FIG. 7B1, FIG. 7B2, FIG. 7C1, FIG. 7C2, and FIG. 7C3, respectively, and illustrate the examples in which the memory cell 21 has the structure illustrated in FIG. 1B2.

For example, as illustrated in FIGS. 8A to 8C and FIGS. 9A1 to 9A3, the conductive layer 112a functions as the wiring 31R and includes a region extending in the X direction. Furthermore, as illustrated in FIGS. 8A to 8C and FIGS. 9B1 and 9B2, the conductive layer 141 functions as the wiring 35 and includes a region extending in the X direction and a region extending in the Y direction. In addition, the conductive layer 141 includes the opening portion 123 in a region where the region extending in the X direction and the region extending in the Y direction intersect with each other.

In the example illustrated in FIGS. 8B and 8C, as in the example illustrated in FIGS. 2B and 2C, parasitic capacitance formed by the conductive layer 115a and the conductive layer 112a is larger than parasitic capacitance formed by the conductive layer 115a and the conductive layer 111a. Here, in the memory cell 21 illustrated in FIG. 1B2, the frequency of change in the potential of the wiring 31R is lower than the frequency of change in the potential of the wiring 33R. As described above, in the case where the conductive layer 111a functions as the wiring 33R and the conductive layer 112a functions as the wiring 31R, noise to the node N illustrated in FIG. 1B2 due to the parasitic capacitance can be reduced as compared with the case where the conductive layer 112a functions as the wiring 33R and the conductive layer 111a functions as the wiring 31R. This can inhibit the data retained in the memory cell 21 from being incorrectly read, for example. Therefore, a memory cell and a semiconductor device which have high reading accuracy can be provided.

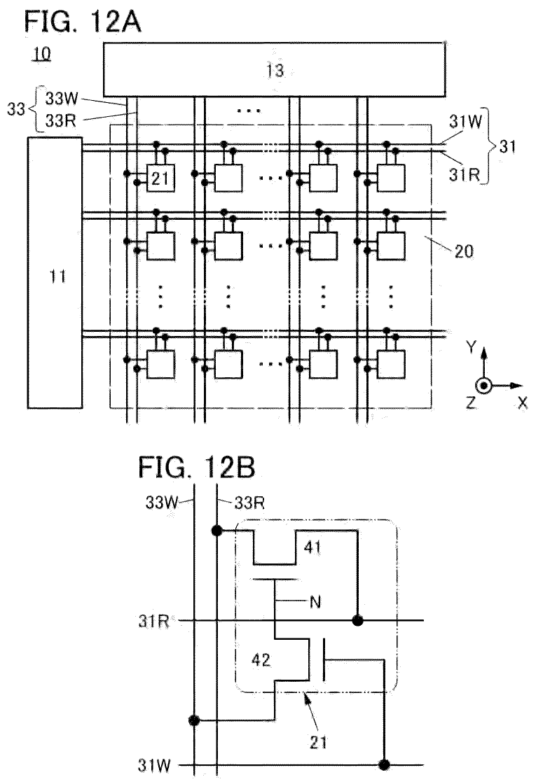

FIG. 12A illustrates a modification example of the structure illustrated in FIG. 1A and illustrates an example where the memory cells 21 are not electrically connected to the power supply circuit 15. Although the power supply circuit 15 is not illustrated in FIG. 12A, a power supply circuit having a function of supplying a power supply potential to the word line driver circuit 11 and the bit line driver circuit 13 can be provided in reality inside or outside the semiconductor device 10.

FIG. 12B is a circuit diagram illustrating a structure example of the memory cell 21 included in the semiconductor device 10 illustrated in FIG. 12A. FIG. 12B illustrates a modification example of the structure illustrated in FIG. 1B2 and is different from the structure illustrated in FIG. 1B2 in not being provided with the capacitor 51. As illustrated in FIG. 12B, the capacitor 51 may be omitted in the memory cell 21 as long as the node N can have enough capacitance owing to the parasitic capacitance such as the gate capacitance of the transistor 41.

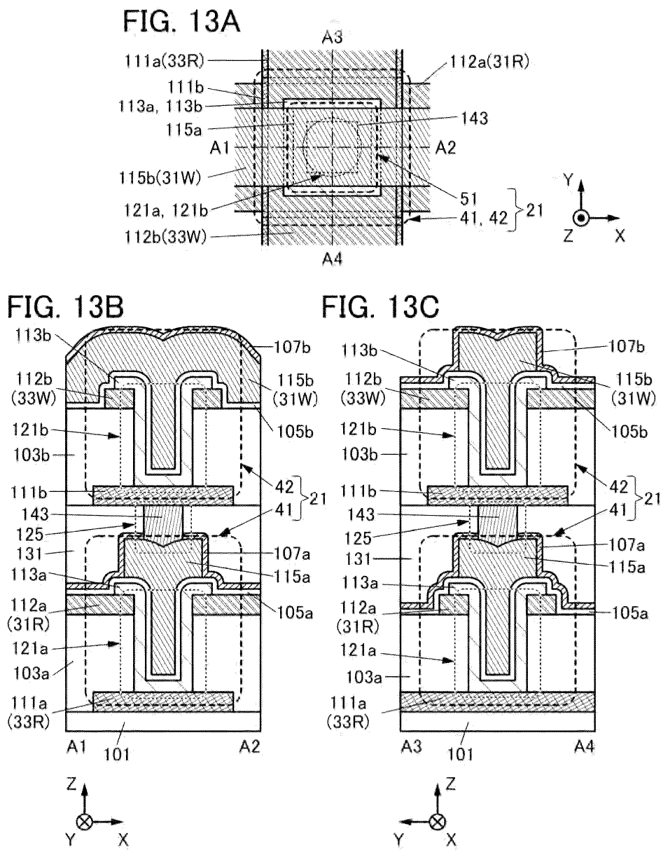

FIG. 13A is a plan view illustrating a structure example of part of the semiconductor device 10 illustrated in FIG. 12A. FIG. 13A illustrates the structure example of the memory cell 21 illustrated in FIG. 12B. FIG. 13B is a cross-sectional view taken along dashed-dotted line A1-A2 in FIG. 13A. FIG. 13C is a cross-sectional view taken along dashed-dotted line A3-A4 in FIG. 13A. The structure illustrated in FIGS. 13A to 13C is different from the structure illustrated in FIGS. 8A to 8C in not being provided with the conductive layer 141, the insulating layer 133, the insulating layer 135, and the insulating layer 137.

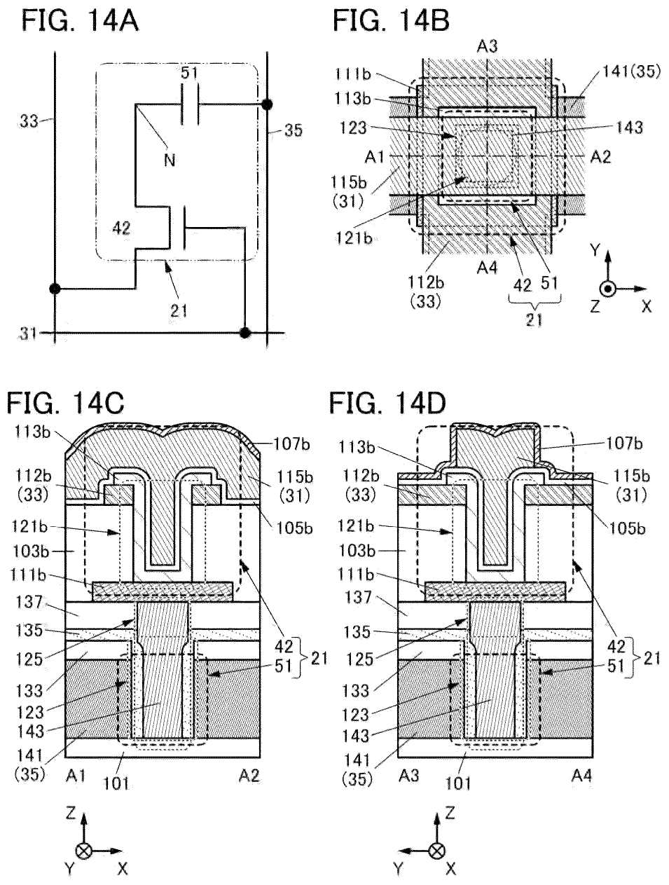

FIG. 14A illustrates a modification example of the structure illustrated in FIG. 1B2 and is different from the structure illustrated in FIG. 1B2 in not being provided with the transistor 41. In the memory cell 21 illustrated in FIG. 14A, when the transistor 42 is turned on, data is written to the memory cell 21 through the wiring 33, and when the transistor 42 is turned off, the data is retained. When the transistor 42 is turned on with the data retained in the memory cell 21, the data is output to the wiring 33. Thus, the data retained in the memory cell 21 is read.

When the structure illustrated in FIG. 14A is used for the memory cell 21, the number of transistors included in the memory cell 21 can be reduced. Thus, the manufacturing process of the semiconductor device of one embodiment of the present invention can be simplified, whereby a low-cost semiconductor device can be provided. The memory cell 21 illustrated in FIG. 14A performs destructive reading, while the memory cell 21 illustrated in FIG. 1B2 performs non-destructive reading, for example. Thus, when the memory cell 21 has the structure illustrated in FIG. 1B2, for example, data rewriting does not need to be performed every time data is read and the frequency of writing data can be reduced.

In the memory cell 21 illustrated in FIG. 14A, the transistor 42 is preferably an OS transistor. As described above, the OS transistor has an extremely low off-state current. Thus, data written to the memory cell 21 can be retained for a long period; therefore, the frequency of refresh operation can be reduced, and the power consumption of the semiconductor device of one embodiment of the present invention can be reduced. A structure of the memory cell 21 using the OS transistor as the transistor 42 illustrated in FIG. 14A is referred to as a dynamic oxide semiconductor random access memory (DOSRAM (registered trademark)).

FIG. 14B is a plan view illustrating a structure example of part of the semiconductor device 10 illustrated in FIG. 1A and illustrates a structure example of the memory cell 21 illustrated in FIG. 14A. FIG. 14C is a cross-sectional view taken along dashed-dotted line A1-A2 in FIG. 14B. FIG. 14D is a cross-sectional view taken along dashed-dotted line A3-A4 in FIG. 14B. As illustrated in FIGS. 14B to 14D, the semiconductor device including the memory cell 21 illustrated in FIG. 14A can have a structure that does not include the insulating layer 103a, the insulating layer 105a, the insulating layer 107a, the conductive layer 111a, the conductive layer 112a, the semiconductor layer 113a, the conductive layer 115a, and the insulating layer 131. In that case, the insulating layer 135, the conductive layer 141, and the conductive layer 143 can be in contact with the top surface of the insulating layer 101, for example.

### <Structure Example of Display Apparatus>

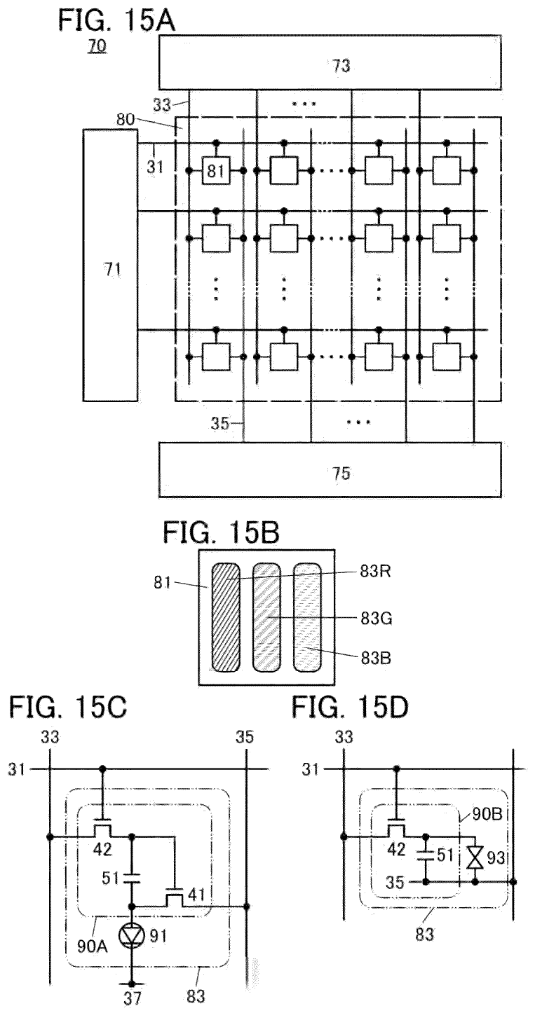

One embodiment of the present invention is applicable to a display apparatus. FIG. 15A is a block diagram illustrating a structure example of a display apparatus 70 that is the display apparatus of one embodiment of the present invention. The display apparatus 70 includes a display portion 80, a scan line driver circuit 71, a signal line driver circuit 73, and a power supply circuit 75. The display portion 80 includes a plurality of pixels 81 arranged in a matrix. Note that the power supply circuit 75 may be provided outside the display apparatus 70.

The scan line driver circuit 71 is electrically connected to the pixels 81 through the wirings 31. The wirings 31 extend in the row direction of the matrix, for example.

The signal line driver circuit 73 is electrically connected to the pixels 81 through the wirings 33. The wirings 33 extend in the column direction of the matrix, for example.

The power supply circuit 75 is electrically connected to the pixels 81 through the wirings 35. FIG. 15A illustrates an example in which the wirings 35 extend in the column direction of the matrix.

The pixel 81 includes a display element (also referred to as a display device), with which an image can be displayed on the display portion 80. As the display element, for example, a light-emitting element (also referred to as a light-emitting device) can be used, and specifically, an organic EL element can be used. As the display element, a liquid crystal element (also referred to as a liquid crystal device) can also be used.

The scan line driver circuit 71 has a function of selecting the pixel 81 to which image data is to be written on the row basis, for example. Specifically, the scan line driver circuit 71 can select the pixel 81 to which image data is to be written by outputting a signal to the wiring 31. Here, the scan line driver circuit 71 can select all the pixels 81 by, for example, outputting the signal to the wiring 31 in the first row, outputting the signal to the wiring 31 in the second row, and outputting the signals to the wirings 31 from the third row to the last row sequentially. Thus, the signal output from the scan line driver circuit 71 to the wiring 31 is a scan signal, and the wiring 31 provided in the display apparatus 70 can be referred to as a scan line.

The signal line driver circuit 73 has a function of generating image data. The image data is supplied to the pixel 81 through the wiring 33. For example, image data can be written to all the pixels 81 included in a row selected by the scan line driver circuit 71. Here, the image data can be represented as a signal (image signal). The wiring 33 provided in the display apparatus 70 can be referred to as a signal line.

The power supply circuit 75 has a function of generating a power supply potential and supplying it to the wiring 35. The power supply circuit 75 has a function of generating, for example, a high power supply potential (hereinafter, also simply referred to as “high potential” or “VDD”) and supplying it to the wiring 35. The power supply circuit 75 may have a function of generating a low power supply potential (hereinafter, also simply referred to as “low potential” or “VSS”). As described above, the wiring 35 functions as a power supply line.

FIG. 15B is a plan view illustrating a structure example of the pixel 81. The pixel 81 can include a plurality of subpixels 83. FIG. 15B illustrates an example in which the pixel 81 includes subpixels 83R, 83G, and 83B. Here, in the case where the pixel 81 includes a light-emitting element as the display element, for example, a planar shape of the subpixel illustrated in FIG. 15B corresponds to the planar shape of a light-emitting region of the light-emitting element. Although the subpixels 83R, 83G, and 83B have the same or substantially the same aperture ratio (also referred to as size or size of a light-emitting region) in FIG. 15B, one embodiment of the present invention is not limited thereto. The aperture ratio of each of the subpixels 83R, 83G, and 83B can be determined as appropriate. The subpixels 83R, 83G, and 83B may have different aperture ratios, or two or more of the subpixels 83R, 83G, and 83B may have the same or substantially the same aperture ratio.

The pixel 81 illustrated in FIG. 15B employs stripe arrangement as the arrangement method of the subpixels 83. Examples of the arrangement of the subpixels 83 include S-stripe arrangement, matrix arrangement, delta arrangement, Bayer arrangement, and PenTile arrangement.

The subpixels 83R, 83G, and 83B emit light of different colors. The subpixels 83R, 83G, and 83B can be of three colors of red (R), green (G), and blue (B) or of three colors of yellow (Y), cyan (C), and magenta (M), for example. Furthermore, four or more subpixels 83 may be provided in the pixel 81. For example, the pixel 81 may include subpixels of four colors of R, G, B, and white (W). In the display apparatus 70, the display portion 80 can display a full-color image by including, in the pixel 81, the plurality of subpixels 83 emitting light of different colors. For example, the pixel 81 may include subpixels of R, G, B, and infrared (IR) light.

Note that a sensor may be provided in the display portion 80, for example, in the pixel 81. For example, the display portion 80 may have a function of a fingerprint sensor. For example, the display portion 80 may have a function of an optical or ultrasonic fingerprint sensor.

FIG. 15C is a circuit diagram illustrating a structure example of the subpixel 83. The subpixel 83 illustrated in FIG. 15C includes a pixel circuit 90A and a light-emitting element 91.

The pixel circuit 90A includes the transistor 41, the transistor 42, and the capacitor 51. That is, the pixel circuit 90A is a 2Tr (transistor) 1C (capacitor) pixel circuit.

In the pixel circuit 90A, one of a source and a drain of the transistor 42 is electrically connected to the wiring 33. The other of the source and the drain of the transistor 42 is electrically connected to a gate of the transistor 41. The gate of the transistor 41 is electrically connected to one electrode of the capacitor 51. A gate of the transistor 42 is electrically connected to the wiring 31.

One of a source and a drain of the transistor 41 is electrically connected to the wiring 35. The other of the source and the drain of the transistor 41 is electrically connected to the other electrode of the capacitor 51. The other electrode of the capacitor 51 is electrically connected to one electrode of the light-emitting element 91. The other electrode of the light-emitting element 91 is electrically connected to the wiring 37. Here, the one electrode of the light-emitting element 91 is also referred to as a pixel electrode. The wiring 37 can be shared by all the subpixels 83, for example. Therefore, the other electrode of the light-emitting element 91 can also be referred to as a common electrode.

As described above, the wiring 31, the wiring 33, and the wiring 35 function as a scan line, a signal line, and a power supply line, respectively. The wiring 37 functions as a power supply line; for example, when the wiring 35 is supplied with a high power supply potential, the wiring 37 is supplied with a low power supply potential. The wiring 37 can be electrically connected to the power supply circuit 75, for example.

In the pixel circuit 90A, the transistor 42 has a function of a switch and is also referred to as a selection transistor. The transistor 42 has a function of controlling the conduction/non-conduction between the wiring 33 and the gate of the transistor 41 on the basis of the potential of the wiring 31. When the transistor 42 is turned on, image data is written to the pixel circuit 90A, and when the transistor 42 is turned off, the written image data is retained.

In the pixel circuit 90A, the transistor 41 has a function of controlling the amount of current flowing through the light-emitting element 91 and is also referred to as a driving transistor. The capacitor 51 has a function of retaining the gate potential of the transistor 41. The luminance of light emitted from the light-emitting element 91 is controlled in accordance with a potential that corresponds to image data and is supplied to the gate of the transistor 41. Specifically, in the case where the wiring 35 is supplied with a high power supply potential and the wiring 37 is supplied with a low power supply potential, the amount of current flowing from the wiring 35 to the wiring 37 is controlled in accordance with the gate potential of the transistor 41, whereby the luminance of light emitted from the light-emitting element 91 is controlled. Thus, the emission luminance of the light-emitting element 91 is controlled.

OS transistors are preferably used as the transistors 41 and 42. An OS transistor has much higher field-effect mobility than a transistor containing amorphous silicon, for example. Thus, by using OS transistors as the transistors 41 and 42, the display apparatus 70 can be driven at high speed.

An OS transistor has an extremely low off-state current as described above. Thus, by using an OS transistor as the transistor 42, charge accumulated in the capacitor 51 can be retained for a long period. Therefore, image data written to the subpixel 83 can be retained for a long period and therefore the frequency of the refresh operation (rewriting image data to the subpixel 83) can be reduced. Thus, power consumption of the display apparatus 70 can be reduced.

To increase the emission luminance of the light-emitting element 91, it is necessary to increase the amount of current flowing through the light-emitting element 91. To increase the current amount, it is necessary to increase the source-drain voltage of the transistor 41 that is a driving transistor. An OS transistor has a higher breakdown voltage between a source and a drain than a Si transistor; hence, a high voltage can be applied between the source and the drain of the OS transistor. Thus, with the use of an OS transistor as the transistor 41, the amount of current flowing through the light-emitting element 91 can be increased, resulting in an increase in emission luminance of the light-emitting element 91.

As the light-emitting element 91, an organic light-emitting diode (OLED) or a quantum-dot light-emitting diode (QLED) is preferably used, for example. Examples of a light-emitting substance contained in the light-emitting element 91 include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material). Alternatively, an LED such as a micro-LED can be used as the light-emitting element 91.

FIG. 15D is a circuit diagram illustrating a structure example of the subpixel 83. The subpixel 83 illustrated in FIG. 15D includes a pixel circuit 90B and a liquid crystal element 93.

The pixel circuit 90B includes the transistor 42 and the capacitor 51. That is, the pixel circuit 90B is a 1Tr1C pixel circuit.

In the pixel circuit 90B, one of the source and the drain of the transistor 42 is electrically connected to the wiring 33. The other of the source and the drain of the transistor 42 is electrically connected to one electrode of the capacitor 51. The one electrode of the capacitor 51 is electrically connected to one electrode of the liquid crystal element 93. The gate of the transistor 42 is electrically connected to the wiring 31. The other electrode of the capacitor 51 and the other electrode of the liquid crystal element 93 are electrically connected to the wiring 35. Here, the one electrode of the liquid crystal element 93 is also referred to as a pixel electrode. The other electrode of the liquid crystal element 93 may be referred to as a common electrode. In the pixel circuit 90B, a ground potential can be supplied to the wiring 35, for example.

In the pixel circuit 90B, the transistor 42 has a function of a switch and has a function of controlling the conduction/non-conduction between the wiring 33 and the one electrode of the liquid crystal element 93 on the basis of the potential of the wiring 33. When the transistor 42 is turned on, image data is written to the pixel circuit 90B, and when the transistor 42 is turned off, the written image data is retained.

The capacitor 51 has a function of retaining the potential of the one electrode of the liquid crystal element 93. The alignment state of the liquid crystal element 93 is controlled in accordance with a potential that corresponds to image data and is supplied to the one electrode of the liquid crystal element 93.

As examples of a mode of the liquid crystal element 93, any of the following modes can be given: a twisted nematic (TN) mode, a super twisted nematic (STN) mode, a vertical alignment (VA) mode, an axially symmetric aligned micro-cell (ASM) mode, an optically compensated birefringence (OCB) mode, a ferroelectric liquid crystal (FLC) mode, an antiferroelectric liquid crystal (AFLC) mode, a multi-domain vertical alignment (MVA) mode, a patterned vertical alignment (PVA) mode, an in-plane switching (IPS) mode, a fringe field switching (FFS) mode, and a transverse bend alignment (TBA) mode. Other examples of the mode include an electrically controlled birefringence (ECB) mode, a polymer dispersed liquid crystal (PDLC) mode, a polymer network liquid crystal (PNLC) mode, and a guest-host mode. Note that the present invention is not limited to these modes, and various modes can be employed.

### <Structure Example 2 of Semiconductor Device>

A structure example of the plurality of memory cells 21 is described below. Specifically, a structure example of the memory cells 21 in four rows and four columns is described with reference to plan views. Note that some reference numerals are omitted in the plan views in some cases.

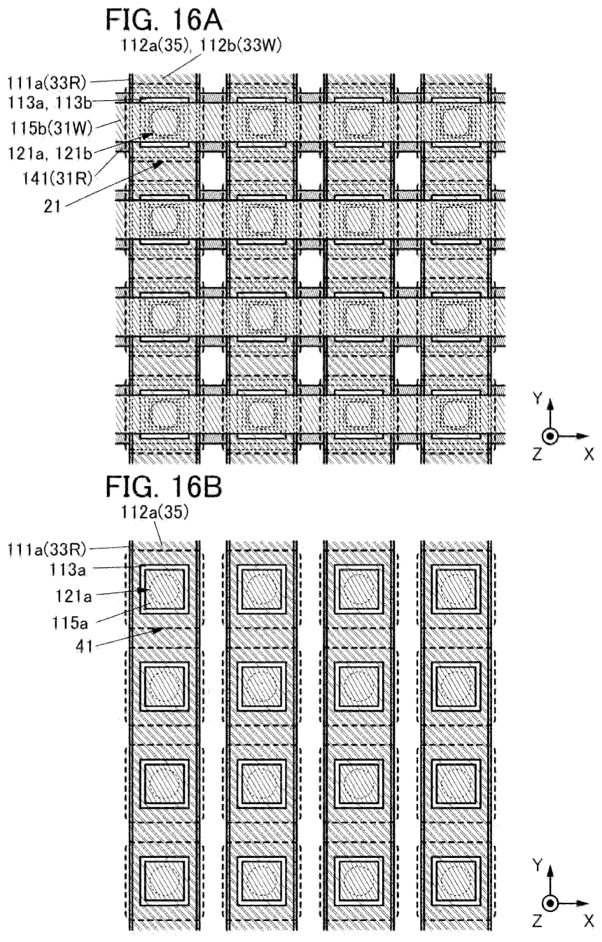

FIG. 16A is a plan view illustrating a structure example in which the memory cells 21 illustrated in FIG. 2A are arranged in a matrix. FIG. 16B is a plan view omitting the transistor 42 and the capacitor 51 from the structure illustrated in FIG. 16A.

As illustrated in FIGS. 16A and 16B, the conductive layer 111a functioning as the wiring 33R and the conductive layer 112a functioning as the wiring 35 each include a region extending in the Y direction and are shared by the memory cells 21 arranged in the Y direction. In other words, the memory cells 21 in one column share the same conductive layer 111a and the same conductive layer 112a. Thus, in reading data retained in the memory cell 21, a current can be prevented from flowing from the plurality of wirings 33R to one wiring 35 functioning as a power supply line. Accordingly, the amount of current flowing through the wiring 35 can be reduced. According to Ohm's law, the voltage drop ΔV of a wiring is a product of the wiring resistance R and the current I(ΔV=R×I). Thus, by reducing the amount of the current flowing through the wiring 35, a decrease in the potential supplied as a power supply potential particularly in the memory cell 21 at a long wiring distance from the power source circuit 15 illustrated in FIG. 1A, for example, can be inhibited. This can inhibit the data retained in the memory cell 21 from being incorrectly read, for example. Therefore, a memory cell and a semiconductor device which have high reading accuracy can be provided.

In the example illustrated in FIG. 16A, the conductive layer 115b functioning as the wiring 31W includes a region extending in the X direction and is shared by the memory cells 21 arranged in the X direction. That is, the memory cells 21 in the same row share the same conductive layer 115b. Moreover, the conductive layer 112b functioning as the wiring 33W includes a region extending in the Y direction and is shared by the memory cells 21 arranged in the Y direction. That is, the memory cells 21 in the same column share the same conductive layer 112b.

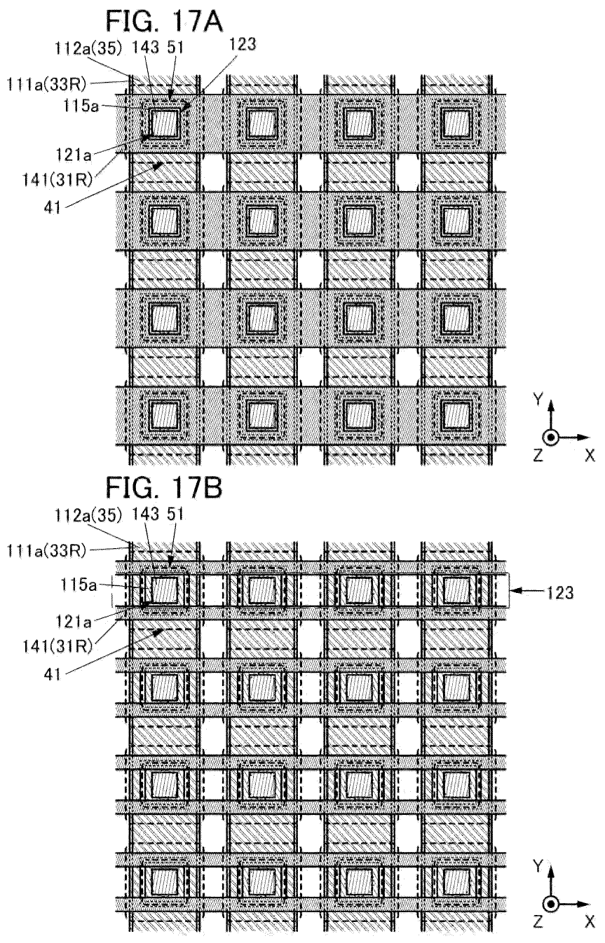

FIG. 17A is a plan view omitting the transistor 42 from the structure illustrated in FIG. 16A. In the example illustrated in the plan views of FIG. 16A and FIG. 17A, the conductive layer 141 functioning as the other electrode of the capacitor 51 covers the entire side surfaces of the conductive layer 143 functioning as the one electrode of the capacitor 51. The conductive layer 141 functioning as the wiring 31R includes a region extending in the X direction and is shared by the memory cells 21 arranged in the X direction. That is, the memory cells 21 in the same row share the same conductive layer 141.

FIG. 17B illustrates a modification example of the structure illustrated in FIG. 17A and illustrates an example in which the conductive layer 141 covers part of the conductive layer 143 in the plan view. Specifically, FIG. 17B illustrates an example in which the planar shape of the conductive layer 143 is quadrangular and the conductive layer 141 covers two sides (e.g., the upper and lower sides) of the conductive layer 143 and does not cover the remaining two sides (e.g., the left and right sides) of the conductive layer 143. In the example illustrated in FIG. 17B, the conductive layer 141 covering the top side of the conductive layer 143 and the conductive layer 141 covering the lower side of the conductive layer 143 provided in the memory cell 21 in the same row are electrically connected to each other in a region that is not illustrated in FIG. 17B. For example, these conductive layers 141 are electrically connected to each other outside the memory portion 20 illustrated in FIG. 1A. Thus, the conductive layers 141 can be regarded as one wiring 31R. It can be said that the opening portion 123 is provided between these conductive layers 141. For example, it can be said that one wiring 31R includes one opening portion 123 which overlaps with all the conductive layers 143 in the same row.

The capacitance of the capacitor 51 can be larger in the example illustrated in FIG. 17A than in the example illustrated in FIG. 17B. In contrast, in the example illustrated in FIG. 17B, the area of the opening portion 123 in the plan view can be larger than that in the example illustrated in FIG. 17A, so that the capacitor 51 can be easily formed.

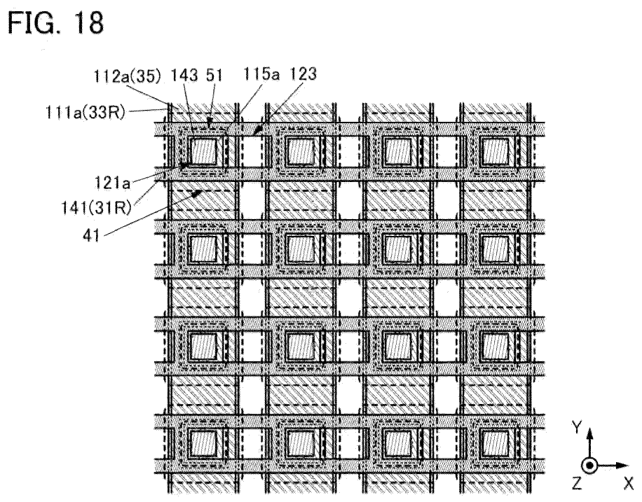

FIG. 18 illustrates a modification example of the structure illustrated in FIG. 17B and illustrates an example in which the planar shape of the conductive layer 143 is quadrangular and the conductive layer 141 covers three sides of the conductive layer 143. In the example illustrated in FIG. 18, the conductive layer 141 can include one opening portion 123 in one memory cell 21.

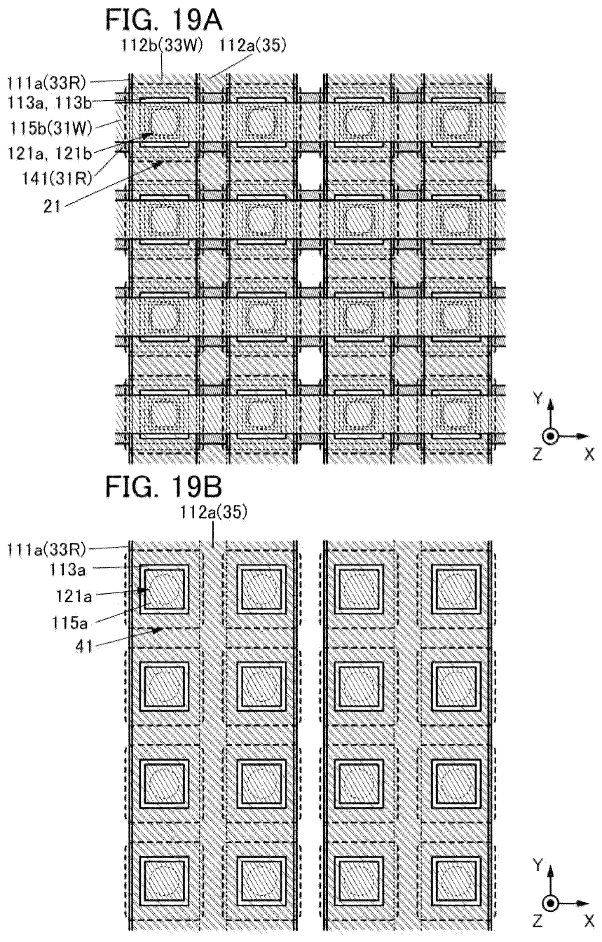

FIGS. 19A and 19B illustrate a modification example of the structure illustrated in FIGS. 16A and 16B, respectively, and illustrate an example in which the conductive layer 112a functioning as the wiring 35 is shared by the memory cells 21 in two adjacent columns. When the memory cells 21 in a plurality of columns share the conductive layer 112a, the memory cells 21 can be arranged at high density.

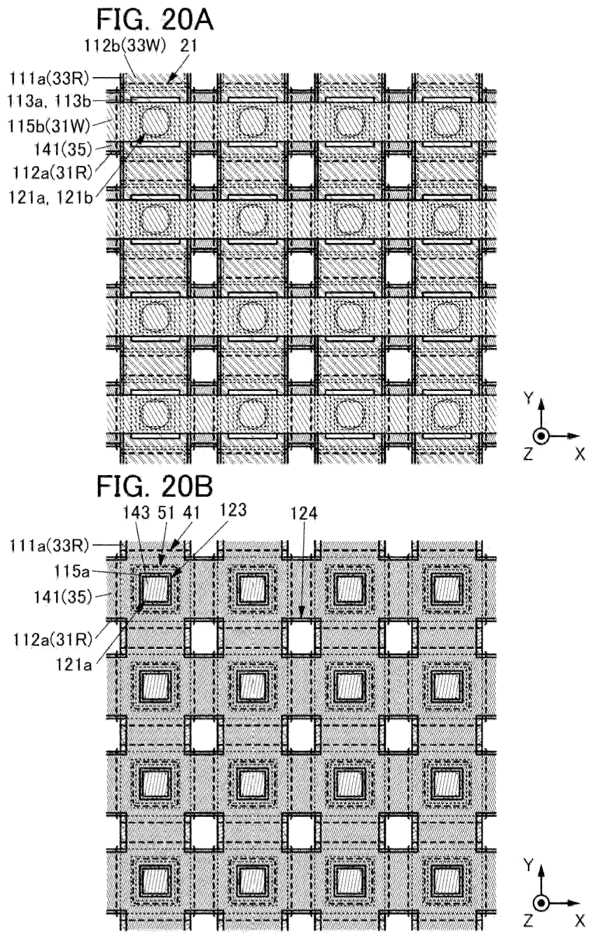

FIG. 20A is a plan view illustrating a structure example in which the memory cells 21 illustrated in FIG. 8A are arranged in a matrix. FIG. 20B is a plan view omitting the transistor 42 from the structure illustrated in FIG. 20A.

As illustrated in FIGS. 20A and 20B, the conductive layer 141 functions as the wiring 35 that is the power supply line and includes a region extending in the X direction and a region extending in the Y direction. In addition, the conductive layer 141 includes the opening portion 123 in a region where the region extending in the X direction and the region extending in the Y direction intersect with each other. When the conductive layer 141 has such a shape, the area of the conductive layer 141 in the plan view can be larger than that of the case where the conductive layer 141 does not include the region extending in the X direction or the region extending in the Y direction in the region illustrated in FIGS. 20A and 20B, for example; accordingly, the wiring resistance of the conductive layer 141 can be reduced. This can inhibit a voltage drop of the power supply potential supplied to the conductive layer 141, whereby a semiconductor device driven at high speed can be provided. Note that in the example illustrated in FIG. 20B, the conductive layer 141 includes an opening portion 124 surrounded by four memory cells.

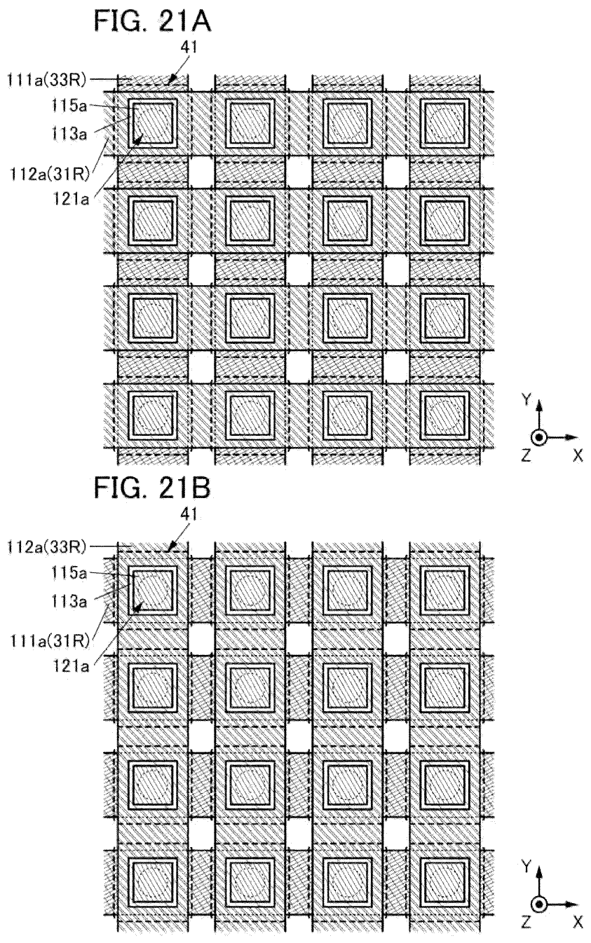

FIG. 21A is a plan view omitting the transistor 42 and the capacitor 51 from the structure illustrated in FIG. 20A. As illustrated in FIG. 20A and FIG. 21A, the conductive layer 115b functioning as the wiring 31W and the conductive layer 112a functioning as the wiring 31R each include a region extending in the X direction and are shared by the memory cells 21 arranged in the X direction. In other words, the memory cells 21 in the same row share the same conductive layer 115b and the same conductive layer 112a. As illustrated in FIG. 20A and FIG. 21A, the conductive layer 112b functioning as the wiring 33W and the conductive layer 111a functioning as the wiring 33R each include a region extending in the Y direction and are shared by the memory cells 21 arranged in the Y direction. In other words, the memory cells 21 in the same column share the same conductive layer 112b and the same conductive layer 111a.

FIG. 21B illustrates a modification example of the structure illustrated in FIG. 21A and illustrates an example in which the conductive layer 111a functions as the wiring 31R and the conductive layer 112a functions as the wiring 33R. In other words, FIG. 21B illustrates an example in which the function of the conductive layer 111a and the function of the conductive layer 112a in FIG. 21A are interchanged. In the example illustrated in FIG. 21B, the conductive layer 111a includes a region extending in the X direction and is shared by the memory cells 21 arranged in the X direction. That is, the memory cells 21 in the same row share the same conductive layer 111a. Moreover, the conductive layer 112a includes a region extending in the Y direction and is shared by the memory cells 21 arranged in the Y direction. That is, the memory cells 21 in the same column share the same conductive layer 112a. Note that in all the transistors 41 in this specification and the like, the function of the conductive layer 111a and the function of the conductive layer 112a can be interchanged.

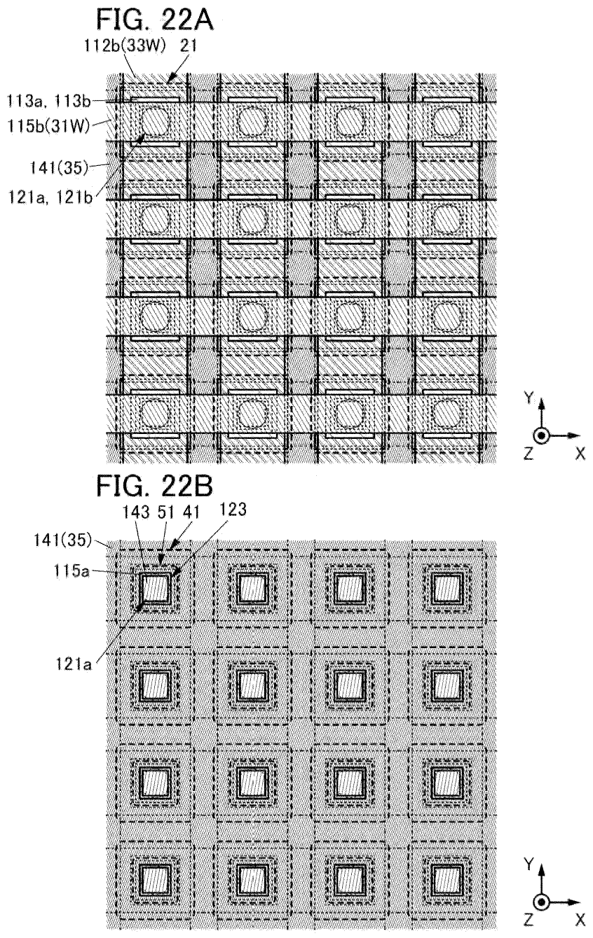

FIGS. 22A and 22B illustrate a modification example of the structure illustrated in FIGS. 20A and 20B, respectively, and illustrate an example in which the conductive layer 141 does not include the opening portion 124. In the example illustrated in FIGS. 22A and 22B, in the memory portion in which the memory cells 21 are arranged in a matrix, the shape of the conductive layer 141 can be quadrangular and the opening portion 123 can be provided in the quadrangular conductive layer 141.

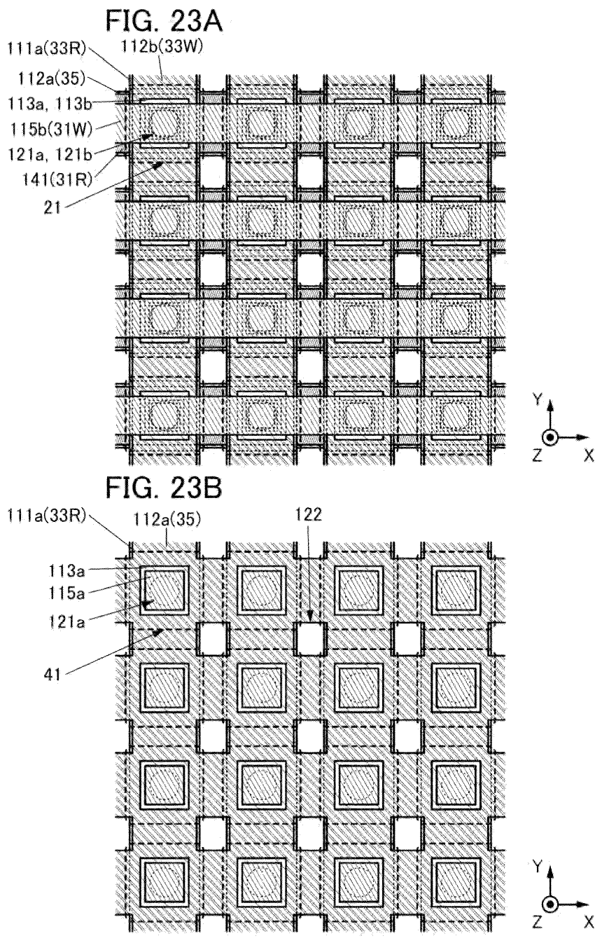

FIGS. 23A and 23B illustrate a modification example of the structure illustrated in FIGS. 16A and 16B, respectively, and the conductive layer 112a functioning as the wiring 35 that is the power supply line includes a region extending in the X direction and a region extending in the Y direction. The conductive layer 112a includes the opening portion 121a in a region where the region extending in the X direction and the region extending in the Y direction intersect with each other. With such a shape of the conductive layer 112a, the wiring resistance of the conductive layer 112a can be lower than that of the structure illustrated in FIGS. 16A and 16B, for example. In contrast, in the example illustrated in FIGS. 23A and 23B, for example, the conductive layers 112a included in all the memory cells 21 are electrically connected to each other. Thus, in reading data retained in the memory cell 21, a current flows from all the wirings 33R toward one conductive layer 112a, for example. Note that in the example illustrated in FIG. 23B, the conductive layer 112a includes an opening portion 122 surrounded by four memory cells 21.

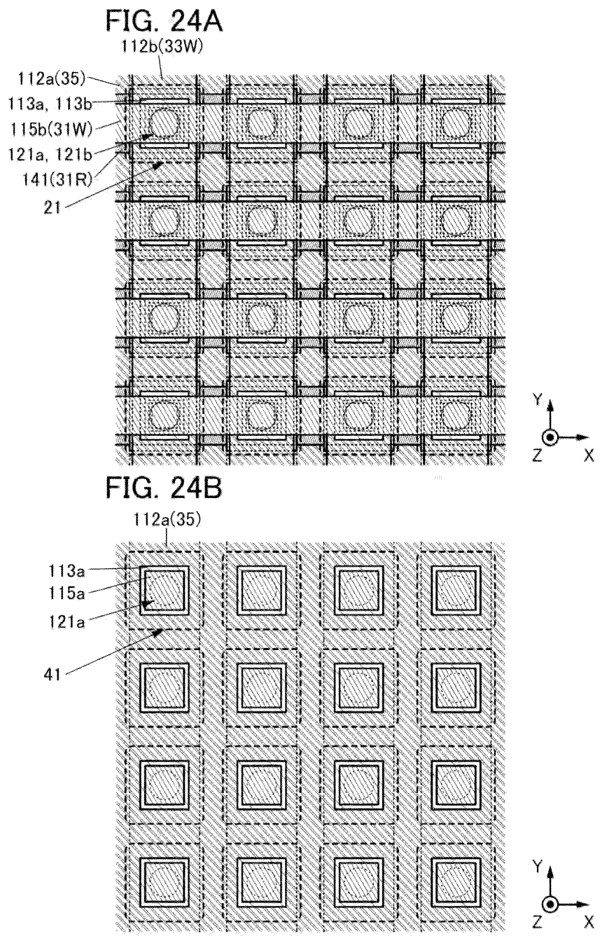

FIGS. 24A and 24B illustrate a modification example of the structure illustrated in FIGS. 23A and 23B, respectively, and illustrate an example in which the conductive layer 112a does not include the opening portion 122. In the example illustrated in FIGS. 24A and 24B, in the memory portion in which the memory cells 21 are arranged in a matrix, the shape of the conductive layer 112a can be quadrangular and the opening portion 121a can be provided in the quadrangular conductive layer 112a.

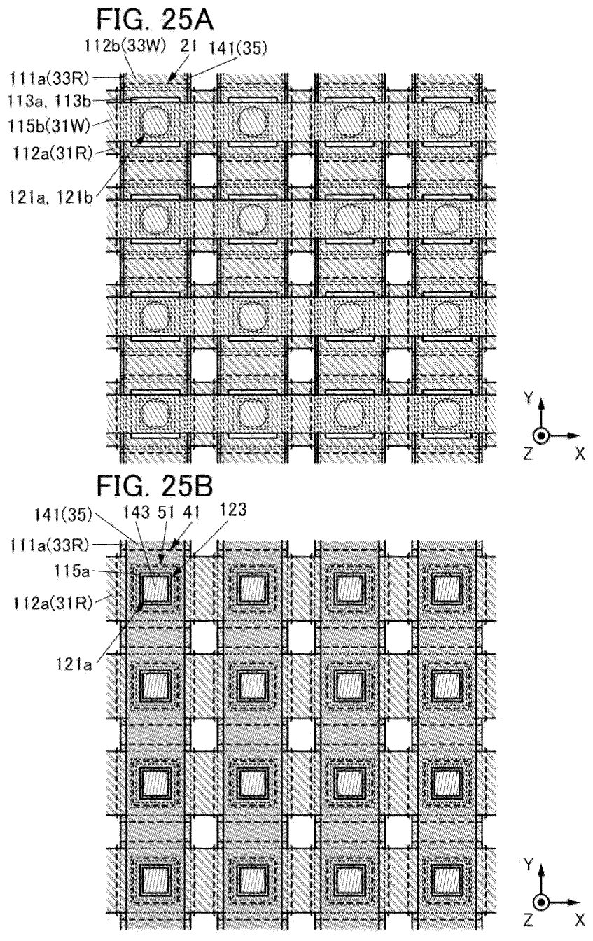

FIGS. 25A and 25B illustrate a modification example of the structure illustrated in FIGS. 20A and 20B, respectively, and illustrate an example in which the conductive layer 141 does not include the region extending in the X direction in the region illustrated in FIGS. 25A and 25B. In the example illustrated in FIGS. 25A and 25B, the conductive layer 141 includes a region extending in the Y direction and is shared by the memory cells 21 arranged in the Y direction. That is, the memory cells 21 in the same column share the same conductive layer 141.

In the example illustrated in FIGS. 25A and 25B, the area where the conductive layer 141 overlaps with another conductive layer can be smaller than that in the example illustrated in FIGS. 20A and 20B. Accordingly, noise due to the conductive layer 141 can be reduced.

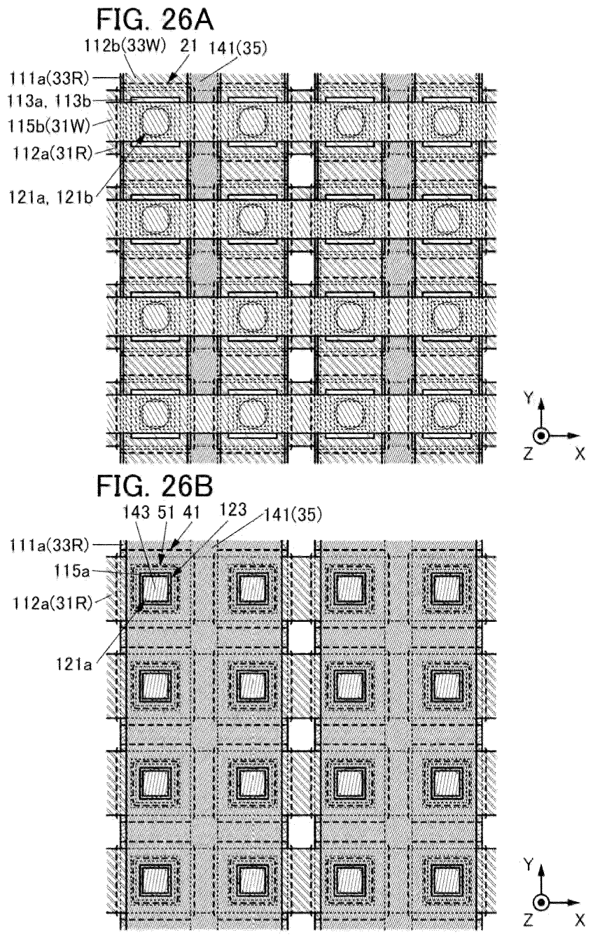

FIGS. 26A and 26B illustrate a modification example of the structure illustrated in FIGS. 25A and 25B, respectively, and illustrate an example in which the conductive layer 141 is shared by the memory cells 21 in two adjacent columns.

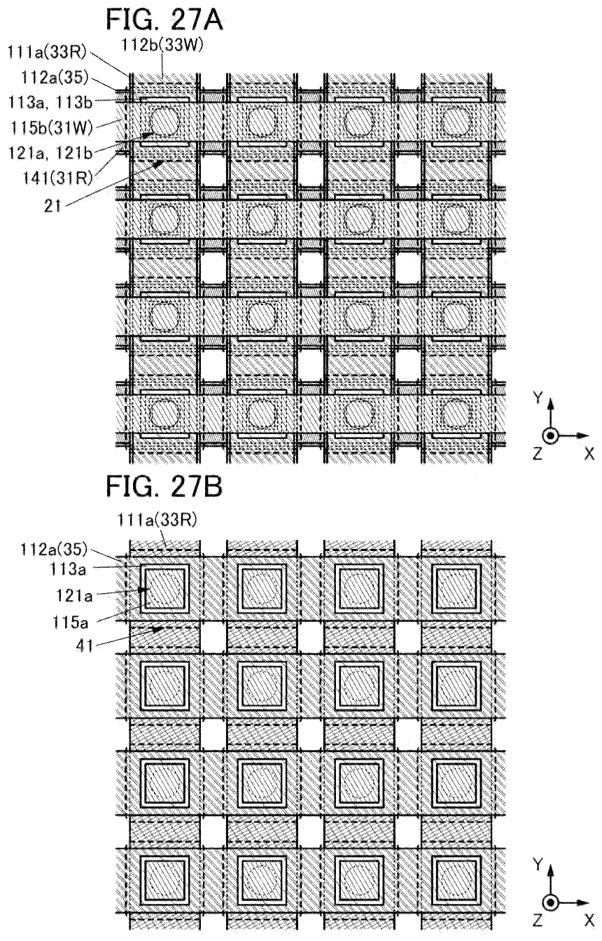

FIGS. 27A and 27B illustrate a modification example of the structure illustrated in FIGS. 16A and 16B, respectively, and illustrate an example in which the conductive layer 112a functioning as the wiring 35 includes a region extending in the X direction and is shared by the memory cells 21 arranged in the X direction. That is, in the example illustrated in FIGS. 27A and 27B, the memory cells 21 in the same row share the same conductive layer 112a.

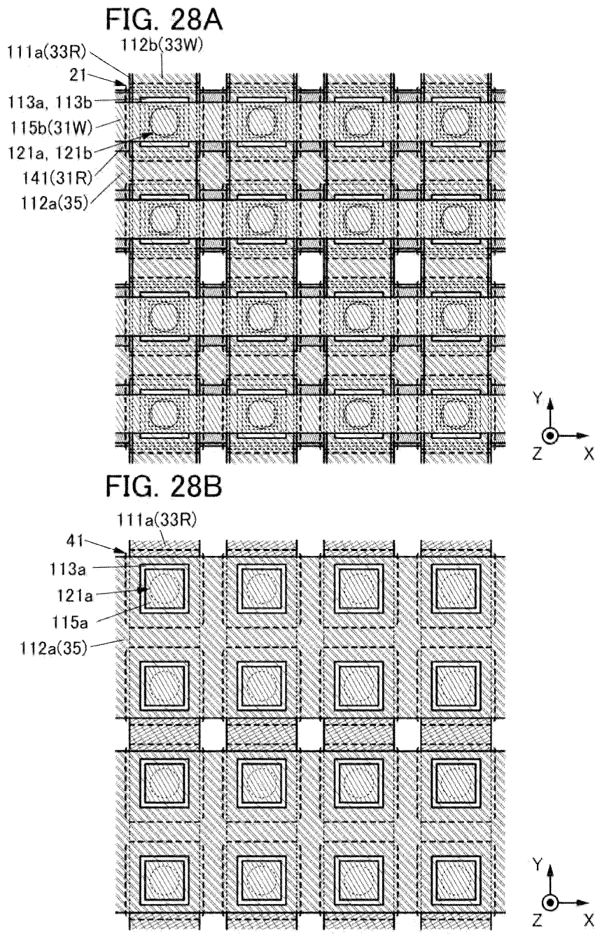

FIGS. 28A and 28B illustrate a modification example of the structure illustrated in FIGS. 27A and 27B, respectively, and illustrate an example in which the conductive layer 112a is shared by the memory cells 21 in two adjacent rows. When the memory cells 21 in a plurality of rows share the conductive layer 112a, the memory cells 21 can be arranged at high density.

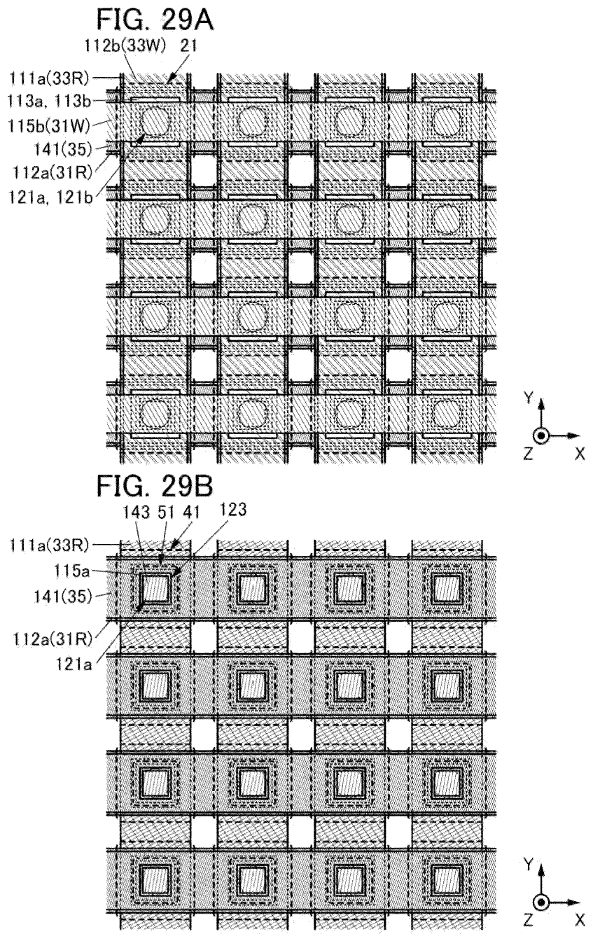

FIGS. 29A and 29B illustrate a modification example of the structure illustrated in FIGS. 25A and 25B, respectively, and illustrate an example in which the conductive layer 141 functioning as the wiring 35 includes a region extending in the X direction and is shared by the memory cells 21 arranged in the X direction. That is, in the example illustrated in FIGS. 29A and 29B, the memory cells 21 in the same row share the same wiring 35.

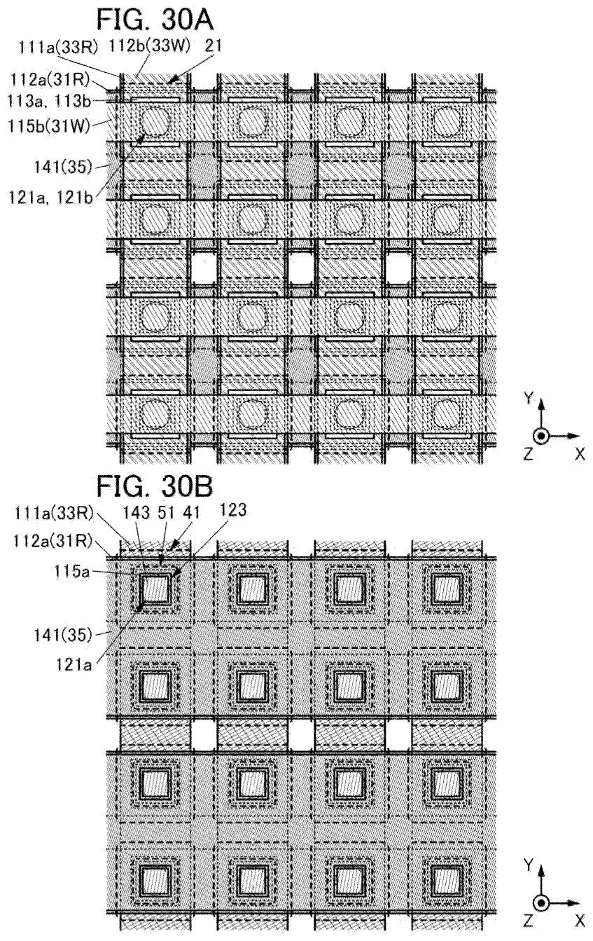

FIGS. 30A and 30B illustrate a modification example of the structure illustrated in FIGS. 29A and 29B, respectively, and illustrate an example in which the conductive layer 141 is shared by the memory cells 21 in two adjacent rows.

Among the above-described structures illustrated in FIG. 16A to FIG. 30B, the structures illustrated in FIG. 16A to FIG. 19B, FIG. 23A to FIG. 24B, and FIG. 27A to FIG. 28B can be applied to the memory cells 21 illustrated in FIG. 1B1 and FIGS. 2A to 2C, for example. The structures illustrated in FIG. 20A to FIG. 22B, FIG. 25A to FIG. 26B, and FIG. 29A to FIG. 30B can be applied to the memory cells 21 illustrated in FIG. 1B2 and FIGS. 8A to 8C, for example. At least part of the structures illustrated in FIG. 16A to FIG. 19B, FIG. 23A to FIG. 24B, and FIG. 27A to FIG. 28B can be applied to the memory cells 21 illustrated in FIG. 1B2 and FIGS. 8A to 8C, for example. At least part of the structures illustrated in FIG. 20A to FIG. 22B, FIG. 25A to FIG. 26B, and FIG. 29A to FIG. 30B can be applied to the memory cells 21 illustrated in FIG. 1B1 and FIGS. 2A to 2C, for example. Furthermore, at least part of the structures illustrated in FIG. 16A to FIG. 30B can be applied to the structures illustrated in FIG. 12B and FIGS. 13A to 13C, for example, and the structure illustrated in FIGS. 14A to 14D.

### <Structure Example 3 of Semiconductor Device>

A structure of the memory cell 21 different from that in FIGS. 2A to 2C is described below. The structure described below can be applied to the memory cell 21 illustrated in FIG. 1B1. Furthermore, at least part of the structure described below can be applied to the memory cells 21 illustrated in FIG. 1B2, FIG. 12B, and FIG. 14A.

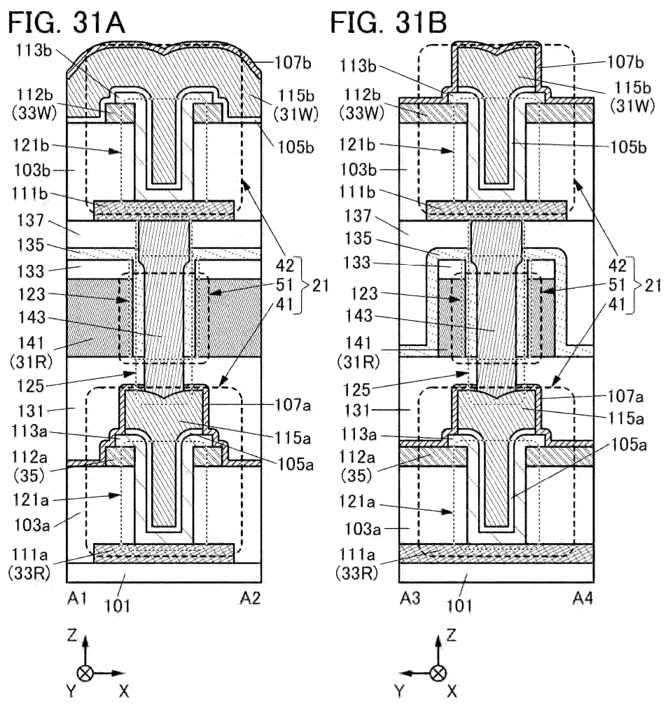

FIGS. 31A and 31B illustrate a modification example of the structure illustrated in FIGS. 2B and 2C, respectively, and illustrate an example in which an upper end portion of the insulating layer 105a is aligned or substantially aligned with a lower end portion of the conductive layer 115a and an upper end portion of the insulating layer 105b is aligned or substantially aligned with a lower end portion of the conductive layer 115b. For example, in the case where the conductive layer 115 is formed by a photolithography method and an etching method and the insulating layer 105 has low etching selectivity with respect to the conductive layer 115, the structure illustrated in FIGS. 31A and 31B may be formed.

In this specification and the like, an upper end portion refers to the uppermost portion of a side end portion, and a lower end portion refers to the lowermost portion of a side end portion. That is, the upper end portion and the lower end portion are each a part of the side end portion.

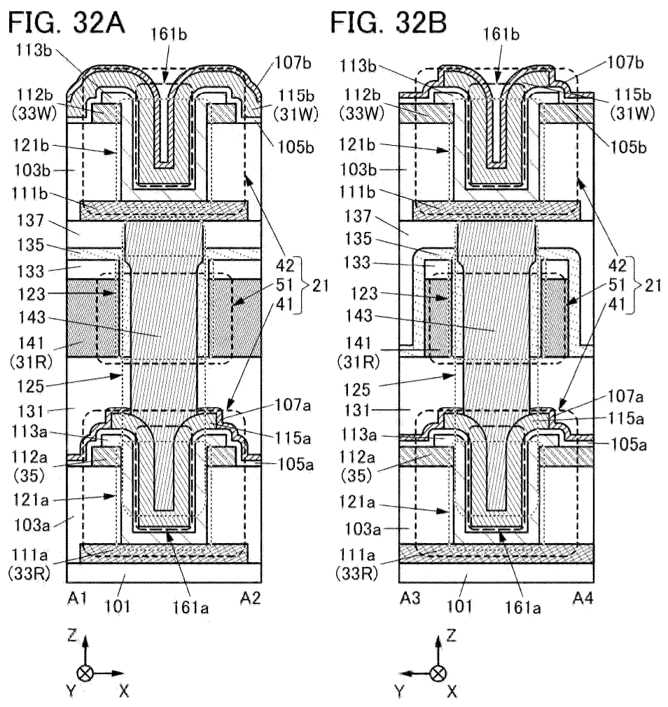

Although FIGS. 2B and 2C and the like illustrate an example in which the conductive layer 115a is provided so as to fill the opening portion 121a and the conductive layer 115b is provided so as to fill the opening portion 121b, one embodiment of the present invention is not limited thereto. FIGS. 32A and 32B illustrate an example in which the conductive layer 115a includes a depressed portion 161a inside the opening portion 121a, and the conductive layer 115b includes a depressed portion 161b inside the opening portion 121b. FIG. 32A is a cross-sectional view along the X-Z plane, and FIG. 32B is a cross-sectional view along the Y-Z plane. FIG. 2A can be referred to for the plan view.

In the case where the ratio between the thickness of the conductive layer 115 and the diameter of the opening portion 121 is small, that is, where the thickness of the conductive layer 115 with respect to the diameter of the opening portion 121 is small, the conductive layer 115a may include the depressed portion 161a and the conductive layer 115b may include the depressed portion 161b as illustrated in FIGS. 32A and 32B. Note that in this specification and the like, the depressed portion 161a and the depressed portion 161b are collectively referred to as a depressed portion 161.

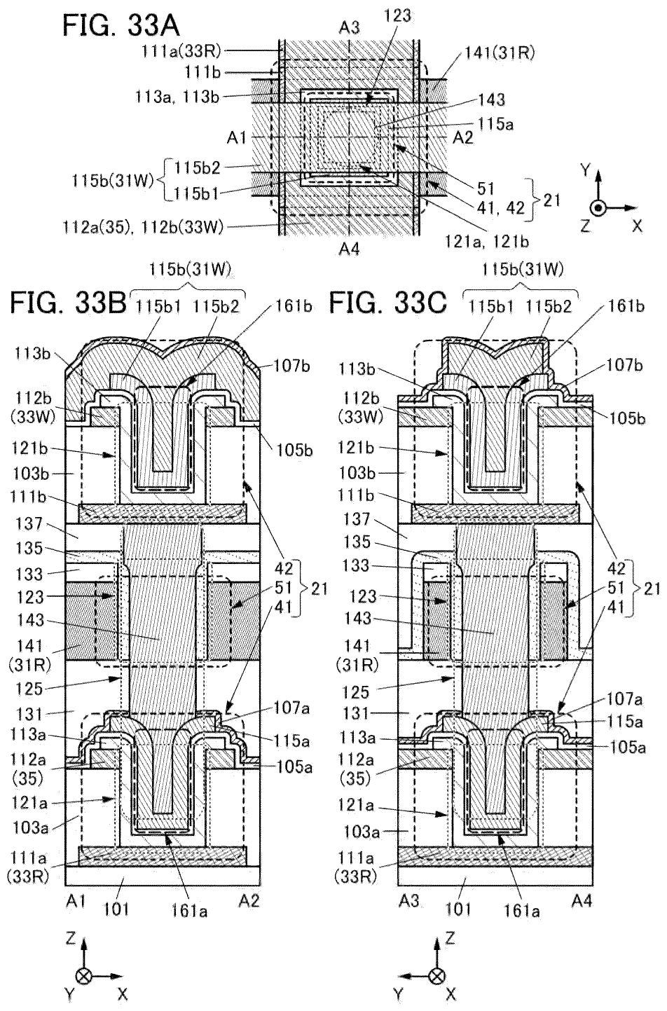

FIGS. 33A to 33C illustrate an example in which the conductive layer 115 includes the depressed portion 161 inside the opening portion 121 and the conductive layer 115b includes a conductive layer 115b1 and a conductive layer 115b2 over the conductive layer 115b1 and the insulating layer 105b. In this example illustrated in FIGS. 33A to 33C, at least part of a side end portion of the conductive layer 115b1 and at least part of a side end portion of the conductive layer 115b2 are not aligned with each other. Although the conductive layer 115b2 covers a side surface of the conductive layer 115b1 in the X-Z plane and the conductive layer 115b2 does not cover a side surface of the conductive layer 115b1 in the Y-Z plane in the example illustrated in FIGS. 33A to 33C, one embodiment of the present invention is not limited thereto. For example, the conductive layer 115b2 may cover the side surface of the conductive layer 115b1 also in the Y-Z plane. In that case, the conductive layer 115b2 can cover all the side surfaces of the conductive layer 115b1.

In the example illustrated in FIGS. 33A to 33C, the conductive layer 115b1 can be provided in the vicinity of the semiconductor layer 113b and the conductive layer 115b2 can be provided in the other region, for example. In that case, for the conductive layer 115b1, a conductive material that is not easily oxidized, a conductive material having a function of inhibiting diffusion of oxygen, or the like, such as a conductive material containing nitrogen (e.g., titanium nitride or tantalum nitride) or a conductive material containing oxygen (e.g., ruthenium oxide), can be used, for example. For the conductive layer 115b1, a semiconductor having high electrical conductivity, typified by polycrystalline silicon containing an impurity element such as phosphorus, or silicide such as nickel silicide may be used. In the above-described manner, the conductive layer 115b can be inhibited from absorbing oxygen contained in the semiconductor layer 113b. For the conductive layer 115b2, a metal material having lower resistance than the material used for the conductive layer 115b1, such as tungsten, aluminum, or copper, can be used.

An example of a method for forming the conductive layer 115b illustrated in FIGS. 33A to 33C is described. First, a conductive film to be the conductive layer 115b1 is formed, and then a pattern is formed by a photolithography method and the conductive film is processed by an etching method using the pattern. Thus, the conductive layer 115b1 is formed. Next, a conductive film to be the conductive layer 115b2 is formed, and then a pattern is formed by a photolithography method and the conductive film is processed by an etching method using the pattern. Thus, the conductive layer 115b2 is formed. In the above-described manner, the conductive layer 115b including the conductive layer 115b1 and the conductive layer 115b2 can be formed.

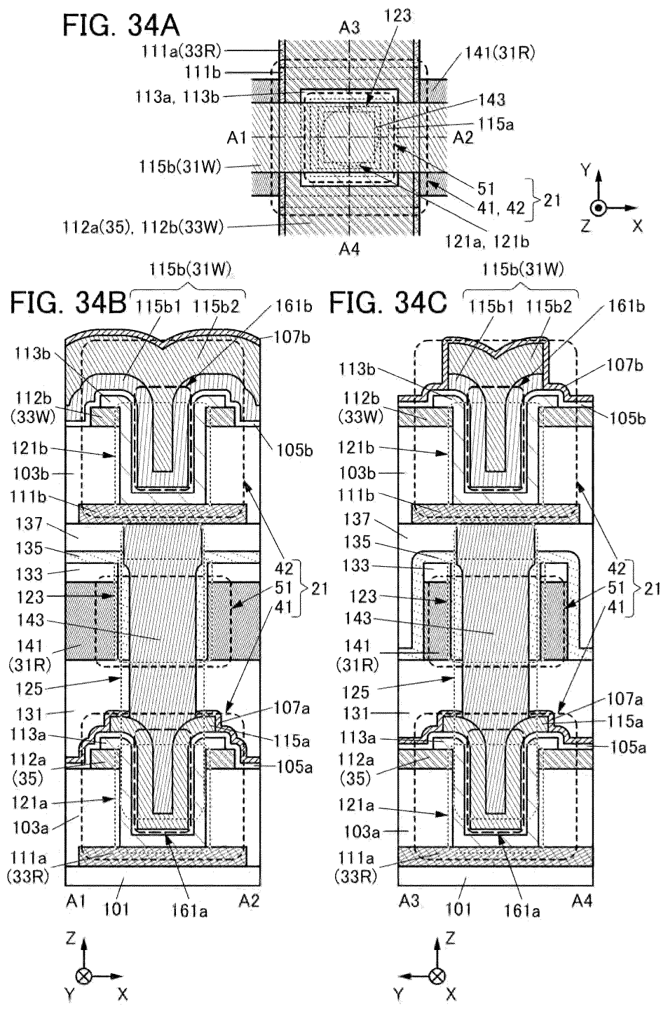

FIGS. 34A, 34B, and 34C illustrate a modification example of the structure illustrated in FIGS. 33A, 33B, and 33C, respectively, and illustrate an example in which an upper end portion of the conductive layer 115b1 and a lower end portion of the conductive layer 115b2 are aligned or substantially aligned with each other. The conductive layer 115b1 and the conductive layer 115b2 can be formed in the following manner: after the conductive film to be the conductive layer 115b1 and the conductive film to be the conductive layer 115b2 thereover are formed, a pattern is formed by a photolithography method and these conductive films are processed by an etching method using the pattern.

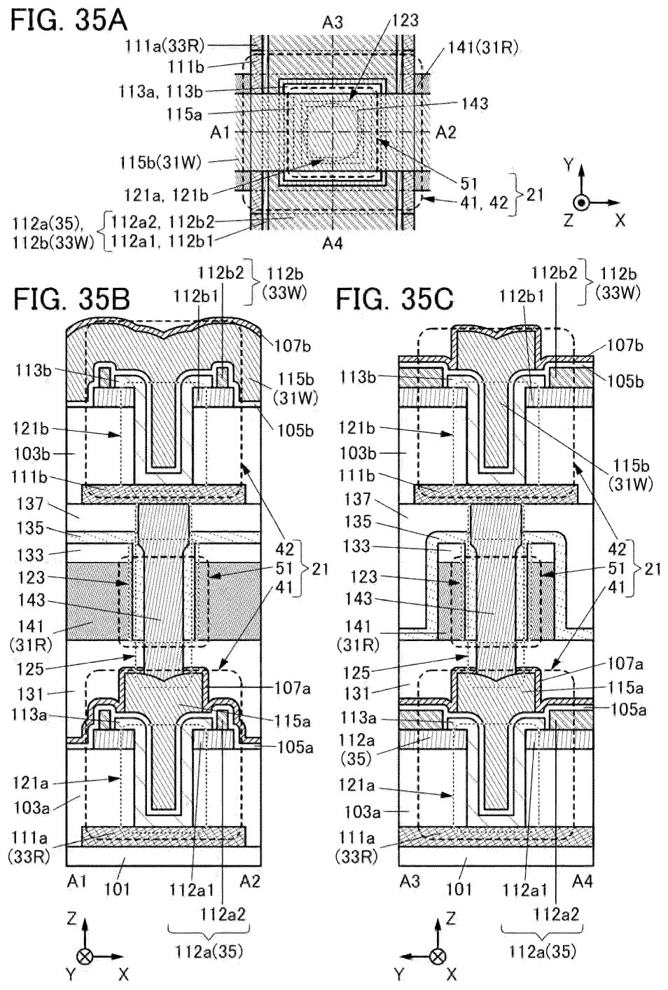

FIGS. 35A to 35C illustrate an example in which the conductive layer 112a includes a conductive layer 112a1 and a conductive layer 112a2 over the conductive layer 112a1. In addition, FIGS. 35A to 35C illustrate an example in which the conductive layer 112b includes a conductive layer 112b1 and a conductive layer 112b2 over the conductive layer 112b1. Here, in the example illustrated in FIGS. 35A to 35C, at least part of a side end portion of the conductive layer 112a1 and at least part of a side end portion of the conductive layer 112a2 are not aligned with each other, and at least part of a side end portion of the conductive layer 112b1 and at least part of a side end portion of the conductive layer 112b2 are not aligned with each other. Although FIGS. 35A to 35C illustrate an example in which the conductive layer 112a2 does not cover a side surface of the conductive layer 112a1 and the conductive layer 112b2 does not cover a side surface of the conductive layer 112b1, one embodiment of the present invention is not limited thereto. For example, the conductive layer 112a2 may cover a side surface of the conductive layer 112a1 on the side opposite to the opening portion 121a, and the conductive layer 112b2 may cover a side surface of the conductive layer 112b1 on the side opposite to the opening portion 121b.

In the example illustrated in FIGS. 35A to 35C, the conductive layer 112a1 can be provided so as to include a region in contact with the semiconductor layer 113a, and the conductive layer 112a2 can be provided so as not to be in contact with the semiconductor layer 113a, for example. Furthermore, the conductive layer 112b1 can be provided so as to include a region in contact with the semiconductor layer 113b, and the conductive layer 112b2 can be provided so as not to be in contact with the semiconductor layer 113b, for example. In that case, for the conductive layer 112a1 and the conductive layer 112b1, a conductive material that is not easily oxidized, a conductive material having a function of inhibiting diffusion of oxygen, or the like, such as a conductive material containing nitrogen (e.g., titanium nitride or tantalum nitride) or a conductive material containing oxygen (e.g., ruthenium oxide), can be used, for example. For the conductive layer 112a1 and the conductive layer 112b1, a semiconductor having high electrical conductivity, typified by polycrystalline silicon containing an impurity element such as phosphorus, or silicide such as nickel silicide may be used. In the above-described manner, the conductive layer 112a can be inhibited from absorbing oxygen contained in the semiconductor layer 113a. In addition, the conductive layer 112b can be inhibited from absorbing oxygen contained in the semiconductor layer 113b. For the conductive layer 112a2 and the conductive layer 112b2, a metal material having lower resistance than the material used for the conductive layer 112a1 and the conductive layer 112b1, such as tungsten, aluminum, or copper, can be used.

An example of a method for forming the conductive layer 112a and the conductive layer 112b illustrated in FIGS. 35A to 35C is described. To form the conductive layer 112a illustrated in FIGS. 35A to 35C, first, a conductive film to be the conductive layer 112a1 is formed, and then a pattern is formed by a photolithography method and the conductive film is processed by an etching method using the pattern. Thus, the conductive layer 112a1 is formed. Next, a conductive film to be the conductive layer 112a2 is formed, and then a pattern is formed by a photolithography method and the conductive film is processed by an etching method using the pattern. Thus, the conductive layer 112a2 is formed. In the above-described manner, the conductive layer 112a including the conductive layer 112a1 and the conductive layer 112a2 can be formed. The conductive layer 112b including the conductive layer 112b1 and the conductive layer 112b2 can be formed by a method similar to that for the conductive layer 112a.

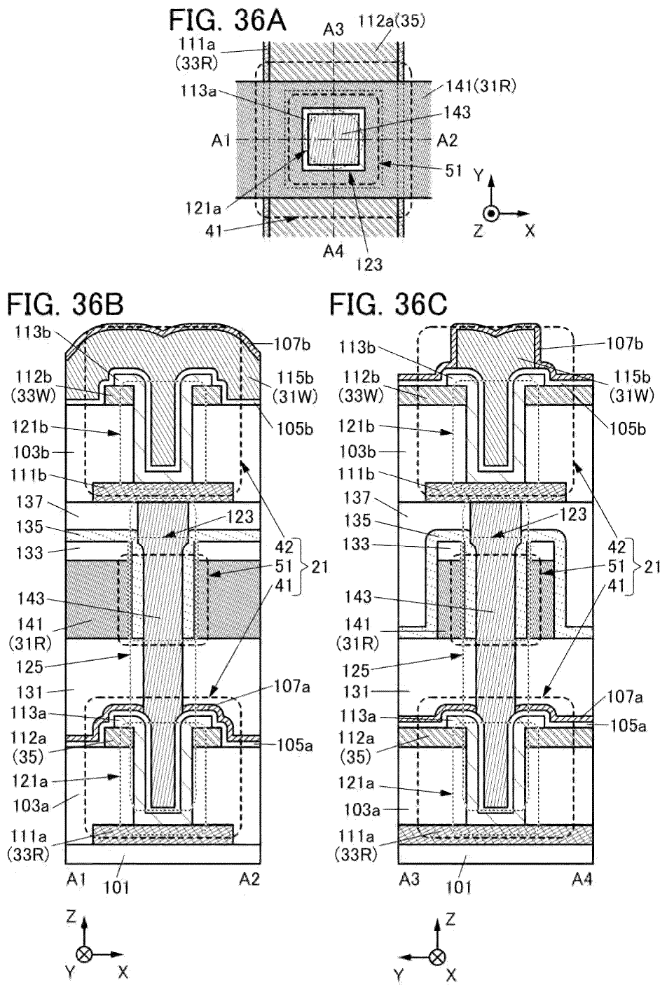

FIGS. 36A to 36C illustrate an example in which the transistor 41 does not include the conductive layer 115a. FIG. 36A is a plan view illustrating structure examples of the transistor 41 and the capacitor 51. FIG. 36B is a cross-sectional view taken along dashed-dotted line A1-A2 in FIG. 36A. FIG. 36C is a cross-sectional view taken along dashed-dotted line A3-A4 in FIG. 36A.

In the example illustrated in FIGS. 36A to 36C, the conductive layer 143 functions as the gate electrode of the transistor 41. That is, the conductive layer 143 functions as both the one electrode of the capacitor 51 and the gate electrode of the transistor 41. As illustrated in FIGS. 36B and 36C, the conductive layer 143 can include, inside the opening portion 121a, a region in contact with a top surface of a depressed portion of the insulating layer 105a and a region in contact with a side surface of the insulating layer 105a, for example.

In the example illustrated in FIGS. 36A to 36C, the etching selectivity of the insulating layer 107a to the insulating layer 105a is preferably high. This can inhibit the insulating layer 105a from being reduced in thickness when the opening portion 125 is formed in the insulating layer 107a. Thus, a short circuit between the semiconductor layer 113a and the conductive layer 143 can be inhibited, for example.

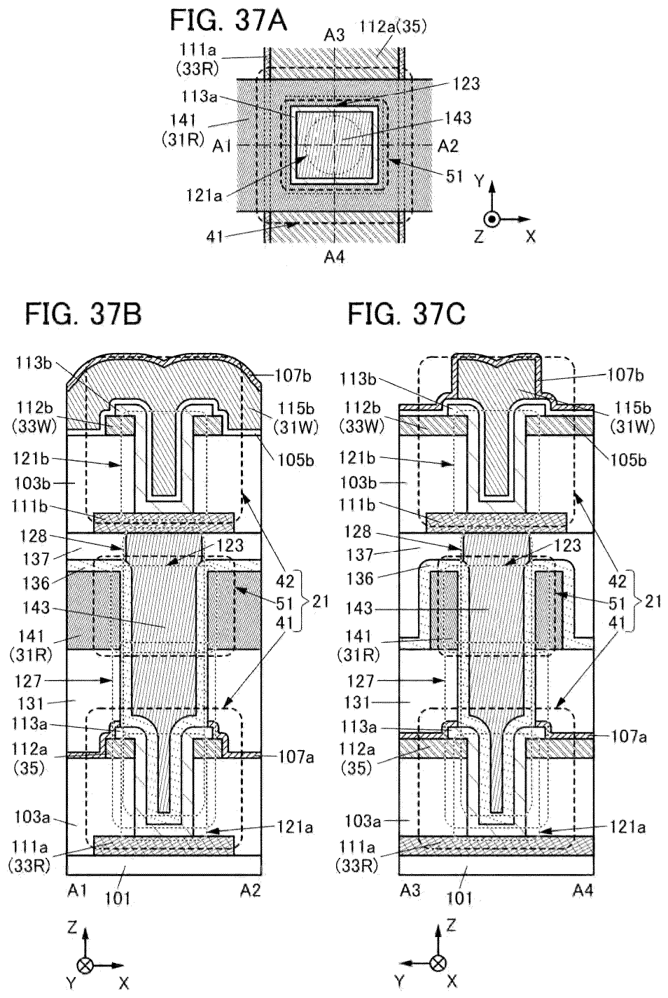

FIGS. 37A, 37B, and 37C illustrate a modification example of the structure illustrated in FIGS. 36A, 36B, and 36C, respectively, and illustrate an example in which the transistor 41 does not include the insulating layer 105a and the capacitor 51 does not include the insulating layer 135. In the example illustrated in FIGS. 37A to 37C, the insulating layer 133 is not provided over the conductive layer 141.

In the example illustrated in FIGS. 37A to 37C, an insulating layer 136 functions as the gate insulating layer of the transistor 41 and the dielectric layer of the capacitor 51. The insulating layer 136 is provided so as to cover the depressed portion of the semiconductor layer 113a, the side surface of the insulating layer 107a, the side surface of the insulating layer 131, and a top surface and the side surface of the conductive layer 141. For example, the insulating layer 136 can include a region in contact with the top surface of the semiconductor layer 113a, a region in contact with a side surface of the depressed portion of the semiconductor layer 113a, a region in contact with the side surface of the insulating layer 107a, a region in contact with the side surface of the insulating layer 131, a region in contact with the top surface the conductive layer 141, and a region in contact with the side surface of the conductive layer 141. For the insulating layer 136, a material similar to the material that can be used for the insulating layer 105 can be used, for example.

In the example illustrated in FIGS. 37A to 37C, an opening portion 127 reaching the semiconductor layer 113a is provided in the insulating layer 107a and the insulating layer 131. Furthermore, an opening portion 128 reaching the insulating layer 136 is provided in the insulating layer 137. In the example illustrated in FIGS. 37A to 37C, the opening portion 123 is provided over the opening portion 127. The opening portion 128 includes a region positioned inside the opening portion 123. Furthermore, the opening portion 127 and the opening portion 128 each include a region positioned inside the opening portion 121a.

The bottom of the opening portion 127 includes the top surface of the depressed portion of the semiconductor layer 113a. A sidewall of the opening portion 127 includes the side surface of the insulating layer 107a and the side surface of the insulating layer 131. The opening portion 127 includes an opening portion included in the insulating layer 107a and an opening portion included in the insulating layer 131. In other words, the opening portion of the insulating layer 107a and the opening portion of the insulating layer 131 which are provided in a region overlapping with the semiconductor layer 113a are each part of the opening portion 127. The shape and the size of the opening portion 127 in the plan view may differ from layer to layer. When the shape of the opening portion 127 is circular in the plan view, the opening portions included in the layers may or may not be concentric with each other.

The conductive layer 143 is provided so as to include a region positioned inside the opening portion 121a, the opening portion 123, the opening portion 127, and the opening portion 128. For example, the conductive layer 143 is provided so as to fill the opening portion 128. Since the opening portion 128 includes the region positioned inside the opening portion 121a and the conductive layer 143 is provided so as to include the region positioned inside the opening portion 128, the conductive layer 143 includes a region positioned inside the opening portion 121a.

In the example illustrated in FIGS. 37A to 37C, the etching selectivity of the insulating layer 137 to the insulating layer 136 is preferably high. This can inhibit the insulating layer 136 from being reduced in thickness when the opening portion 128 is formed in the insulating layer 137. For example, the insulating layer 136 inside the opening portion 121a can be inhibited from being reduced in thickness. Thus, a short circuit between the semiconductor layer 113a and the conductive layer 143 can be inhibited, for example.

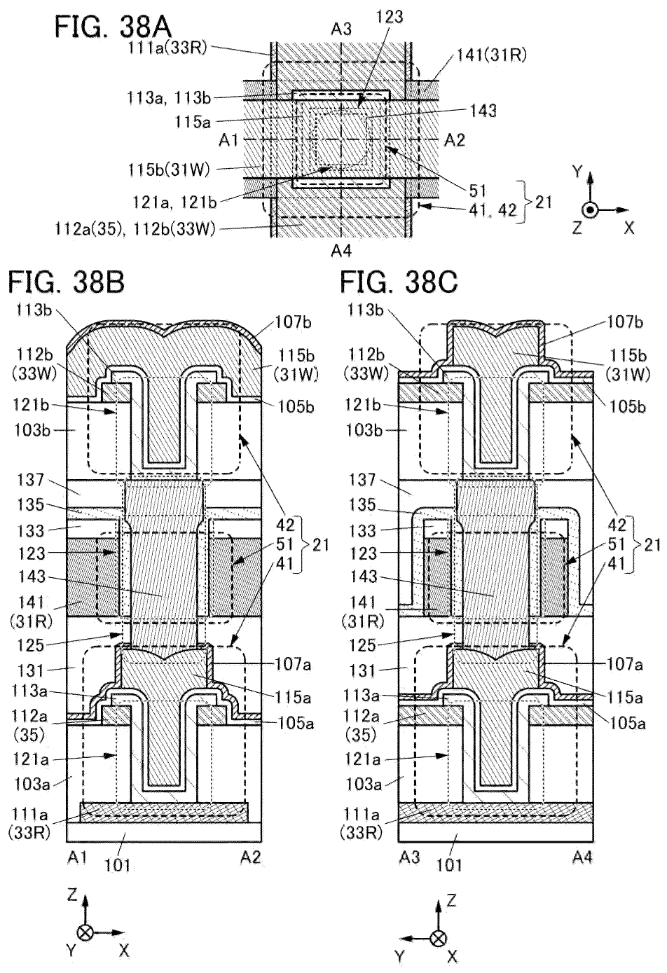

FIGS. 38A to 38C illustrate an example in which the transistor 42 does not include the conductive layer 111b. FIG. 38A is a plan view, FIG. 38B is a cross-sectional view taken along dashed-dotted line A1-A2 in FIG. 38A, and FIG. 38C is a cross-sectional view taken along dashed-dotted line A3-A4 in FIG. 38A.

In the example illustrated in FIGS. 38A to 38C, the conductive layer 143 functions as the one of the source electrode and the drain electrode of the transistor 42. That is, the conductive layer 143 functions as both the one electrode of the capacitor 51 and the one of the source electrode and the drain electrode of the transistor 42. As illustrated in FIGS. 38B and 38C, the top surface of the conductive layer 143 can include a region in contact with a bottom surface of the semiconductor layer 113b, for example. In the case where the conductive layer 111b is not provided over the conductive layer 143, the manufacturing process of the semiconductor device can be simplified. In contrast, in the case where the conductive layer 111b is provided over the conductive layer 143, layout flexibility can be increased.

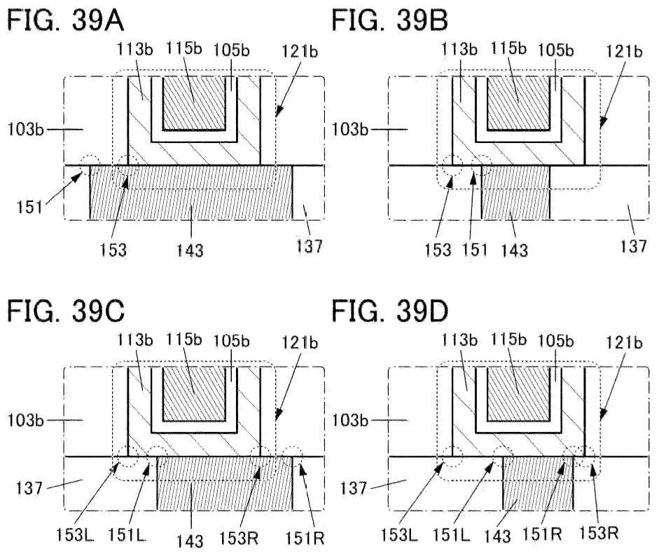

FIG. 39A is an enlarged view extracting part of the structure illustrated in FIG. 38B and illustrating part of the conductive layer 143, part of the insulating layer 137, part of the insulating layer 103b, part of the semiconductor layer 113b, part of the insulating layer 105b, and part of the conductive layer 115b. In FIG. 39A, an upper end portion of the conductive layer 143 is referred to as an end portion 151. A lower end portion of the semiconductor layer 113b inside the opening portion 121b is referred to as an end portion 153.

In the example illustrated in FIG. 39A, the end portion 151 is positioned on the outer side of the end portion 153. In that case, inside the opening portion 121b, the entire bottom surface of the semiconductor layer 113b overlaps with the conductive layer 143; for example, the entire bottom surface of the semiconductor layer 113b is in contact with the conductive layer 143. Therefore, in the example illustrated in FIG. 39A, the entire bottom surface of the semiconductor layer 113b inside the opening portion 121b can serve as the source region or the drain region.

FIGS. 39B, 39C, and 39D illustrate a modification example of the structure illustrated in FIG. 39A. FIG. 39B illustrates an example in which the end portion 151 is positioned on the inner side of the end portion 153. FIG. 39C illustrates an example in which an end portion 151L, which is the left upper end portion the conductive layer 143, is positioned on the inner side (on the right side) of an end portion 153L, which is the left lower end portion of the semiconductor layer 113b inside the opening portion 121b, and an end portion 151R, which is the right upper end portion of the conductive layer 143, is positioned on the outer side (on the right side) of an end portion 153R, which is the right lower end portion of the semiconductor layer 113b inside the opening portion 121b. Note that the end portion 151L may be positioned on the outer side of the end portion 153L, and the end portion 151R may be positioned on the inner side of the end portion 153R. FIG. 39D illustrates an example in which the end portion 151L is positioned on the inner side (on the right side) of the end portion 153L, the end portion 151R is positioned on the inner side (on the left side) of the end portion 153R, and the distance between the end portion 151L and the end portion 153L is longer than the distance between the end portion 151R and the end portion 153R. Note that the distance between the end portion 151L and the end portion 153L may be shorter than the distance between the end portion 151R and the end portion 153R.

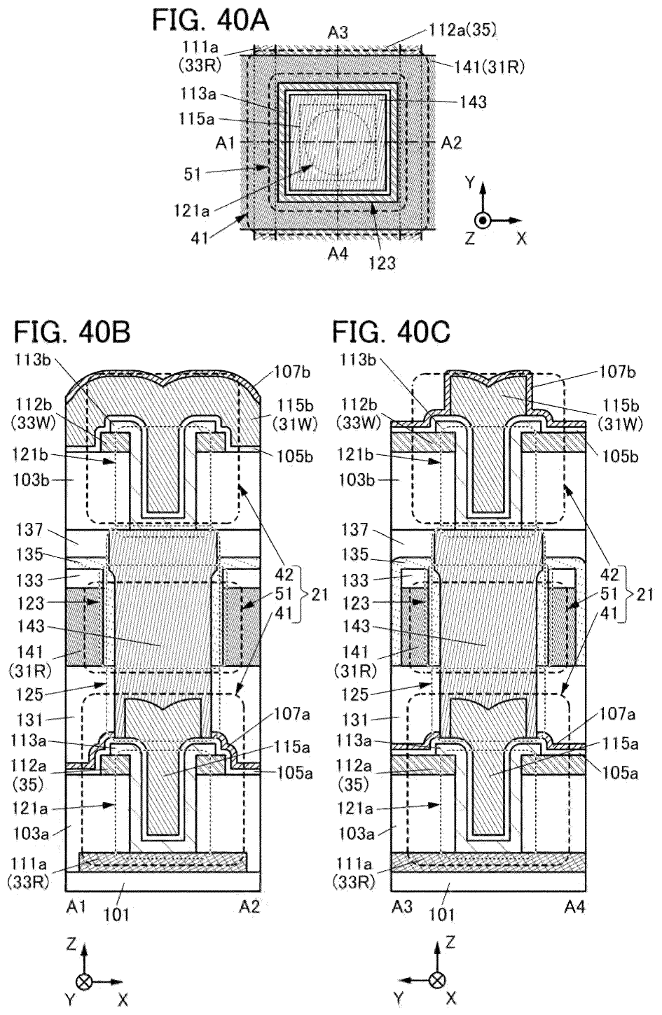

FIGS. 40A, 40B, and 40C illustrate a modification example of FIGS. 38A, 38B, and 38C, respectively, and illustrate an example in which the conductive layer 143 covers the conductive layer 115a. For clarity of the drawing, a structure example of the transistor 42 is not illustrated in FIG. 40A.

In the example illustrated in FIGS. 40A to 40C, the width of the conductive layer 143 can be larger than that in the example illustrated in FIGS. 38A to 38C; therefore, wiring resistance of the conductive layer 143 can be reduced. In contrast, in the example illustrated in FIGS. 38A to 38C, the opening portion 125 does not reach the insulating layer 105a; therefore, the insulating layer 105a can be prevented from being reduced in thickness by processing of part of the insulating layer 105a, for example, at the time of forming the opening portion 125 in the insulating layer 107a. Thus, a short circuit between the semiconductor layer 113a and the conductive layer 143 can be prevented, for example.

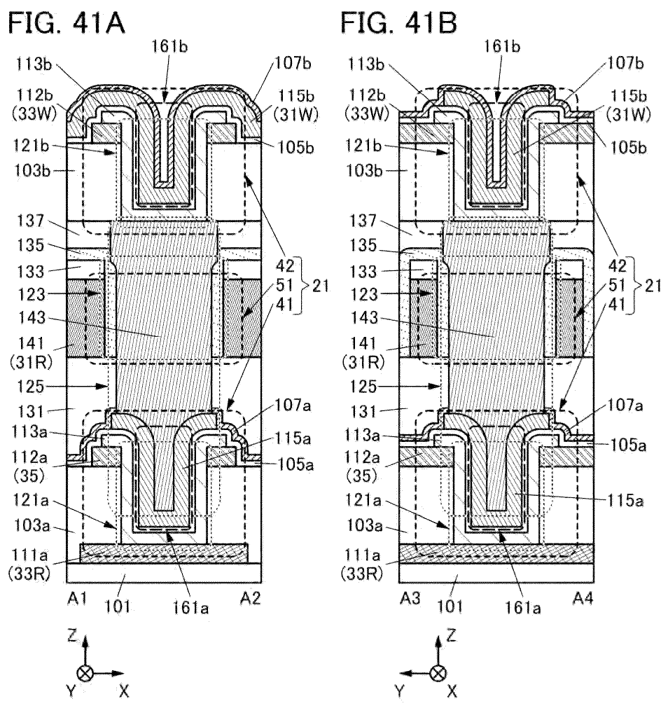

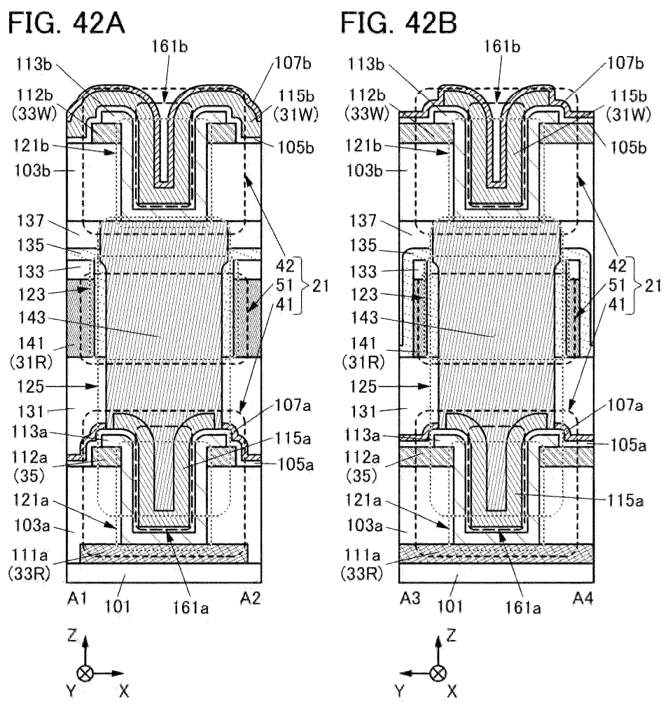

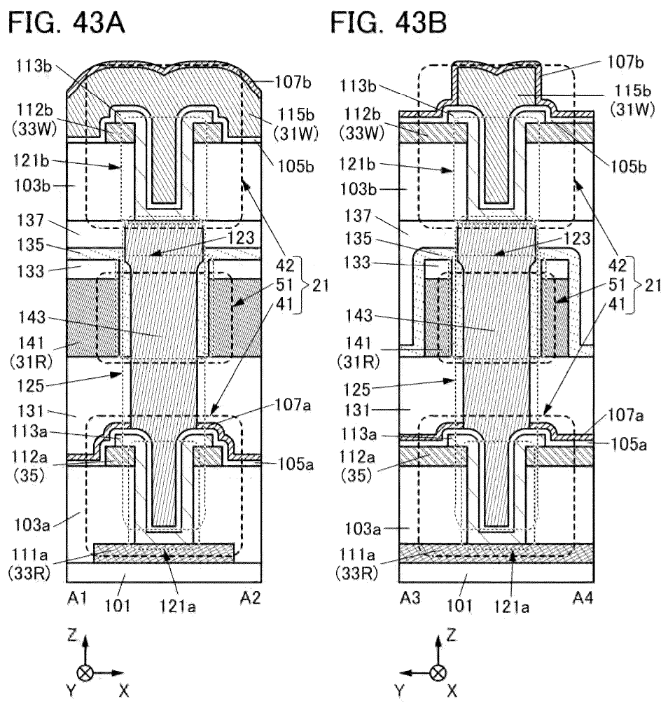

FIGS. 41A and 41B and FIGS. 42A and 42B illustrate modification examples of the structures illustrated in FIGS. 38B and 38C and FIGS. 40B and 40C, respectively, and illustrate examples in which the conductive layer 115 includes the depressed portion 161 inside the opening portion 121. FIGS. 43A and 43B illustrate a modification example of the structure illustrated in FIGS. 38B and 38C and illustrate an example in which the transistor 41 does not include the conductive layer 115a and the conductive layer 143 functions as the gate electrode of the transistor 41.

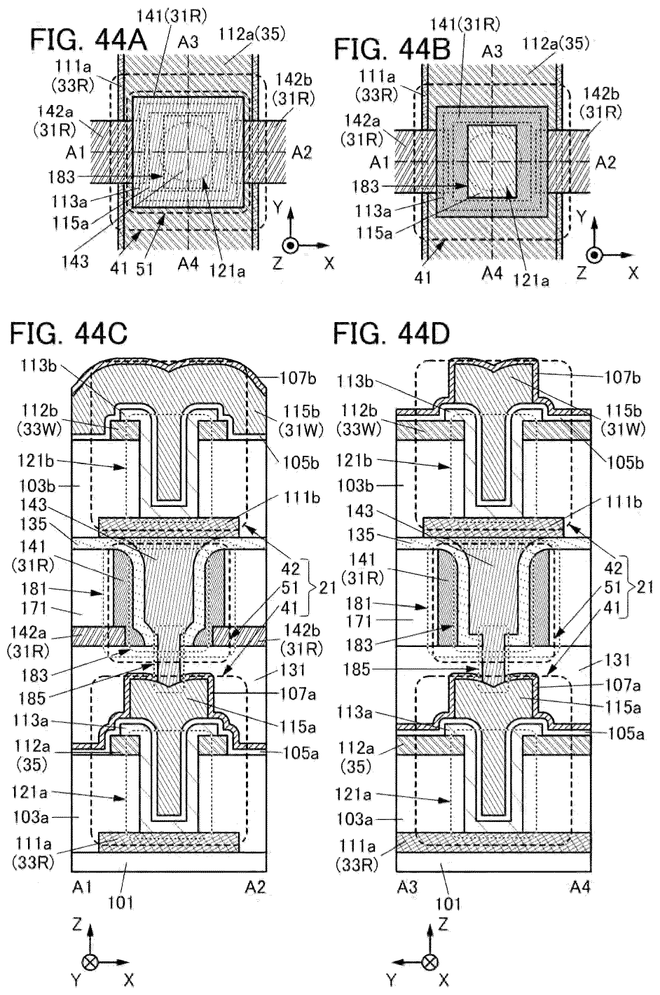

FIG. 44A illustrates a modification example of the structure illustrated in FIG. 2A and illustrates structure examples of the transistor 41 and the capacitor 51. That is, FIG. 44A does not illustrate a structure example of the transistor 42. FIG. 44B is a plan view omitting the conductive layer 143 from FIG. 44A. FIG. 44C is a cross-sectional view taken along dashed-dotted line A1-A2 in FIGS. 44A and 44B. FIG. 44D is a cross-sectional view taken along dashed-dotted line A3-A4 in FIGS. 44A and 44B. In the example illustrated in FIGS. 44A to 44D, the structure between the insulating layer 131 and the insulating layer 103b/the conductive layer 111b is different from that in FIGS. 2A to 2C.

The semiconductor device illustrated in FIGS. 44A to 44D includes a conductive layer 142a and a conductive layer 142b over the insulating layer 131 and an insulating layer 171 over the insulating layer 131, the conductive layer 142a, and the conductive layer 142b. In the insulating layer 171, an opening portion 181 reaching the insulating layer 131, the conductive layer 142a, and the conductive layer 142b is provided. The opening portion 181 includes a region positioned between the conductive layer 142a and the conductive layer 142b and includes a region overlapping with the conductive layer 115a. The capacitor 51 is provided inside the opening portion 181. Here, the insulating layer 171 functions as an interlayer insulating layer. For the insulating layer 171, any of the materials similar to the materials that can be used for the insulating layer 103 can be used, for example. Note that the conductive layer 142a and the conductive layer 142b may or may not be included in the memory cell 21.

As described above, the capacitor 51 includes the conductive layer 141, the conductive layer 143, and the insulating layer 135. The conductive layer 141 functions as the other electrode of the capacitor 51. The conductive layer 143 functions as the one electrode of the capacitor 51. Furthermore, the insulating layer 135 functions as the dielectric layer of the capacitor 51.

The conductive layer 141 is provided so as to cover, inside the opening portion 181, a side surface of the insulating layer 171, top and side surfaces of the conductive layer 142a, top and side surfaces of the conductive layer 142b, and a top surface of the insulating layer 131. The conductive layer 141 can have a shape that is along the side surface of the insulating layer 171, the top and side surfaces of the conductive layer 142a, the top and side surfaces of the conductive layer 142b, and the top surface of the insulating layer 131. For example, the conductive layer 141 can include a region in contact with the side surface of the insulating layer 171, a region in contact with the top surface of the conductive layer 142a, a region in contact with the side surface of the conductive layer 142a, a region in contact with the top surface of the conductive layer 142b, a region in contact with the side surface of the conductive layer 142b, and a region in contact with the top surface of the insulating layer 131. By including the region in contact with the conductive layer 142a and the region in contact with the conductive layer 142b, the conductive layer 141 can be electrically connected to the conductive layer 142a and the conductive layer 142b, for example. In the conductive layer 141, an opening portion 183 is provided so as to include a region overlapping with the conductive layer 115a. The opening portion 183 includes a region contained in the opening portion 181. The planar shape of the opening portion 183 is quadrangular in the example illustrated in FIGS. 44A and 44B but can be similar to the planar shape that the opening portion 123 can have.

The conductive layer 142a and the conductive layer 142b each include a region extending in the X direction. The conductive layer 142a and the conductive layer 142b function as the wiring 31R. The conductive layer 142a and the conductive layer 142b may at least partly function as the other electrode of the capacitor 51. The conductive layer 141 that is electrically connected to the conductive layer 142a and the conductive layer 142b may at least partly function as the wiring 31R.

For the conductive layer 142a and the conductive layer 142b, any of materials similar to the materials that can be used for the conductive layer 141 can be used. In particular, a single layer or stacked layers of a conductive material with high conductivity, such as tungsten, aluminum, or copper, is preferably used for the conductive layer 142a and the conductive layer 142b. By using a conductive material with high conductivity for the conductive layer 142a and the conductive layer 142b in this manner, conductivity of the wiring 31R can be improved.

The insulating layer 135 and the conductive layer 143 are each provided so as to include a region positioned inside the opening portion 183. Specifically, inside the opening portion 183, the insulating layer 135 is provided so as to cover the side surface of the conductive layer 141, and the conductive layer 143 is provided on the inner side of the insulating layer 135 so as to, for example, fill the opening portion 183. In other words, the insulating layer 135 is provided so as to include, inside the opening portion 183, a region positioned between the conductive layer 141 and the conductive layer 143. Here, since the opening portion 183 includes a region contained in the opening portion 181, the insulating layer 135 can be regarded as including, inside the opening portion 181, a region positioned between the conductive layer 141 and the conductive layer 143.

FIGS. 44C and 44D illustrate an example in which the conductive layer 141 includes a curved portion between its top and side surfaces and the insulating layer 135 covers the top surface, the side surface, and the curved portion of the conductive layer 141. Note that the curved portion of the conductive layer 141 may be included in one or both of the top surface and the side surface of the conductive layer 141. Furthermore, the conductive layer 141 does not necessarily include the curved portion. In the case where the conductive layer 141 does not include the curved portion, the top surface of the conductive layer 141 is positioned below the top surface of the insulating layer 171, for example. Specifically, for example, the uppermost portion of the conductive layer 141 can be positioned below the upper end portion of the opening portion 181 in the insulating layer 171.

The insulating layer 135 is provided between the insulating layer 171 and the insulating layer 103b/the conductive layer 111b so as to cover the top surface of the insulating layer 171. Thus, in the example illustrated in FIGS. 44C and 44D, the insulating layer 135 has a shape that is along the top surface of the insulating layer 171, the top surface, the curved portion, and the side surface of the conductive layer 141, and the top surface of the insulating layer 131.

An opening portion 185 is provided in the insulating layer 107a, the insulating layer 131, and the insulating layer 135. The opening portion 185 is provided so as to include a region overlapping with the opening portion 181 and the opening portion 183 and reach the conductive layer 115a.

The bottom of the opening portion 185 includes the top surface of the conductive layer 115a. A sidewall of the opening portion 185 includes a side surface of the insulating layer 107a, a side surface of the insulating layer 131, and a side surface of the insulating layer 135. The opening portion 185 includes an opening portion included in the insulating layer 107a, an opening portion included in the insulating layer 131, and an opening portion included in the insulating layer 135. In other words, the opening portion of the insulating layer 107a, the opening portion of the insulating layer 131, and the opening portion of the insulating layer 135 which are provided in a region overlapping with the conductive layer 115a are each part of the opening portion 185. The shape and the size of the opening portion 185 in the plan view may differ from layer to layer. When the shape of the opening portion 185 is circular in the plan view, the opening portions included in the layers may or may not be concentric with each other.

The conductive layer 143 is provided so as to include a region positioned inside the opening portion 181, the opening portion 183, and the opening portion 185. For example, the conductive layer 143 is provided so as to fill the opening portion 183 and the opening portion 185.

FIGS. 44C and 44D illustrate an example in which the top surface of the conductive layer 143 is aligned or substantially aligned with the top surface of the insulating layer 135. Note that the top surface of the conductive layer 143 is not necessarily aligned or substantially aligned with the top surface of the insulating layer 135. For example, the top surface of the conductive layer 143 may be positioned below the top surface of the insulating layer 135.

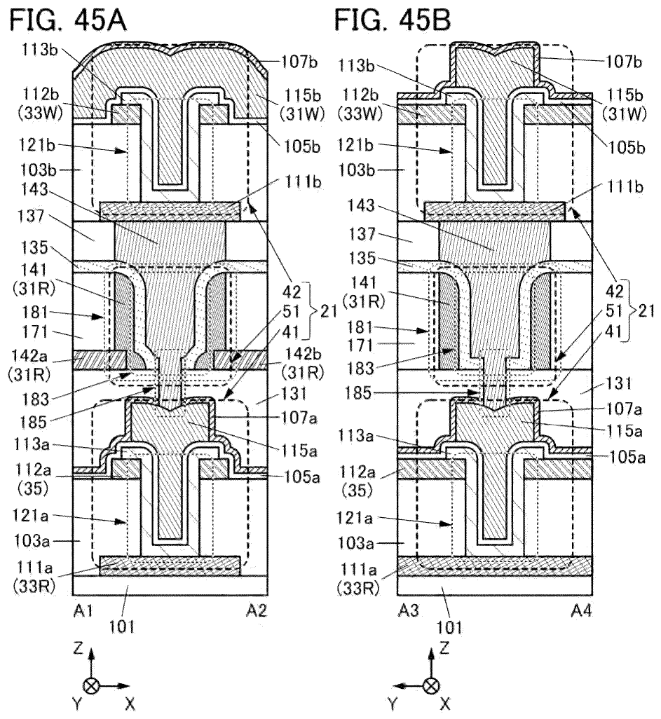

FIGS. 45A and 45B illustrate a modification example of the structure illustrated in FIGS. 44C and 44D, respectively, and illustrate an example in which the insulating layer 137 is provided over the insulating layer 135 and the top surface of the insulating layer 137 and the top surface of the conductive layer 143 are aligned or substantially aligned with each other. In the example illustrated in FIGS. 45A and 45B, a short circuit between the conductive layer 141 and the conductive layer 111b can be prevented more easily than in the example illustrated in FIGS. 44C and 44D, for example. In contrast, in the example illustrated in FIGS. 44C and 44D, the manufacturing process of the semiconductor device can be simplified as compared with the example illustrated in FIGS. 45A and 45B. Note that the structure where the insulating layer 137 is provided over the insulating layer 135 or the insulating layer 136 and the top surface of the insulating layer 137 and the top surface of the conductive layer 143 are aligned or substantially aligned with each other can be applied to all the semiconductor devices having a structure where the insulating layer 135 or the insulating layer 136 covers at least part of the top surface and the curved portion of the conductive layer 141 and at least part of the top surface of the insulating layer 171.

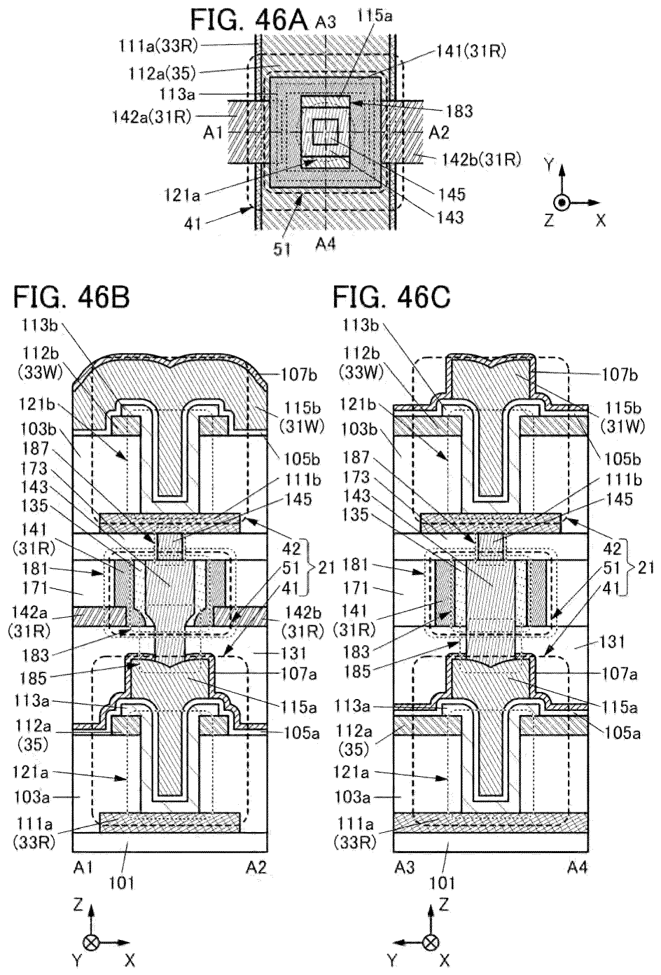

FIGS. 46A, 46B, and 46C illustrate a modification example of the structure illustrated in FIGS. 44A, 44C, and 44D, respectively, and illustrate an example in which the insulating layer 135 is provided over neither the conductive layer 141 nor the insulating layer 171. FIGS. 46B and 46C illustrate an example in which the top surfaces of the insulating layer 135, the conductive layer 141, the conductive layer 143, and the insulating layer 171 are aligned or substantially aligned with each other. Although the top surface of the conductive layer 141 is planarized completely and a curved portion is not provided between the top and side surfaces of the conductive layer 141 in the example illustrated in FIGS. 46B and 46C, the conductive layer 141 may include a curved portion.

In the example illustrated in FIGS. 46B and 46C, an insulating layer 173 is provided over the conductive layer 141, the conductive layer 143, the insulating layer 135, and the insulating layer 171, and the conductive layer 111b and the insulating layer 103b are provided over the insulating layer 173. In the insulating layer 173, an opening portion 187 reaching the conductive layer 143 is provided. A conductive layer 145 is provided inside the opening portion 187. For example, the conductive layer 145 is provided so as to fill the opening portion 187. The conductive layer 145 includes, inside the opening portion 187, a region in contact with the top surface of the conductive layer 143, a region in contact with the bottom surface of the conductive layer 111b, and a region in contact with a side surface of the insulating layer 173, for example. When the conductive layer 145 includes the region in contact with the conductive layer 143 and the region in contact with the conductive layer 111b, for example, the conductive layer 143 and the conductive layer 111b can be electrically connected to each other through the conductive layer 145.

The insulating layer 173 functions as an interlayer insulating layer, and any of the materials similar to the materials that can be used for the insulating layer 131 can be used for the insulating layer 173. For the conductive layer 145, any of materials similar to the materials that can be used for the conductive layer 143 can be used.

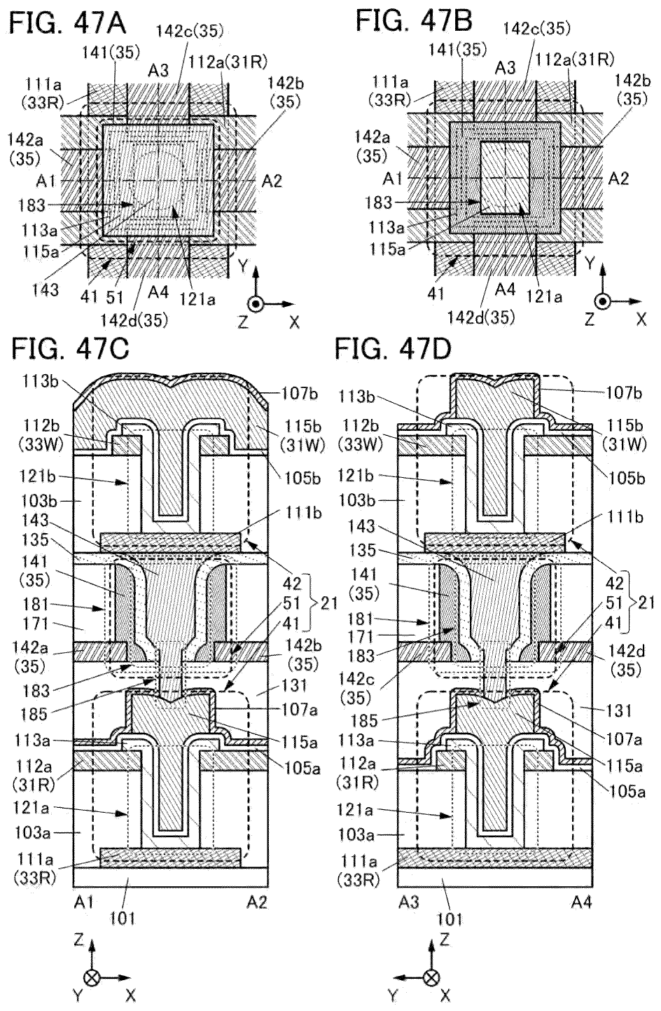

FIG. 47A illustrates a modification example of the structure illustrated in FIG. 8A and illustrates structure examples of the transistor 41 and the capacitor 51. That is, FIG. 47A does not illustrate a structure example of the transistor 42. FIG. 47B is a plan view omitting the conductive layer 143 from FIG. 47A. FIG. 47C is a cross-sectional view taken along dashed-dotted line A1-A2 in FIGS. 47A and 47B. FIG. 47D is a cross-sectional view taken along dashed-dotted line A3-A4 in FIGS. 47A and 47B. In the example illustrated in FIGS. 47A to 47D, the structure between the insulating layer 131 and the insulating layer 103b/the conductive layer 111b is different from that in FIGS. 8A to 8C.

The semiconductor device illustrated in FIGS. 47A to 47D includes the conductive layer 142a, the conductive layer 142b, a conductive layer 142c, and a conductive layer 142d over the insulating layer 131 and the insulating layer 171 over the insulating layer 131, the conductive layer 142a, the conductive layer 142b, the conductive layer 142c, and the conductive layer 142d. As in the example illustrated in FIGS. 44A to 44D, the conductive layer 142a and the conductive layer 142b each include a region extending in the X direction. Here, the conductive layer 142c and the conductive layer 142d each include a region extending in the Y direction. Note that the conductive layer 142a, the conductive layer 142b, the conductive layer 142c, and the conductive layer 142d may or may not be included in the memory cell 21.

In the insulating layer 171, the opening portion 181 reaching the insulating layer 131, the conductive layer 142a, the conductive layer 142b, the conductive layer 142c, and the conductive layer 142d is provided. The opening portion 181 includes a region positioned between the conductive layer 142a and the conductive layer 142b and between the conductive layer 142c and the conductive layer 142d and includes a region overlapping with the conductive layer 115a. The capacitor 51 is provided inside the opening portion 181 as in the example illustrated in FIGS. 44A to 44D.

The conductive layer 141 is provided so as to cover, inside the opening portion 181, a side surface of the insulating layer 171, top and side surfaces of the conductive layer 142a, top and side surfaces of the conductive layer 142b, top and side surfaces of the conductive layer 142c, top and side surfaces of the conductive layer 142d, and a top surface of the insulating layer 131. The conductive layer 141 can have a shape that is along the side surface of the insulating layer 171, the top and side surfaces of the conductive layer 142a, the top and side surfaces of the conductive layer 142b, the top and side surfaces of the conductive layer 142c, the top and side surfaces of the conductive layer 142d, and the top surface of the insulating layer 131. For example, the conductive layer 141 can include a region in contact with the side surface of the insulating layer 171, a region in contact with the top surface of the conductive layer 142a, a region in contact with the side surface of the conductive layer 142a, a region in contact with the top surface of the conductive layer 142b, a region in contact with the side surface of the conductive layer 142b, a region in contact with the top surface of the conductive layer 142c, a region in contact with the side surface of the conductive layer 142c, a region in contact with the top surface of the conductive layer 142d, a region in contact with the side surface of the conductive layer 142d, and a region in contact with the top surface of the insulating layer 131. By including the region in contact with the conductive layer 142a, the region in contact with the conductive layer 142b, the region in contact with the conductive layer 142c, and the region in contact with the conductive layer 142b, the conductive layer 141 can be electrically connected to the conductive layer 142a, the conductive layer 142b, the conductive layer 142c, and the conductive layer 142d, for example. As described above, in the conductive layer 141, an opening portion 183 is provided so as to include a region overlapping with the conductive layer 115a.

As described above, the conductive layer 142a and the conductive layer 142b each include a region extending in the X direction, and the conductive layer 142c and the conductive layer 142d each include a region extending in the Y direction. The conductive layer 142a, the conductive layer 142b, the conductive layer 142c, and the conductive layer 142d function as the wiring 35. The conductive layer 142a, the conductive layer 142b, the conductive layer 142c, and the conductive layer 142d may at least partly function as the other electrode of the capacitor 51. The conductive layer 141 that is electrically connected to the conductive layer 142a, the conductive layer 142b, the conductive layer 142c, and the conductive layer 142d may at least partly function as the wiring 35.

For the conductive layer 142a, the conductive layer 142b, the conductive layer 142c, and the conductive layer 142d, any of materials similar to the materials that can be used for the conductive layer 141 can be used. In particular, a single layer or stacked layers of a conductive material with high conductivity, such as tungsten, aluminum, or copper, is preferably used for the conductive layer 142a, the conductive layer 142b, the conductive layer 142c, and the conductive layer 142d. By using a conductive material with high conductivity for the conductive layer 142a, the conductive layer 142b, the conductive layer 142c, and the conductive layer 142d in this manner, conductivity of the wiring 35 can be improved.

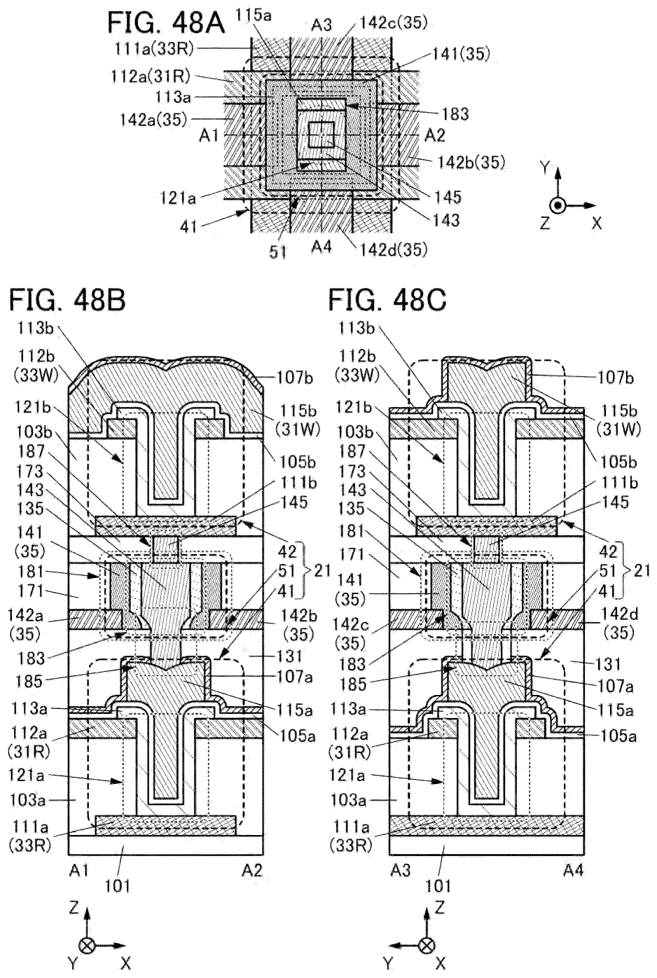

FIGS. 48A, 48B, and 48C illustrate a modification example of the structure illustrated in FIGS. 47A, 47C, and 47D, respectively, and illustrate an example in which the insulating layer 135 is provided over neither the conductive layer 141 nor the insulating layer 171 as in the example illustrated in FIGS. 46A to 46C.

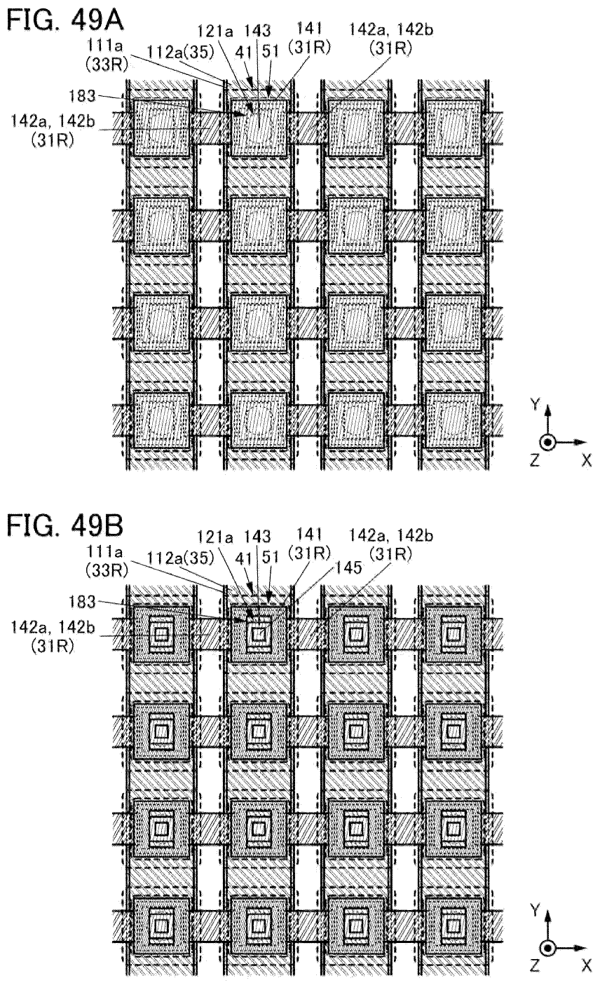

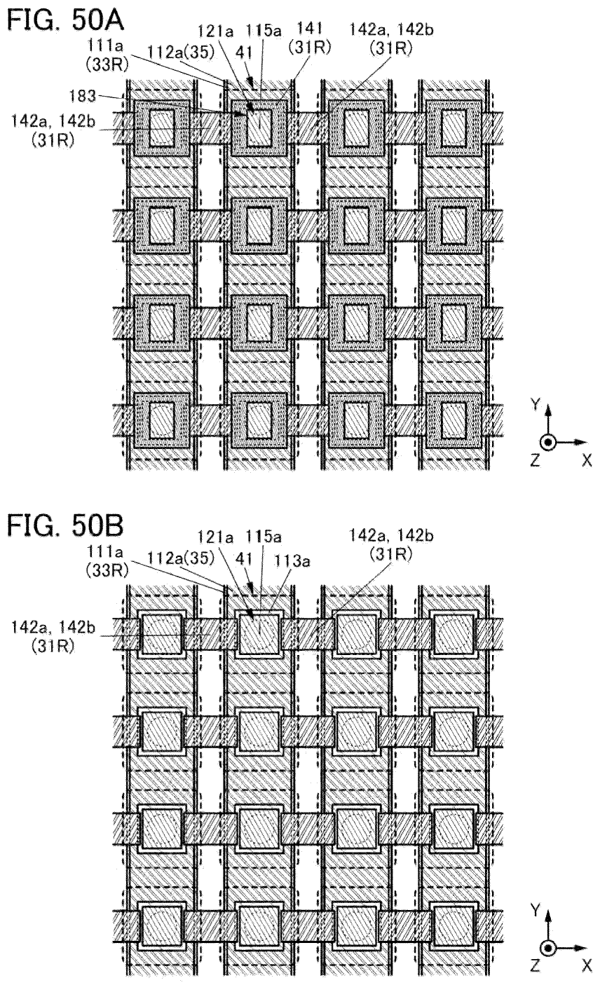

FIG. 49A is a plan view illustrating a structure example in which the transistors 41 and the capacitors 51 illustrated in FIG. 44A are arranged in a matrix. FIG. 49B is a plan view illustrating a structure example in which the transistors 41 and the capacitors 51 illustrated in FIG. 46A are arranged in a matrix. FIG. 50A is a plan view omitting the conductive layer 143 from FIG. 49A. A plan view omitting the conductive layer 143 from FIG. 49B can be similar to FIG. 50A. FIG. 50B is a plan view omitting the conductive layer 141 from FIG. 50A.

As illustrated in FIGS. 49A and 49B and FIG. 50A, the conductive layer 142a including a region in contact with the conductive layer 141 included in the memory cell also serves as the conductive layer 142b included in a memory cell that is adjacent to the memory cell in the X direction, for example. That is, the conductive layer 142a including the region in contact with the conductive layer 141 included in the memory cell and the conductive layer 142b included in the memory cell that is adjacent to the memory cell in the X direction are the same conductive layer, for example. In other words, one conductive layer is shared as the conductive layer 142a including the region in contact with the conductive layer 141 included in the memory cell and the conductive layer 142b included in the memory cell that is adjacent to the memory cell in the X direction, for example. In the example illustrated in FIGS. 49A and 49B and FIG. 50A, the conductive layers 141 included in the memory cells arranged in the X direction are electrically connected to each other through the conductive layer 142a and the conductive layer 142b.

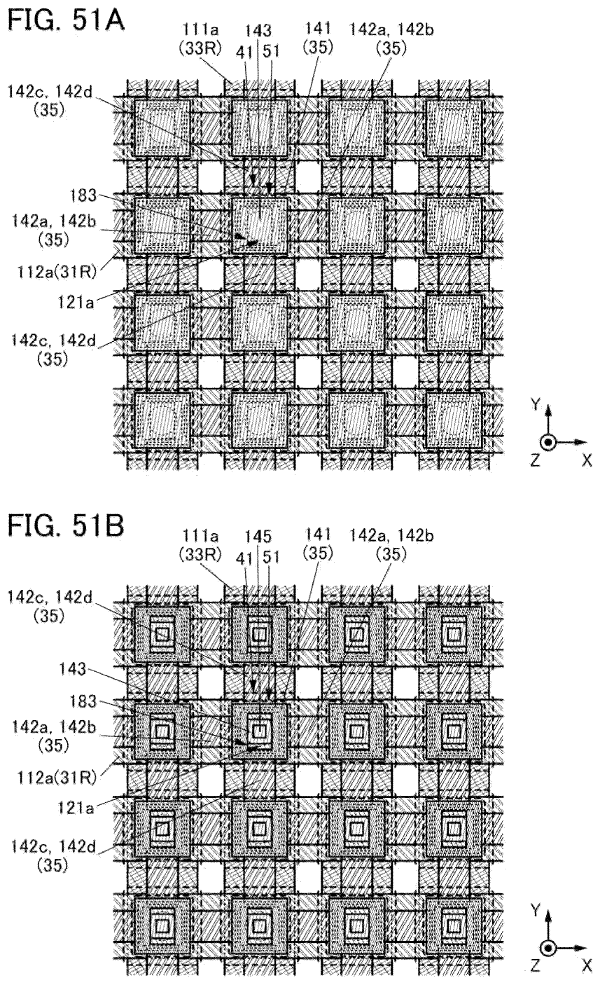

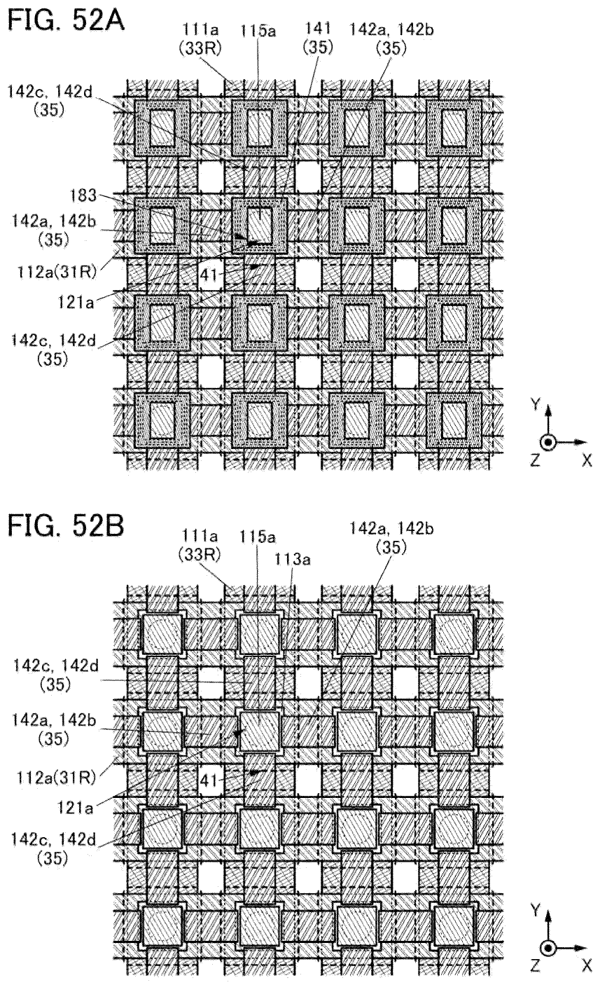

FIG. MA is a plan view illustrating a structure example in which the transistors 41 and the capacitors 51 illustrated in FIG. 47A are arranged in a matrix. FIG. 51B is a plan view illustrating a structure example in which the transistors 41 and the capacitors 51 illustrated in FIG. 48A are arranged in a matrix. FIG. 52A is a plan view omitting the conductive layer 143 from FIG. 51A. A plan view omitting the conductive layer 143 from FIG. 51B can be similar to FIG. 52A. FIG. 52B is a plan view omitting the conductive layer 141 from FIG. 52A.

In the example illustrated in FIGS. 51A and 51B and FIG. 52A, as in the example illustrated in FIGS. 49A and 49B and FIG. 50A, the conductive layer 142a including a region in contact with the conductive layer 141 included in the memory cell also serves as the conductive layer 142b included in a memory cell that is adjacent to the memory cell in the X direction, for example. Furthermore, in the example illustrated in FIGS. 51A and 51B and FIG. 52A, the conductive layer 142c including a region in contact with the conductive layer 141 included in the memory cell also serves as the conductive layer 142d included in a memory cell that is adjacent to the memory cell in the X direction, for example. That is, the conductive layer 142c including the region in contact with the conductive layer 141 included in the memory cell and the conductive layer 142d included in the memory cell that is adjacent to the memory cell in the Y direction are the same conductive layer, for example. In other words, one conductive layer is shared as the conductive layer 142c including the region in contact with the conductive layer 141 included in the memory cell and the conductive layer 142d included in the memory cell that is adjacent to the memory cell in the Y direction, for example.

In the example illustrated in FIGS. 51A and 51B and FIG. 52A, the conductive layers 141 included in the memory cells arranged in the X direction are electrically connected to each other through the conductive layer 142a and the conductive layer 142b. Furthermore, the conductive layers 141 included in the memory cells arranged in the Y direction are electrically connected to each other through the conductive layer 142c and the conductive layer 142d. Thus, all the conductive layers 141 can be electrically connected to each other through the conductive layer 142a, the conductive layer 142b, the conductive layer 142c, and the conductive layer 142d, for example.

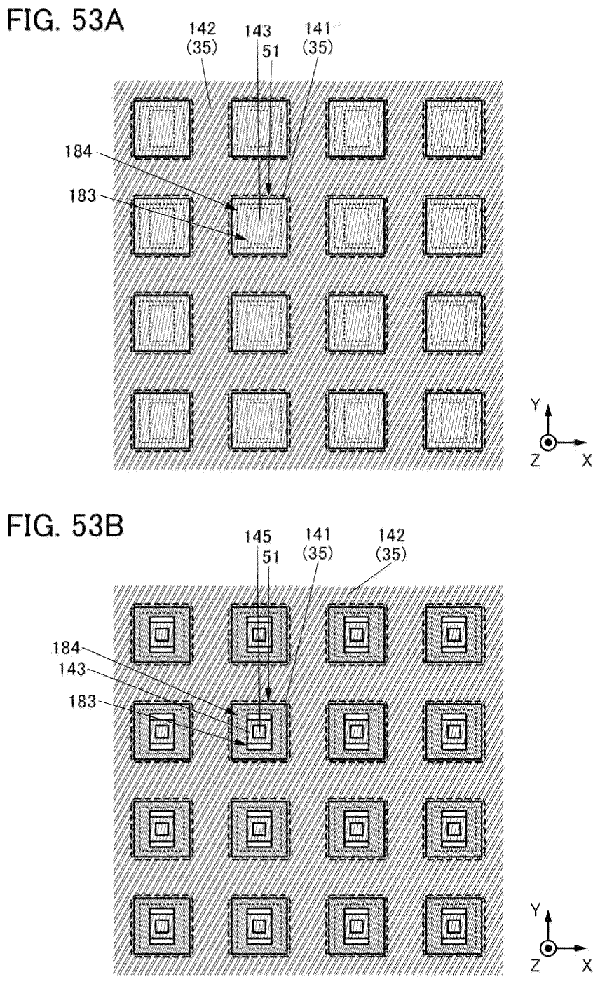

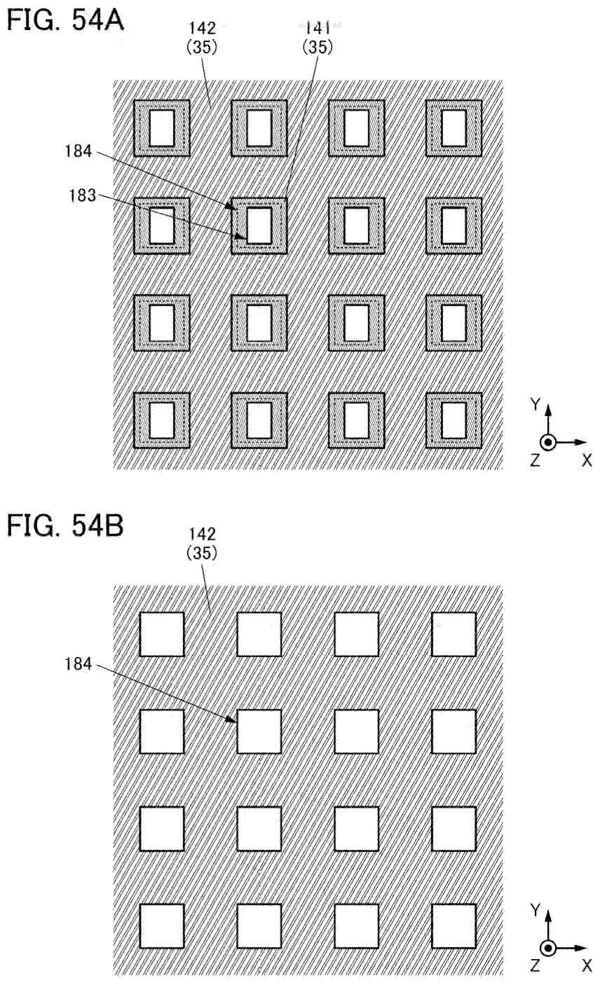

FIGS. 53A and 53B and FIGS. 54A and 54B illustrate a modification example of the structure illustrated in FIGS. 51A and 51B and FIGS. 52A and 52B, respectively, and illustrate an example in which the conductive layer 142a, the conductive layer 142b, the conductive layer 142c, and the conductive layer 142d are combined to form a conductive layer 142. In FIG. 53A to FIG. 54B, the transistor 41 and the transistor 42 are not illustrated.

In the example illustrated in FIG. 53A to FIG. MB, an opening portion 184 is provided in the conductive layer 142 functioning as the wiring 35, and the conductive layer 141 and the conductive layer 143 are each provided so as to include a region overlapping with the opening portion 184. In the example illustrated in FIG. 53B, the conductive layer 145 is provided so as to include a region overlapping with the opening portion 184. The planar shape of the opening portion 184 is quadrangular in the example illustrated in FIG. 53A to FIG. 54B but can be similar to the planar shape that the opening portion 183 can have.

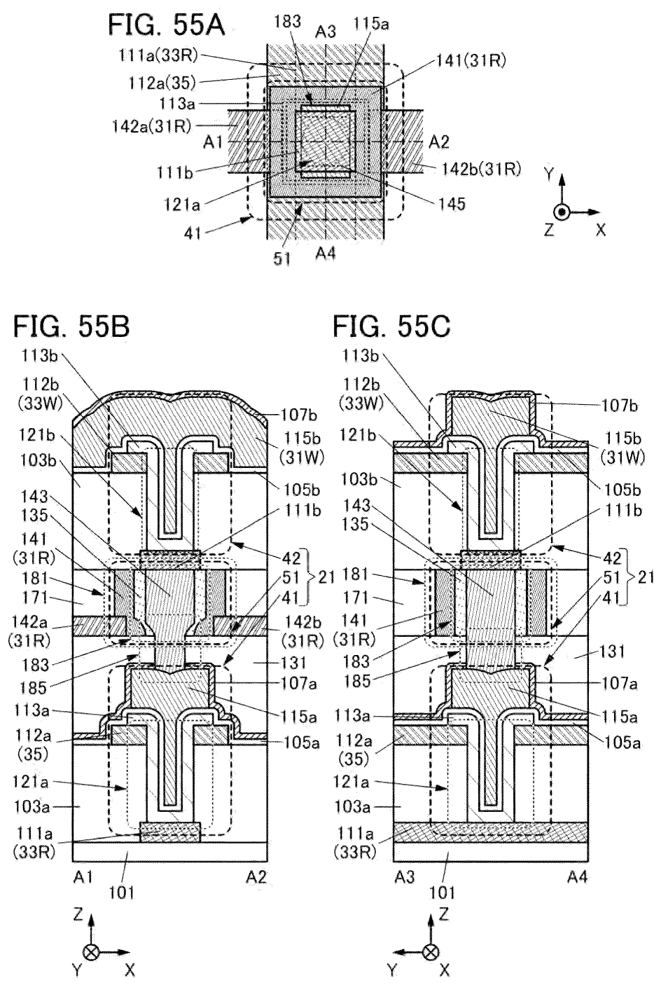

FIGS. 55A, 55B, and 55C illustrate a modification example of the structure illustrated in FIGS. 46A, 46B, and 46C, respectively, and illustrate an example in which the conductive layer 145 and the insulating layer 173 are not provided. In the example illustrated in FIGS. 55A to 55C, for example, the top surface of the conductive layer 143 includes a region in contact with the bottom surface of the conductive layer 111b, whereby the conductive layer 143 and the conductive layer 111b can be electrically connected to each other. Here, the conductive layer 111b is provided so as not to be in contact with the conductive layer 141. Although the conductive layer 111b includes a region in contact with the top surface of the insulating layer 135 in the example illustrated in FIGS. 55B and 55C, it is acceptable that the conductive layer 111b is not in contact with the top surface of the insulating layer 135; in that case, the lower end portion of the conductive layer 111b is positioned on the inner side of the upper end portion of the conductive layer 143, for example, in the X direction and the Y direction. Thus, for example, a structure where the conductive layer 111b entirely overlaps with the top surface of the conductive layer 143 can be formed.

Although FIGS. 55B to 55C illustrate an example in which the top surfaces of the insulating layer 135, the conductive layer 141, the conductive layer 143, and the insulating layer 171 are aligned or substantially aligned with each other, one embodiment of the present invention is not limited thereto. For example, the top surface of the conductive layer 141 may be positioned below the top surface of the conductive layer 143. For example, in the case where a conductive film to be the conductive layer 111b is formed and processed by etching to form the conductive layer 111b, if the etching selectivity of the conductive film to the conductive layer 141 is low, part of the conductive layer 141 might be processed. In that case, the top surface of the conductive layer 141 might be positioned below the top surface of the conductive layer 143.

In the example illustrated in FIGS. 55A to 55C, the manufacturing process of the semiconductor device can be simplified compared with the example illustrated in FIGS. 46A to 46C, for example. In contrast, in the example illustrated in FIGS. 46A to 46C, for example, the conductive layer 111b can be provided so as to include a region overlapping with the conductive layer 141, whereby layout flexibility can be increased. Furthermore, a short circuit between the conductive layer 141 and the conductive layer 111b can be prevented easily; accordingly, the reliability of the memory cell 21 can be improved, and a highly reliable semiconductor device can be provided.

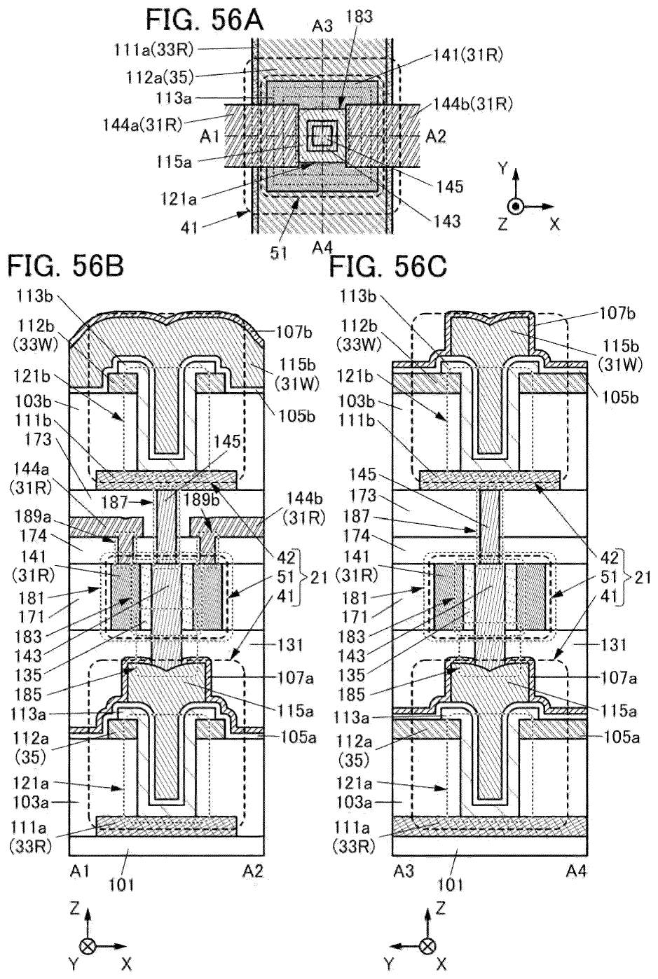

FIGS. 56A, 56B, and 56C illustrate a modification example of the structure illustrated in FIGS. 46A, 46B, and 46C, respectively, and illustrate an example in which the conductive layer 142a and the conductive layer 142b are not provided.

In the example illustrated in FIGS. 56B and 56C, an insulating layer 174 is provided over the insulating layer 171, the conductive layer 141, the insulating layer 135, and the conductive layer 143. A conductive layer 144a and a conductive layer 144b are provided over the insulating layer 174, and the insulating layer 173 is provided so as to cover top and side surfaces of the conductive layer 144a and top and side surfaces of the conductive layer 144b.

An opening portion 189a and an opening portion 189b reaching the conductive layer 141 are provided in the insulating layer 174. The conductive layer 144a is provided inside the opening portion 189a, and the conductive layer 144b is provided inside the opening portion 189b. The conductive layer 144a includes a region in contact with, for example, the conductive layer 141 inside the opening portion 189a. Furthermore, the conductive layer 144b includes a region in contact with, for example, the conductive layer 141 inside the opening portion 189b. For example, when the conductive layer 141 includes a region in contact with the conductive layer 144a and a region in contact with the conductive layer 144b, the conductive layer 141 can be electrically connected to the conductive layer 144a and the conductive layer 144b.

The conductive layer 144a and the conductive layer 144b each include a region extending in the X direction. As in the conductive layer 142a and the conductive layer 142b, the conductive layer 144a and the conductive layer 144b function as the wiring 31R. For the conductive layer 144a and the conductive layer 144b, any of materials similar to the materials that can be used for the conductive layer 142a and the conductive layer 142b can be used.

The insulating layer 174 functions as an interlayer insulating layer, and any of the materials similar to the materials that can be used for the insulating layer 173 can be used for the insulating layer 174. In the example illustrated in FIGS. 56B and 56C, the opening portion 187 is provided in the insulating layer 174 as well as in the insulating layer 173.

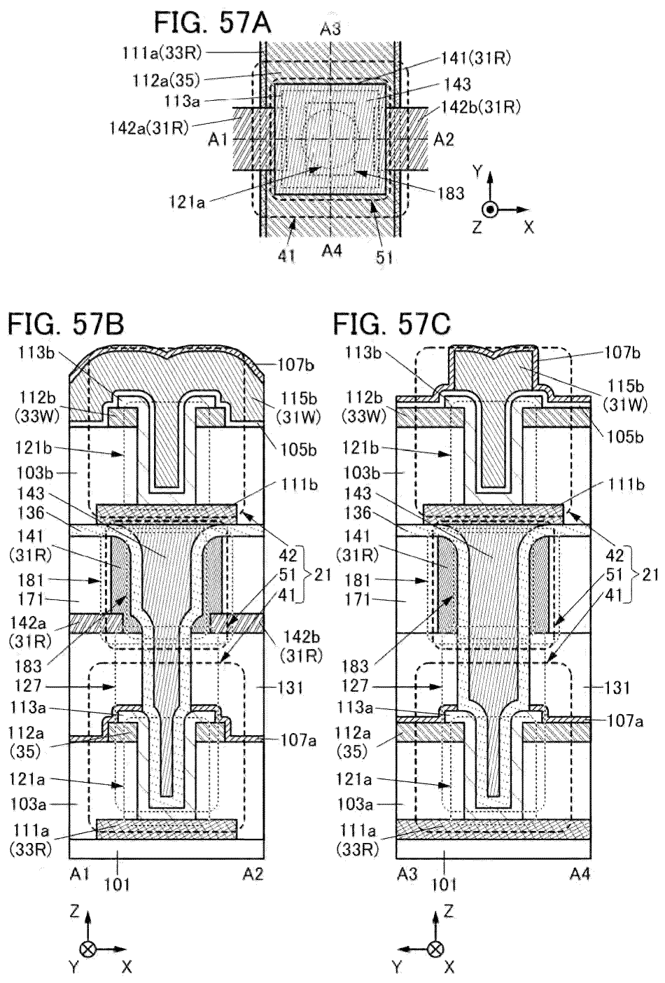

FIGS. 57A, 57B, and 57C illustrate a modification example of the structure illustrated in FIGS. 37A, 37B, and 37C, respectively, and illustrate an example in which the structure between the insulating layer 131 and the insulating layer 103b/the conductive layer 111b is similar to that illustrated in FIGS. 44A, 44C, and 44D. In the example illustrated in FIGS. 57A to 57C, not the opening portion 185 but the opening portion 127 is provided in the insulating layer 107a and the insulating layer 131.

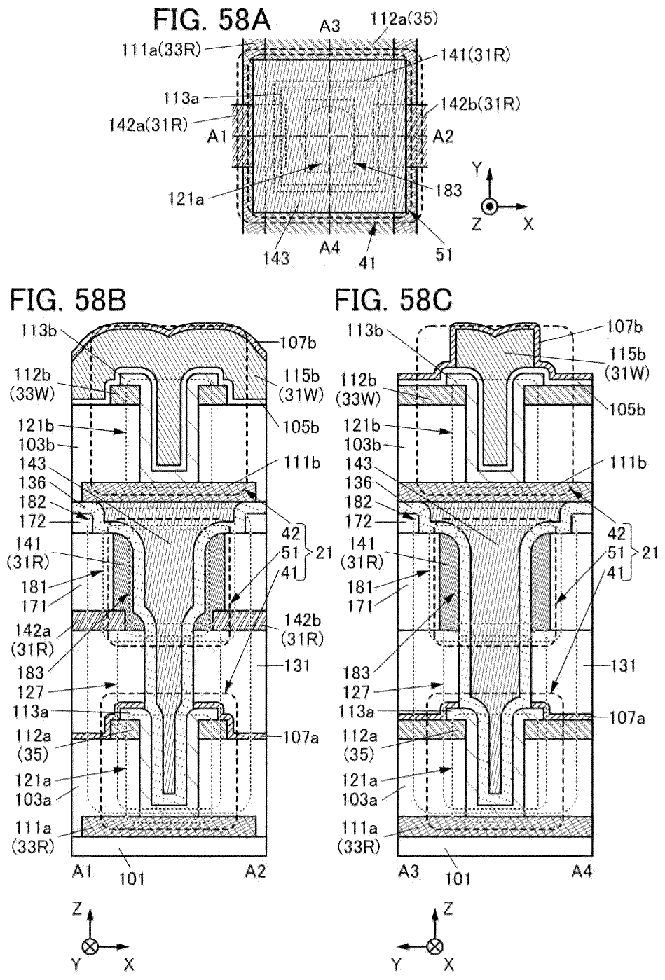

FIGS. 58A, 58B, and 58C illustrate a modification example of the structure illustrated in FIGS. 57A, 57B, and 57C, respectively, and illustrate an example in which an insulating layer 172 is provided over the insulating layer 171.

In the insulating layer 172, an opening portion 182 reaching the insulating layer 171, the conductive layer 141, and the semiconductor layer 113a is provided, and the insulating layer 136 and the conductive layer 143 are each provided so as to include a region positioned inside the opening portion 182. The insulating layer 136 is provided so as to cover the depressed portion of the semiconductor layer 113a, the side surface of the insulating layer 107a, the side surface of the insulating layer 131, the conductive layer 141, the top surface of the insulating layer 171, and top and side surfaces of the insulating layer 172. The conductive layer 143 is provided on the inner side of the insulating layer 136. The conductive layer 143 is provided so as to, for example, fill the opening portion 182. Note that the opening portion 182 includes the regions positioned inside the opening portion 121a, the opening portion 127, and the opening portion 181.

The insulating layer 172 functions as an interlayer insulating layer, and any of the materials similar to the materials that can be used for the insulating layer 131 can be used for the insulating layer 172. Here, it is preferable that the etching selectivity of the insulating layer 172 to the insulating layer 171 is high in order to inhibit processing of the insulating layer 171 in addition to the insulating layer 172 at the time of forming the opening portion 182 in the insulating layer 172.

In the example illustrated in FIGS. 58A to 58C, the area of a region where the top surface of the conductive layer 141 and the conductive layer 143 overlap with each other with the insulating layer 136 therebetween can be larger than that in the example illustrated in FIGS. 57A to 57C, for example. Thus, in the example illustrated in FIGS. 58A to 58C, the capacitance of the capacitor 51 can be larger than that in the example illustrated in FIGS. 57A to 57C, for example. In contrast, in the example illustrated in FIGS. 57A to 57C, the manufacturing process of the semiconductor device can be simplified as compared with the example illustrated in FIGS. 58A to 58C, for example.

### <Structure Example 4 of Semiconductor Device>

An example in which the shapes of the transistor 41 and the transistor 42 are different from those in FIGS. 2A to 2C is described below. The structure described below can be applied to the memory cell 21 illustrated in FIG. 1B1. Furthermore, at least part of the structure described below can be applied to the memory cells 21 illustrated in FIG. 1B2, FIG. 12B, and FIG. 14A.

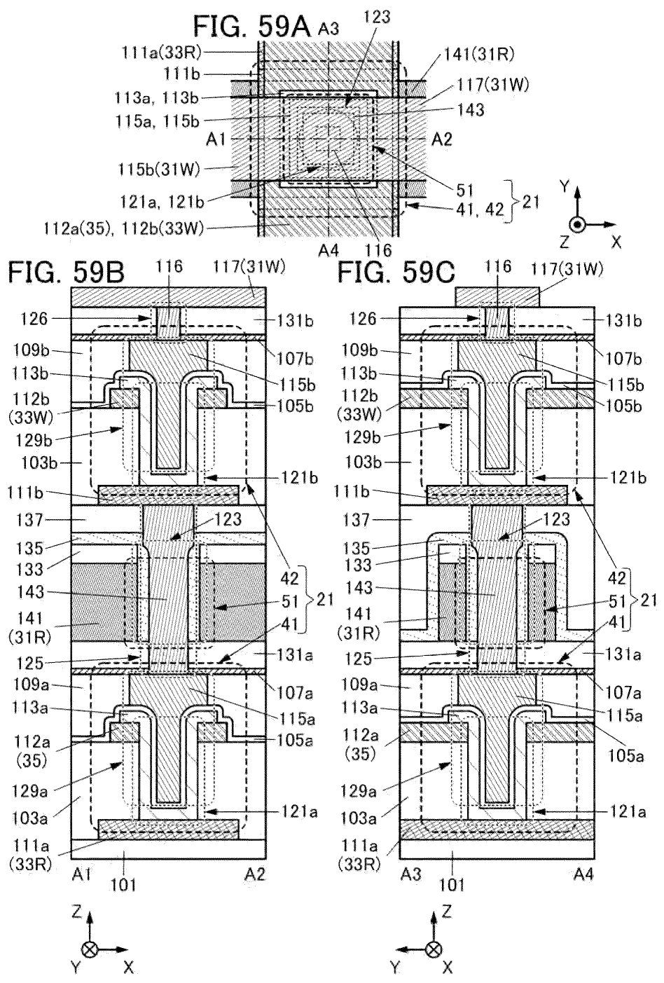

FIGS. 59A to 59C illustrate an example in which an insulating layer 109a is provided over the insulating layer 105a. In the insulating layer 109a, an opening portion 129a including a region overlapping with the opening portion 121a is provided. The conductive layer 115a is provided inside the opening portion 129a. The insulating layer 109a and the conductive layer 115a are planarized. Furthermore, the insulating layer 107a is provided over the insulating layer 109a and the conductive layer 115a, and an insulating layer 131a is provided over the insulating layer 107a. Note that the insulating layer 109a functions as an interlayer insulating layer.

The capacitor 51 is provided over the insulating layer 131a. Note that the description of the insulating layer 131 in this specification can be appropriately applied to the semiconductor device illustrated in FIGS. 59A to 59C by reading the insulating layer 131 as the insulating layer 131a.

The transistor 42 can have a structure similar to that of the transistor 41. Specifically, an insulating layer 109b is provided over the insulating layer 105b. In the insulating layer 109b, an opening portion 129b including a region overlapping with the opening portion 121b is provided. The conductive layer 115b is provided inside the opening portion 129b. The insulating layer 109b and the conductive layer 115b are planarized. Furthermore, the insulating layer 107b is provided over the insulating layer 109b and the conductive layer 115b, and an insulating layer 131b is provided over the insulating layer 107b. Note that the insulating layer 109b functions as an interlayer insulating layer.

In this specification and the like, the insulating layer 109a and the insulating layer 109b are collectively referred to as an insulating layer 109, and the opening portion 129a and the opening portion 129b are collectively referred to as an opening portion 129.

In the insulating layer 107b and the insulating layer 131b, an opening portion 126 reaching the conductive layer 115b is provided. The bottom of the opening portion 126 includes the top surface of the conductive layer 115b. A sidewall of the opening portion 126 includes the side surface of the insulating layer 107b and the side surface of the insulating layer 131b. The opening portion 126 includes an opening portion included in the insulating layer 107b and an opening portion included in the insulating layer 131b. In other words, the opening portion of the insulating layer 107b and the opening portion of the insulating layer 131b which are provided in a region overlapping with the conductive layer 115b are each part of the opening portion 126. The shape and the size of the opening portion 126 in the plan view may differ from layer to layer. When the shape of the opening portion 126 is circular in the plan view, the opening portions included in the layers may or may not be concentric with each other.

A conductive layer 116 is provided inside the opening portion 126. For example, the conductive layer 116 is provided so as to fill the opening portion 126. The conductive layer 116 can include, inside the opening portion 126, a region in contact with the top surface of the conductive layer 115b, a region in contact with the side surface of the insulating layer 107b, and a region in contact with the side surface of the insulating layer 131b, for example.

A conductive layer 117 is provided over the conductive layer 116 and the insulating layer 131b. The conductive layer 117 includes a region in contact with a top surface of the conductive layer 116 and a region in contact with a top surface of the insulating layer 131b, for example. For example, when the conductive layer 116 includes a region in contact with the conductive layer 115b and a region in contact with the conductive layer 117, the conductive layer 115b and the conductive layer 117 can be electrically connected to each other through the conductive layer 116. Here, the conductive layer 117 functions as the wiring 31W and includes a region extending in the X direction. Providing the conductive layer 116 and the conductive layer 117 which are electrically connected to the conductive layer 115b functioning as the gate electrode of the transistor 42 allows the conductive layer 115b to be planarized and the conductive layer 115b to be electrically connected to the word line driver circuit 11 illustrated in FIG. 1A, for example. In the structure illustrated in FIGS. 59A to 59C, the conductive layer 115b and the conductive layer 116 as well as the conductive layer 117 may be regarded as the wiring 31W.

For the insulating layer 109, any of the materials similar to the materials that can be used for the insulating layer 103 can be used, for example. Here, the etching selectivity of the insulating layer 109 to the insulating layer 105 is preferably high. This can inhibit the insulating layer 105 from being reduced in thickness when the opening portion 129 is formed in the insulating layer 109. Thus, a short circuit between the semiconductor layer 113a and the conductive layer 115a can be inhibited, for example.

For the conductive layer 116, any of materials similar to the materials that can be used for the conductive layer 143 can be used. For the conductive layer 117, any of materials similar to the materials that can be used for the conductive layer 141 can be used.

The transistor 41 and the transistor 42 having the structure illustrated in FIGS. 59A to 59C can be miniaturized more than the transistor 41 and the transistor 42 having the structure illustrated in FIGS. 2A to 2C, for example. Therefore, the memory cells can be miniaturized and highly integrated. Accordingly, a semiconductor device that capable of being miniaturized and highly integrated can be provided. In contrast, the transistor 41 and the transistor 42 having the structure illustrated in FIGS. 2A to 2C can be formed by a method simpler than the method for forming the transistor 41 and the transistor 42 having the structure illustrated in FIGS. 59A to 59C; accordingly, the semiconductor device can be manufactured through a simplified process and provided at low cost.

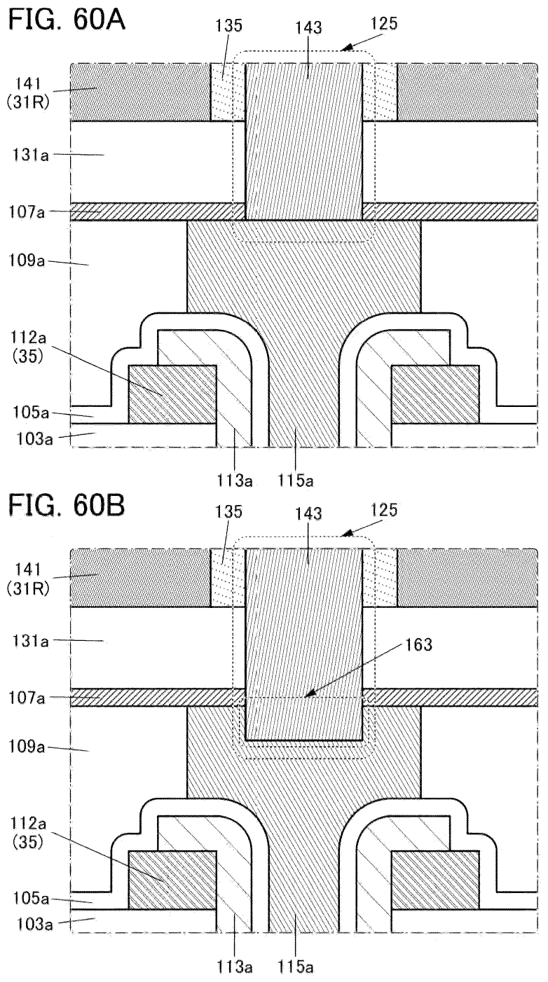

FIG. 60A is an enlarged view extracting part of the structure illustrated in FIG. 59B and illustrating part of the insulating layer 103a, part of the conductive layer 112a, part of the semiconductor layer 113a, part of the insulating layer 105a, part of the conductive layer 115a, part of the insulating layer 109a, part of the insulating layer 107a, part of the insulating layer 131a, part of the conductive layer 141, part of the insulating layer 135, and part of the conductive layer 143. FIG. 60A illustrates an example in which the top surface of the conductive layer 115a and the bottom surface of the conductive layer 143 provided inside the opening portion 125 are aligned or substantially aligned with a top surface of the insulating layer 109a.

FIG. 60B illustrates a modification example of FIG. 60A and illustrates an example in which the conductive layer 115a includes a depressed portion 163. For example, at the time of processing the insulating layer 107a in forming the opening portion 125, the depressed portion 163 is formed in the conductive layer 115a by processing part of the conductive layer 115a.

A modification example of the structure illustrated in FIGS. 59A to 59C is described below.

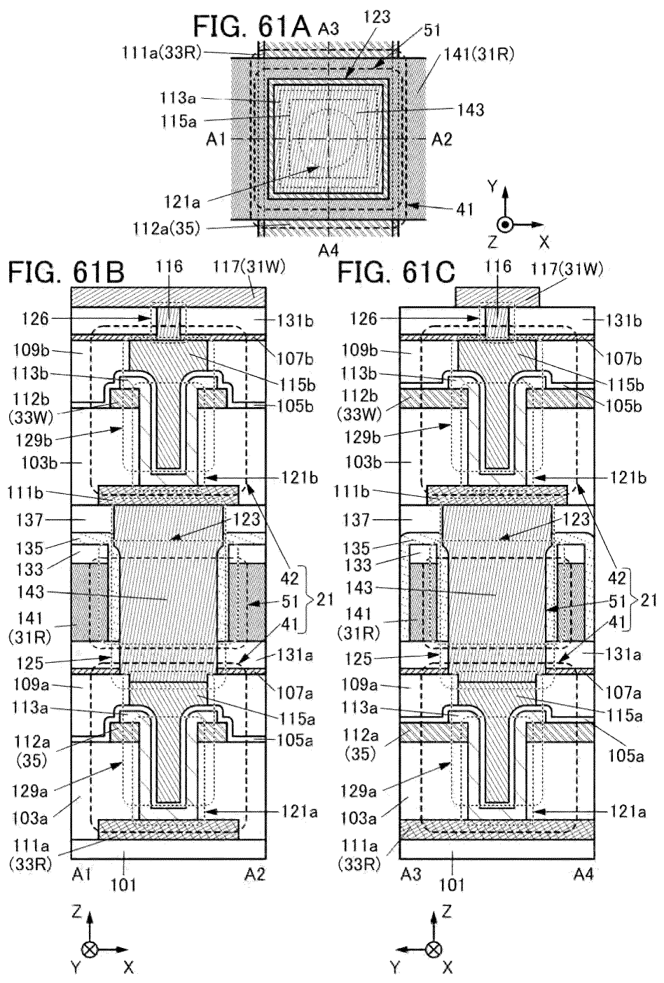

FIGS. 61A to 61C illustrate an example in which the top surface of the conductive layer 115a is positioned below the top surface of the insulating layer 109a and the conductive layer 143 is in contact with part of the top surface of the insulating layer 109a. For example, part of the conductive layer 115a is processed at the time of processing the insulating layer 107a in forming the opening portion 125, so that the top surface of the conductive layer 115a is positioned below the top surface of the insulating layer 109a. In the example illustrated in FIGS. 61A to 61C, the entire top surface of the conductive layer 115a can be in contact with the conductive layer 143.

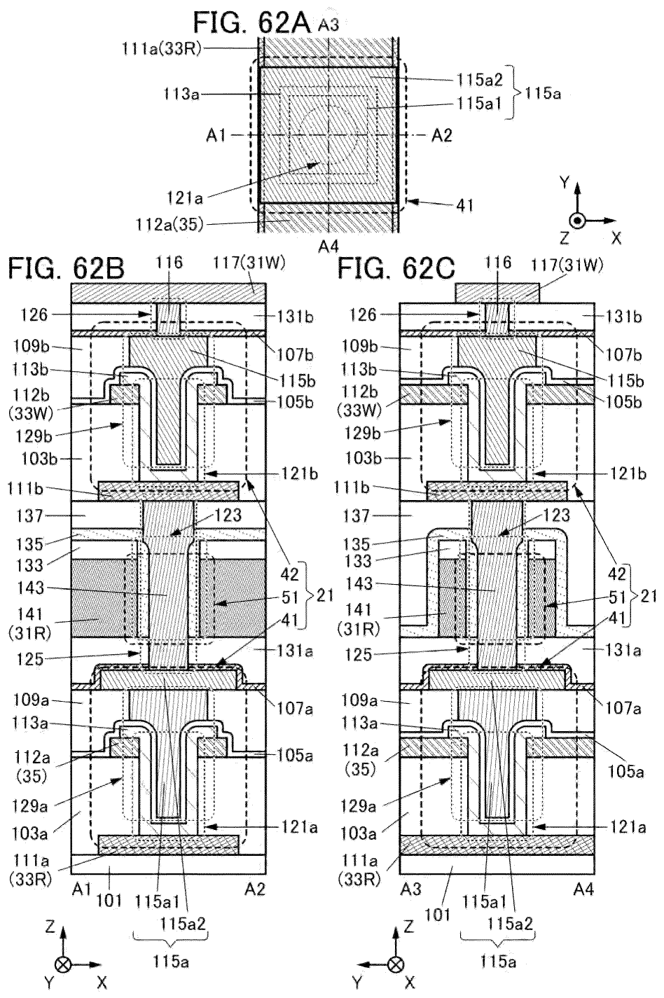

FIGS. 62A to 62C illustrate an example in which the conductive layer 115a includes a conductive layer 115a1 provided inside the opening portion 129a and a conductive layer 115a2 over the conductive layer 115al. Although FIGS. 62A to 62C illustrate an example in which the conductive layer 115a2 includes a region that is positioned over the insulating layer 109a and does not overlap with the conductive layer 115al, the conductive layer 115a2 may entirely overlap with the conductive layer 115al, for example.

In the example illustrated in FIGS. 62A to 62C, the opening portion 125 is formed so as to reach the conductive layer 115a2. This can prevent formation of the depressed portion 163 as illustrated in FIG. 60B in the conductive layer 115al. In contrast, in the case where the transistor 41 has a structure that does not include the conductive layer 115a2, the manufacturing process of the transistor 41 can be simplified.

In the example illustrated in FIGS. 62A to 62C, the conductive layer 115a1 is provided closer to the semiconductor layer 113a than the conductive layer 115a2 is. The conductive layer 115b1 illustrated in FIG. 33A to FIG. 34C is provided closer to the semiconductor layer 113b than the conductive layer 115b2 is. Accordingly, any of materials similar to the materials that can be used for the conductive layer 115b1 can be used for the conductive layer 115al. In addition, any of materials similar to the materials that can be used for the conductive layer 115b2 can be used for the conductive layer 115a2.

In order to form the conductive layer 115a illustrated in FIGS. 62A to 62C, first, the conductive layer 115a1 is formed inside the opening portion 129a. Next, a conductive film to be the conductive layer 115a2 is formed over the conductive layer 115al and the insulating layer 109a, and then a pattern is formed by a photolithography method and the conductive film is processed by an etching method using the pattern. Thus, the conductive layer 115a2 is formed. Through the above-described steps, the conductive layer 115a including the conductive layer 115a1 and the conductive layer 115a2 can be formed.

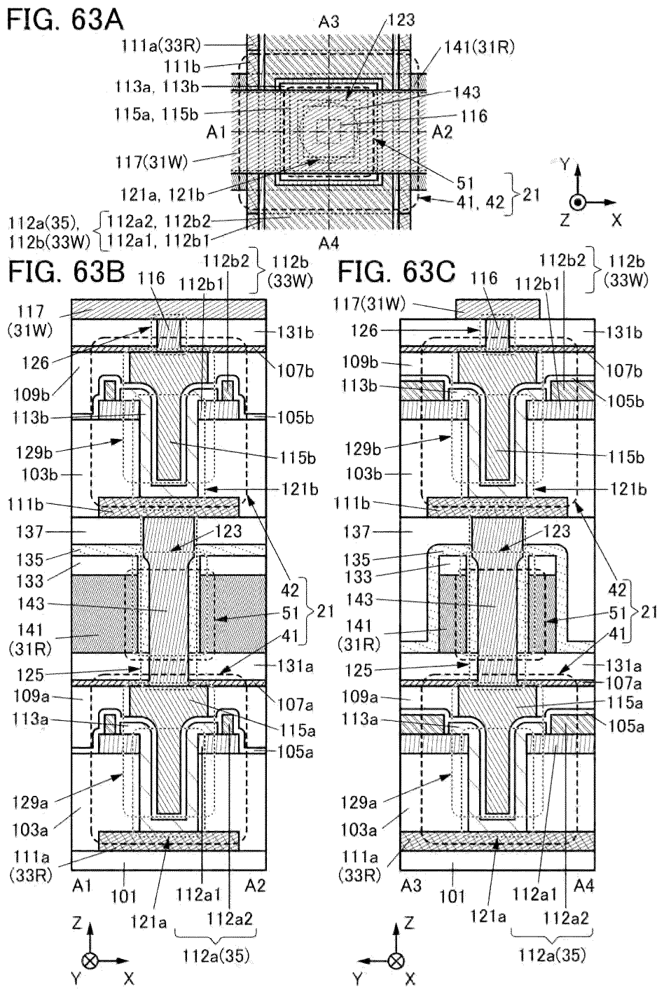

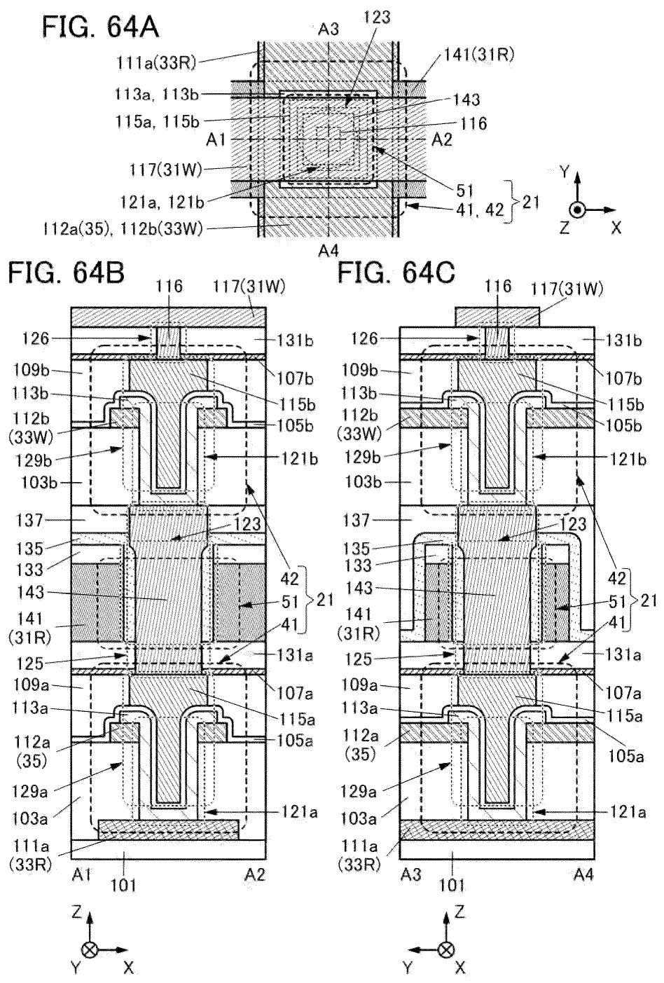

FIGS. 63A to 63C illustrate an example in which the conductive layer 112a includes the conductive layer 112a1 and the conductive layer 112a2 over the conductive layer 112a1 and the conductive layer 112b includes the conductive layer 112b1 and the conductive layer 112b2 over the conductive layer 112b1, as in the example illustrated in FIGS. 35A to 35C. FIGS. 64A to 64C illustrate an example in which the transistor 42 does not include the conductive layer 111b, as in the example illustrated in FIGS. 38A to 38C.

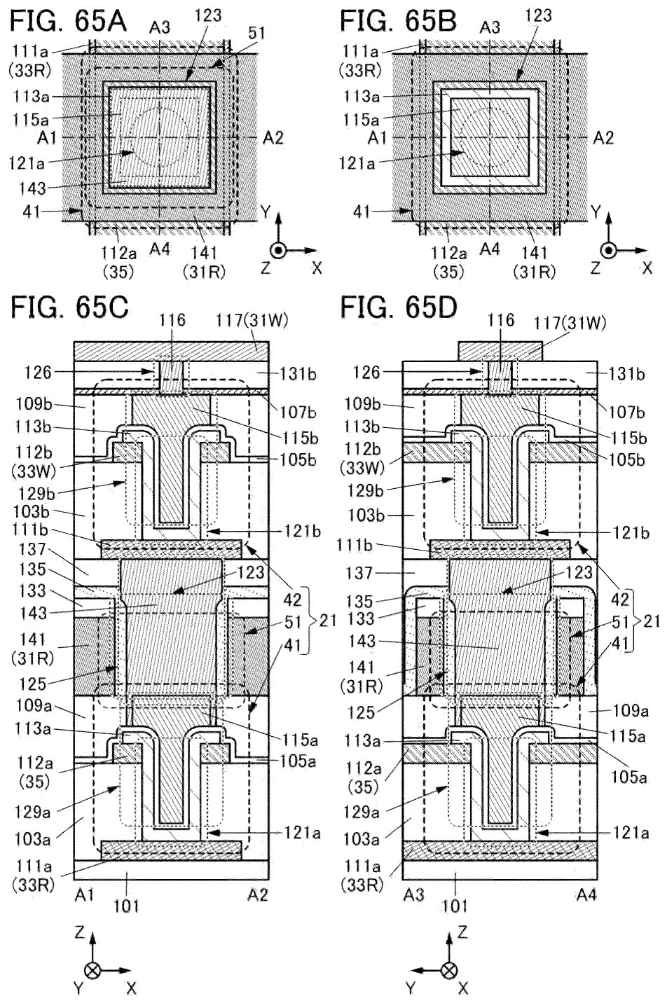

FIG. 65A is a plan view illustrating a structure example of a semiconductor device of one embodiment of the present invention and illustrating structure examples of the transistor 41 and the capacitor 51. FIG. 65A does not illustrate a structure example of the transistor 42. FIG. 65B is a plan view omitting the conductive layer 143 from the structure illustrated in FIG. 65A. FIG. 65C is a cross-sectional view taken along dashed-dotted line A1-A2 in FIGS. 65A and 65B. FIG. 65D is a cross-sectional view taken along dashed-dotted line A3-A4 in FIGS. 65A and 65B.

The memory cell 21 illustrated in FIGS. 65C and 65D is different from that illustrated in FIGS. 59B and 59C in not including the insulating layer 107a and the insulating layer 131a. In the example illustrated in FIGS. 65C and 65D, the top surface of the conductive layer 115a and a bottom surface of the conductive layer 141 are positioned on the same plane, for example. Here, for example, when the conductive layer 115a and the conductive layer 141 do not overlap with each other in the plan view as illustrated in FIG. 65B, even though the top surface of the conductive layer 115a and the bottom surface of the conductive layer 141 are positioned on the same plane, a short circuit due to the contact between the conductive layer 115a and the conductive layer 141 can be prevented.

As illustrated in FIGS. 65A, 65C, and 65D, the conductive layer 143 preferably covers the conductive layer 115a. For example, the conductive layer 143 preferably covers the top surface and the side surface of the conductive layer 115a outside the opening portion 121a. This can prevent a short circuit between the conductive layer 115a and the conductive layer 141 due to the contact therebetween. Although FIGS. 65C and 65D illustrate an example in which the conductive layer 143 includes a region in contact with the top surface of the insulating layer 105a, the insulating layer 109a may be provided between the insulating layer 105a and the conductive layer 143 in the region. In the case where the etching selectivity of the insulating layer 137 to the insulating layer 109a is high, for example, the insulating layer 109a is not processed at the time of forming the opening portion 125, whereby a structure where the conductive layer 143 does not cover the side surface of the conductive layer 115a can be formed. Furthermore, unless a short circuit between the conductive layer 141 and the conductive layer 115a is caused, as in the example illustrated in FIGS. 59B and 59C, a structure where the bottom surface of the conductive layer 143 covers only part of the top surface of the conductive layer 115a and the insulating layer 135 includes a region overlapping with the conductive layer 115a can be formed.

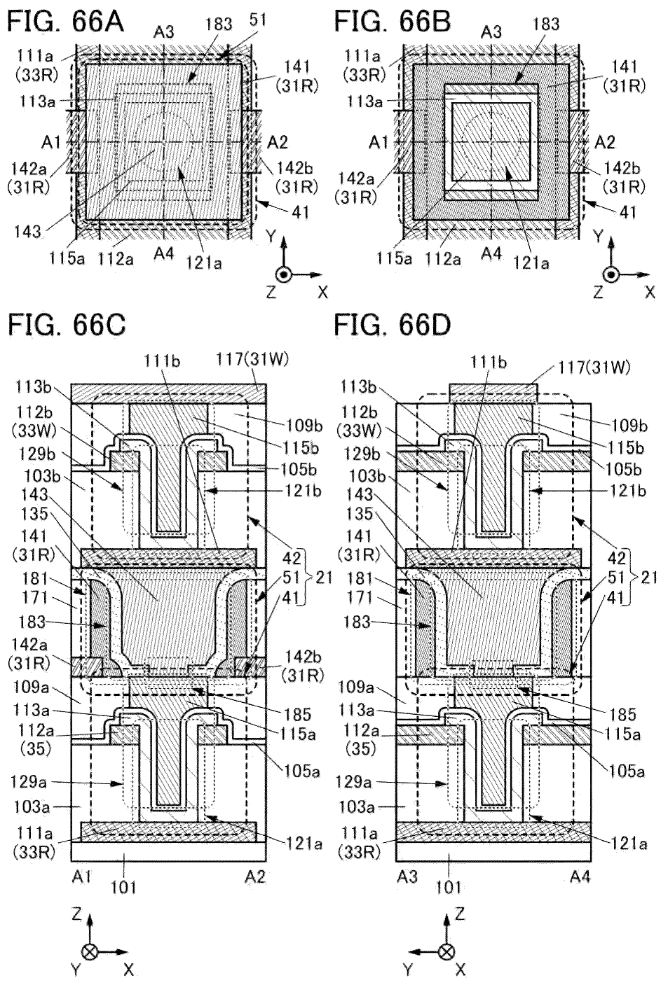

In the case where the insulating layer 107a and the insulating layer 131a are not provided over the conductive layer 115a, the manufacturing process of the semiconductor device can be simplified. In contrast, in the case where the insulating layer 107a and the insulating layer 131a are provided over the conductive layer 115a, layout flexibility can be increased. Furthermore, a short circuit between the conductive layer 115a and the conductive layer 141 can be prevented easily; accordingly, the reliability of the memory cell 21 can be improved, and a highly reliable semiconductor device can be provided. FIG. 66A illustrates a modification example of the structure illustrated in FIG. 59A and illustrates structure examples of the transistor 41 and the capacitor 51. That is, FIG. 66A does not illustrate a structure example of the transistor 42. FIG. 66B is a plan view omitting the conductive layer 143 from FIG. 66A. FIG. 66C is a cross-sectional view taken along dashed-dotted line A1-A2 in FIGS. 66A and 66B. FIG. 66D is a cross-sectional view taken along dashed-dotted line A3-A4 in FIGS. 66A and 66B. In the example illustrated in FIGS. 66A to 66D, the insulating layer 107a, the insulating layer 107b, the insulating layer 131a, the insulating layer 131b, and the conductive layer 116 are not provided. Furthermore, in the example illustrated in FIGS. 66A to 66D, the structure between the insulating layer 109a/the conductive layer 115a and the insulating layer 103b/the conductive layer 111b is similar to the structure between the insulating layer 131 and the insulating layer 103b/the conductive layer 111b illustrated in FIGS. 44A to 44D.

In the example illustrated in FIGS. 66C and 66D, the opening portion 185 reaching the conductive layer 115a is provided in the insulating layer 135. Furthermore, the conductive layer 117 can include a region in contact with the top surface of the conductive layer 115b, for example.

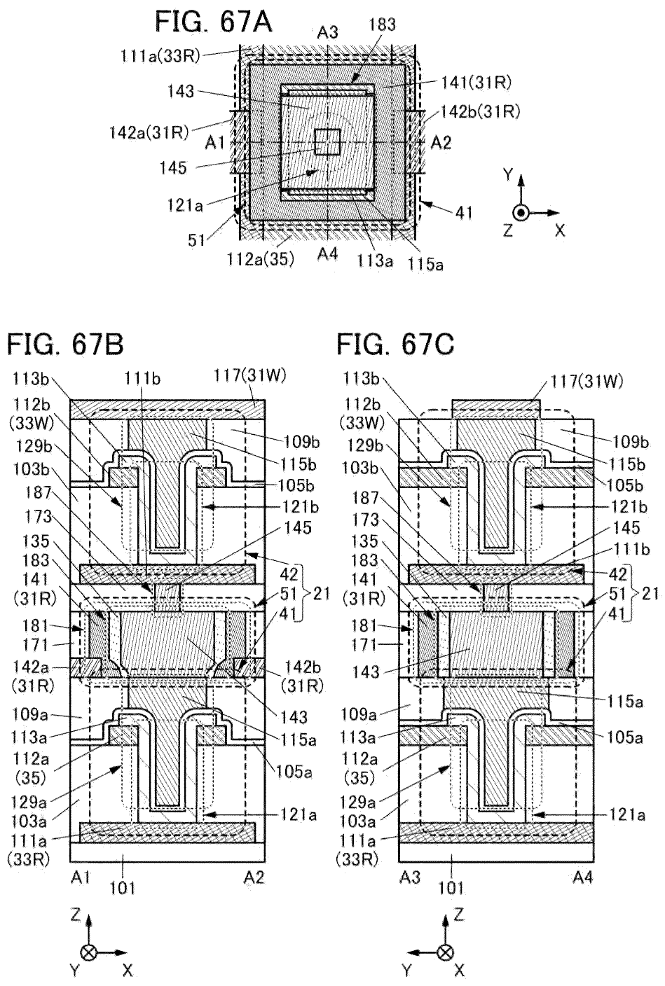

FIGS. 67A, 67B, and 67C illustrate a modification example of the structure illustrated in FIGS. 66A, 66C, and 66D, respectively, and illustrate an example in which the structure between the insulating layer 109a/the conductive layer 115a and the insulating layer 103b/the conductive layer 111b is similar to the structure between the insulating layer 131 and the insulating layer 103b/the conductive layer 111b illustrated in FIGS. 46A to 46C.

### <Structure Example 5 of Semiconductor Device>

A structure example of the memory cell 21 of the case where the capacitor 51 has a structure different from that in FIGS. 2A to 2C is described below. The structure described below can be applied to the memory cell 21 illustrated in FIG. 1B1. Furthermore, at least part of the structure described below can be applied to the memory cells 21 illustrated in FIG. 1B2 and FIG. 14A.

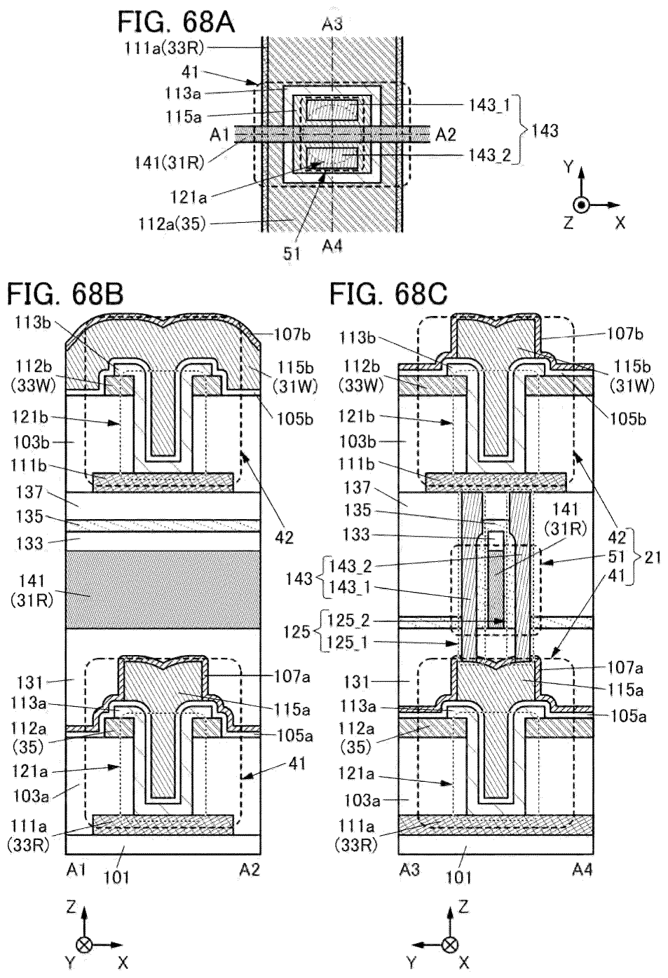

FIGS. 68A to 68C illustrate an example in which the memory cell 21 includes a conductive layer 143_1 and a conductive layer 143_2 as the conductive layer 143 and the conductive layer 141 is provided between the conductive layer 143_1 and the conductive layer 143_2. FIG. 68A is a plan view illustrating structure examples of the transistor 41 and the capacitor 51. FIG. 68B is a cross-sectional view taken along dashed-dotted line A1-A2 in FIG. 68A. FIG. 68C is a cross-sectional view taken along dashed-dotted line A3-A4 in FIG. 68A.

In the plan view of FIG. 68A, the conductive layer 143_1 is provided on the A3 side of the conductive layer 141, and the conductive layer 143_2 is provided on the A4 side of the conductive layer 141. As illustrated in FIG. 68C, as the opening portion 125, an opening portion 125_1 and an opening portion 125_2 are provided in the insulating layer 107a, the insulating layer 131, the insulating layer 135, and the insulating layer 137. The conductive layer 143_1 is provided inside the opening portion 125_1, and the conductive layer 143_2 is provided inside the opening portion 125_2. In the example illustrated of FIG. 68A, the conductive layer 141 is provided between the conductive layer 143_1 and the conductive layer 143_2 in the plan view. In other words, the conductive layer 141 covers one side of the conductive layer 143_1 and one side of the conductive layer 143_2 in the plan view.

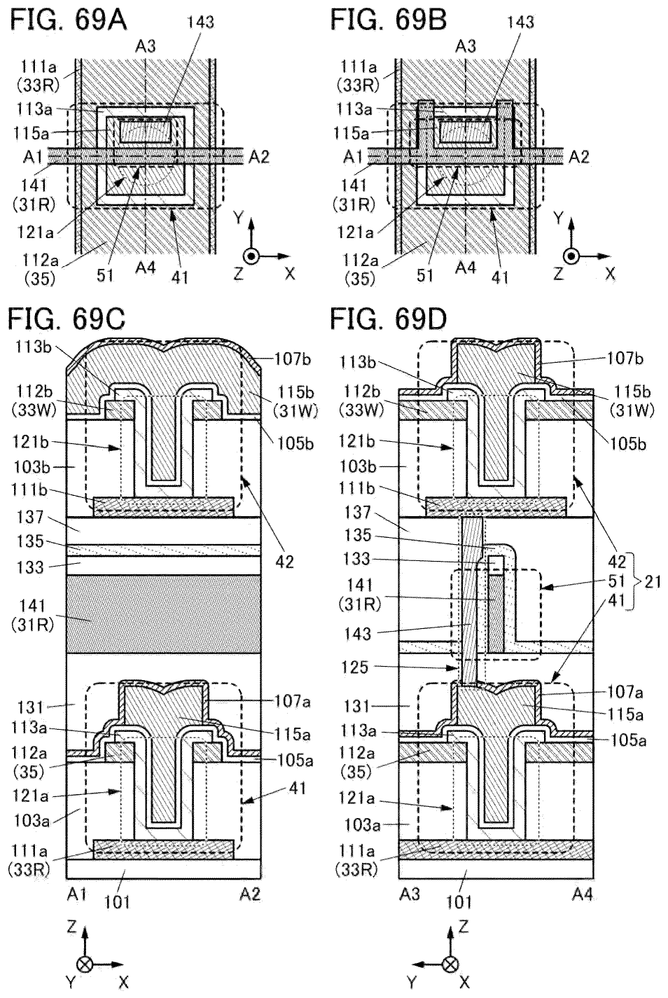

FIG. 69A illustrates a modification example of the structure illustrated in FIG. 68A and illustrates an example in which the conductive layer 143_2 is not provided. FIG. 69B illustrates a modification example of the structure illustrated in FIG. 69A and illustrates an example in which the conductive layer 141 is provided so as to cover three sides of the conductive layer 143 in the plan view. In FIGS. 69A and 69B, the conductive layer 143_1 illustrated in FIG. 68A serves as the conductive layer 143.

The capacitance of the capacitor 51 can be larger in the example illustrated in FIG. 69B than the example illustrated in FIG. 69A. In contrast, in the example illustrated in FIG. 69A, the conductive layer 141 can be formed more easily than in the example illustrated in FIG. 69B.

FIG. 69C is a cross-sectional view taken along dashed-dotted line A1-A2 in FIGS. 69A and 69B. FIG. 69D is a cross-sectional view taken along dashed-dotted line A3-A4 in FIGS. 69A and 69B. In FIG. 69D, the opening portion 125_2 illustrated in FIG. 68C is not provided and the opening portion 125_1 serves as the opening portion 125.

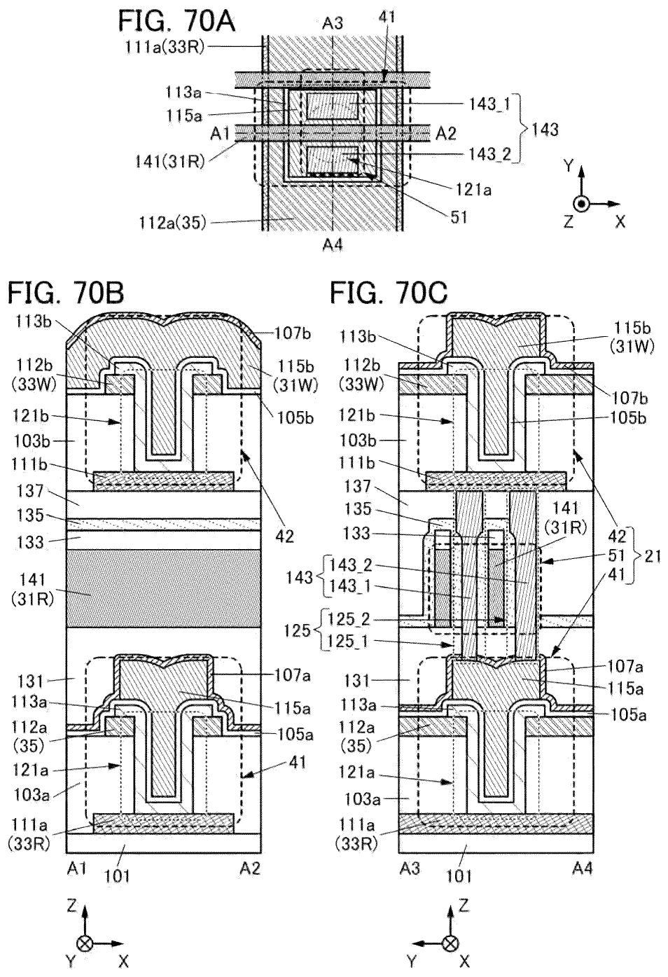

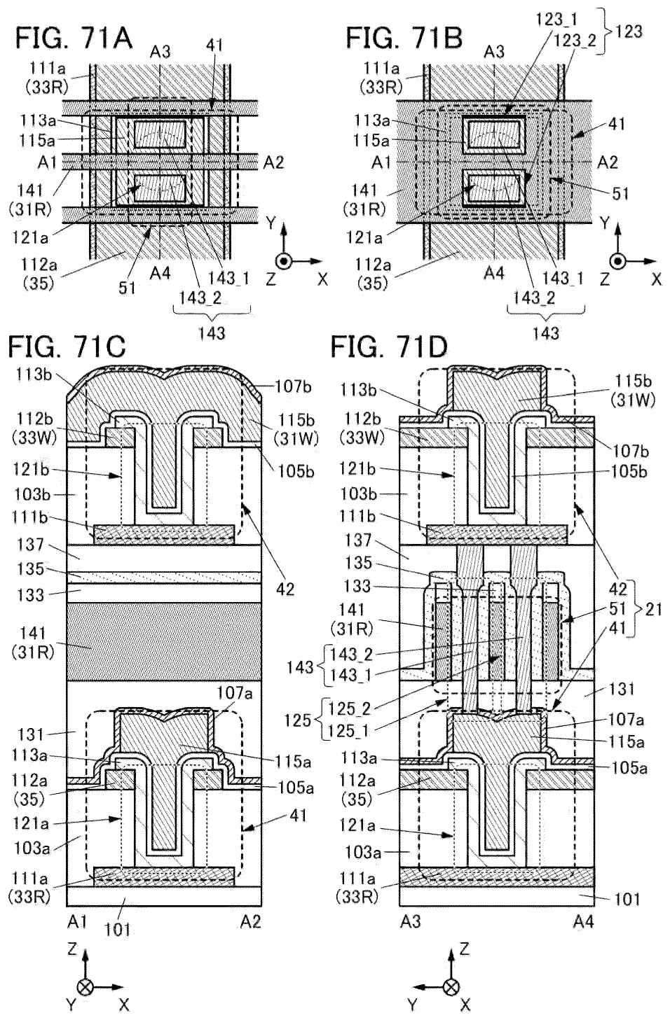

FIGS. 70A, 70B, and 70C illustrate a modification example of the structure illustrated in FIGS. 68A, 68B, and 68C, respectively, and illustrate an example in which the conductive layer 141 is provided so as to cover two sides of the conductive layer 143_1 in the plan view. FIG. 71A illustrates a modification example of the structure illustrated in FIG. 70A and illustrates an example in which the conductive layer 141 is provided so as to cover two sides of the conductive layer 143_2 as well as the two sides of the conductive layer 143_1 in the plan view. FIG. 71B illustrates a modification example of the structure illustrated in FIG. 71A and illustrates an example in which conductive layer 141 covers the entire side surfaces of the conductive layer 143_1 and the entire side surfaces of the conductive layer 143_2 in the plan view. FIG. 71C is a cross-sectional view taken along dashed-dotted line A1-A2 in FIGS. 71A and 71B. FIG. 71D is a cross-sectional view taken along dashed-dotted line A3-A4 in FIGS. 71A and 71B.

FIG. 71B illustrates an opening portion 123_1 and an opening portion 123_2 as the opening portion 123 included in the conductive layer 141. The conductive layer 143_1 is provided inside the opening portion 123_1, and the conductive layer 143_2 is provided inside the opening portion 123_2.

The capacitance of the capacitor 51 can be larger in the example illustrated in FIG. 71B than the example illustrated in FIG. 71A. In contrast, in the example illustrated in FIG. 71A, the conductive layer 141 can be formed more easily than in the example illustrated in FIG. 71B.

In the example illustrated in FIG. 70A, the conductive layer 141 provided on the A3 side of the conductive layer 143_1 and the conductive layer 141 provided between the conductive layer 143_1 and the conductive layer 143_2 are electrically connected to each other in a region not illustrated in FIG. 70A. For example, these conductive layers 141 are electrically connected to each other outside the memory portion 20 illustrated in FIG. 1A, for example. Thus, these conductive layers 141 can be regarded as one wiring 31R. Similarly, in the example illustrated in FIG. 71A, the conductive layer 141 provided on the A3 side of the conductive layer 143_1, the conductive layer 141 provided between the conductive layer 143_1 and the conductive layer 143_2, and the conductive layer 141 provided on the A4 side of the conductive layer 143_2 are electrically connected to one another in a region not illustrated in FIG. 71A. Thus, these conductive layers 141 can be regarded as one wiring 31R.

In the examples illustrated in FIG. 68A to FIG. 71D, three or more conductive layers 143 may be provided. In that case, three or more opening portions 125 are provided in the insulating layer 107a, the insulating layer 131, the insulating layer 135, and the insulating layer 137. Furthermore, as in the example illustrated in FIG. 70A, for example, the conductive layer 141 may cover two sides of any of the conductive layers 143. As in the example illustrated in FIG. 71A, the conductive layer 141 may cover two sides of every conductive layer 143. Moreover, as in the example illustrated in FIG. 71B, the conductive layer 141 may cover the entire side surfaces of every conductive layer 143.

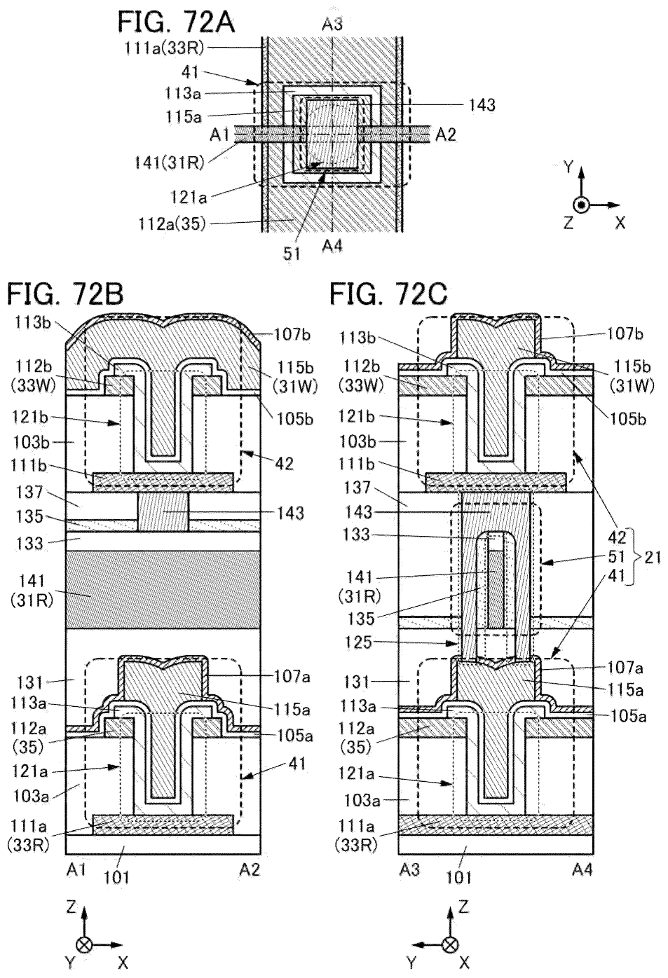

FIGS. 72A, 72B, and 72C illustrate a modification example of the structure illustrated in FIGS. 68A, 68B, and 68C, respectively, and illustrate an example in which the conductive layer 143 includes a region overlapping with the top surface of the conductive layer 141. In the example illustrated in FIGS. 72A to 72C, one opening portion 125 is provided in the insulating layer 137, the insulating layer 135, the insulating layer 131, and the insulating layer 107a, and one conductive layer 143 is provided inside the opening portion 125. As illustrated in FIG. 72C, the conductive layer 143 can cover the side and top surfaces of the conductive layer 141 in the Y-Z plane. Here, not only the insulating layer 135 but also the insulating layer 133 may function as the dielectric layer of the capacitor 51. In this case, the insulating layer 133 is included in the capacitor 51.

As illustrated in FIGS. 72B and 72C, the conductive layer 143 can include a region in contact with the top surface of the insulating layer 133. In that case, the etching selectivity of the insulating layer 107a and the insulating layer 131 to the insulating layer 133 is preferably high. This can inhibit the insulating layer 133 from being reduced in thickness when the opening portion 125 is formed in the insulating layer 107a and the insulating layer 131. Thus, a short circuit between the conductive layer 141 and the conductive layer 143 can be inhibited. Note that the insulating layer 135 may be provided between the insulating layer 133 and the conductive layer 143; in this case, the thickness of the insulating layer 135 in the region between the insulating layer 133 and the conductive layer 143 is smaller than the thickness of the insulating layer 135 in the region not overlapping with the top surface of the insulating layer 133, for example.

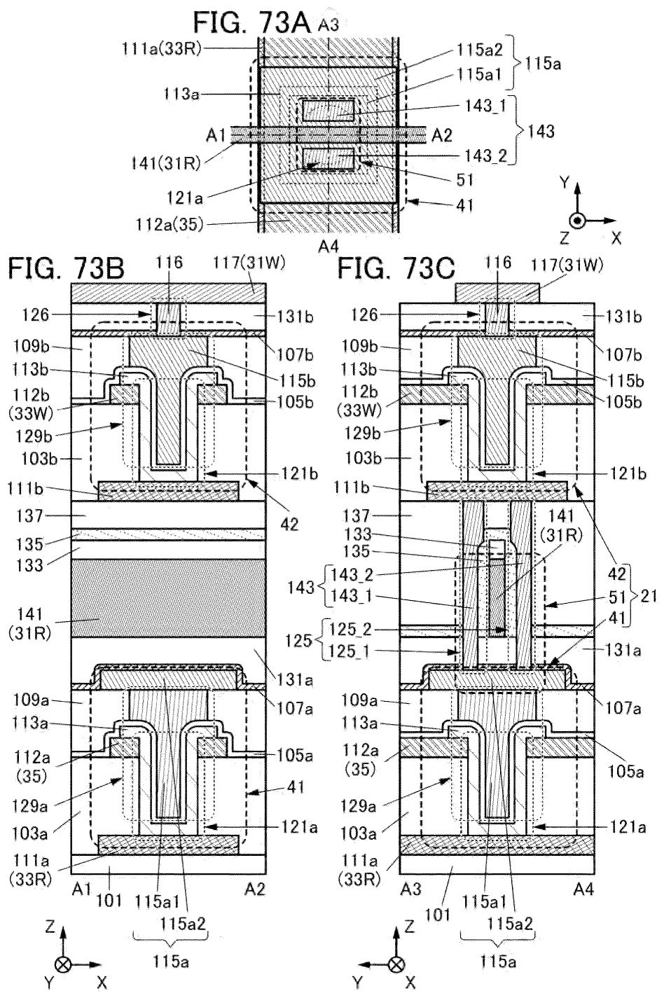

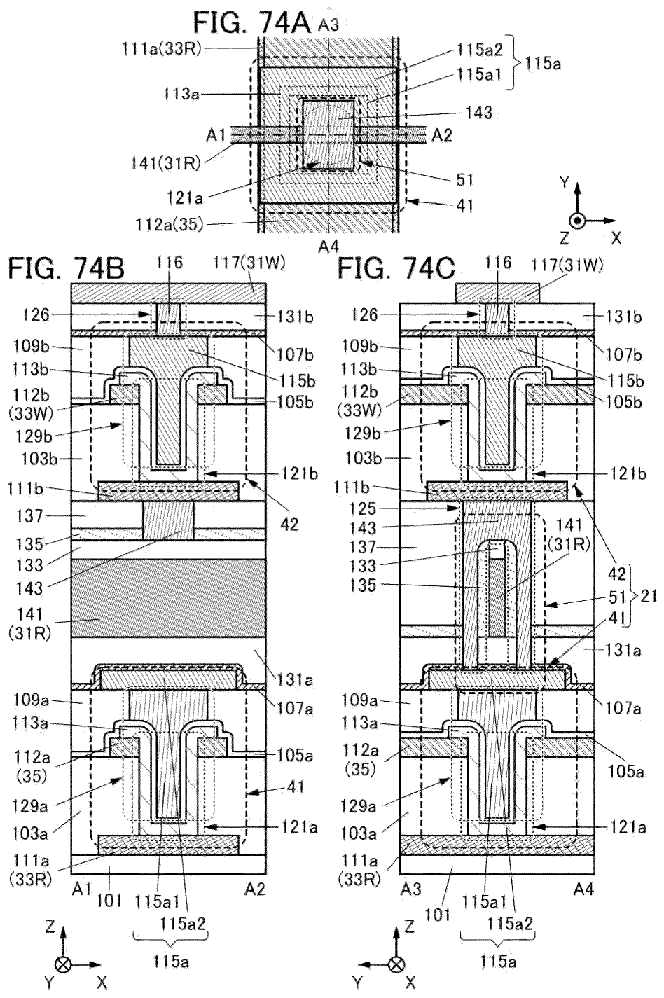

FIGS. 73A, 73B, and 73C illustrate a modification example of the structure illustrated in FIGS. 62A, 62B, and 62C, respectively, and illustrate an example in which the memory cell 21 includes the conductive layer 143_1 and the conductive layer 143_2 as the conductive layer 143 and the conductive layer 141 is provided between the conductive layer 143_1 and the conductive layer 143_2 as in the example illustrated in FIGS. 68A to 68C. As illustrated in FIG. 73C, a structure where the conductive layer 143 covers the side surface of the conductive layer 141 and the conductive layer 115a2 covers the bottom surface of the conductive layer 141 in the Y-Z plane can be formed. Here, in some cases, the conductive layer 115a2 functions as the one electrode of the capacitor 51, and the insulating layer 107a and the insulating layer 131a function as the dielectric layer of the capacitor 51. In this case, the conductive layer 115a2, the insulating layer 107a, and the insulating layer 131a are included in the capacitor 51. FIGS. 74A, 74B, and 74C illustrate a modification example of the structure illustrated in FIGS. 73A, 73B, and 73C, respectively, and illustrate an example in which the conductive layer 143 includes a region overlapping with the top surface of the conductive layer 141 as in the example illustrated in FIGS. 72A to 72C. In the example illustrated in FIGS. 74A to 74C, one opening portion 125 is provided in the insulating layer 137, the insulating layer 135, the insulating layer 131a, and the insulating layer 107a, and one conductive layer 143 is provided inside the opening portion 125. As illustrated in FIG. 74C, a structure where the conductive layer 143 covers the side and top surfaces of the conductive layer 141 and the conductive layer 115a2 covers the bottom surface of the conductive layer 141 in the Y-Z plane can be formed. Here, in some cases, the conductive layer 115a2 functions as the one electrode of the capacitor 51, and the insulating layer 107a, the insulating layer 131a, and the insulating layer 133 function as the dielectric layer of the capacitor 51. In this case, the conductive layer 115a2, the insulating layer 107a, the insulating layer 131a, and the insulating layer 133 are included in the capacitor 51.

### <Structure Example 6 of Semiconductor Device>

A structure example of a plurality of the transistors 41 and 42 is described below. Specifically, a structure example of the transistors 41 and 42 provided in the memory cells in four rows and four columns is described with reference to plan views.

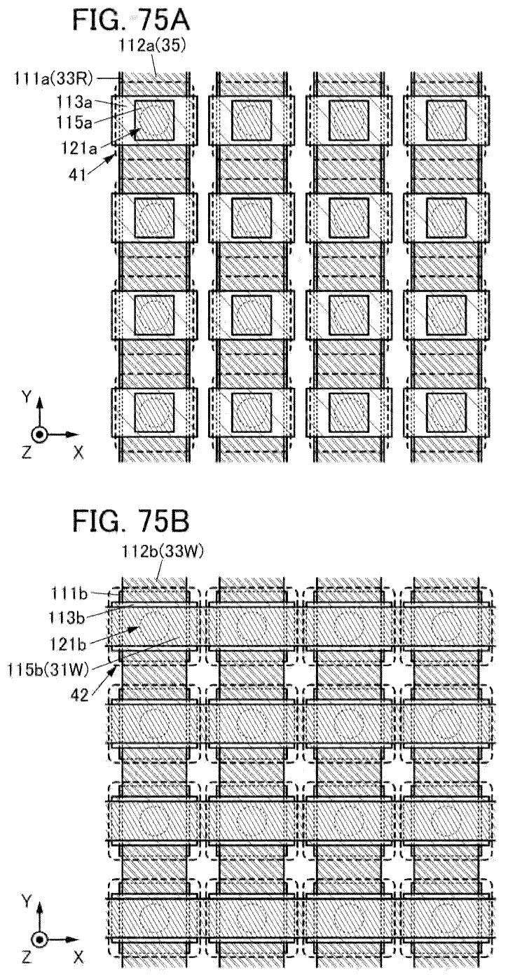

FIG. 75A illustrates a modification example of the transistor 41 included in the memory cell 21 illustrated in FIG. 16A, and FIG. 75B illustrates a modification example of the transistor 42 included in the memory cell 21 illustrated in FIG. 16A. FIG. 75A illustrates an example in which the side end portion of the semiconductor layer 113a is positioned on the outer side of the side end portion that is of the conductive layer 112a and does not face the opening portion 121a in the X direction, and FIG. 75B illustrates an example in which the side end portion of the semiconductor layer 113b is positioned on the outer side of the side end portion that is of the conductive layer 112b and does not face the opening portion 121b in the X direction. In the example illustrated in FIG. 75A, the semiconductor layer 113a includes a region not overlapping with the conductive layer 112a. In the example illustrated in FIG. 75B, the semiconductor layer 113b includes a region not overlapping with the conductive layer 112b. Although FIG. 75A illustrates an example in which the side end portion of the semiconductor layer 113a is positioned on the outer side of the side end portion of the conductive layer 111a in the X direction and FIG. 75B illustrates an example in which the side end portion of the semiconductor layer 113b is positioned on the outer side of the side end portion of the conductive layer 111b in the X direction, one embodiment of the present invention is not limited thereto. For example, the side end portion of the semiconductor layer 113a may be positioned between the side end portion of the conductive layer 111a and the side end portion that is of the conductive layer 112a and does not face the opening portion 121a in the X direction. Furthermore, the side end portion of the semiconductor layer 113b may be positioned between the side end portion of the conductive layer 111b and the side end portion that is of the conductive layer 112b and does not face the opening portion 121b in the X direction.

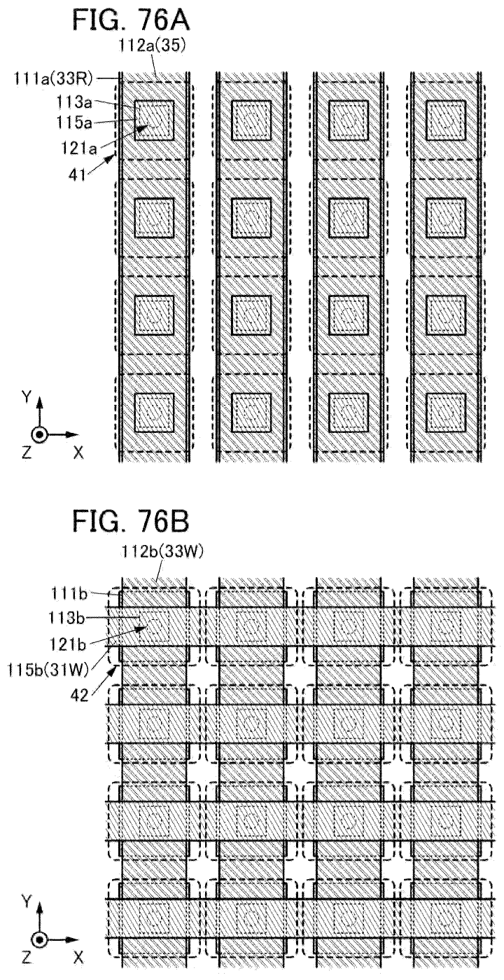

FIG. 76A illustrates a modification example of the transistor 41 included in the memory cell 21 illustrated in FIG. 16A, and FIG. 76B illustrates a modification example of the transistor 42 included in the memory cell 21 illustrated in FIG. 16A. FIG. 76A illustrates an example in which the side end portion of the conductive layer 115a is positioned on the outer side of the side end portion of the semiconductor layer 113a, and FIG. 76B illustrates an example in which the side end portion of the conductive layer 115b is positioned on the outer side of the side end portion of the semiconductor layer 113b. In the example illustrated in FIG. 76A, the entire semiconductor layer 113a can overlap with the conductive layer 115a; in the example illustrated in FIG. 76B, the entire semiconductor layer 113b can overlap with the conductive layer 115b.

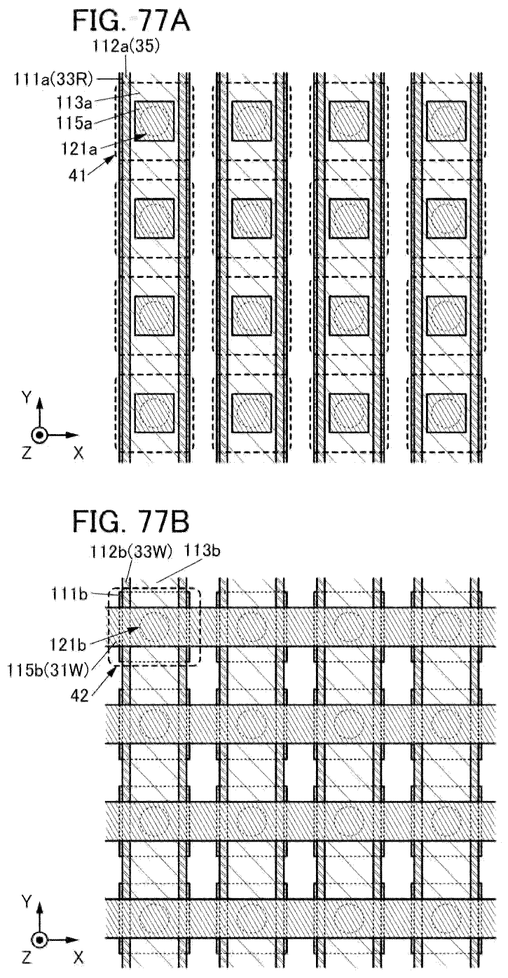

FIG. 77A illustrates a modification example of the transistor 41 included in the memory cell 21 illustrated in FIG. 16A, and FIG. 77B illustrates a modification example of the transistor 42 included in the memory cell 21 illustrated in FIG. 16A. FIG. 77A illustrates an example in which the semiconductor layer 113a is shared by the transistors 41 arranged in the Y direction, that is, in which the semiconductor layer 113a is shared by the transistors 41 included in the memory cells in the same column. FIG. 77B illustrates an example in which the semiconductor layer 113b is shared by the transistors 42 arranged in the Y direction, that is, in which the semiconductor layer 113b is shared by the transistors 42 included in the memory cells in the same column.

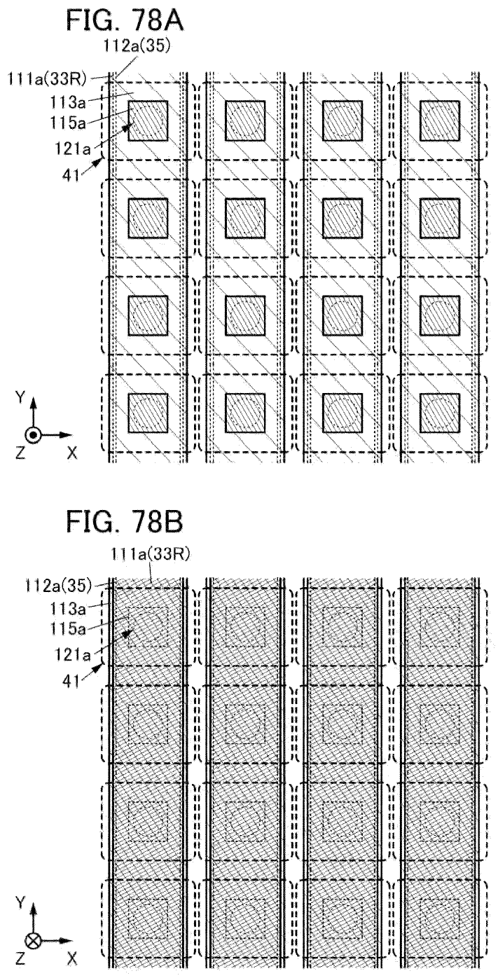

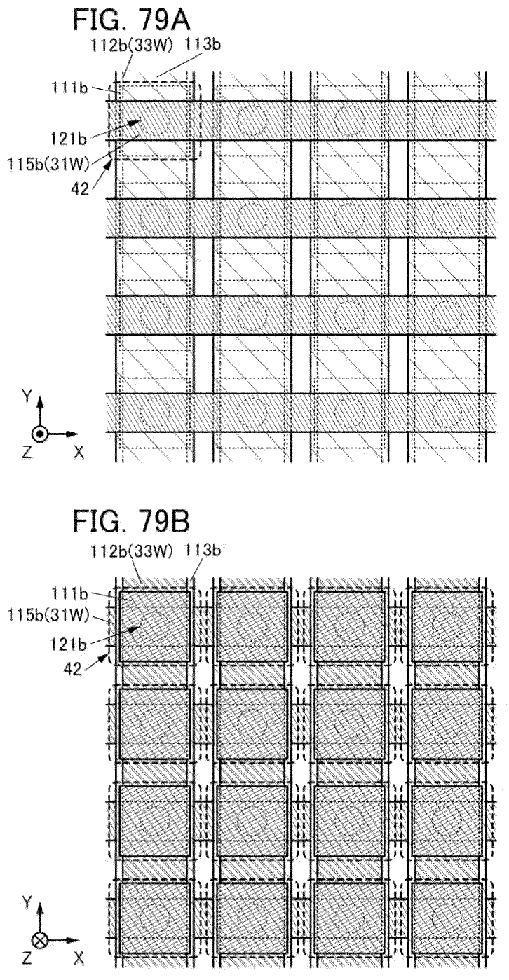

FIG. 78A illustrates a modification example of the transistor 41 illustrated in FIG. 77A, and FIG. 78B is a plan view thereof seen from the reverse side of FIG. 78A in the Z direction. FIG. 79A illustrates a modification example of the transistor 42 illustrated in FIG. 77B, and FIG. 79B is a plan view thereof seen from the reverse side of FIG. 79A in the Z direction. Note that, in the case where FIG. 78A and FIG. 79A are referred to as top views, for example, FIG. 78B and FIG. 79B can be referred to as bottom views.

FIGS. 78A and 78B illustrate an example in which the side end portion of the semiconductor layer 113a is positioned on the outer side of the side end portion that is of the conductive layer 112a and does not face the opening portion 121a in the X direction, and FIGS. 79A and 79B illustrate an example in which the side end portion of the semiconductor layer 113b is positioned on the outer side of the side end portion that is of the conductive layer 112b and does not face the opening portion 121b in the X direction. The structure illustrated in FIGS. 78A and 78B can be regarded as the structure obtained by combining the structures illustrated in FIG. 75A and FIG. 77A, and the structure illustrated in FIGS. 79A and 79B can be regarded as the structure obtained by combining the structures illustrated in FIG. 75B and FIG. 77B.

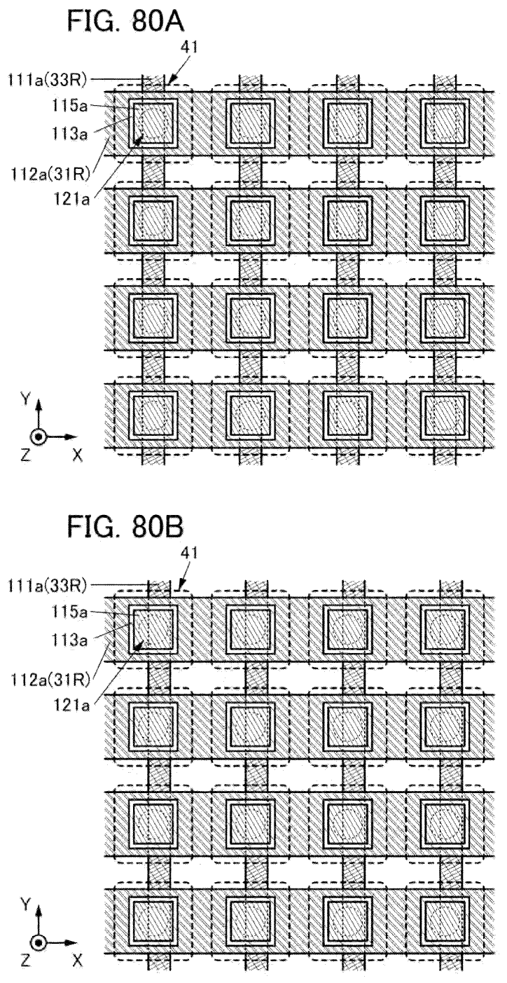

FIG. 80A illustrates a modification example of the transistor 41 illustrated in FIG. 21A and illustrates an example in which part of the opening portion 121a does not overlap with the conductive layer 111a. In the example illustrated in FIG. 80A, parasitic capacitance between the conductive layer 111a and the conductive layer 115a can be small, for example. In the example illustrated in FIG. 21A, the width of one of the source region and the drain region can be increased.

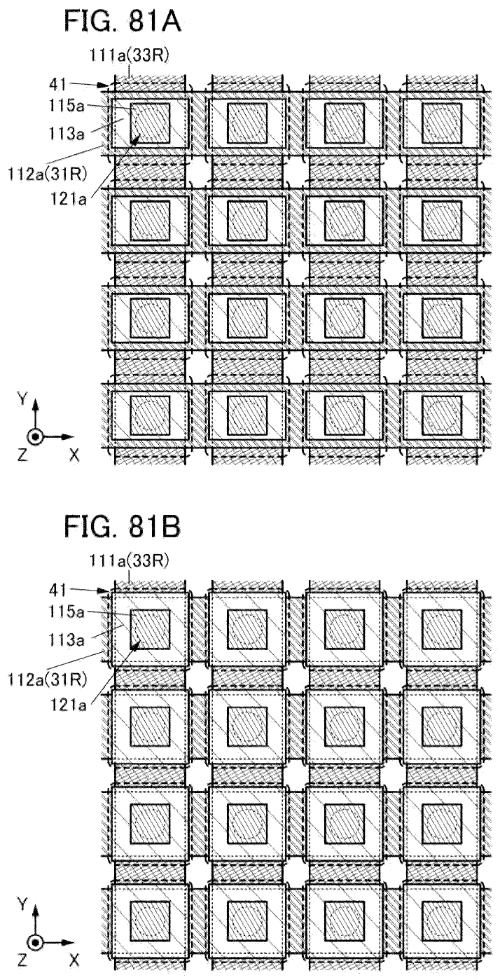

FIG. 80B illustrates a modification example of the transistor 41 illustrated in FIG. 80A and illustrates an example in which the central axis of the conductive layer 111a extending in the Y direction does not overlap with the center of the opening portion 121a. FIG. 80B illustrates an example in which the right side end portion of the conductive layer 111a does not overlap with the opening portion 121a and the left side end portion of the conductive layer 111a includes a region overlapping with the opening portion 121a. Note that both the left side end portion and the right side end portion of the conductive layer 111a may or may not include a region overlapping with the opening portion 121a. FIG. 81A illustrates a modification example of the transistor 41 illustrated in FIG. 21A and illustrates an example in which the side end portion of the semiconductor layer 113a is positioned on the outer side of the side end portion of the conductive layer 111a in the X direction. In the example illustrated in FIG. 81A, the semiconductor layer 113a includes a region not overlapping with the conductive layer 111a.

FIG. 81B illustrates a modification example of the transistor 41 illustrated in FIG. 81A and illustrates an example in which the side end portion of the semiconductor layer 113a is positioned on the outer side of the side end portion of the conductive layer 112a in the Y direction. In the example illustrated in FIG. 81B, the semiconductor layer 113a includes a region not overlapping with the conductive layer 112a.

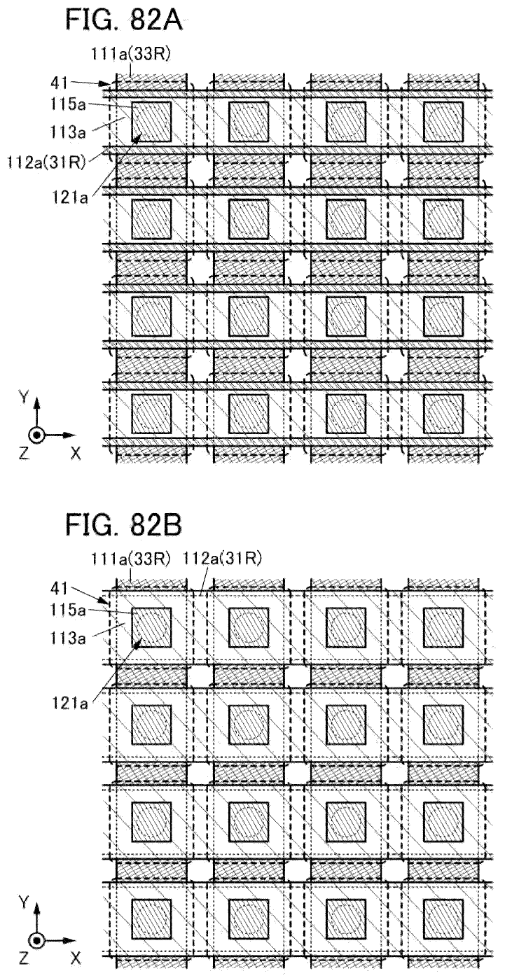

FIGS. 82A and 82B illustrate modification examples of the transistor 41 illustrated in FIGS. 81A and 81B, respectively, and illustrate examples in which the semiconductor layer 113a is shared by the transistors 41 arranged in the X direction, that is, in which the semiconductor layer 113a is shared by the transistors 41 included in the memory cells in the same row.

Among the structures illustrated in FIG. 75A to FIG. 82B, the transistors 41 illustrated in FIG. 75A, FIG. 76A, FIG. 77A, FIG. 78A, and FIG. 78B can be used as the transistors 41 illustrated in FIG. 1B1, FIG. 2A, FIG. 3A1, FIG. 12B, and FIG. 13A, for example. The transistors 41 illustrated in FIG. 80A to FIG. 82B can be used as the transistors 41 illustrated in FIG. 1B2, FIG. 8A, and FIG. 9A1, for example. Furthermore, the transistors 42 illustrated in FIG. 75B, FIG. 76B, FIG. 77B, FIG. 79A, and FIG. 79B can be used as the transistors 42 illustrated in FIG. 1B1, FIG. 1B2, FIG. 2A, FIG. 3A1, FIG. 8A, FIG. 9A1, FIG. 12B, FIG. 13A, FIG. 14A, and FIG. 14B, for example. Note that in some cases, at least part of the structures illustrated in FIG. 75A, FIG. 76A, FIG. 77A, FIG. 78A, and FIG. 78B can be applied to the transistors 41 illustrated in FIG. 1B2, FIG. 8A, and FIG. 9A1, for example. Furthermore, in some cases, at least part of the structures illustrated in FIG. 80A to FIG. 82B can be applied to the transistors 41 illustrated in FIG. 1B1, FIG. 2A, FIG. 3A1, FIG. 12B, and FIG. 13A, for example.

### <Materials for Semiconductor Device>

Materials that can be used for a semiconductor device are described below.

### [Substrate]

As a substrate where the transistor 41, the transistor 42, and the capacitor 51 are formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. A semiconductor substrate in which an insulator region is provided in the above semiconductor substrate, e.g., a silicon on insulator (SOI) substrate or the like is used. Examples of the conductor substrate include a graphite substrate, a metal substrate, an alloy substrate, and a conductive resin substrate. Other examples include a substrate containing a nitride of a metal, a substrate including an oxide of a metal, an insulator substrate provided with a conductor or a semiconductor, a semiconductor substrate provided with a conductor or an insulator, and a conductor substrate provided with a semiconductor or an insulator. Alternatively, any of these substrates provided with an element may be used.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

With further miniaturization and higher integration of a transistor, for example, a problem such as generation of a leakage current may arise because of a thinned gate insulating layer. When a high-k material is used for the insulator functioning as a gate insulating layer, the voltage at the time of operation of the transistor can be reduced while the physical thickness is maintained. In addition, the equivalent oxide thickness (EOT) of the insulator functioning as the gate insulating layer can be reduced. By contrast, when a low-dielectric-constant material is used for the insulator functioning as an interlayer insulating layer, parasitic capacitance formed between wirings can be reduced. Thus, a material is preferably selected depending on the function of an insulator. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that the above-listed silicon oxide may contain nitrogen. Silicon oxide may be formed using, for example, organosilane such as tetraethoxysilane (TEOS).

A transistor including a metal oxide can have stable electrical characteristics when surrounded by an insulator having a function of inhibiting transmission of impurities and oxygen. The insulator having a function of inhibiting transmission of impurities and oxygen can have, for example, a single-layer structure or a stacked-layer structure of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting transmission of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

An insulator that is in contact with a semiconductor or provided in the vicinity of the semiconductor layer, such as a gate insulating layer, preferably includes a region containing excess oxygen. For example, when an insulator including a region containing excess oxygen is in contact with a semiconductor layer or provided in the vicinity of the semiconductor layer, the number of oxygen vacancies in the semiconductor layer can be reduced. Examples of an insulator in which a region containing excess oxygen is easily formed include silicon oxide, silicon oxynitride, and porous silicon oxide. Examples of the insulator having a barrier property against oxygen include an oxide containing one or both of aluminum and hafnium, an oxide containing hafnium and silicon (hafnium silicate), magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of an insulator having a barrier property against hydrogen include aluminum oxide, magnesium oxide, hafnium oxide, gallium oxide, indium gallium zinc oxide, silicon nitride, and silicon nitride oxide.

An insulator having a barrier property against oxygen and an insulator having a barrier property against hydrogen can each be regarded as an insulator having a barrier property against one or both of oxygen and hydrogen.

Examples of an insulator having a function of capturing or fixing hydrogen include an oxide containing magnesium and an oxide containing one or both of aluminum and hafnium. These oxides preferably have an amorphous structure. In such an oxide having an amorphous structure, an oxygen atom has a dangling bond, and the oxide has a property of capturing or fixing hydrogen with the dangling bond in some cases. Although these oxides preferably have an amorphous structure, a crystal region may be partly formed.

Note that in this specification and the like, a barrier insulating film refers to an insulating film having a barrier property. A barrier property refers to a property of hardly diffusing a target substance (also referred to as a property of hardly transmitting a target substance, low permeability of a target substance, or a function of inhibiting diffusion of a target substance). Note that a function of capturing or fixing (also referred to as gettering) a target substance can be rephrased as a barrier property. Note that hydrogen described as a target substance refers to at least one of a hydrogen atom, a hydrogen molecule, a water molecule, a substance bonded to hydrogen, such as OH⁻, and the like. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like. Specifically, a barrier property against oxygen refers to a property of hardly diffusing at least one of an oxygen atom, an oxygen molecule, and the like.

### [Conductor]

For the conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. As examples of the conductive material containing oxygen, indium oxide containing tungsten oxide, indium oxide containing titanium oxide, indium tin oxide, indium tin oxide containing titanium oxide, indium tin oxide to which silicon is added, indium zinc oxide, indium zinc oxide containing tungsten oxide, and the like can be given. In this specification and the like, a conductive material containing oxygen may be referred to as an oxide conductor.

In addition, a conductive material containing tungsten, copper, or aluminum as its main component is preferable because it has high conductivity.

Conductors formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

In the case where a metal oxide is used for the channel formation region of the transistor, the conductor functioning as the gate electrode preferably employs a stacked-layer structure combining a material containing the above metal element and a conductive material containing oxygen. In this case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen such as titanium nitride or tantalum nitride may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from a surrounding insulator or the like can be captured in some cases.

### [Metal Oxide]

A metal oxide has a lattice defect in some cases. Examples of the lattice defect include point defects such as an atomic vacancy and an exotic atom, linear defects such as transition, plane defects such as a grain boundary, and volume defects such as a cavity. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, when a metal oxide with a large number of lattice defects is used for a semiconductor layer of a transistor, the electrical characteristics of the transistor might be unstable. Therefore, a metal oxide used for a semiconductor layer of a transistor preferably has a small number of lattice defects.

As for a transistor using a metal oxide, particularly when oxygen vacancies (Vo) and impurities are in a channel formation region of the metal oxide, electrical characteristics of the transistor easily vary and the reliability thereof might be degraded. In some cases, hydrogen in the vicinity of the oxygen vacancies forms VoH and generates an electron serving as a carrier. Therefore, when the channel formation region in the metal oxide includes oxygen vacancies, the transistor tends to have normally-on characteristics (a channel is generated even when no voltage is applied to a gate electrode and a current flows through the transistor). Therefore, the oxygen vacancies and the impurities are preferably reduced as much as possible in the channel formation region in the metal oxide. In other words, the metal oxide preferably includes an i-type (intrinsic) or substantially i-type channel formation region with a low carrier concentration.

The kind of a lattice defect that is likely to exist in a metal oxide and the number of lattice defects that exist vary depending on the structure of the metal oxide, a method for depositing the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. An a-like structure has a structure between an nc structure and an amorphous structure.

A metal oxide having an a-like structure and a metal oxide having an amorphous structure each include a void or a low-density region. That is, a metal oxide having an a-like structure and a metal oxide having an amorphous structure each have lower crystallinity than a metal oxide having an nc structure and a metal oxide having a CAAC structure. Moreover, a metal oxide having an a-like structure has higher hydrogen concentration in the metal oxide than a metal oxide having an nc structure and a metal oxide having a CAAC structure. Thus, a lattice defect is likely to be generated in a metal oxide having an a-like structure and a metal oxide having an amorphous structure.

Therefore, a metal oxide with high crystallinity is preferably used for a semiconductor layer of a transistor. For example, a metal oxide having a CAAC structure or a metal oxide having a single crystal structure is preferably used. The use of the metal oxide for a transistor enables the transistor to have favorable electrical characteristics. In addition, the transistor can have high reliability.

For the channel formation region of a transistor, a metal oxide that increases the on-state current of the transistor is preferably used. To increase the on-state current of the transistor, the carrier mobility of the metal oxide used for the transistor is increased. To increase the carrier mobility of the metal oxide, the transfer of carriers (electrons in the case of an n-channel transistor) needs to be facilitated or scattering factors that affect the carrier transfer need to be reduced. Note that the carriers flow from the source to the drain through the channel formation region. Hence, the on-state current of the transistor can be increased by providing a channel formation region through which carriers can easily flow in the channel length direction.

Here, it is preferable to use a metal oxide with high crystallinity for a metal oxide including a channel formation region. The crystal preferably has a crystal structure where a plurality of layers (for example, a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor, a CAAC-OS, and the like.

The c-axis of the above crystal is preferably aligned in the normal direction with respect to the formation surface or film surface of the metal oxide. This enables the plurality of layers to be placed parallel to or substantially parallel to the formation surface or film surface of the metal oxide. In other words, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal are a YbFe₂O₄ structure, a Yb₂Fe₃O₇ structure, their deformed structures, and the like.

Preferably, each of the first to third layers is composed of one metal element or a plurality of metal elements with the same valence and oxygen. The valence of the one or plurality of metal elements contained in the first layer is preferably equal to the valence of the one or plurality of metal elements contained in the second layer. The first layer and the second layer may contain the same metal element. The valence of the one or plurality of metal elements contained in the first layer is preferably different from the valence of the one or plurality of metal elements contained in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide in one embodiment of the present invention include indium oxide, gallium oxide, and zinc oxide. The metal oxide in one embodiment of the present invention preferably contains at least indium (In) or zinc (Zn). The metal oxide preferably contains two or three kinds selected from indium, the element M, and zinc. The element M is a metal element or metalloid element having a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M included in the metal oxide is preferably one or more of the above elements, further preferably one or more selected from aluminum, gallium, tin, and yttrium, and still further preferably gallium. When the element M included in the metal oxide is gallium, the metal oxide in one embodiment of the present invention preferably includes one or more selected from indium, gallium, and zinc. In this specification and the like, a metal element and a metalloid element may be collectively referred to as a “metal element” and a “metal element” in this specification and the like may refer to a metalloid element.

As the metal oxide in one embodiment of the present invention, for example, indium zinc oxide (In—Zn oxide), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (In—Sn—Zn oxide), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, or IAGZO) can be used. Alternatively, indium tin oxide containing silicon, gallium tin oxide (Ga—Sn oxide), aluminum tin oxide (Al—Sn oxide), or the like can be used. Alternatively, the above-described oxide having an amorphous structure can be used. For example, indium oxide having an amorphous structure, indium tin oxide having an amorphous structure, or the like can be used.

By increasing the proportion of the number of indium atoms in the total number of atoms of all the metal elements included in the metal oxide, the field-effect mobility of the transistor can be increased.

Instead of indium or in addition to indium, the metal oxide may contain one or more kinds of metal elements whose period number in the periodic table is large. As the overlap between orbits of metal elements is larger, the metal oxide tends to have higher carrier conductivity. Thus, when a metal element with a large period number is included in the metal oxide, the field-effect mobility of the transistor can be increased in some cases. As examples of the metal element with a large period number, the metal elements belonging to Period 5 and those belonging to Period 6 are given. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements included in the metal oxide, the metal oxide has high crystallinity, so that diffusion of impurities in the metal oxide can be inhibited. Consequently, a change in electrical characteristics of the transistor is suppressed and the transistor can have high reliability.

By increasing the proportion of the number of element M atoms in the total number of atoms of all the metal elements included in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor is suppressed and the transistor can have high reliability.

By increasing the proportion of the number of In atoms in the total number of atoms of all the metal elements included in the metal oxide, a high on-state current and high frequency characteristics of the transistor can be achieved.

In the description of this embodiment, In—Ga—Zn oxide is sometimes taken as an example of the metal oxide.

For the formation of a metal oxide having the layered crystal structure, atomic layers are preferably deposited one by one. By an ALD method, a metal oxide having the layered crystal structure is easily formed.

Examples of the ALD method include a thermal ALD method, in which a precursor and a reactant react with each other only by a thermal energy, and a plasma-enhanced ALD (PEALD) method, in which a reactant excited by plasma is used.

An ALD method enables atomic layers to be deposited one by one, and has various advantages such as formation of an extremely thin film, deposition on a component with a high aspect ratio, formation of a film with few defects such as pinholes, deposition with excellent coverage, and low-temperature deposition. A PEALD method utilizing plasma is preferable, because deposition at lower temperature is possible in some cases. Note that some precursors used in the ALD method contain an element such as carbon or chlorine. Thus, a film formed by the ALD method sometimes contains an element such as carbon or chlorine in a larger quantity than a film formed by another deposition method. Note that these elements can be quantified by XPS or SIMS.

When an ALD method is used as the deposition method of a metal oxide, one or both of a deposition condition with a high substrate temperature and impurity removal treatment can form a film with smaller amounts of carbon and chlorine than the case of using an ALD method without the condition and the treatment.

For example, impurity removal treatment is preferably intermittently performed during deposition of the metal oxide in an atmosphere containing oxygen. Furthermore, impurity removal treatment is preferably performed in an atmosphere containing oxygen after the deposition of the metal oxide. The impurities in the film can be removed by performing impurity removal treatment during and/or after the deposition of the metal oxide. This can inhibit impurities (e.g., hydrogen, carbon, and nitrogen) contained in a raw material such as a precursor from remaining in the metal oxide. Accordingly, the impurity concentration in the metal oxide can be reduced. In addition, the crystallinity of the metal oxide can be increased.

Examples of the impurity removal treatment include plasma treatment, microwave treatment, and heat treatment.

When plasma treatment or microwave treatment is performed, the substrate temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. The heat treatment temperature is preferably higher than or equal to 100° C., higher than or equal to 200° C., higher than or equal to 300° C., or higher than or equal to 400° C., and lower than or equal to 500° C. or lower than or equal to 450° C.

The temperature of the impurity removal treatment is particularly preferably set lower than or equal to the maximum temperature in the manufacturing process of a transistor or a semiconductor device, in which case the impurity content in the metal oxide can be reduced without decrease in productivity. For example, when the maximum temperature in manufacturing the semiconductor device of one embodiment of the present invention is lower than or equal to 500° C., preferably lower than or equal to 450° C., the productivity of the semiconductor device can be improved.

Here, the microwave treatment refers to, for example, treatment using an apparatus including a power source that generates high-density plasma with the use of a microwave. Note that in this specification and the like, a microwave refers to an electromagnetic wave having a frequency higher than or equal to 300 MHz and lower than or equal to 300 GHz in some cases.

The microwave treatment is preferably performed with a microwave treatment apparatus including a power source for generating high-density plasma using microwaves, for example. Here, the frequency of the microwave treatment apparatus is preferably set to be higher than or equal to 300 MHz and lower than or equal to 300 GHz, further preferably higher than or equal to 2.4 GHz and lower than or equal to 2.5 GHz, and can be 2.45 GHz, for example. Oxygen radicals at a high density can be generated with high-density plasma. The electric power of the power source that applies microwaves of the microwave treatment apparatus is preferably set to be higher than or equal to 1000 W and lower than or equal to 10000 W, further preferably higher than or equal to 2000 W and lower than or equal to 5000 W. A power source may be provided in the microwave treatment apparatus to apply RF to the substrate side. Furthermore, application of RF to the substrate side allows oxygen ions generated by the high-density plasma to be introduced into a film efficiently.

The microwave treatment is preferably performed under reduced pressure, and the pressure is preferably higher than or equal to 10 Pa and lower than or equal to 1000 Pa, further preferably higher than or equal to 300 Pa and lower than or equal to 700 Pa. The treatment temperature is preferably higher than or equal to room temperature (25° C.) and lower than or equal to 750° C., further preferably higher than or equal to 300° C. and lower than or equal to 500° C., and further preferably higher than or equal to 400° C. and lower than or equal to 450° C.

The microwave treatment or the plasma treatment may be followed successively by heat treatment without exposure to the air. The heat treatment temperature is, for example, preferably higher than or equal to 100° C. and lower than or equal to 750° C., further preferably higher than or equal to 300° C. and lower than or equal to 500° C., still further preferably higher than or equal to 400° C. and lower than or equal to 450° C. The microwave treatment can be performed using an oxygen gas and an argon gas, for example. Here, the oxygen flow rate ratio (O₂/O₂+Ar) is higher than 0% and lower than or equal to 100%. The oxygen flow rate ratio (O₂/O₂+Ar) is preferably higher than 0% and lower than or equal to 50%. The oxygen flow rate ratio (O₂/O₂+Ar) is further preferably higher than or equal to 10% and lower than or equal to 40%. The oxygen flow rate ratio (O₂/O₂+Ar) is still further preferably higher than or equal to 10% and lower than or equal to 30%.

The heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, the heat treatment may be performed in such a manner that heat treatment is performed in an atmosphere of a nitrogen gas or an inert gas, and then another heat treatment is performed in an atmosphere containing an oxidizing gas at ppm or more, 1% or more, or 10% or more in order to compensate for released oxygen. The heat treatment may be performed under an atmosphere of ultra-dry air (air in which water content is 20 ppm or less, preferably 1 ppm or less, further preferably 10 ppb or less).

By performing the heat treatment in such a manner, an impurity such as hydrogen or carbon contained in the metal oxide can be removed. For example, carbon in the metal oxide can be released as CO₂ and CO, and hydrogen in the metal oxide can be released as H₂O. Furthermore, metal atoms and oxygen atoms are rearranged concurrently with removal of the impurity, which improves crystallinity. Thus, a metal oxide having a layered crystal structure with high crystallinity, specifically, a metal oxide having a CAAC structure can be formed.

Unlike in, for example, a deposition method in which particles ejected from a target are deposited, in an ALD method, a film is formed by reaction at a surface of an object to be processed. Thus, an ALD method is a deposition method that is less likely to be influenced by the shape of an object to be processed and thus enables favorable step coverage. In particular, an ALD method can provide excellent step coverage and excellent thickness uniformity and thus can be favorably used for covering a surface of an opening portion with a high aspect ratio, for example. On the other hand, an ALD method has a relatively low deposition rate; thus, it is sometimes preferable to combine an ALD method with another deposition method with a high deposition rate such as a sputtering method or a CVD method. For example, a method in which a sputtering method is used to deposit a first metal oxide, and an ALD method is used to deposit a second metal oxide over the first metal oxide can be given. For example, in the case where the first metal oxide has a crystal part, crystal growth occurs in the second metal oxide with the use of the crystal part as a nucleus.

When an ALD method is used, the composition of a film to be formed can be controlled with the amount of introduced source gases. For example, a film with a certain composition can be formed by adjusting the amount of introduced source gases, the number of times of introduction (also referred to as the number of pulses), and the time required for one pulse (also referred to as the pulse time) in an ALD method. Moreover, for example, when the source gas is changed during the deposition in an ALD method, a film whose composition is continuously changed can be formed. In the case where a film is formed while the source gas is changed, as compared with the case where a film is formed using a plurality of deposition chambers, the time taken for the deposition can be shortened because the time taken for transfer and pressure adjustment is omitted. Hence, the productivity of the semiconductor device can be improved in some cases.

### [[Transistor Including Metal Oxide]]

Next, a transistor including a metal oxide (oxide semiconductor) will be described. Hereinafter, a transistor with a semiconductor layer of an oxide semiconductor is sometimes referred to as an OS transistor, and a transistor with a semiconductor layer of silicon is sometimes referred to as a Si transistor.

When the metal oxide (oxide semiconductor) of one embodiment of the present invention is used for a transistor, the transistor can have high field-effect mobility. In addition, the transistor can have high reliability. Furthermore, a miniaturized or highly integrated transistor can be achieved. For example, a transistor with a channel length of greater than or equal to 2 nm and less than or equal to 30 nm can be manufactured. An oxide semiconductor having a low carrier concentration is preferably used for a channel formation region of the transistor. For example, the carrier concentration in the channel formation region of an oxide semiconductor is lower than or equal to 1×10¹⁸ cm⁻³, preferably lower than or equal to 1×10¹⁷ cm⁻³, further preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and accordingly has a low density of trap states in some cases.

Charge trapped by the trap states in the oxide semiconductor takes a long time to disappear and might behave like fixed charge. A transistor whose channel formation region is formed in an oxide semiconductor having a high density of trap states has unstable electrical characteristics in some cases.

In order to obtain stable electrical characteristics of the transistor, it is effective to reduce the concentration of impurities in the oxide semiconductor. In order to reduce the impurity concentration in the oxide semiconductor, the impurity concentration in a film that is adjacent to the oxide semiconductor is preferably reduced. Examples of the impurity include hydrogen, carbon, and nitrogen. Note that impurities in an oxide semiconductor refer to, for example, elements other than the main components of the oxide semiconductor. For example, an element with a concentration of lower than 0.1 atomic % is an impurity.

The band gap of the oxide semiconductor is preferably larger than that of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

As miniaturization of a Si transistor progresses, a short-channel effect (also referred to as SCE) appears. Thus, a Si transistor is difficult to miniaturize. A factor that causes a short-channel effect is a small band gap of silicon. Meanwhile, an OS transistor uses an oxide semiconductor, which is a semiconductor material with a large band gap, and thus is less likely to suffer from a short-channel effect. In other words, a short-channel effect does not appear or hardly appears in an OS transistor.

Note that the short-channel effect refers to degradation of electrical characteristics which becomes obvious along with miniaturization of a transistor (a decrease in channel length). Specific examples of the short-channel effect include a decrease in threshold voltage, an increase in subthreshold swing value (sometime also referred to as S value), an increase in leakage current, and the like. Here, the S value means the amount of change in gate voltage in the subthreshold region when the drain voltage keeps constant and the drain current changes by one order of magnitude.

The characteristic length is widely used as an indicator of resistance to a short-channel effect. The characteristic length is an indicator of curving of potential in a channel formation region. As the characteristic length is shorter, the potential rises more sharply, which means that the resistance to a short-channel effect is high.

An OS transistor is an accumulation-type transistor, and a Si transistor is an inversion-type transistor. Thus, an OS transistor has a smaller characteristic length between a source region and a channel formation region and a smaller characteristic length between a drain region and the channel formation region than a Si transistor. Accordingly, an OS transistor has higher resistance to a short channel effect than a Si transistor. That is, in the case where a transistor with a short channel length needs to be manufactured, an OS transistor is more suitable than a Si transistor.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Thus, the OS transistor can be regarded as having an n⁺/n⁻/n⁺ accumulation-type junction-less transistor structure or an n⁺/n⁻/n⁺ accumulation-type non junction transistor structure where the channel formation region is an n⁻ region and the source and drain regions are n⁺ regions.

An OS transistor having the above structure enables a semiconductor device to have favorable electrical characteristics even when the semiconductor device is miniaturized or highly integrated. For example, favorable electrical characteristics can be obtained even when the channel length or the gate length of the OS transistor is greater than or equal to 1 nm and less than or equal to 20 nm, greater than or equal to 1 nm and less than or equal to 15 nm, greater than or equal to 3 nm and less than or equal to 10 nm, greater than or equal to 5 nm and less than or equal to 7 nm, or greater than or equal to 5 nm and less than or equal to 6 nm. Meanwhile, it is sometimes difficult for a Si transistor to have a gate length less than or equal to 20 nm or less than or equal to 15 nm due to appearance of a short-channel effect. Thus, an OS transistor can be used as a transistor with a short channel length more suitably than a Si transistor. Note that the gate length refers to the length of a gate electrode in a direction in which carriers move inside a channel formation region during operation of the transistor.

Miniaturization of an OS transistor can improve the high frequency characteristics of the transistor. Specifically, the cutoff frequency of the transistor can be improved. In the case where the gate length of the OS transistor is within the above range, the cutoff frequency of the transistor can be higher than or equal to 50 GHz, preferably higher than or equal to 100 GHz, further preferably higher than or equal to 150 GHz at room temperature, for example.

As described above, an OS transistor has advantages over a Si transistor, such as a low off-state current and capability of having a short channel length.

### [[Impurity in Metal Oxide]]

The influence of impurities in the metal oxide (oxide semiconductor) will be described here.

When silicon or carbon, which is a Group 14 element, is contained in an oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, further preferably lower than or equal to 1×10¹⁹ atoms/cm³, still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to have normally-on characteristics. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, further preferably lower than or equal to 5×10¹⁸ atoms/cm³, still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier. Thus, a transistor including an oxide semiconductor which contains hydrogen is likely to be normally on. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains alkali metal or alkaline earth metal, defect states are formed and carriers are generated in some cases. Thus, a transistor including an oxide semiconductor which contains alkali metal or alkaline earth metal is likely to be normally-on. Thus, the concentration of alkali metal or alkaline earth metal in the channel formation region of the oxide semiconductor measured by SIMS is set lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [Other Semiconductor Materials]

The semiconductor layer 113 can be rephrased as a semiconductor layer including a channel formation region of a transistor. The semiconductor materials that can be used for the semiconductor layer are not limited to the above metal oxides. A semiconductor material which has a band gap (a semiconductor material that is not a zero-gap semiconductor) can be used as the semiconductor. For example, a single element semiconductor, a compound semiconductor, a layered material (also referred to as an atomic layered material or a two-dimensional material), or the like is preferably used as the semiconductor material.

In this specification and the like, the layered material is a group of materials having a layered crystal structure. In the layered crystal structure, layers formed by covalent bonding or ionic bonding are stacked with bonding such as the Van der Waals bonding, which is weaker than covalent bonding or ionic bonding. The layered material has high electrical conductivity in a monolayer, that is, high two-dimensional electrical conductivity. When a material that functions as a semiconductor and has high two-dimensional electrical conductivity is used for a channel formation region, the transistor can have a high on-state current.

Examples of the single-element semiconductor that can be used as the semiconductor material include silicon and germanium. Examples of silicon that can be used for the semiconductor layer include single crystal silicon, polycrystalline silicon, microcrystalline silicon, and amorphous silicon. An example of polycrystalline silicon is low-temperature polysilicon (LTPS).

Examples of the compound semiconductor that can be used as the semiconductor material include silicon carbide, silicon germanium, gallium arsenide, indium phosphide, boron nitride, and boron arsenide. Boron nitride that can be used as the semiconductor layer preferably includes an amorphous structure. Boron nitride that can be used as the semiconductor layer preferably includes a crystal with a cubic structure.

Examples of the layered material include graphene, silicene, boron carbonitride, and chalcogenide. Boron carbonitride serving as the layered material contains carbon, nitrogen, and boron atoms arranged in a hexagonal lattice structure on a plane.

Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As the semiconductor layer, a transition metal chalcogenide functioning as a semiconductor is preferably used, for example. Specific examples of the transition metal chalcogenide which can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

### <Example 1 of Method for Manufacturing Semiconductor Device>

As a method for manufacturing the semiconductor device of one embodiment of the present invention, an example of a method for manufacturing the semiconductor device illustrated in FIGS. 2A to 2C is described below.

In the drawings showing the method for manufacturing the semiconductor device of one embodiment of the present invention, each drawing A is a plan view unless otherwise noted. Each drawing B is a cross-sectional view taken along dashed-dotted line A1-A2 in the corresponding drawing A, and each drawing C is a cross-sectional view taken along dashed-dotted line A3-A4 in the corresponding drawing A.

In the following steps, an insulating material for forming an insulator, a conductive material for forming a conductor, or a semiconductor material for forming a semiconductor can be deposited by appropriately using a deposition method such as a sputtering method, a CVD method, an MBE method, a PLD method, or an ALD method.

Examples of the sputtering method include an RF sputtering method in which a high-frequency power source is used for a sputtering power supply, a DC sputtering method in which a DC power source is used, and a pulsed DC sputtering method in which a voltage is applied while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a compound such as an oxide, a nitride, or a carbide is deposited by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a PECVD method. A thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. By contrast, such plasma damage is not caused and the yield of semiconductor devices can be increased with the thermal CVD method which does not use plasma. A thermal CVD method yields a film with few defects because of no plasma damage during deposition.

As the ALD method, a thermal ALD method, in which a precursor and a reactant react with each other only by a thermal energy, a PEALD method, in which a reactant excited by plasma is used, or the like can be used.

Methods of CVD and ALD differ from a sputtering method by which particles ejected from a target or the like are deposited. Thus, a CVD method and an ALD method less likely to be influenced by the shape of an object to be processed and thus enables favorable step coverage. In particular, an ALD method can provide excellent step coverage and excellent thickness uniformity and thus can be suitably used for covering a surface of an opening portion with a high aspect ratio, for example. An ALD method has a relatively low deposition rate; thus, it is sometimes preferable to combine an ALD method with another deposition method with a high deposition rate such as a CVD method.

By a CVD method, a film with a certain composition can be deposited by adjusting the flow rate ratio of the source gases. For example, when the flow rate ratio of the source gases is changed during the deposition in a CVD method, a film whose composition is continuously changed can be deposited. In the case where a film is formed while the flow rate ratio of the source gases is changed, as compared with the case where a film is formed using a plurality of deposition chambers, the time taken for the deposition can be shortened because the time taken for transfer or pressure adjustment is omitted. Hence, the productivity of the semiconductor device can be improved in some cases.

An ALD method, with which a plurality of different kinds of precursors are introduced at a time, enables formation of a film with desired composition. In the case where a plurality of different kinds of precursors are introduced, the cycle number of precursor deposition is controlled, whereby a film with desired composition can be formed.

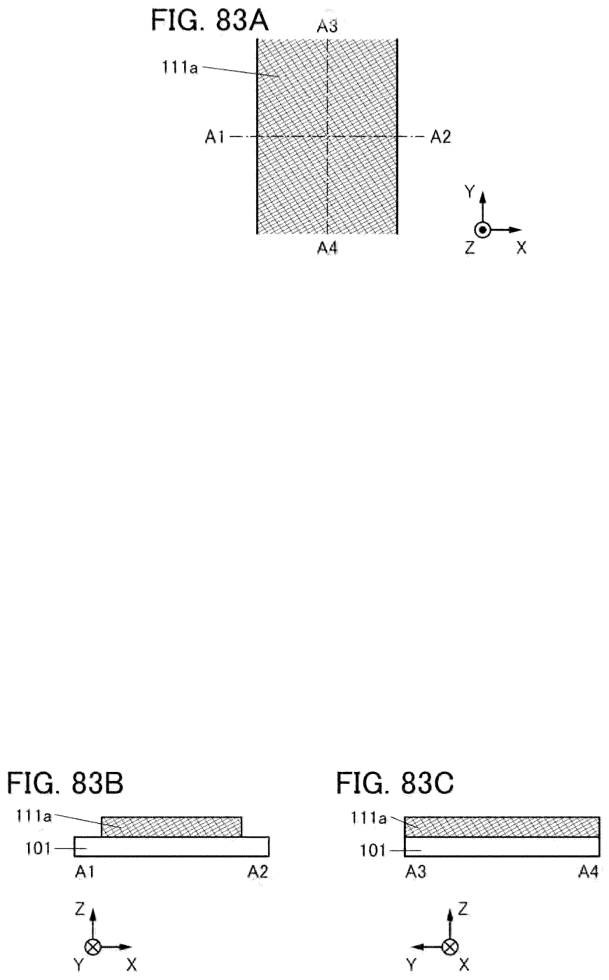

First, a substrate (not illustrated) is prepared, and the insulating layer 101 is formed over the substrate (FIGS. 83A to 83C). Any of the above-described insulating materials can be appropriately used for the insulating layer 101. A deposition method such as a sputtering method, a CVD method, an MBE method, a PLD method, or an ALD method can be appropriately used to form the insulating layer 101.

Next, the conductive layer 111a is formed over the insulating layer 101 (FIGS. 83A to 83C). For example, the conductive layer 111a can be formed by forming and processing a conductive film to be the conductive layer 111a. For the conductive film to be the conductive layer 111a, a conductive material which can be used for the above-described conductive layer 111a can be used as appropriate.

The conductive film to be the conductive layer 111a can be formed by appropriately using a deposition method such as a sputtering method, a CVD method, an MBE method, a PLD method, or an ALD method. For example, as the conductive film to be the conductive layer 111a, a stacked-layer film in which tungsten and titanium nitride are deposited in this order by a CVD method can be used. After the conductive film to be the conductive layer 111a is formed, formation of a pattern is performed by a lithography method, and the conductive film is processed by a dry etching method, a wet etching method, or the like using the pattern, whereby the conductive layer 111a can be formed. Here, for microfabrication, the conductive film is preferably processed by a dry etching method.

In the lithography method, first, a resist is exposed to light through a mask. Next, a region exposed to light is removed or left using a developing solution, so that a resist mask is formed. Thus, a pattern is formed.

A resist mask is formed by, for example, exposure of the resist to light such as KrF excimer laser light, ArF excimer laser light, extreme ultraviolet (EUV) light, or the like. A liquid immersion technique may be employed in which a portion between a substrate and a projection lens is filled with a liquid (e.g., water) to perform light exposure. An electron beam or an ion beam may be used instead of the above-mentioned light. Note that a mask is not necessary in the case of using an electron beam or an ion beam. To remove the resist mask, dry etching treatment such as ashing or wet etching treatment can be used. Alternatively, wet etching treatment can be performed after dry etching treatment, or dry etching treatment can be performed after wet etching treatment.

Next, etching treatment is performed using the resist mask. Thus, the conductive layer, the semiconductor layer, the insulating layer, and the like can be processed into desired shapes.

In the case of performing dry etching treatment as the above-described etching treatment, an etching gas containing halogen can be used as an etching gas; specifically, an etching gas containing one or more of fluorine, chlorine, and bromine can be used. For example, as the etching gas, a C₄F₆ gas, a C₅F₆ gas, a C₄F₈ gas, a CF₄ gas, a SF₆ gas, a NF₃ gas, a CHF₃ gas, a Cl₂ gas, a BCl₃ gas, a SiCl₄ gas, a CCl₄ gas, a BBr₃ gas, or the like can be used alone or in combination. To the above etching gas, an oxygen gas, a carbon dioxide gas, a nitrogen gas, a helium gas, an argon gas, a hydrogen gas, a hydrocarbon gas, or the like can be added as appropriate. The etching conditions can be set as appropriate depending on an object to be etched.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, the capacitively coupled plasma etching apparatus may have a structure in which different high-frequency voltages are applied to one of the parallel-plate electrodes. Alternatively, the capacitively coupled plasma etching apparatus may have a structure in which high-frequency voltages with the same frequency are applied to the parallel-plate electrodes. Alternatively, the capacitively coupled plasma etching apparatus may have a structure in which high-frequency voltages with different frequencies are applied to the parallel-plate electrodes. Alternatively, a dry etching apparatus including a high-density plasma source can be used. As the dry etching apparatus including a high-density plasma source, an inductively coupled plasma (ICP) etching apparatus can be used, for example.

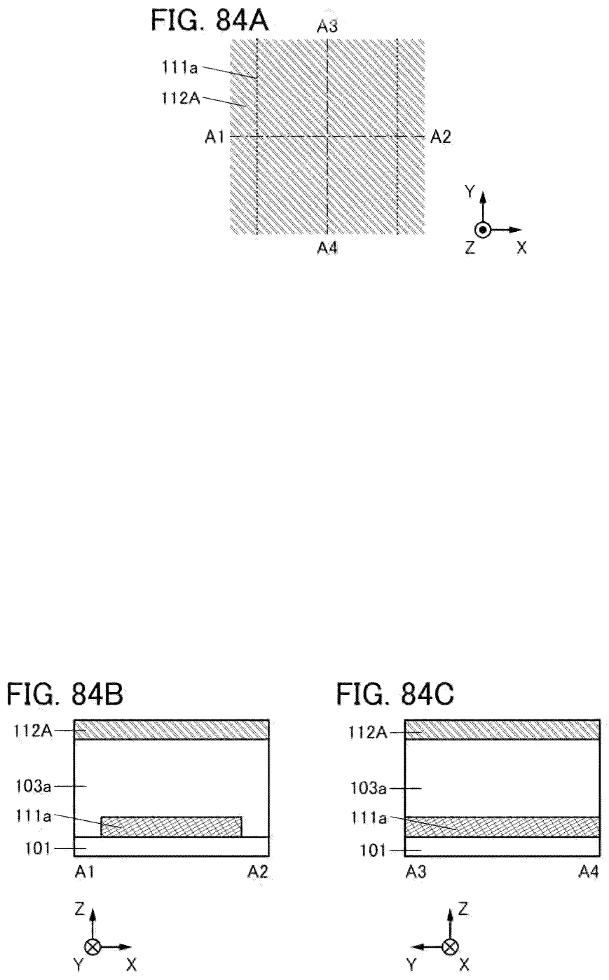

Next, the insulating layer 103a is formed over the insulating layer 101 and the conductive layer 111a (FIGS. 84A to 84C). As the insulating layer 103a, any of the above-described insulating materials can be appropriately used. The insulating layer 103a can be formed by appropriately using a deposition method such as a sputtering method, a CVD method, an MBE method, a PLD method, or an ALD method. For example, as the insulating layer 103a, a silicon oxide film is formed by a sputtering method. Note that it is preferable that the top surface of the deposited insulating layer 103a be planarized by chemical mechanical polishing (CMP) treatment. The planarization treatment on the insulating layer 103 makes it possible to favorably form the conductive layer 112a. Furthermore, aluminum oxide may be deposited over the insulating layer 103a by a sputtering method, for example, and then subjected to CMP treatment until the insulating layer 103a is exposed. The CMP treatment can planarize and smooth the surface of the insulating layer 103a. When the CMP treatment is performed with the aluminum oxide placed over the insulating layer 103a, it is easy to detect the endpoint of the CMP treatment.

Note that the CMP treatment is unnecessary in some cases. In such a case, the top surface of the insulating layer 103a has a convex shape. By not performing planarization treatment, manufacturing cost can be reduced and production yield can be increased.

Here, since the thickness of the insulating layer 103a over the conductive layer 111a corresponds to the channel length of the transistor 41, the thickness of the insulating layer 103a can be set as appropriate depending on the design value of the channel length of the transistor 41.

When the insulating layer 103a is deposited by a sputtering method in an oxygen-containing atmosphere, the insulating layer 103a containing excess oxygen can be formed. Since a molecule containing hydrogen is not used as a deposition gas in the sputtering method, the concentration of hydrogen in the insulating layer 103a can be reduced. When the insulating layer 103a is deposited in this manner, oxygen can be supplied to the channel formation region of the semiconductor layer 113a which is formed after the deposition of the insulating layer 103a, so that oxygen vacancies and VoH can be reduced.

Next, a conductive film 112A is formed over the insulating layer 103a (FIGS. 84A to 84C). Any of the conductive materials that can be used for the above-described conductive layer 112a can be appropriately used for conductive film 112A. The conductive film 112A can be formed by appropriately using a deposition method such as a sputtering method, a CVD method, an MBE method, a PLD method, or an ALD method.

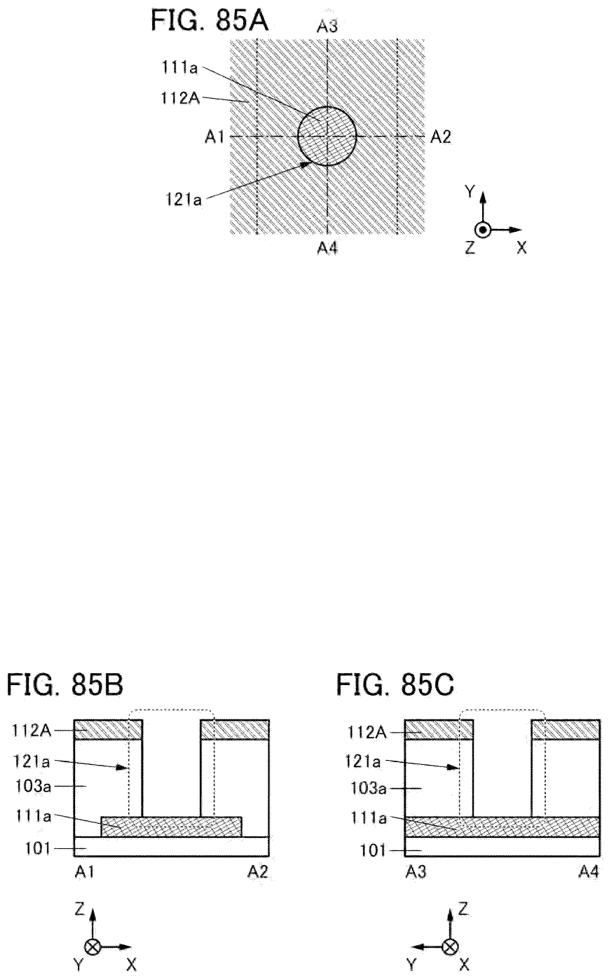

Next, part of the conductive film 112A and part of the insulating layer 103a are processed to form the opening portion 121a reaching the conductive layer 111a (FIGS. 85A to 85C). The opening portion 121a can be formed by a lithography method and an etching method, for example.

As described above, the sidewall of the opening portion 121a is preferably perpendicular to the top surface of the conductive layer 111a. This structure enables miniaturization and high integration of the semiconductor device. The sidewall of the opening portion 121a may be tapered. When the sidewall of the opening portion 121a is tapered, coverage with a later-described metal oxide film to be the semiconductor layer 113a is improved, so that the number of defects such as voids can be reduced, for example.

The maximum width of the opening portion 121a (the maximum diameter in the case where the opening portion 121a is circular in the plan view) is preferably small. For example, the maximum width of the opening portion 121a is preferably greater than or equal to 1 nm and less than or equal to 60 nm, greater than or equal to 1 nm and less than or equal to 50 nm, greater than or equal to 1 nm and less than or equal to 40 nm, greater than or equal to 5 nm and less than or equal to 30 nm, or greater than or equal to nm and less than or equal to 20 nm.

Since the opening portion 121a has a high aspect ratio, part of the conductive film 112A and part of the insulating layer 103a are preferably processed by anisotropic etching. It is particularly preferable to use a dry etching method because it is suitable for microfabrication. The conductive film 112A and the insulating layer 103a may be processed under different processing conditions. Depending on the conditions for processing part of the conductive film 112A and part of the insulating layer 103a, the inclination of a side surface of the conductive film 112A in the opening portion 121a and the inclination of the side surface of the insulating layer 103a in the opening portion 121a may be different from each other.

Next, heat treatment may be performed. The heat treatment is performed at a temperature higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, for example. The heat treatment may be performed under a reduced pressure. By the above-described heat treatment, impurities such as water contained in the insulating layer 103a, for example, can be reduced before the later-described metal oxide film to be the semiconductor layer 113a is deposited.

The gas used in the above-described heat treatment is preferably highly purified. For example, the amount of moisture contained in the gas used in the above-described heat treatment is 1 ppb or less, preferably 0.1 ppb or less, and further preferably 0.05 ppb or less. The heat treatment using a highly purified gas can, for example, prevent the entry of moisture into the insulating layer 103a as much as possible.

Next, a metal oxide film to be the semiconductor layer 113a is formed in contact with at least part of the bottom and sidewall of the opening portion 121a and at least part of a top surface of the conductive film 112A. For the metal oxide film, any of the above-described metal oxides that can be used for the semiconductor layer 113a can be appropriately used. The metal oxide film can be formed by appropriately using a deposition method such as a sputtering method, a CVD method, an MBE method, a PLD method, or an ALD method. Here, the metal oxide film is preferably formed in contact with the bottom and sidewall of the opening portion 121a with a high aspect ratio. Thus, the metal oxide film is preferably formed by a deposition method with favorable coverage, and is further preferably formed by a CVD method, or an ALD method. For example, an In—Ga—Zn oxide is deposited by an ALD method as the metal oxide film.

Note that in the case where the sidewall of the opening portion 121a has a tapered shape, the method for depositing the metal oxide film to be the semiconductor layer 113a is not limited to a CVD method or an ALD method. For example, a sputtering method may be used.

In the case where the semiconductor layer 113a has a stacked-layer structure, the layers included in the semiconductor layer 113a may be deposited by the same method or different methods from each other. For example, in the case where the semiconductor layer 113a has a stacked-layer structure of two layers, the lower metal oxide film may be formed by a sputtering method and the upper metal oxide film may be formed by an ALD method. A metal oxide film deposited by a sputtering method is likely to have crystallinity. Thus, when a metal oxide film having crystallinity is provided as the lower metal oxide film, the crystallinity of the upper metal oxide film can be increased. Even when a pin hole, disconnection, or the like is formed in the lower metal oxide film deposited by a sputtering method, the upper metal oxide film deposited by an ALD method with favorable coverage can fill the portion.

Here, the metal oxide film to be the semiconductor layer 113a is preferably formed in contact with the top surface of the conductive layer 111a in the opening portion 121a, the side surface of the insulating layer 103a in the opening portion 121a, the side surface of the conductive film 112A in the opening portion 121a, and the top surface of the conductive film 112A. When the metal oxide film is formed in contact with the conductive layer 111a, the conductive layer 111a functions as the one of the source electrode and the drain electrode of the transistor 41. In addition, when the metal oxide film is formed in contact with the conductive film 112A, the conductive layer 112a formed in a later step functions as the other of the source electrode and the drain electrode of the transistor 41.

Next, heat treatment is preferably performed. The heat treatment is performed at a temperature higher than or equal to 250° C. and lower than or equal to 650° C., preferably higher than or equal to 400° C. and lower than or equal to 600° C. so that the above-described metal oxide film does not become polycrystals. For the details of the heat treatment, the above description can be referred to.

Here, the above-described heat treatment is preferably performed in the state where the insulating layer 103a containing excess oxygen is in contact with the metal oxide film. By the heat treatment performed in that manner, oxygen is supplied from the insulating layer 103a to the channel formation region of the semiconductor layer 113a, whereby oxygen vacancies and VoH can be reduced.

Although the heat treatment is performed after the deposition of the metal oxide film in the above description, the present invention is not limited thereto. Heat treatment may be further performed in a later step.

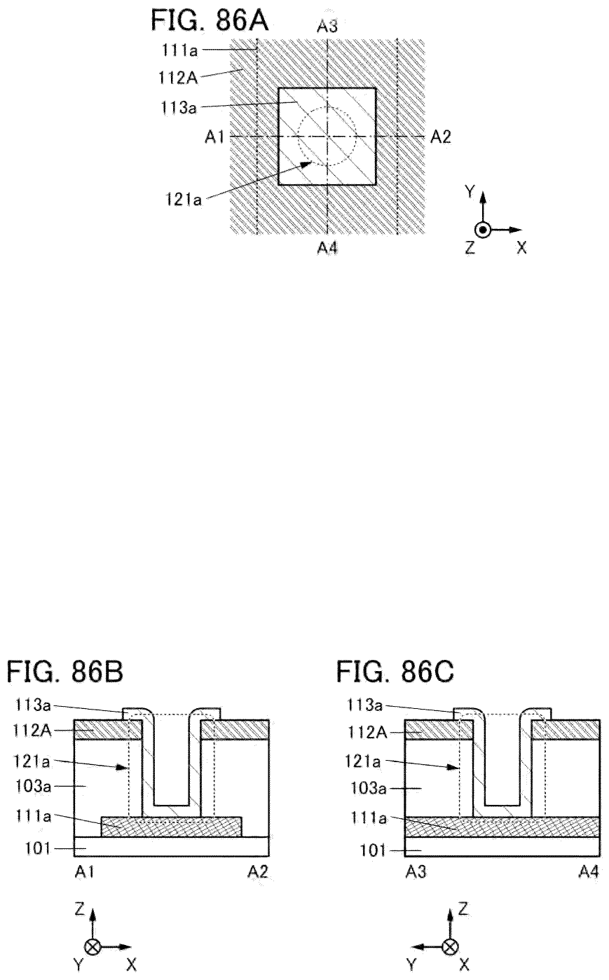

Next, for example, a pattern is formed by a lithography method, and then the metal oxide film to be the semiconductor layer 113a is processed by an etching method using the pattern. Thus, the semiconductor layer 113a is formed (FIGS. 86A to 86C). Part of the semiconductor layer 113a is formed in the opening portion 121a. The semiconductor layer 113a includes a region in contact with a side surface of the conductive film 112A and a region in contact with the top surface of the conductive film 112A. In the above-described manner, the semiconductor layer 113a is formed so as to include a region in contact with the top surface of the conductive layer 111a, a region in contact with the side surface of the conductive film 112A, and a region in contact with the top surface of the conductive film 112A and so as to include a region positioned inside the opening portion 121a.

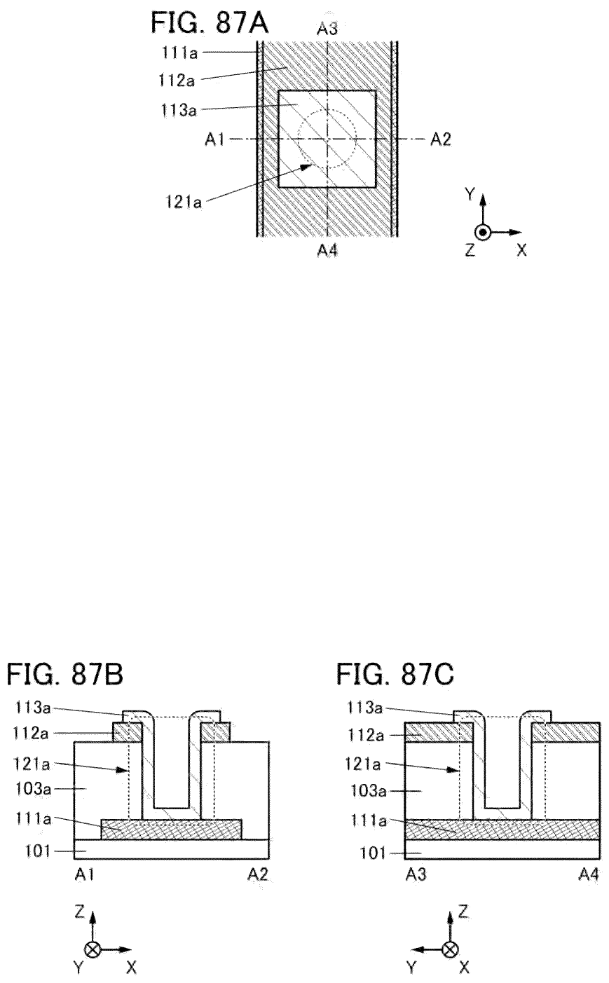

Next, part of the conductive film 112A is processed to form the conductive layer 112a (FIGS. 87A to 87C). The conductive layer 112a can be formed by, for example, forming a pattern by a lithography method and then processing the conductive film 112A by an etching method using the pattern. Although the processing can be performed, for example, by a dry etching method or a wet etching method, processing by a dry etching method is preferable because it is suitable for microfabrication.

Here, a method that is different from the above-described formation method in formation of the conductive layer 112a and the semiconductor layer 113a is described.

This method is similar to the above-described formation method until the step of forming the conductive film 112A illustrated in FIGS. 84A to 84C.

Next, part of the conductive film 112A is processed to form the conductive layer 112a. For example, the above description can be referred to for the method for forming the conductive layer 112a.

Next, part of the conductive layer 112a and part of the insulating layer 103a are processed to form the opening portion 121a reaching the conductive layer 111a. For example, the above description can be referred to for the method for forming the opening portion 121a.

Next, heat treatment may be performed. For example, the above description can be referred to for conditions of the heat treatment.

Next, a metal oxide film to be the semiconductor layer 113a is formed in contact with at least part of the bottom and sidewall of the opening portion 121a and at least part of the top surface of the conductive layer 112a. In that case, the metal oxide film includes a region in contact with the top surface of the insulating layer 103a. For example, the above description can be referred to for the method for forming the metal oxide film.

Next, heat treatment is preferably performed. For example, the above description can be referred to for conditions of the heat treatment.

Next, the metal oxide film to be the semiconductor layer 113a is processed by a lithography method to form the semiconductor layer 113a (FIGS. 87A to 87C).

The following steps for manufacturing the semiconductor device are common in both of the methods.

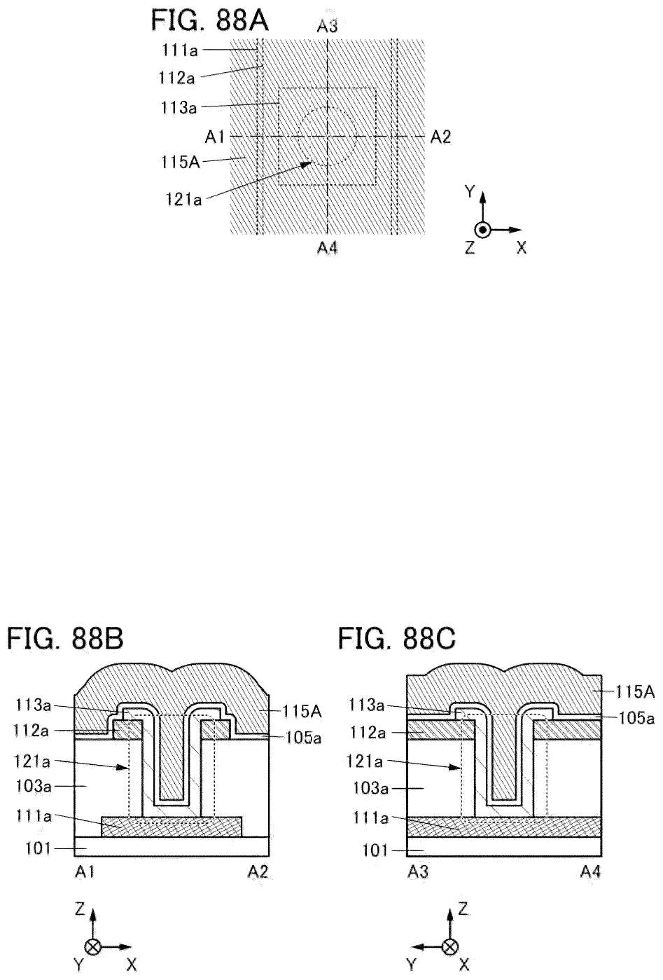

Next, the insulating layer 105a is formed over the semiconductor layer 113a, the conductive layer 112a, and the insulating layer 103a (FIGS. 88A to 88C). For the insulating layer 105a, any of the above-described insulating materials can be appropriately used. The insulating layer 105a can be formed by appropriately using a deposition method such as a sputtering method, a CVD method, an MBE method, a PLD method, or an ALD method. Here, the insulating layer 105a is preferably formed in contact with the semiconductor layer 113a provided in the opening portion 121a with a high aspect ratio. Thus, the insulating layer 105a is preferably formed by a deposition method with favorable coverage, and is further preferably formed by a CVD method, an ALD method, or the like. For example, silicon oxide is deposited by an ALD method as the insulating layer 105a.

Note that in the case where the sidewall of the opening portion 121a has a tapered shape, the method for depositing the insulating layer 105a is not limited to a CVD method or an ALD method. For example, a sputtering method may be used.

When the insulating layer 105a is formed after the semiconductor layer 113a is formed, the side end portion of the semiconductor layer 113a is covered with the insulating layer 105a. Therefore, a short circuit between the semiconductor layer 113a and the conductive layer 115a formed in a later step can be prevented. Furthermore, in the above-described structure, the side end portion of the conductive layer 112a is covered with the insulating layer 105a. Thus, a short circuit between the conductive layer 112a and the conductive layer 115a can be prevented.

Next, a conductive film 115A is formed to fill the depressed portion of the insulating layer 105a (FIGS. 88A to 88C). For the conductive film 115A, any of the conductive materials that can be used for the conductive layer 115a can be appropriately used. The conductive film 115A can be formed by appropriately using a deposition method such as a sputtering method, a CVD method, an MBE method, a PLD method, or an ALD method. Here, the conductive film 115A is preferably formed in contact with the insulating layer 105a provided in the opening portion 121a with a high aspect ratio. Thus, the conductive film 115A is preferably formed by a deposition method with favorable coverage or embeddability, and is further preferably formed by a CVD method, an ALD method, or the like.

In the case where the conductive film 115A is formed by a CVD method, the average surface roughness of the top surface of the conductive film 115A is sometimes increased. In this case, the conductive film 115A is preferably planarized by a CMP method. At this time, before CMP treatment, a silicon oxide film or a silicon oxynitride film may be formed over the conductive film 115A and CMP treatment may be performed until the silicon oxide film or the silicon oxynitride film is removed.

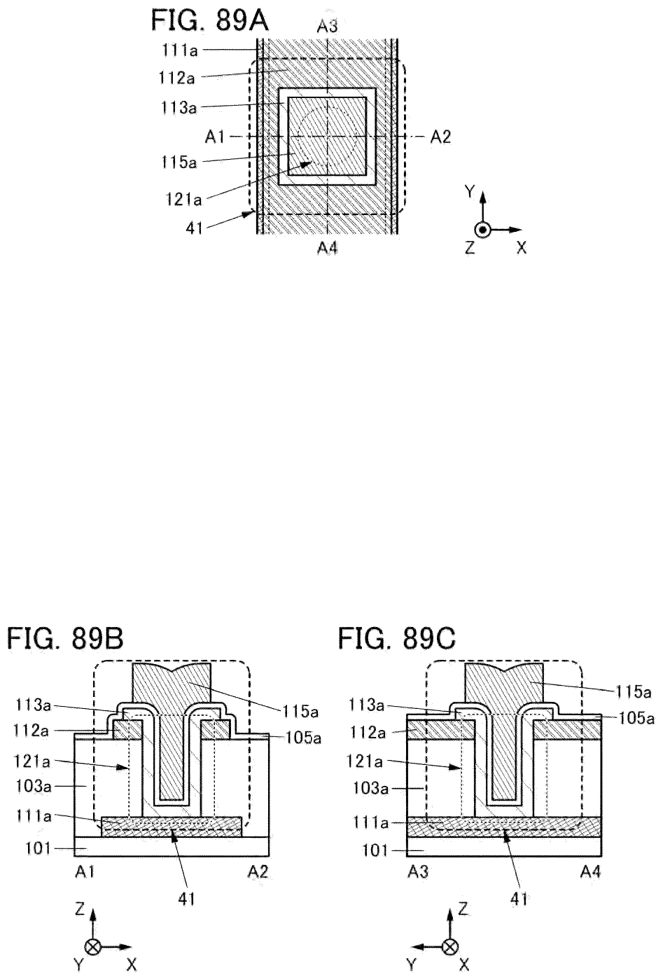

Next, part of the conductive film 115A is processed to form the conductive layer 115a (FIGS. 89A to 89C). The conductive layer 115a can be formed by, for example, forming a pattern by a lithography method and then processing the conductive film 115A by an etching method using the pattern. Although the processing can be performed, for example, by a dry etching method or a wet etching method, processing by a dry etching method is preferable because it is suitable for microfabrication. The conductive layer 115a is formed so as to include a region positioned inside the opening portion 121a and a region facing the semiconductor layer 113a with the insulating layer 105a therebetween.

As illustrated in FIGS. 89A to 89C, the side end portion of the conductive layer 115a is preferably positioned on the inner side of the side end portion of the semiconductor layer 113a. Accordingly, a short circuit between the conductive layer 115a and the semiconductor layer 113a can be prevented.

In the above-described manner, the transistor 41 including the conductive layer 111a, the conductive layer 112a, the semiconductor layer 113a, the insulating layer 105a, and the conductive layer 115a can be formed. As described above, the conductive layer 111a functions as the one of the source electrode and the drain electrode of the transistor 41, the conductive layer 112a functions as the other of the source electrode and the drain electrode of the transistor 41, the insulating layer 105a functions as the gate insulating layer of the transistor 41, and the conductive layer 115a functions as the gate electrode of the transistor 41.

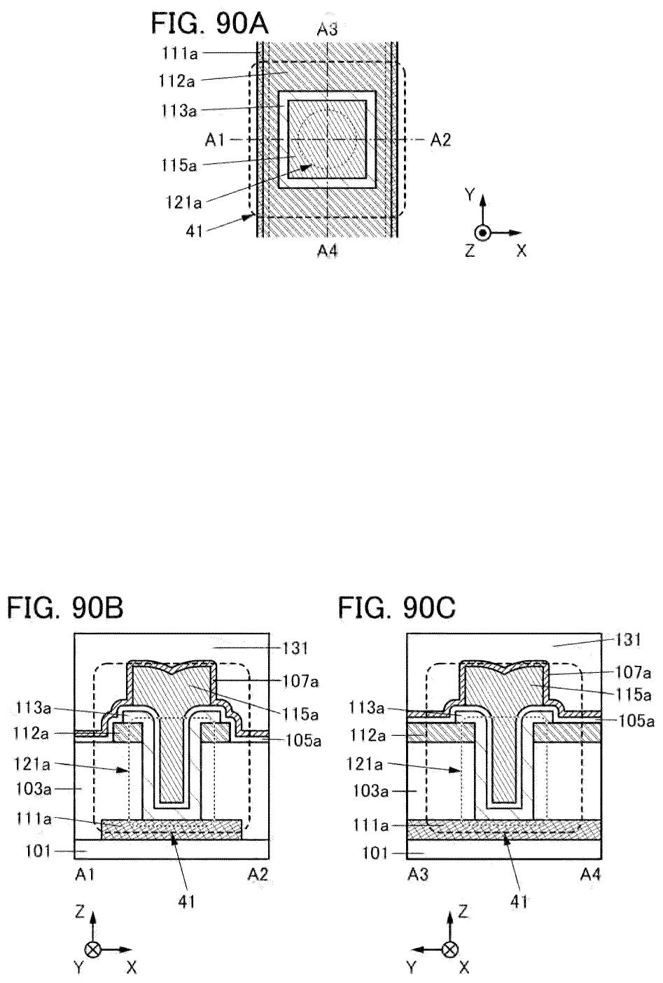

Next, the insulating layer 107a is formed to cover the transistor 41. Specifically, the insulating layer 107a is formed to cover the conductive layer 115a and the insulating layer 105a. Then, the insulating layer 131 is formed over the insulating layer 107a (FIGS. 90A to 90C). Any of the above-described insulating materials can be appropriately used for the insulating layer 107a and the insulating layer 131. The insulating layer 107a and the insulating layer 131 can be formed by appropriately using a deposition method such as a sputtering method, a CVD method, an MBE method, a PLD method, or an ALD method. The top surface of the deposited insulating layer 131 is preferably planarized by CMP treatment. Note that the CMP treatment is unnecessary in some cases. In such a case, the top surface of the insulating layer 131 has a convex shape. By not performing planarization treatment, manufacturing cost can be reduced and production yield can be increased.

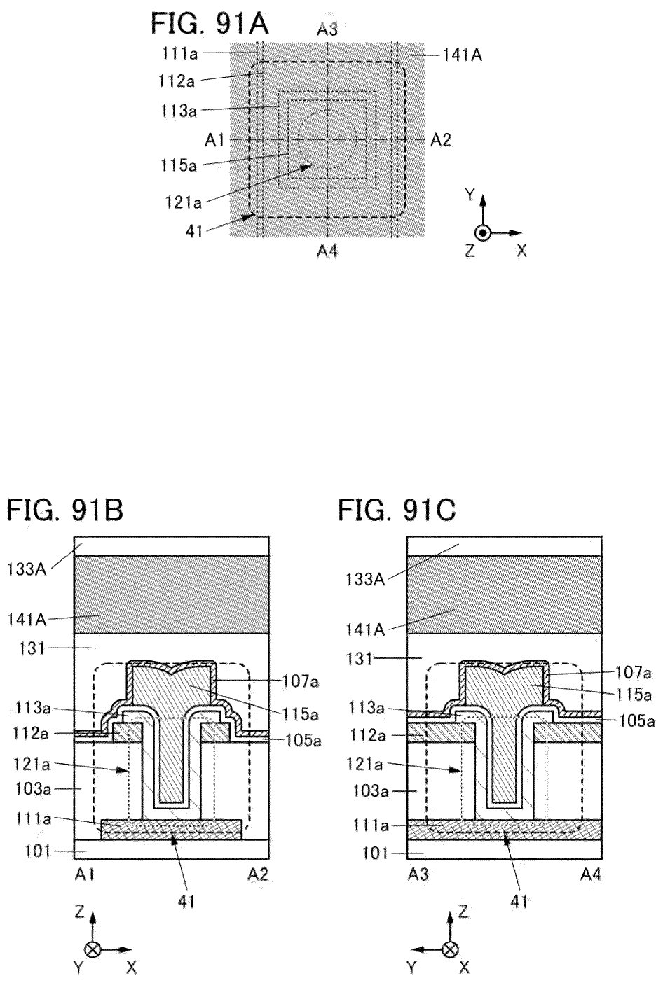

Next, a conductive film 141A is formed over the insulating layer 131, and an insulating film 133A is formed over the conductive film 141A (FIGS. 91A to 91C). For the conductive film 141A, any of the above-described conductive materials that can be used for the conductive layer 141 can be appropriately used. For the insulating film 133A, any of the above-described insulating materials that can be used for the insulating layer 133 can be appropriately used. The conductive film 141A and the insulating film 133A can each be formed by appropriately using a deposition method such as a sputtering method, a CVD method, an MBE method, a PLD method, or an ALD method.

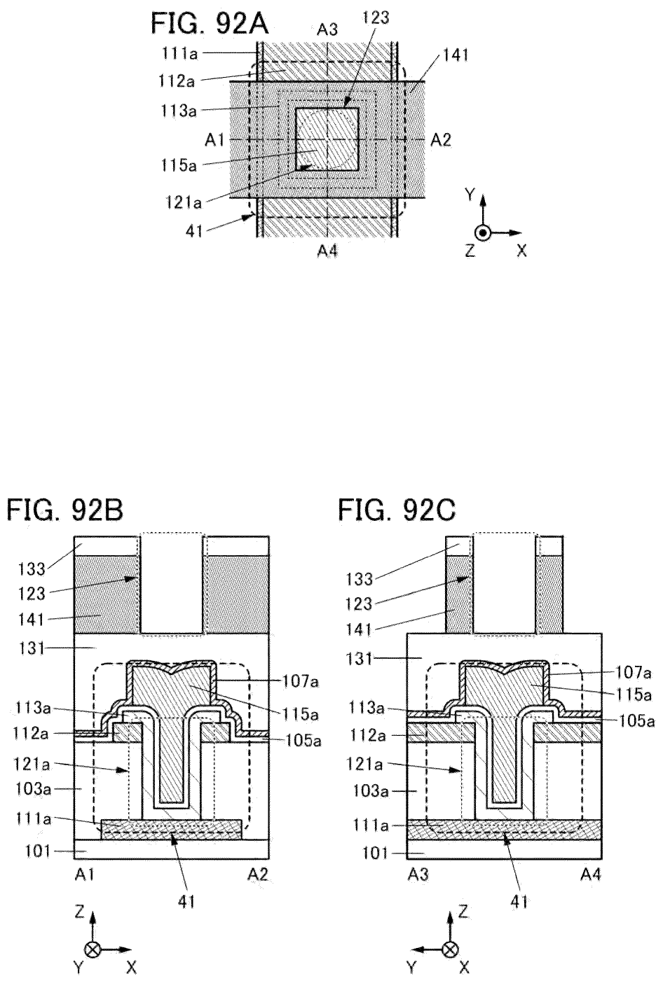

Next, part of the conductive film 133A and part of the conductive film 141A are processed to form the insulating layer 133 and the conductive layer 141 including the opening portion 123 (FIGS. 92A to 92C). The insulating layer 133 and the conductive layer 141 can be formed by, for example, forming a pattern by a lithography method and then processing the insulating film 133A and the conductive film 141A by an etching method using the pattern. Although the processing can be performed, for example, by a dry etching method or a wet etching method, processing by a dry etching method is preferable because it is suitable for microfabrication. Here, the opening portion 123 is formed so as to include a region overlapping with at least part of the conductive layer 115a.

The insulating layer 133 and the conductive layer 141 including the opening portion 123 can be formed by performing formation of a pattern by a lithography method twice and processing the insulating film 133A and the conductive film 141A by an etching method, for example. For example, after the insulating film 133A and the conductive film 141A are formed, a resist mask is formed and etching is performed using the resist mask to form the opening portion 123 in the insulating film 133A and the conductive film 141A. Next, the resist mask is removed. Then, a resist mask is formed, and the insulating film 133A and the conductive film 141A including the opening portion 123 are etched using the resist mask. In the above-described manner, the insulating layer 133 and the conductive layer 141 including the opening portion 123 can be formed. Note that after the insulating layer 133 and the conductive layer 141 which do not include the opening portion 123 are formed, the opening portion 123 may be formed in the insulating layer 133 and the conductive layer 141.

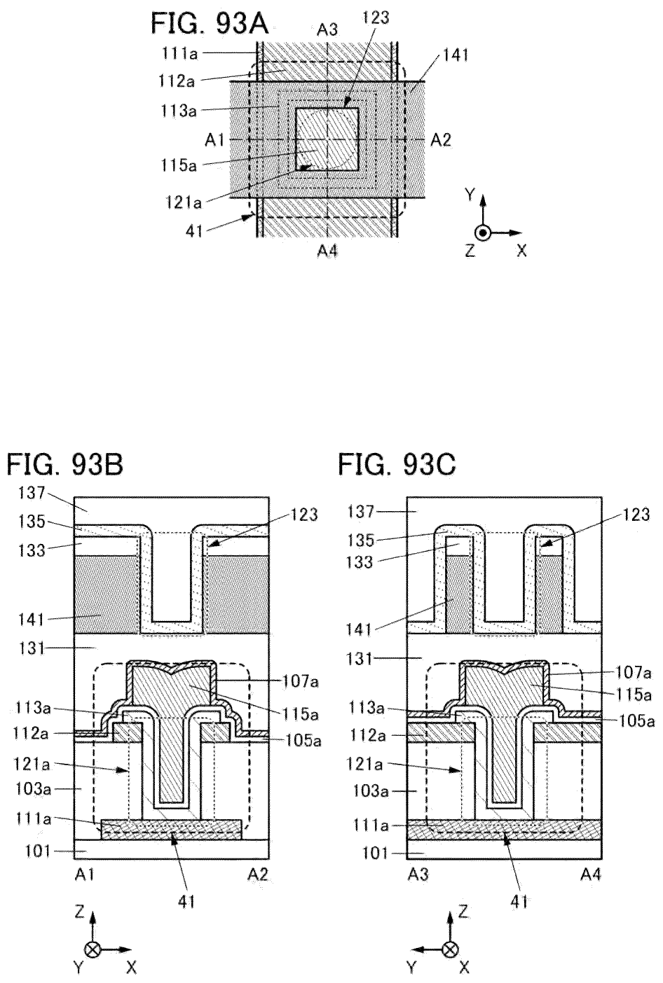

Next, the insulating layer 135 is formed over the insulating layer 131 and the insulating layer 133 (FIGS. 93A to 93C). The insulating layer 135 is formed to cover at least part of the conductive layer 141 and at least part of the insulating layer 133. For example, the insulating layer 135 is formed to cover the side surface of the conductive layer 141 and the side surface and top surface of the insulating layer 133. For example, the insulating layer 135 is formed to include, inside the opening portion 123, a region in contact with the top surface of the insulating layer 131, a region in contact with the side surface of the conductive layer 141, and a region in contact with the side surface of the insulating layer 133.

For the insulating layer 135, any of the above-described high-k materials or materials that can show ferroelectricity can be appropriately used. The insulating layer 135 can be formed by appropriately using a deposition method such as a sputtering method, a CVD method, an MBE method, a PLD method, or an ALD method. For example, a stacked-layer film in which zirconium oxide, aluminum oxide, and zirconium oxide are deposited in this order by an ALD method is formed as the insulating layer 135.

Next, the insulating layer 137 is formed over the insulating layer 135 (FIGS. 93A to 93C). The insulating layer 137 can be formed so as to fill the opening portion 123. Any of the above-described insulating materials can be appropriately used for the insulating layer 137. The insulating layer 137 can be formed by appropriately using a deposition method such as a sputtering method, a CVD method, an MBE method, a PLD method, or an ALD method. The top surface of the deposited insulating layer 137 is preferably planarized by CMP treatment. Note that the CMP treatment is unnecessary in some cases. In such a case, the top surface of the insulating layer 137 has a convex shape. By not performing planarization treatment, manufacturing cost can be reduced and production yield can be increased.

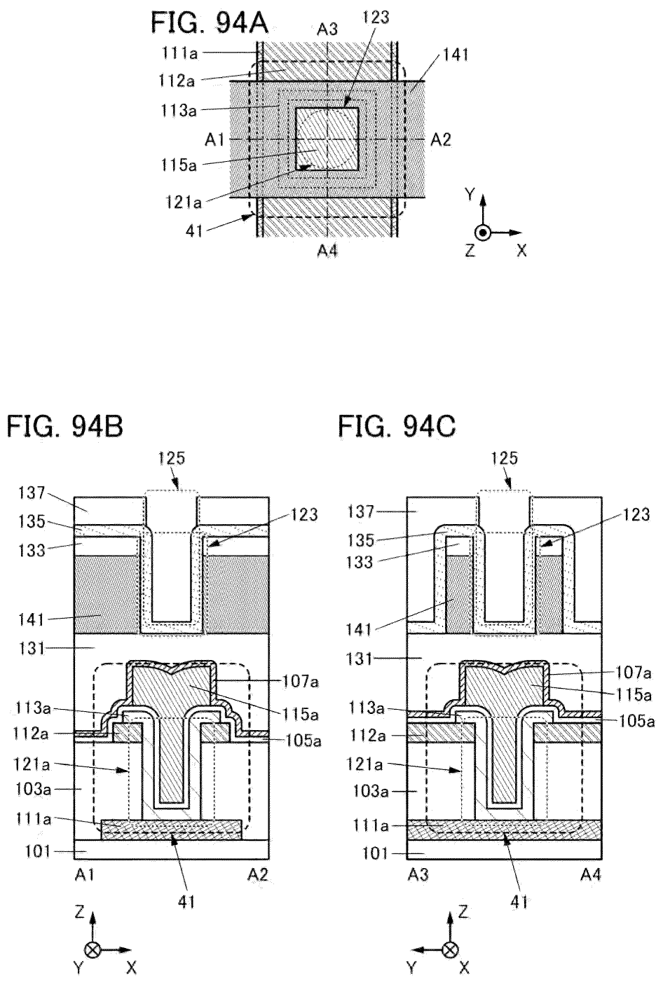

Next, part of the insulating layer 137 is processed to form the opening portion 125 that reaches the insulating layer 135 and includes a region overlapping with the opening portion 123 (FIGS. 94A to 94C). The opening portion 125 can be formed by, for example, forming a pattern by a lithography method and processing the insulating layer 137 by an etching method using the pattern. Since the opening portion 125 formed in the insulating layer 137 has a high aspect ratio here, the insulating layer 137 is preferably processed by anisotropic etching. It is particularly preferable to use a dry etching method because it is suitable for microfabrication.

Here, part of the insulating layer 137 is preferably processed under conditions where the etching selectivity of the insulating layer 137 to the insulating layer 135 is high, that is, conditions where the insulating layer 137 is easily etched and the insulating layer 135 is not easily etched. Accordingly, the insulating layer 135 can be inhibited from being processed unintentionally and reduced in thickness at the time of processing the insulating layer 137. Thus, a short circuit between the conductive layer 141 and the conductive layer 143 formed in a later step can be inhibited, for example.

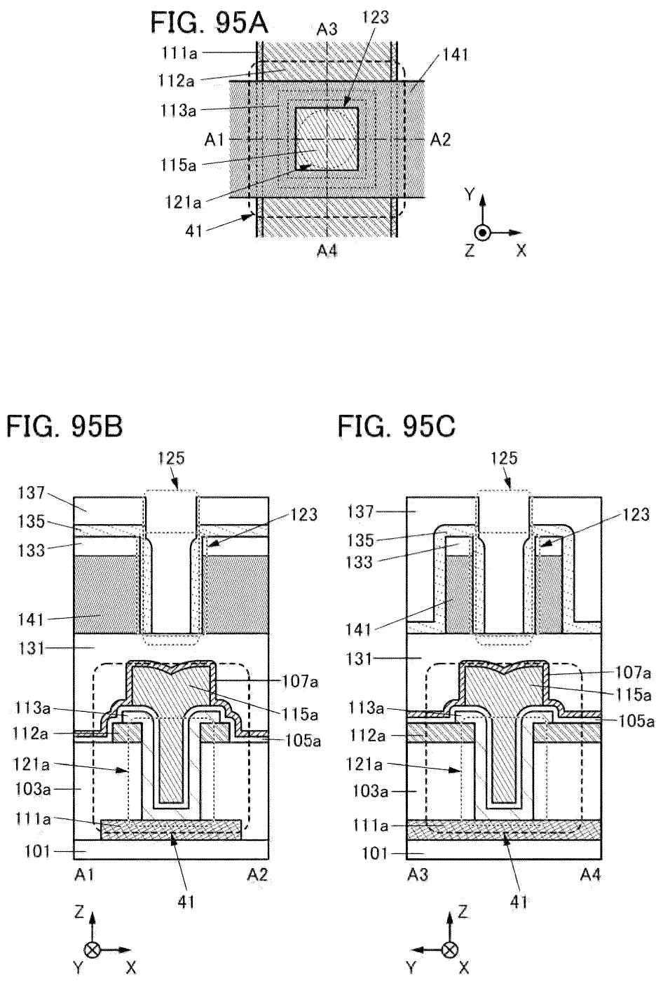

Next, part of the insulating layer 135 is processed so that the opening portion 125 can reach the insulating layer 131 (FIGS. 95A to 95C). Using anisotropic etching to process the insulating layer 135 can inhibit processing of the side surface of the insulating layer 135. This can inhibit a reduction in the thickness of the insulating layer 135 in a region sandwiched between the side surface of the conductive layer 141 and the side surface of the conductive layer 143 formed in a later step, whereby the conductive layer 141 and the conductive layer 143 can be inhibited from being provided adjacently. Thus, a short circuit between the conductive layer 141 and the conductive layer 143 can be inhibited, for example. It is particularly preferable to use a dry etching method because it is suitable for microfabrication.

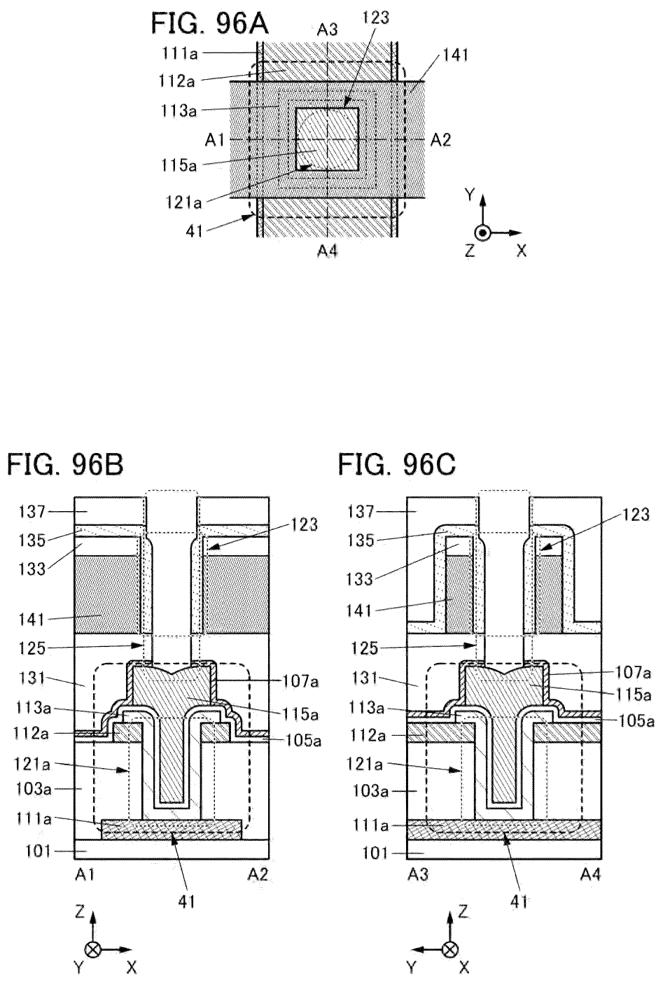

Next, part of the insulating layer 131 and part of the insulating layer 107a are processed so that the opening portion 125 can reach the conductive layer 115a (FIGS. 96A to 96C). Part of the insulating layer 131 and part of the insulating layer 107a are preferably processed under conditions where the etching selectivity of the insulating layer 131 and the insulating layer 107a to the insulating layer 135 is high, that is, conditions where the insulating layer 131 and/or the insulating layer 107a is easily etched and the insulating layer 135 is not easily etched. Accordingly, the insulating layer 135 can be inhibited from being processed unintentionally and reduced in thickness at the time of processing the insulating layer 131 and the insulating layer 107a. Thus, a short circuit between the conductive layer 141 and the conductive layer 143 formed in a later step can be inhibited, for example. Note that part of the insulating layer 131 and part of the insulating layer 107a are preferably processed by anisotropic etching. It is particularly preferable to use a dry etching method because it is suitable for microfabrication.

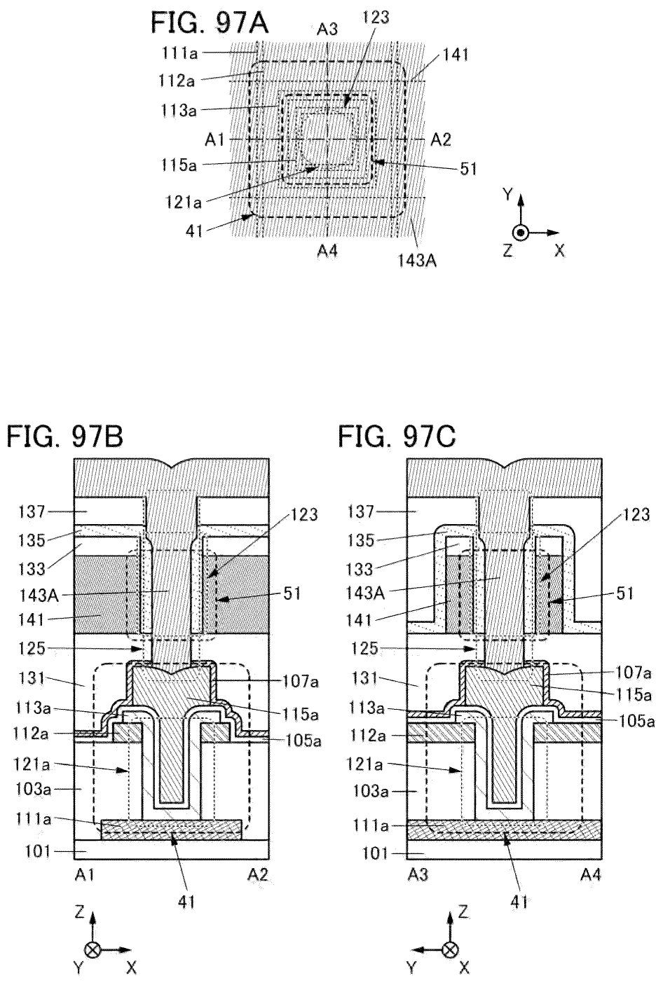

Next, a conductive film 143A is formed to fill the opening portion 125 (FIGS. 97A to 97C). The conductive film 143A is formed inside the opening portion 125 and over the insulating layer 137.

For the conductive film 143A, any of the conductive materials that can be used for the conductive layer 143 can be appropriately used. The conductive film 143A can be formed by appropriately using a deposition method such as a sputtering method, a CVD method, an MBE method, a PLD method, or an ALD method. Here, the conductive film 143A is preferably formed in contact with the insulating layer 135 and the conductive layer 115a inside the opening portion 125 with a high aspect ratio. Thus, the conductive film 143A is preferably formed by a deposition method with favorable coverage or embeddability, and is further preferably formed by a CVD method, an ALD method, or the like.

Although the conductive film 143A is provided so as to fill the opening portion 125 in the above description, the present invention is not limited thereto. For example, a depressed portion reflecting the shape of the opening portion 125 might be formed in a center portion of the conductive film 143A. The depressed portion may be filled with an inorganic insulating material, for example.

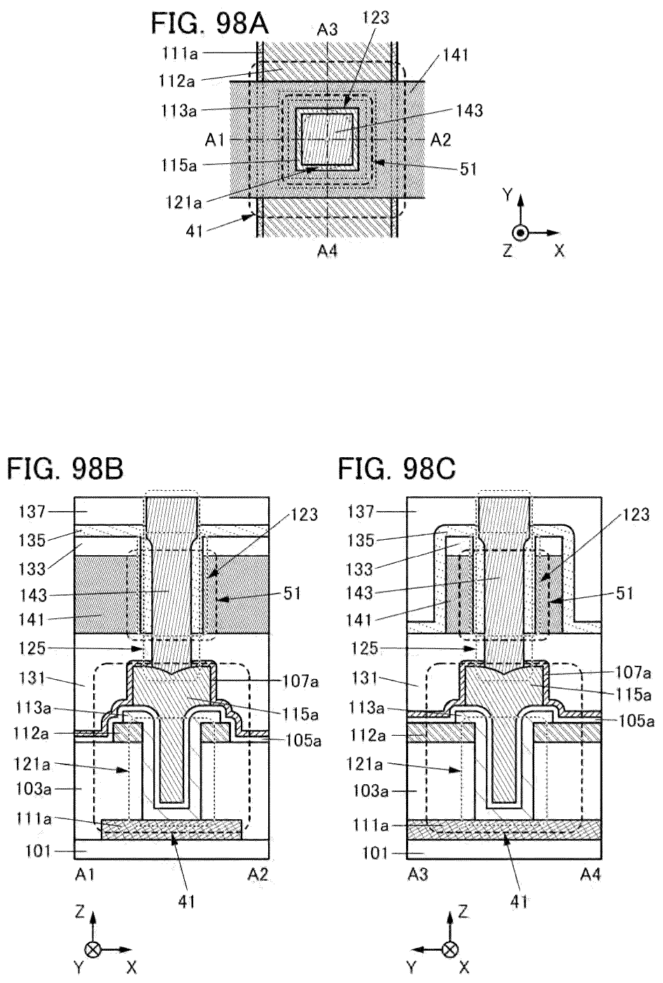

Next, the conductive layer 143 is formed so as to include a region positioned inside the opening portion 125 (FIGS. 98A to 98C). For example, the conductive layer 143 can be formed by removing the conductive film 143A over the insulating layer 137 by CMP treatment. The conductive layer 143 is formed so as to be electrically connected to the conductive layer 115a. For example, the conductive layer 143 is formed so that the bottom surface of the conductive layer 143 can include, inside the opening portion 125, a region in contact with the top surface of the conductive layer 115a.

In the above-described manner, the capacitor 51 including the conductive layer 141, the insulating layer 135, and the conductive layer 143 can be formed.

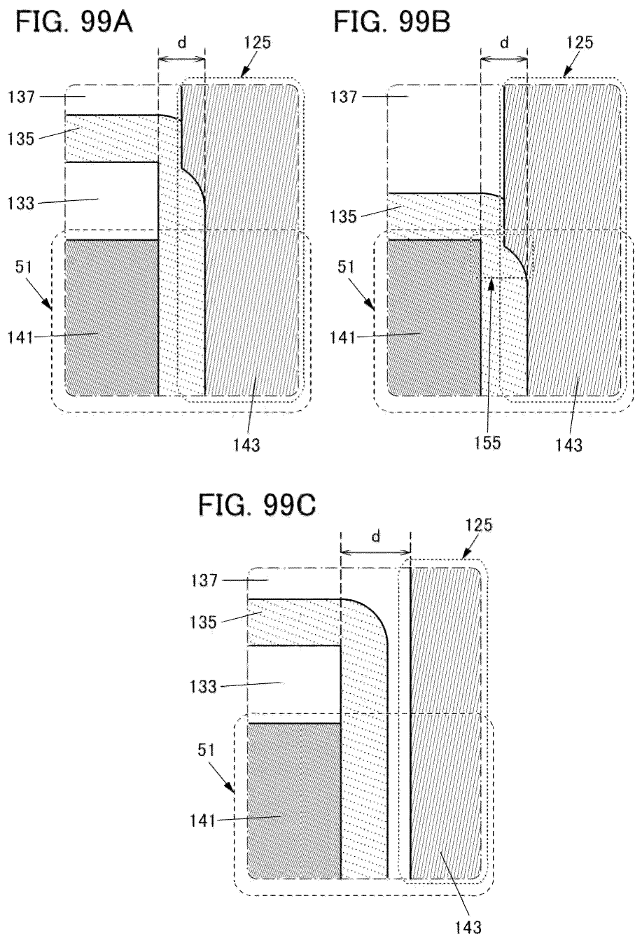

FIG. 99A is an enlarged view extracting parts of the capacitor 51, the insulating layer 133, and the insulating layer 137 which are illustrated in FIG. 98B. FIG. 99B illustrates a structure example omitting the insulating layer 133 from the structure in FIG. 99A. In the example illustrated in FIG. 99B, the insulating layer 135 is provided so as to be in contact with the top surface of the conductive layer 141, for example. Here, a distance between the side surface of the conductive layer 141 and the side surface of the conductive layer 143 is referred to as a distance d. The distance d can be, for example, the maximum distance between the side surface of the conductive layer 141 and the side surface of the conductive layer 143. In FIGS. 99A and 99B, for example, the maximum thickness of the insulating layer 135 in a region sandwiched between the side surface of the conductive layer 141 and the side surface of the conductive layer 143 is the distance d.

As illustrated in FIG. 99B, in the case where the insulating layer 133 is not provided over the conductive layer 141, a region 155 where the thickness of the insulating layer 135 is small might be formed between the conductive layer 141 and the conductive layer 143 in the step of forming the opening portion 125. In the region 155, the distance between the conductive layer 141 and the conductive layer 143 is short. This might cause a short circuit between the conductive layer 141 and the conductive layer 143 in the region 155, for example. The insulating layer 133 provided over the conductive layer 141 as illustrated in FIG. 99A can inhibit formation of the region 155. Accordingly, the reliability of the memory cell can be improved, and a method for manufacturing a highly reliable semiconductor device can be provided. Furthermore, a method for manufacturing a semiconductor device with high yield can be provided. Note that the insulating layer 133 is not necessarily provided as long as a short circuit between the conductive layer 141 and the conductive layer 143 does not occur, for example. In that case, the manufacturing process of the semiconductor device can be simplified.

FIG. 99C illustrates an example in which the insulating layer 137 is provided between the side surface of the insulating layer 135 and the side surface of the conductive layer 143. In that case, for example, the maximum sum of the thickness of the insulating layer 135 and the thickness of the insulating layer 137 in the region sandwiched between the side surface of the conductive layer 141 and the side surface of the conductive layer 143 is the distance d. In the example illustrated in FIG. 99C, not only the insulating layer 135 but also the insulating layer 137 serves as the dielectric layer of the capacitor 51. Moreover, a structure in which the conductive layer 143 is not in contact with the insulating layer 135 is possible. In the structure illustrated in FIG. 99C, the insulating layer 133 may be omitted.

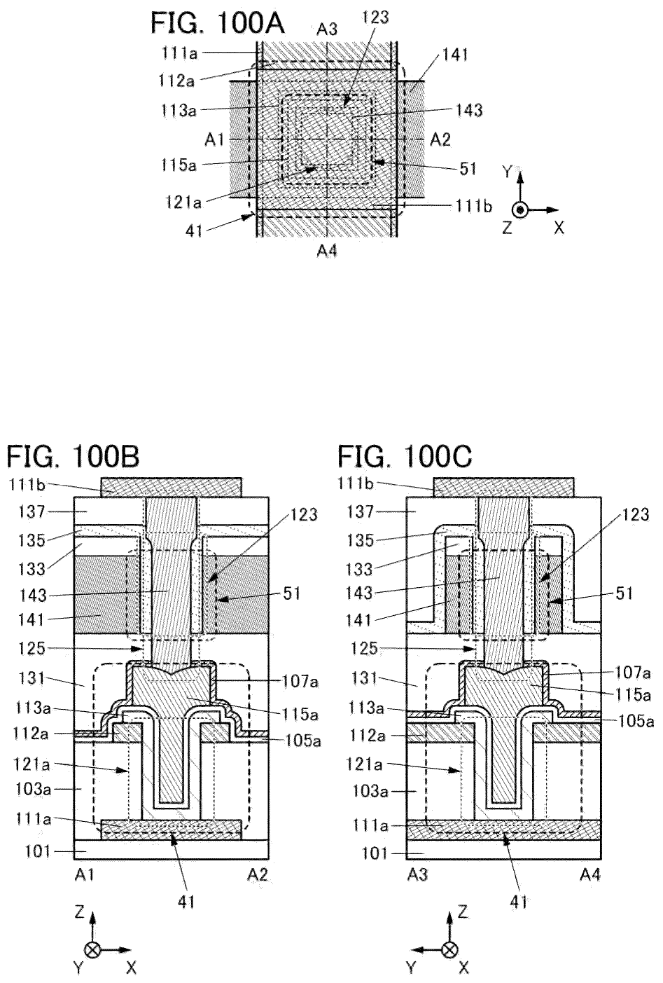

Next, the conductive layer 111b is formed over the conductive layer 143 and the insulating layer 137 (FIGS. 100A to 100C). For example, the conductive layer 111b is formed so as to include a region in contact with the top surface of the conductive layer 143. Thus, the conductive layer 111b and the conductive layer 143 can be electrically connected to each other. Furthermore, as described above, the conductive layer 143 is electrically connected to the conductive layer 115a. Therefore, the conductive layer 115a, the conductive layer 143, and the conductive layer 111b can be electrically connected to one another. The conductive layer 111b can be formed by a method similar to that for the conductive layer 111a.

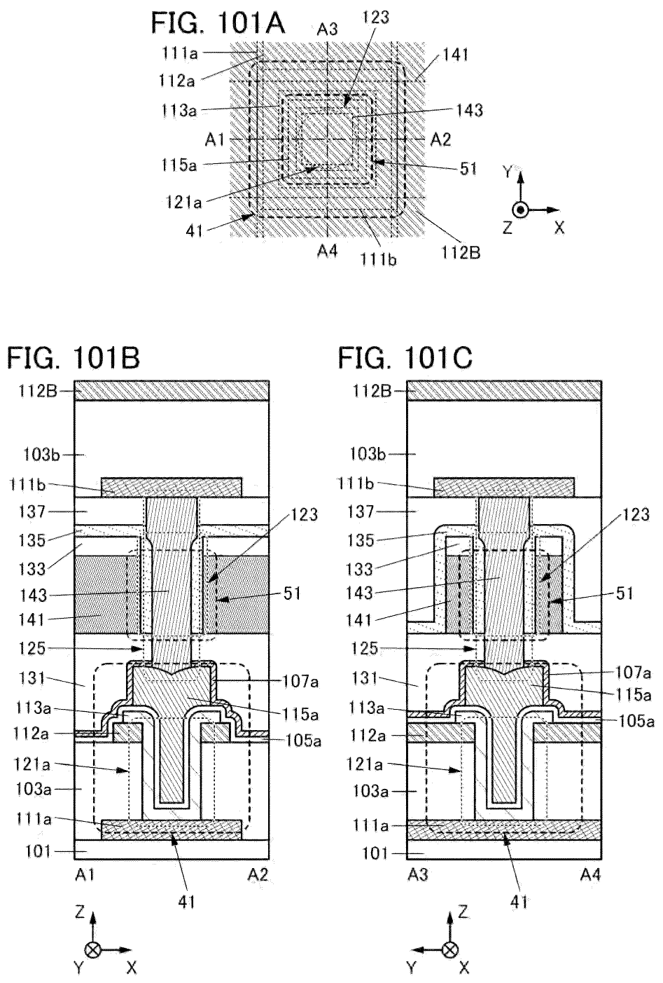

Next, the insulating layer 103b is formed over the insulating layer 137 and the conductive layer 111b, and a conductive film 112B is formed over the insulating layer 103b (FIGS. 101A to 101C). The insulating layer 103b can be formed by a method similar to that for the insulating layer 103a, and the conductive film 112B can be formed by a method similar to that for the conductive film 112A.

Next, the conductive layer 112b, the opening portion 121b, the semiconductor layer 113b, the insulating layer 105b, the conductive layer 115b, and the insulating layer 107b are formed by methods similar to the methods for forming the conductive layer 112a, the opening portion 121a, the semiconductor layer 113a, the insulating layer 105a, the conductive layer 115a, and the insulating layer 107a (FIGS. 2A to 2C).

In the above-described manner, the transistor 42 including the conductive layer 111b, the conductive layer 112b, the semiconductor layer 113b, the insulating layer 105b, and the conductive layer 115b can be formed. As described above, the conductive layer 111b functions as the one of the source electrode and the drain electrode of the transistor 42, the conductive layer 112b functions as the other of the source electrode and the drain electrode of the transistor 42, the insulating layer 105b functions as the gate insulating layer of the transistor 42, and the conductive layer 115b functions as the gate electrode of the transistor 42.

In the above-described manner, the semiconductor device illustrated in FIGS. 2A to 2C including the memory cells 21 in each of which the transistor 41, the transistor 42, and the capacitor 51 are provided can be manufactured.

### <Example 2 of Method for Manufacturing Semiconductor Device>

As the method for manufacturing the semiconductor device of one embodiment of the present invention, an example of a method for manufacturing the semiconductor device illustrated in FIGS. 37A to 37C is described below.

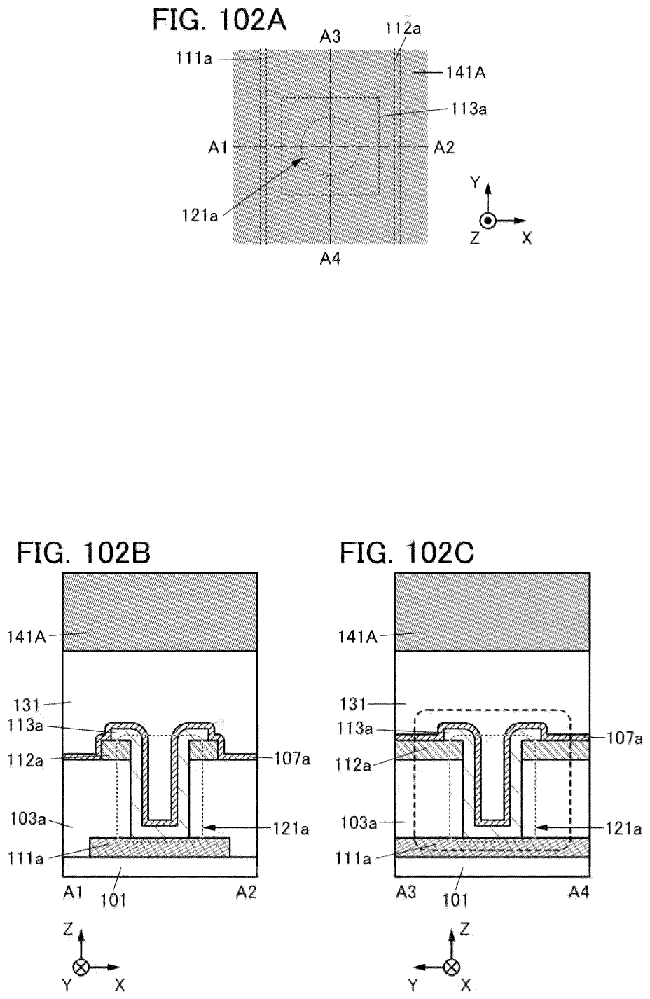

First, steps similar to those illustrated in FIG. 83A to FIG. 87C are performed. Next, the insulating layer 107a is formed over the semiconductor layer 113a, the conductive layer 112a, and the insulating layer 103a, and the insulating layer 131 is formed over the insulating layer 107a (FIGS. 102A to 102C). For the formation of the insulating layer 107a and the insulating layer 131, the description of FIGS. 90A to 90C can be referred to.

Next, the conductive film 141A is formed over the insulating layer 131 (FIGS. 102A to 102C). For the formation of the conductive film 141A, the description of FIGS. 91A to 91C can be referred to.

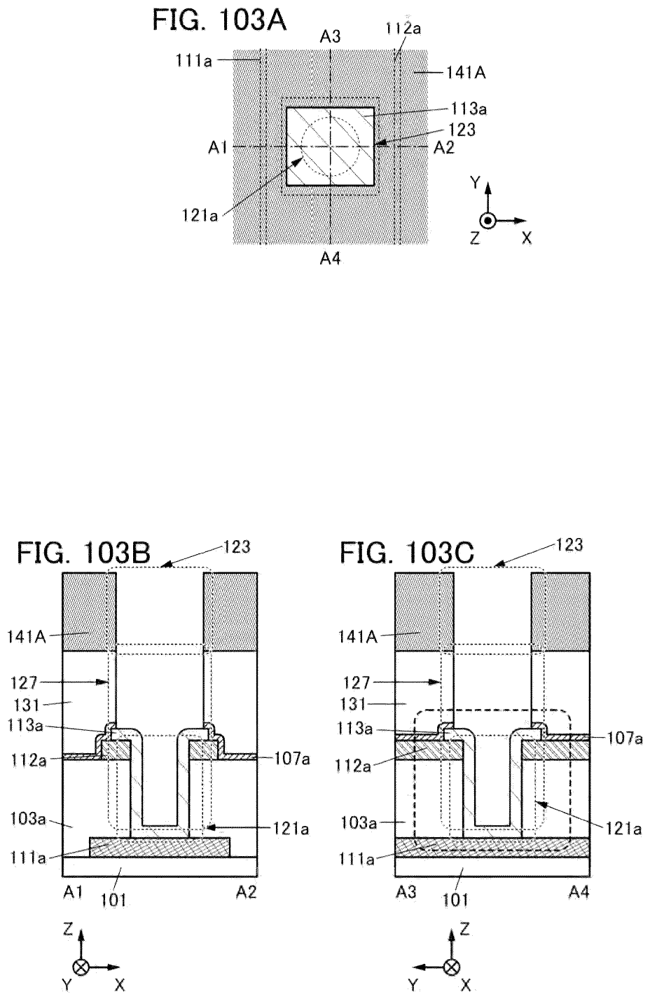

Next, part of the conductive film 141A is processed to form the opening portion 123 reaching the insulating layer 131. Furthermore, part of the insulating layer 131 and part of the insulating layer 107a are processed, so that the opening portion 127 reaching the semiconductor layer 113a is formed so as to include a region overlapping with the opening portion 123 (FIGS. 103A to 103C). For the formation of the opening portion 123, the description of FIGS. 92A to 92C can be referred to.

The opening portion 127 can be formed by, for example, forming a pattern by a lithography method and processing the insulating layer 131 by an etching method using the pattern. Here, the insulating layer 131 is preferably processed by anisotropic etching. It is particularly preferable to use a dry etching method because it is suitable for microfabrication.

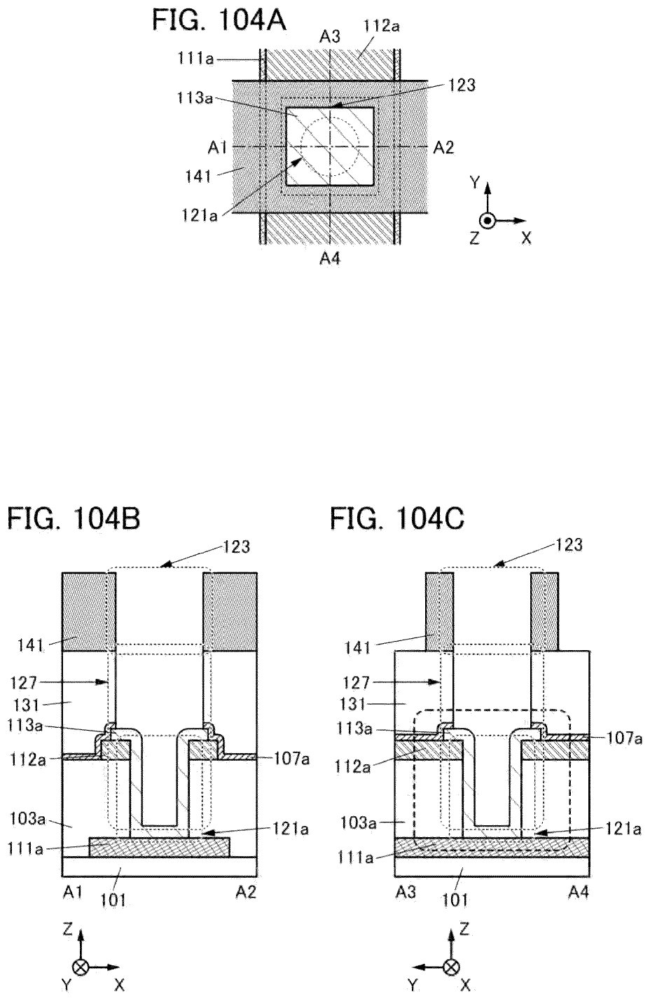

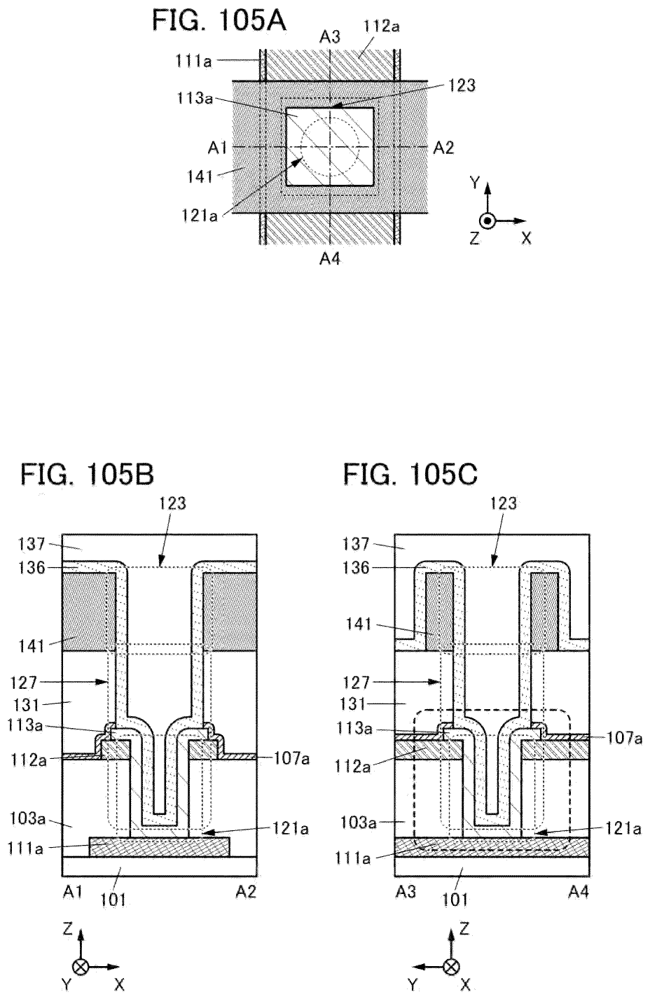

Next, part of the conductive film 141A including the opening portion 123 is processed to form the conductive layer 141 (FIGS. 104A to 104C). For the formation of the conductive layer 141, the description of FIGS. 92A to 92C can be referred to. Note that after the conductive layer 141 not including the opening portion 123 is formed, the opening portion 123 may be formed in the conductive layer 141, and the opening portion 127 may be formed in the insulating layer 131 and the insulating layer 107a. Next, the insulating layer 136 is formed over the semiconductor layer 113a and the conductive layer 141 (FIGS. 105A to 105C). The insulating layer 136 is formed so as to cover at least part of the semiconductor layer 113a and at least part of the conductive layer 141. For example, the insulating layer 136 is formed so as to cover at least part of the top surface and the depression portion's side surface of the semiconductor layer 113a and at least part of the top and side surfaces of the conductive layer 141. For example, the insulating layer 136 is formed so as to include a region in contact with the top surface of the semiconductor layer 113a, a region in contact with the depressed portion's side surface of the semiconductor layer 113a, a region in contact with the side surface of the insulating layer 107a, a region in contact with the side surface of the insulating layer 131, a region in contact with the side surface of the conductive layer 141, and a region in contact with the top surface of the conductive layer 141.

For the insulating layer 136, any of the above-described high-k materials can be used, for example. The insulating layer 136 can be formed by appropriately using a deposition method such as a sputtering method, a CVD method, an MBE method, a PLD method, or an ALD method.

Next, the insulating layer 137 is formed over the insulating layer 136 (FIGS. 105A to 105C). The insulating layer 137 can be formed so as to fill the opening portion 123 and the opening portion 127. For the formation of the insulating layer 137, the description of FIGS. 93A to 93C can be referred to.

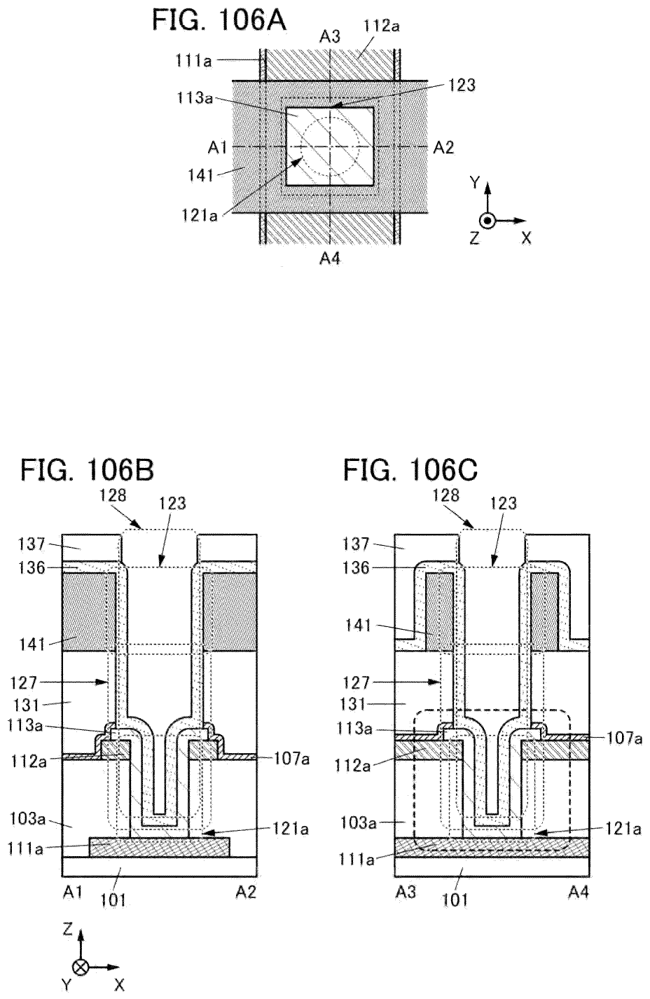

Next, part of the insulating layer 137 is processed, so that the opening portion 128 reaching the insulating layer 136 is formed so as to include a region overlapping with the opening portion 123 and the opening portion 127 (FIGS. 106A to 106C). The opening portion 128 can be formed by a method similar to the method that can be used to form the opening portion 127.

Since the opening portion 128 has a high aspect ratio, part of the insulating layer 137 is preferably processed by anisotropic etching. It is particularly preferable to use a dry etching method because it is suitable for microfabrication.

In the formation of the opening portion 128 here, part of the insulating layer 137 is preferably processed under conditions where the etching selectivity of the insulating layer 137 to the insulating layer 136 is high, that is, conditions where the insulating layer 137 is easily etched and the insulating layer 136 is not easily etched. Accordingly, the insulating layer 136 can be inhibited from being processed unintentionally and reduced in thickness at the time of forming the opening portion 128. Thus, a short circuit between the semiconductor layer 113a and the conductive layer 143 and between the conductive layer 141 and the conductive layer 143 can be inhibited, for example. Note that the conductive layer 143 is formed in a later step.

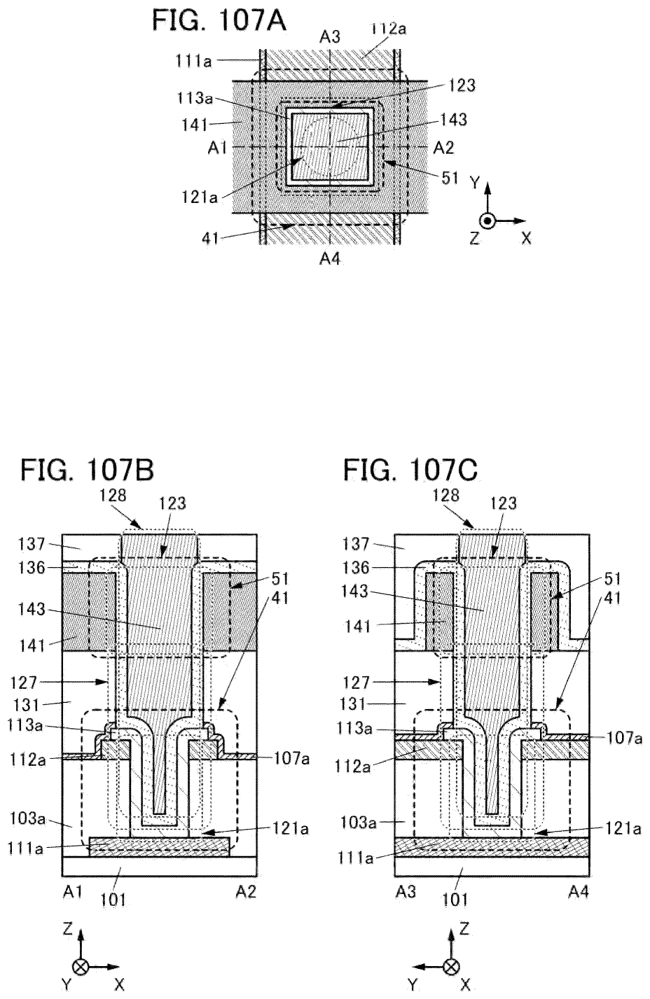

Next, the conductive layer 143 is formed so as to include a region positioned inside the opening portion 128 (FIGS. 107A to 107C). Thus, the transistor 41 including the conductive layer 111a, the conductive layer 112a, the semiconductor layer 113a, the insulating layer 136, and the conductive layer 143 can be formed. As described above, the conductive layer 111a functions as the one of the source electrode and the drain electrode of the transistor 41, the conductive layer 112a functions as the other of the source electrode and the drain electrode of the transistor 41, the insulating layer 136 functions as the gate insulating layer of the transistor 41, and the conductive layer 143 functions as the gate electrode of the transistor 41. Furthermore, the capacitor 51 including the conductive layer 141, the insulating layer 136, and the conductive layer 143 can be formed. For the formation of the conductive layer 143, the description of FIG. 97A to FIG. 98C can be referred to.

Then, the steps illustrated in FIG. 100A to FIG. 101C and the subsequent steps are performed. In the above-described manner, the semiconductor device illustrated in FIGS. 37A to 37C including the memory cells 21 in each of which the transistor 41, the transistor 42, and the capacitor 51 are provided can be manufactured.

### <Example 3 of Method for Manufacturing Semiconductor Device>

As the method for manufacturing the semiconductor device of one embodiment of the present invention, an example of a method for manufacturing the semiconductor device illustrated in FIGS. 44A, 44C, and 44D is described below.

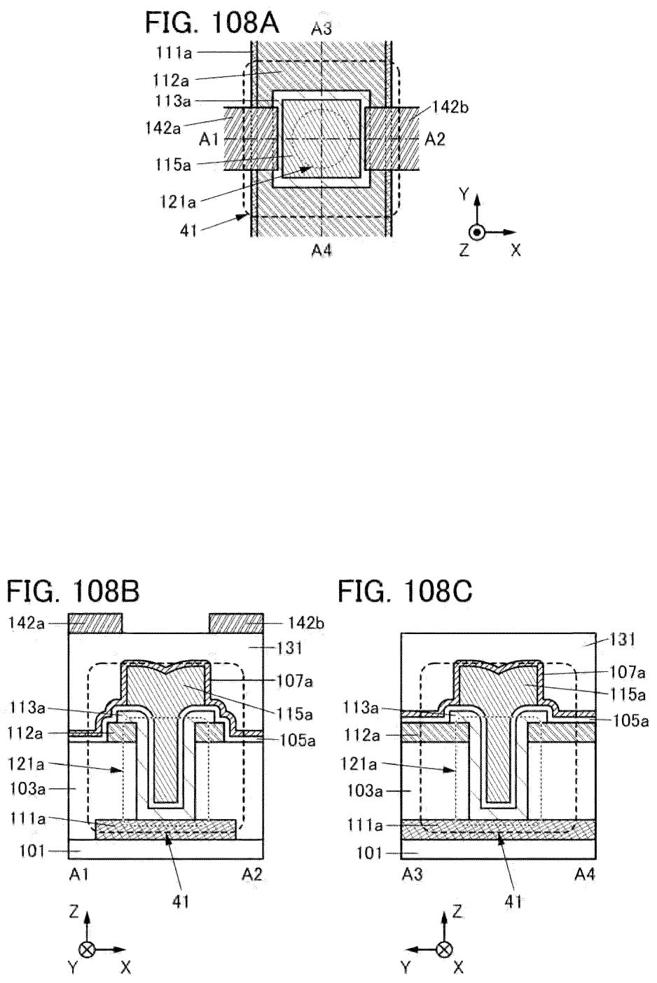

First, steps similar to those illustrated in FIG. 83A to FIG. 90C are performed. Next, the conductive layer 142a and the conductive layer 142b are formed over the insulating layer 131 (FIGS. 108A to 108C). For example, the conductive layer 142a and the conductive layer 142b can be formed by forming and processing a conductive film to be the conductive layer 142a and the conductive layer 142b. For the conductive film to be the conductive layer 142a and the conductive layer 142b, any of the above-described conductive materials that can be used for the conductive layer 142a and the conductive layer 142b can be appropriately used.

The conductive film to be the conductive layers 142a and 142b can be formed by appropriately using a deposition method such as a sputtering method, a CVD method, an MBE method, a PLD method, or an ALD method. After the conductive film to be the conductive layers 142a and 142b is formed, formation of a pattern is performed by a lithography method, and the conductive film is processed by a dry etching method, a wet etching method, or the like using the pattern, whereby the conductive layers 142a and 142b can be formed. Here, for microfabrication, the conductive film is preferably processed by a dry etching method.

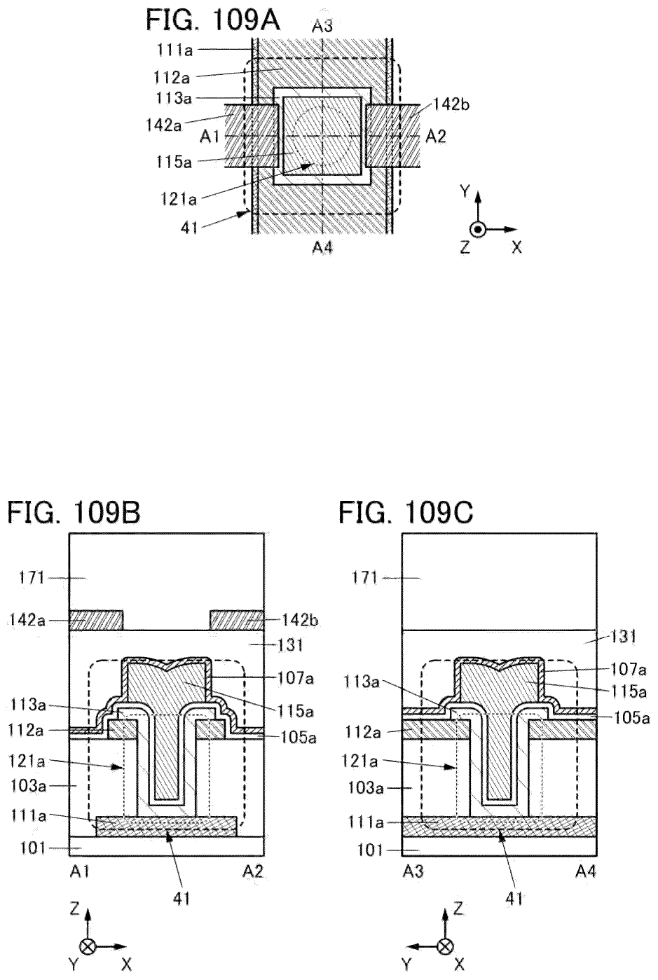

Next, the insulating layer 171 is formed over the insulating layer 131, the conductive layer 142a, and the conductive layer 142b (FIGS. 109A to 109C). Any of the above-described insulating materials can be appropriately used for the insulating layer 171. The insulating layer 171 can be formed by appropriately using a deposition method such as a sputtering method, a CVD method, an MBE method, a PLD method, or an ALD method. The top surface of the deposited insulating layer 171 is preferably planarized by CMP treatment. Note that the CMP treatment is unnecessary in some cases. In such a case, the top surface of the insulating layer 171 has a convex shape. By not performing planarization treatment, manufacturing cost can be reduced and production yield can be increased.

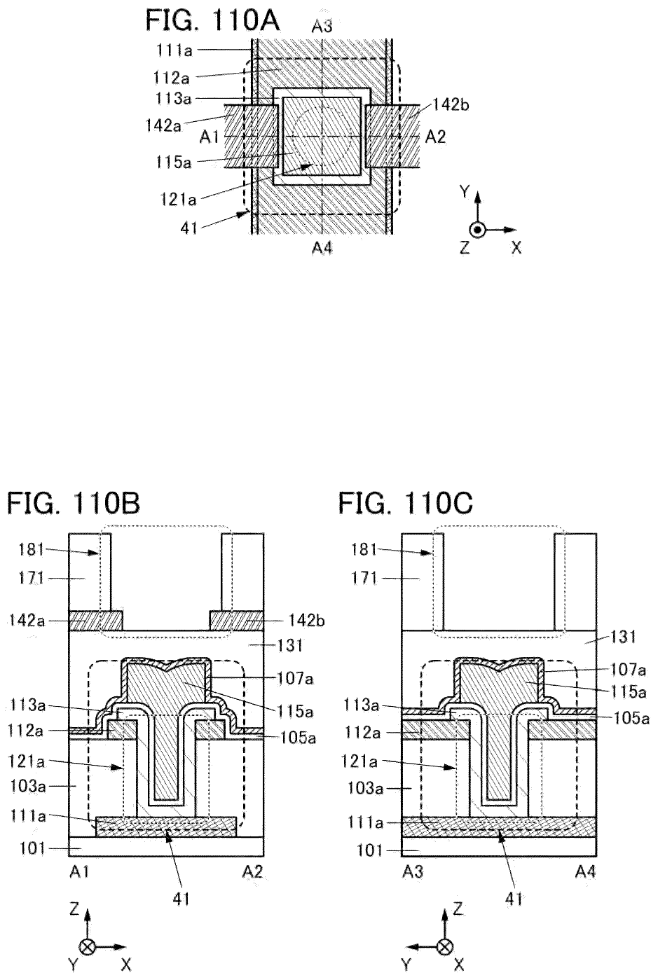

Next, part of the insulating layer 171 is processed, so that the opening portion 181 reaching the insulating layer 131, the conductive layer 142a, and the conductive layer 142b is formed so as to include a region overlapping with the conductive layer 115a (FIGS. 110A to 110C). The opening portion 181 can be formed by, for example, forming a pattern by a lithography method and processing the insulating layer 171 by an etching method using the pattern. Here, the insulating layer 171 is preferably processed by anisotropic etching. It is particularly preferable to use a dry etching method because it is suitable for microfabrication.

Here, part of the insulating layer 171 is preferably processed under conditions where the etching selectivity of the insulating layer 171 to the insulating layer 131 is high, that is, conditions where the insulating layer 171 is easily etched and the insulating layer 131 is not easily etched. Accordingly, the insulating layer 131 can be inhibited from being processed unintentionally and reduced in thickness at the time of processing the insulating layer 171. Thus, a short circuit between the conductive layer 115a and the conductive layer 141 formed in a later step can be inhibited, for example.

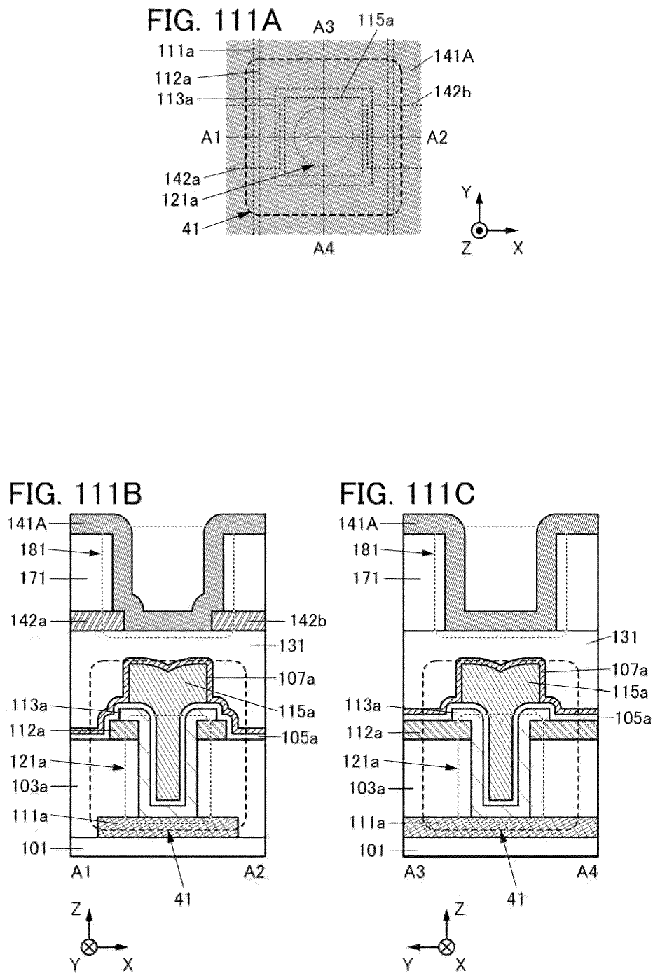

Next, the conductive film 141A is formed over the insulating layer 131, the insulating layer 171, the conductive layer 142a, and the conductive layer 142b (FIGS. 111A to 111C). For the formation of the conductive film 141A, the description of FIGS. 91A to 91C can be referred to.

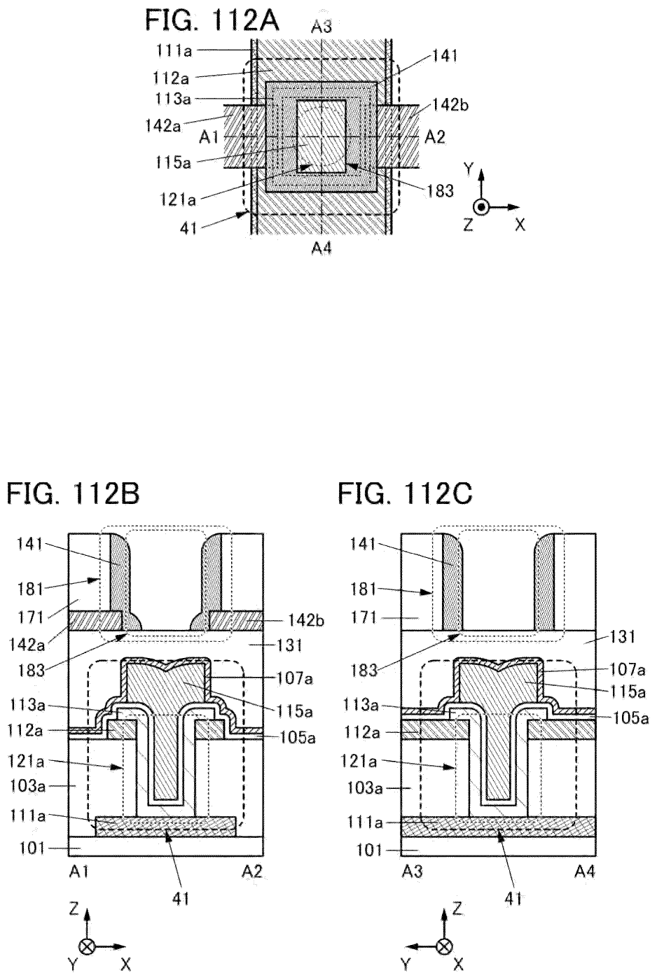

Next, the conductive film 141A is processed, so that the conductive layer 141 that includes the opening portion 183 including a region overlapping with the conductive layer 115a is formed inside the opening portion 181 (FIGS. 112A to 112C). For example, etching treatment is uniformly or substantially uniformly performed on a top surface of the conductive film 141A. Thus, the conductive layer 141 can be formed along the side surface of the insulating layer 171, the top surface of the conductive layer 142a, the side surface of the conductive layer 142a, the top surface of the conductive layer 142b, the side surface of the conductive layer 142b, and the top surface of the insulating layer 131 inside the opening portion 181. Specifically, the etching treatment can form the conductive layer 141 including, inside the opening portion 181, a region in contact with the side surface of the insulating layer 171, a region in contact with the top surface of the conductive layer 142a, a region in contact with the side surface of the conductive layer 142a, a region in contact with the top surface of the conductive layer 142b, a region in contact with the side surface of the conductive layer 142b, and a region in contact with the top surface of the insulating layer 131. Etching treatment performed uniformly or substantially uniformly on a film in this manner is referred to as etch-back treatment. A dry etching method is preferably employed for the etch-back treatment. Note that the conductive layer 141 may be formed by a lithography method.

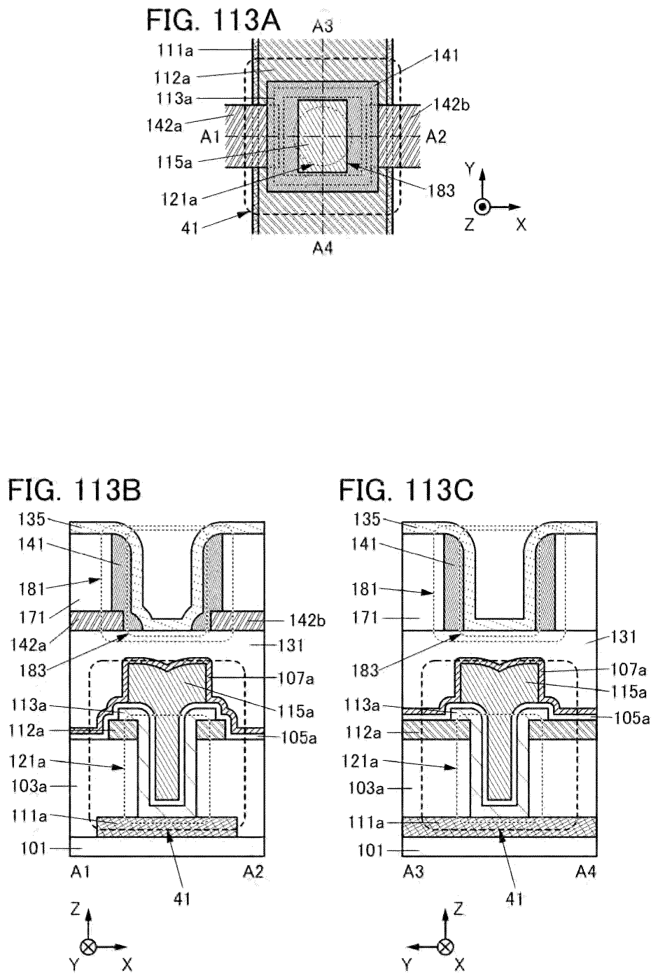

Next, the insulating layer 135 is formed so as to include a region positioned inside the opening portion 181, specifically, inside the opening portion 183 (FIGS. 113A to 113C). The insulating layer 135 is formed so as to cover at least part of the conductive layer 141 and at least part of the insulating layer 171. For example, the insulating layer 135 is formed so as to cover the top surface of the insulating layer 171 and the conductive layer 141. For example, the insulating layer 135 is formed so as to include a region in contact with the conductive layer 141 and a region in contact with the top surface of the insulating layer 131 inside the opening portion 183. For the formation of the insulating layer 135, the description of FIGS. 93A to 93C can be referred to.

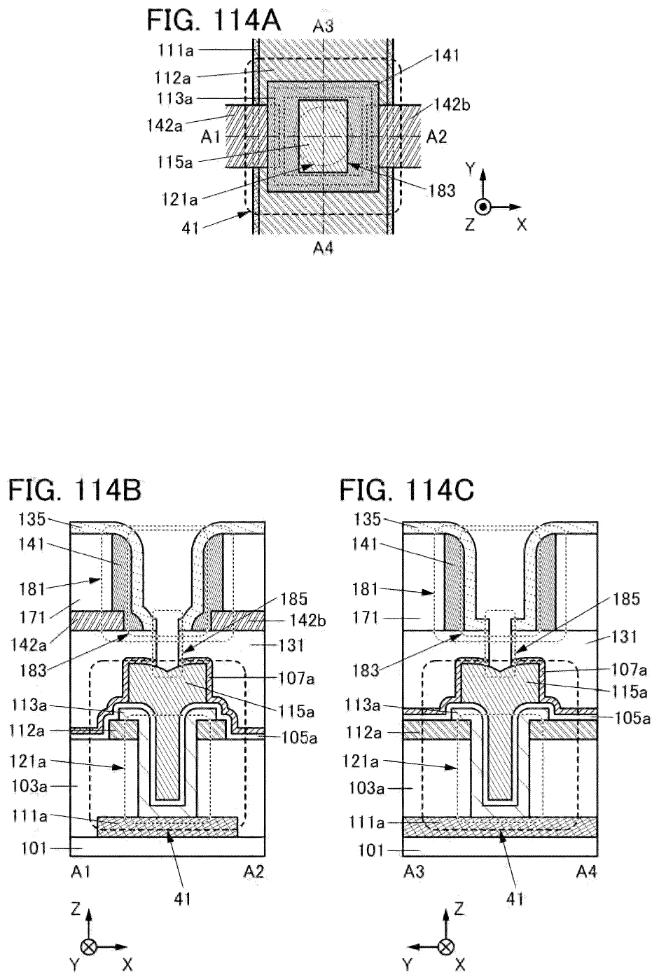

Next, part of the insulating layer 135, part of the insulating layer 131, and part of the insulating layer 107a are processed to form the opening portion 185 reaching the conductive layer 115a (FIGS. 114A to 114C). The opening portion 185 can be formed by, for example, forming a pattern by a lithography method and processing the insulating layer 135, the insulating layer 131, and the insulating layer 107a by an etching method using the pattern. Here, the insulating layer 135, the insulating layer 131, and the insulating layer 107a are preferably processed by anisotropic etching. It is particularly preferable to use a dry etching method because it is suitable for microfabrication.

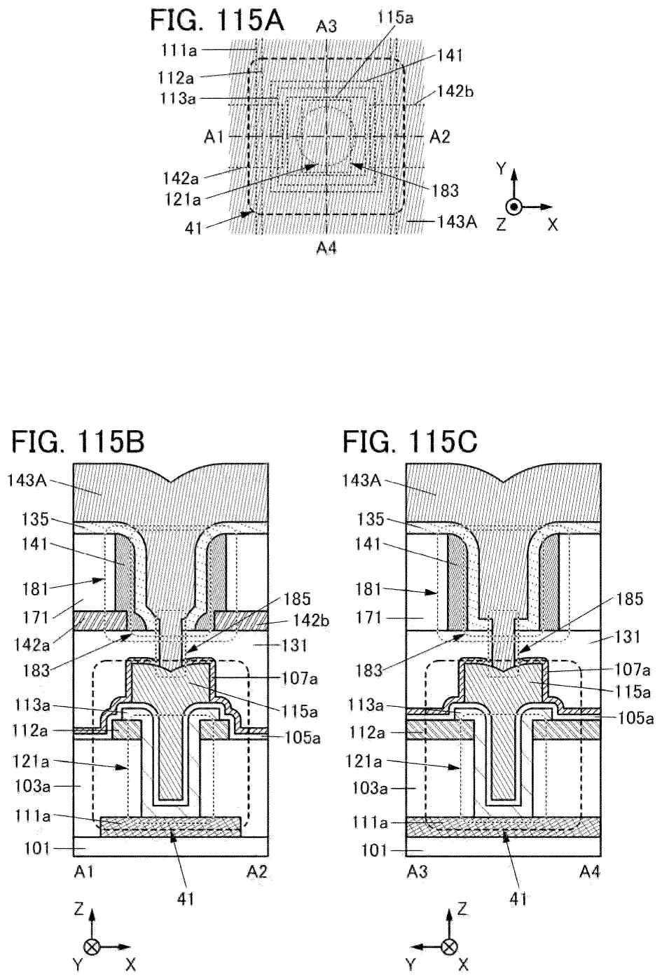

Next, the conductive film 143A is formed so as to fill the opening portion 185 and cover the insulating layer 135 (FIGS. 115A to 115C). For the formation of the conductive film 143A, the description of FIGS. 97A to 97C can be referred to.

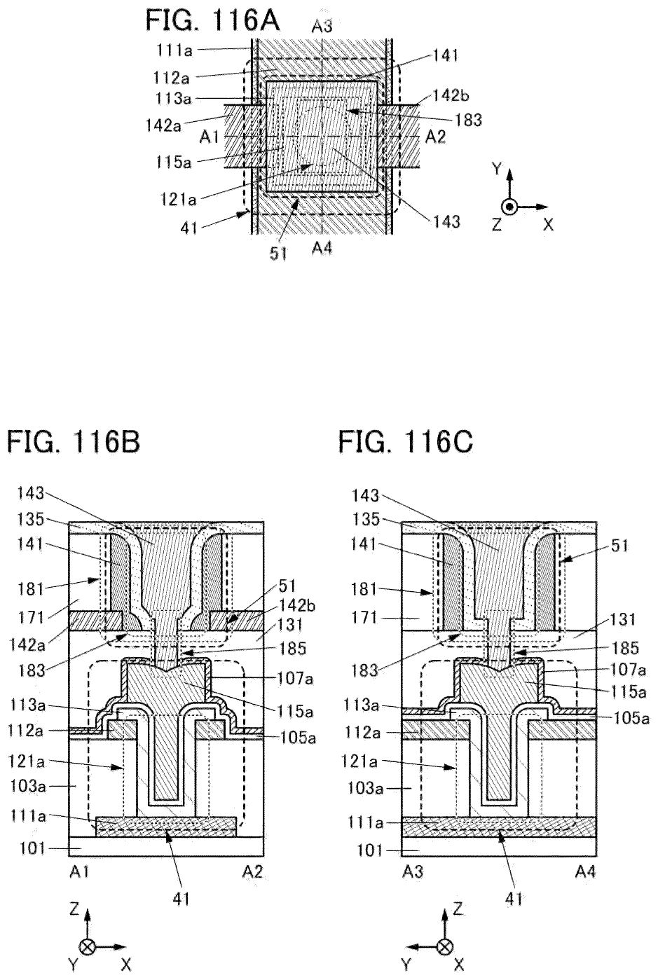

Next, the conductive layer 143 is formed so as to include a region positioned inside the opening portion 185 and cover the insulating layer 135 inside the opening portion 183 (FIGS. 116A to 116C). For example, the conductive layer 143 can be formed by performing planarization treatment such as CMP treatment on the conductive film 143A until the top surface of the insulating layer 135 is exposed. For example, the conductive layer 143 can be formed so that the bottom surface of the conductive layer 143 can include, inside the opening portion 185, a region in contact with the top surface of the conductive layer 115a.

In the above-described manner, the capacitor 51 including the conductive layer 141, the insulating layer 135, and the conductive layer 143 can be formed.

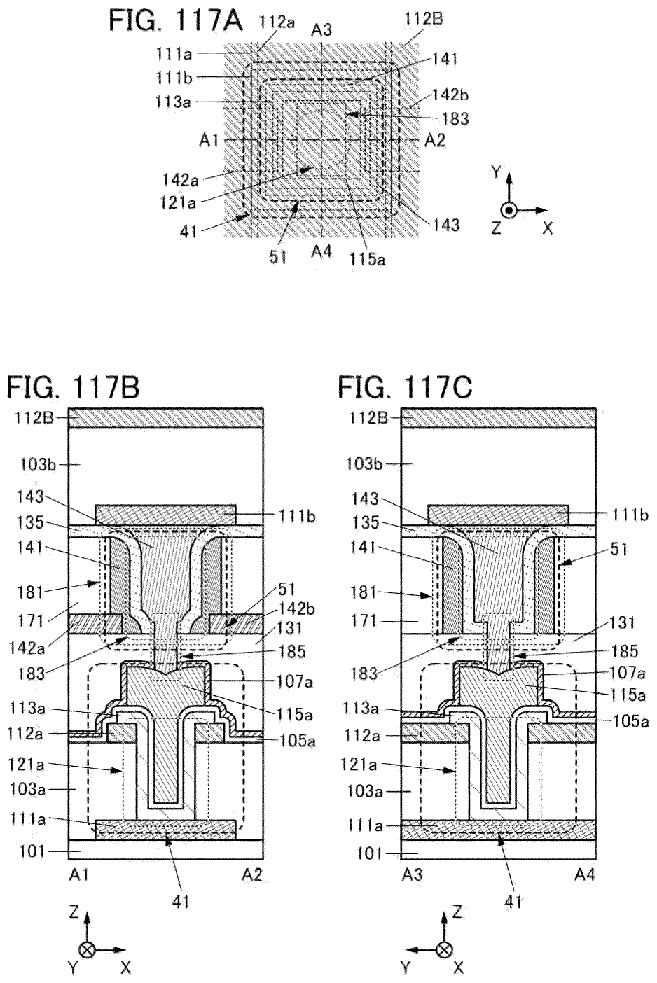

Next, the conductive layer 111b is formed over the conductive layer 143 and the insulating layer 135 (FIGS. 117A to 117C). For example, the conductive layer 111b is formed so as to include a region in contact with the top surface of the conductive layer 143. Thus, the conductive layer 111b and the conductive layer 143 can be electrically connected to each other. Furthermore, as described above, the conductive layer 143 is electrically connected to the conductive layer 115a. Therefore, the conductive layer 115a, the conductive layer 143, and the conductive layer 111b can be electrically connected to one another. The conductive layer 111b can be formed by a method similar to that for the conductive layer 111a.

Next, the insulating layer 103b is formed over the insulating layer 135 and the conductive layer 111b, and the conductive film 112B is formed over the insulating layer 103b (FIGS. 117A to 117C). For the formation of the insulating layer 103b and the conductive film 112B, the description of FIGS. 101A to 101C can be referred to.

Next, the conductive layer 112b, the opening portion 121b, the semiconductor layer 113b, the insulating layer 105b, the conductive layer 115b, and the insulating layer 107b are formed by methods similar to the methods for forming the conductive layer 112a, the opening portion 121a, the semiconductor layer 113a, the insulating layer 105a, the conductive layer 115a, and the insulating layer 107a (FIGS. 44A to 44C). In the above-described manner, the semiconductor device illustrated in FIGS. 44A to 44C including the memory cells 21 in each of which the transistor 41, the transistor 42, and the capacitor 51 are provided can be manufactured.

### <Example 4 of Method for Manufacturing Semiconductor Device>

As the method for manufacturing the semiconductor device of one embodiment of the present invention, an example of a method for manufacturing the semiconductor device illustrated in FIGS. 45A and 45B is described below.

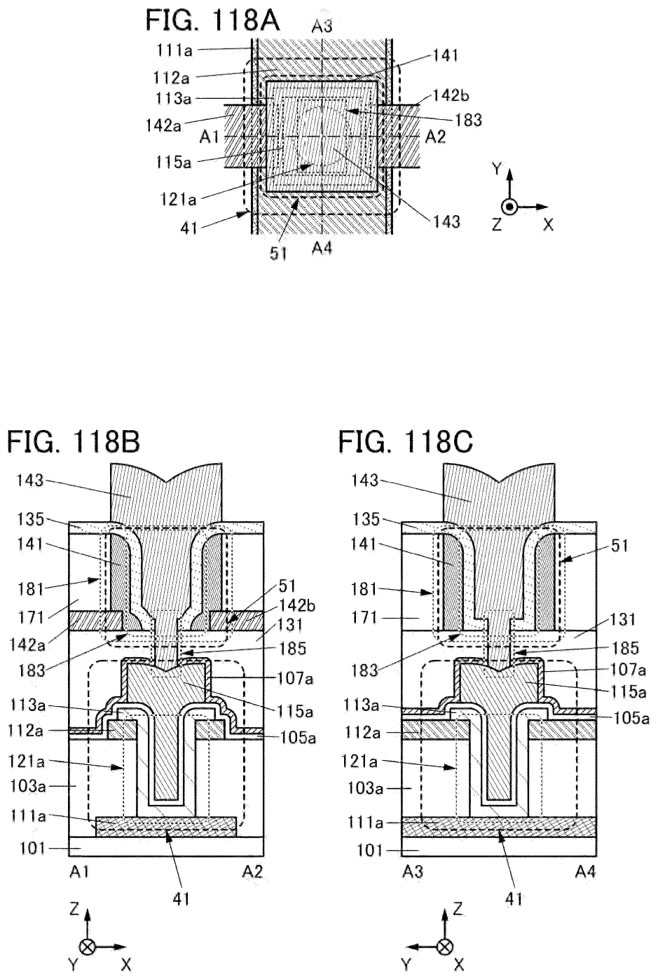

First, steps similar to those illustrated in FIG. 108A to FIG. 115C are performed. Next, the conductive layer 143 is formed by, for example, forming a pattern by a lithography method and then processing the conductive film 143A by an etching method using the pattern (FIGS. 118A to 118C). Although the processing can be performed, for example, by a dry etching method or a wet etching method, processing by a dry etching method is preferable because it is suitable for microfabrication. The conductive layer 143 is formed so as to include a region positioned inside the opening portion 185 and cover the insulating layer 135 inside the opening portion 183. In the above-described manner, the capacitor 51 including the conductive layer 141, the insulating layer 135, and the conductive layer 143 can be formed.

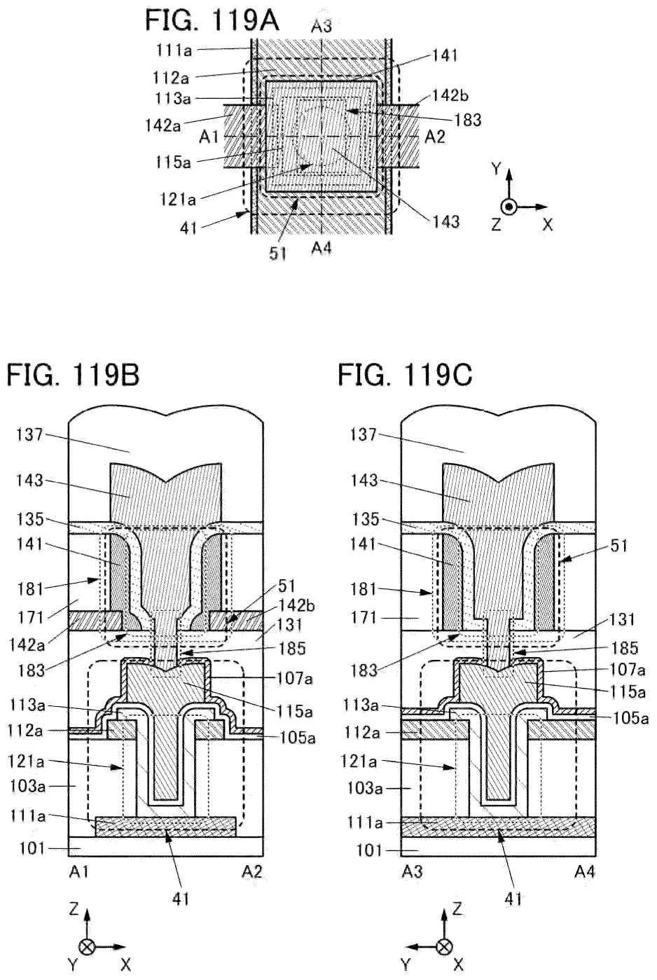

Next, the insulating layer 137 is formed over the insulating layer 135 and the conductive layer 143 (FIGS. 119A to 119C). Any of the above-described insulating materials can be appropriately used for the insulating layer 137. The insulating layer 137 can be formed by appropriately using a deposition method such as a sputtering method, a CVD method, an MBE method, a PLD method, or an ALD method.

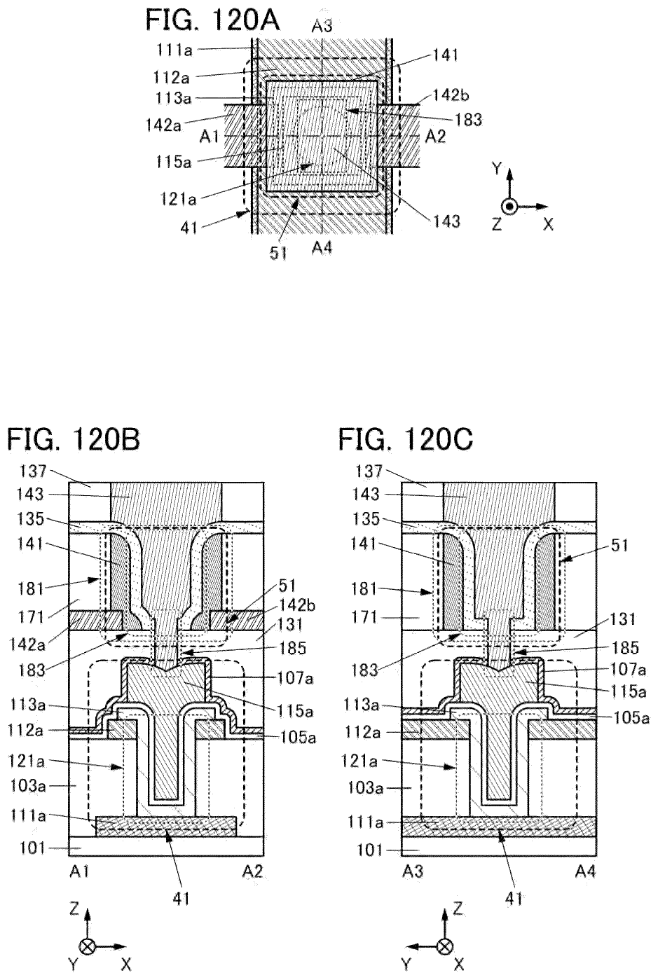

Next, the insulating layer 137 and the conductive layer 143 are subjected to planarization treatment such as CMP treatment until the top surface of the conductive layer 143 is exposed (FIGS. 120A to 120C). FIGS. 120B and 120C illustrate an example in which the top surface of the insulating layer 137 and the top surface of the conductive layer 143 are aligned or substantially aligned. Note that the planarization treatment is not necessarily performed until the entire top surface of the conductive layer 143 becomes aligned with or substantially aligned with the top surface of the insulating layer 137, for example. At least part of the depressed portion formed owing to the opening portion 183 at the time of forming the conductive film 143A may remain in the top surface of the conductive layer 143, and the depressed portion may be filled with the insulating layer 137, for example.

By performing the planarization treatment after the conductive layer 143 and the insulating layer 137 are formed as illustrated in FIG. 118A to FIG. 120C, the insulating layer 135 can be inhibited from being reduced in thickness by the planarization treatment, as compared with the case of performing planarization treatment on the conductive film 143A including a region in contact with the top surface of the insulating layer 135 as, for example, illustrated in FIGS. 116A to 116C. Accordingly, a short circuit between the conductive layer 141 and the conductive layer 111b can be easily prevented, for example. In contrast, in the case of performing planarization treatment on the conductive film 143A including the region in contact with the top surface of the insulating layer 135, formation of a pattern by a lithography method and processing using the pattern are not performed on the conductive film 143A, for example. In addition, formation of the insulating layer 137 is not performed as well. Thus, the manufacturing process of the semiconductor device can be simplified.

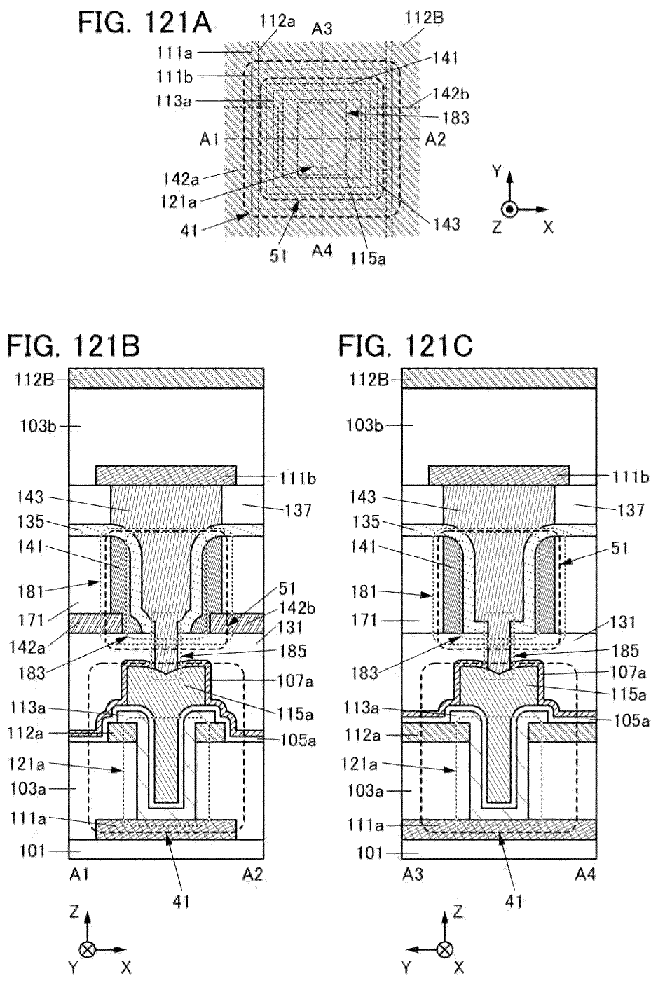

Next, the conductive layer 111b is formed over the conductive layer 143 and the insulating layer 137 (FIGS. 121A to 121C). For example, the conductive layer 111b is formed so as to include a region in contact with the top surface of the conductive layer 143. Thus, the conductive layer 111b and the conductive layer 143 can be electrically connected to each other. Furthermore, as described above, the conductive layer 143 is electrically connected to the conductive layer 115a. Therefore, the conductive layer 115a, the conductive layer 143, and the conductive layer 111b can be electrically connected to one another. The conductive layer 111b can be formed by a method similar to that for the conductive layer 111a.

Next, the insulating layer 103b is formed over the insulating layer 137 and the conductive layer 111b, and the conductive film 112B is formed over the insulating layer 103b (FIGS. 121A to 121C). For the formation of the insulating layer 103b and the conductive film 112B, the description of FIGS. 101A to 101C can be referred to.

Next, the conductive layer 112b, the opening portion 121b, the semiconductor layer 113b, the insulating layer 105b, the conductive layer 115b, and the insulating layer 107b are formed by methods similar to the methods for forming the conductive layer 112a, the opening portion 121a, the semiconductor layer 113a, the insulating layer 105a, the conductive layer 115a, and the insulating layer 107a (FIGS. 45A and 45B). In the above-described manner, the semiconductor device illustrated in FIGS. 45A and 45B including the memory cells 21 in each of which the transistor 41, the transistor 42, and the capacitor 51 are provided can be manufactured.

### <Example 5 of Method for Manufacturing Semiconductor Device>

As the method for manufacturing the semiconductor device of one embodiment of the present invention, an example of a method for manufacturing the semiconductor device illustrated in FIGS. 46A to 46C is described below.

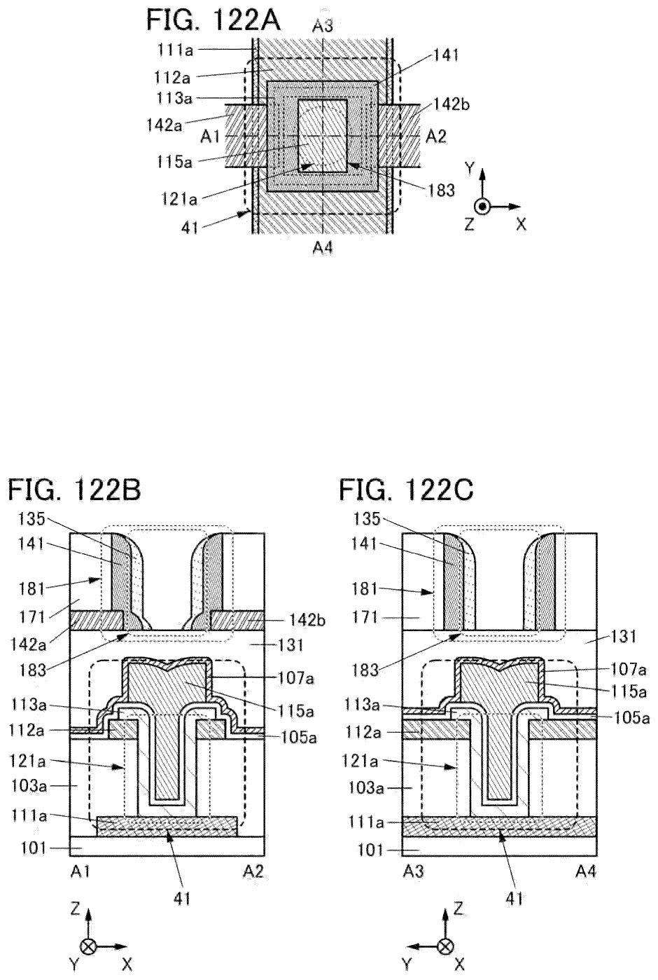

First, steps similar to those illustrated in FIG. 108A to FIG. 113C are performed. Next, the insulating layer 135 is subjected to etch-back treatment, so that the insulating layer 135 can have a shape that is along the side surface of the conductive layer 141 in the opening portion 183 (FIGS. 122A to 122C). Furthermore, the insulating layer 135 can have a shape that is along the curved portion of the conductive layer 141 as well as the side surface of the conductive layer 141.

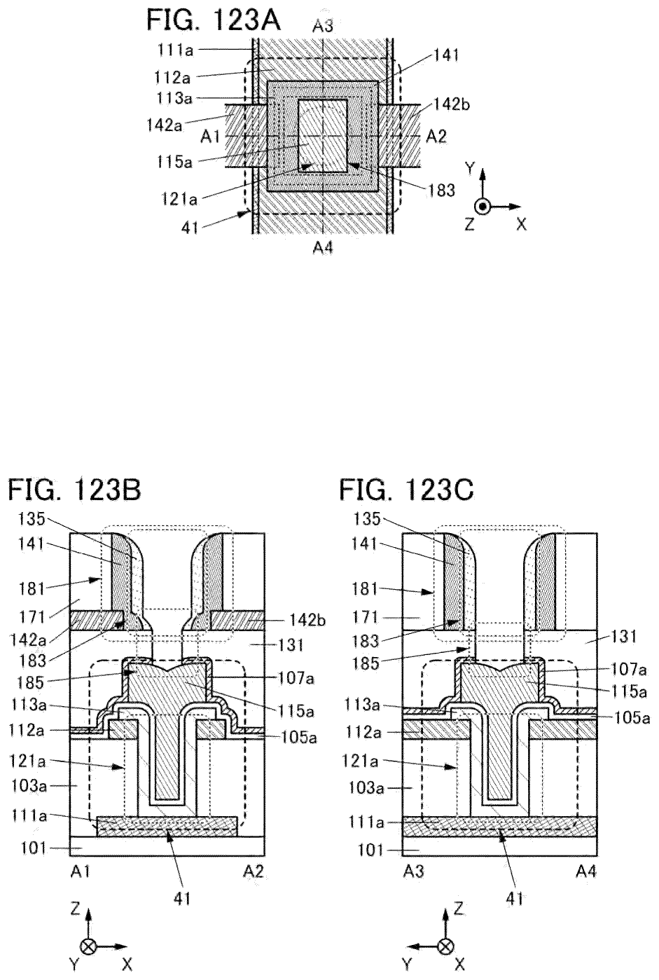

Next, the opening portion 185 is formed by processing part of the insulating layer 131 and part of the insulating layer 107a (FIGS. 123A to 123C). For the formation of the opening portion 185, the description of FIGS. 114A to 114C can be referred to. Here, part of the insulating layer 131 is preferably processed under conditions where the etching selectivity of the insulating layer 131 to the insulating layer 135 is high, that is, conditions where the insulating layer 131 is easily etched and the insulating layer 135 is not easily etched. Accordingly, the insulating layer 135 can be inhibited from being reduced in thickness while reduction in the diameter of the opening portion 185 is inhibited.

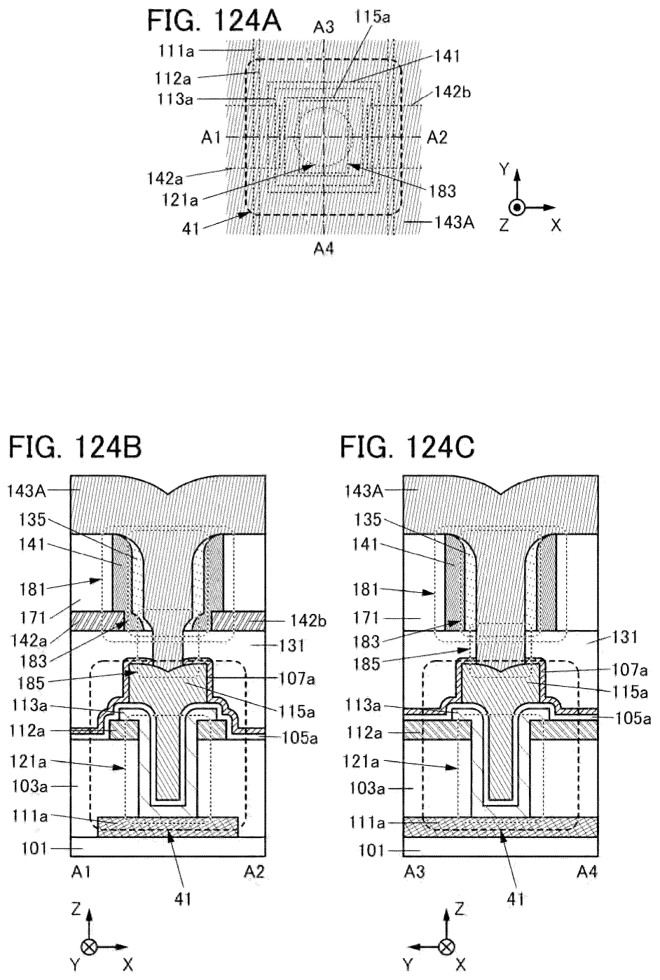

Next, the conductive film 143A is formed so as to fill the opening portion 185 and cover the insulating layer 135, the conductive layer 141, and the insulating layer 171 (FIGS. 124A to 124C). For the formation of the conductive film 143A, the description of FIGS. 115A to 115C can be referred to.

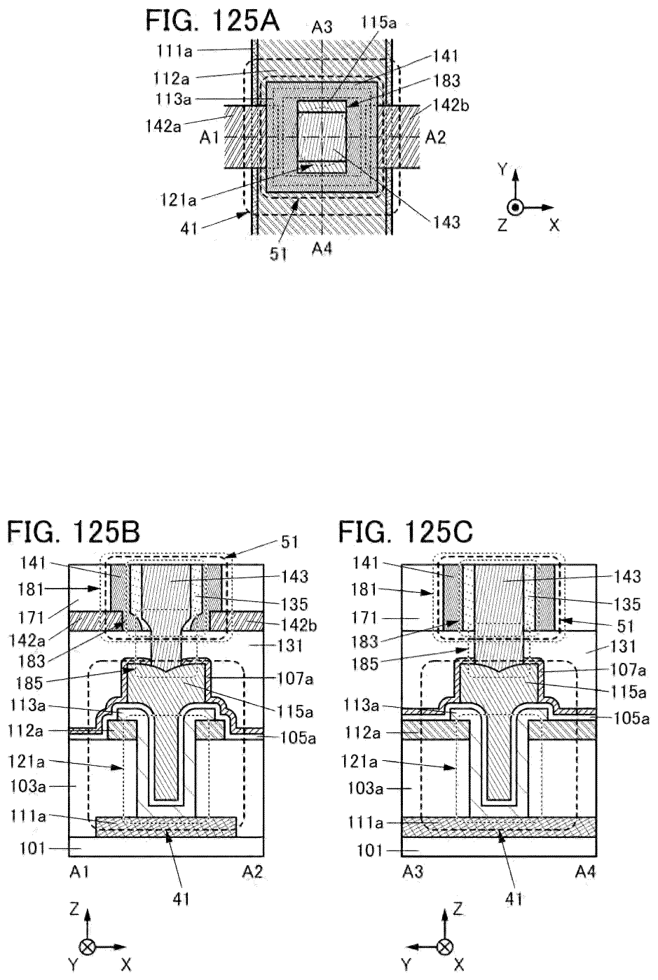

Next, the conductive film 143A, the insulating layer 135, the conductive layer 141, and the insulating layer 171 are subjected to planarization treatment such as CMP treatment. Thus, the conductive layer 143 can be formed so as to include a region positioned inside the opening portion 183 and a region positioned inside the opening portion 185 and so as not to be in contact with the conductive layer 141 (FIGS. 125A to 125C). Although the planarization treatment is performed until the curved portion between the top and side surfaces of the insulating layer 135 and the curved portion between the top and side surfaces of the conductive layer 141 are completely removed in the example illustrated in FIGS. 125B and 125C, part of the curved portion of the insulating layer 135 and part of the curved portion of the conductive layer 141 may be left, for example.

In the above-described manner, the capacitor 51 including the conductive layer 141, the insulating layer 135, and the conductive layer 143 can be formed.

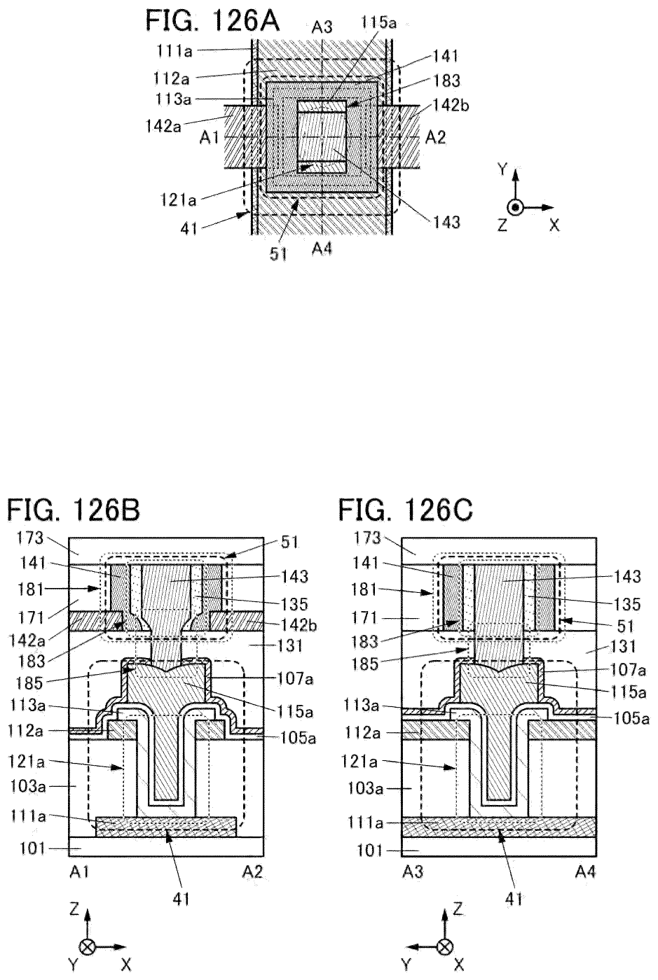

Next, the insulating layer 173 is formed over the conductive layer 141, the conductive layer 143, the insulating layer 135, and the insulating layer 171 (FIGS. 126A to 126C). The insulating layer 173 can be formed by a method similar to that for the insulating layer 131.

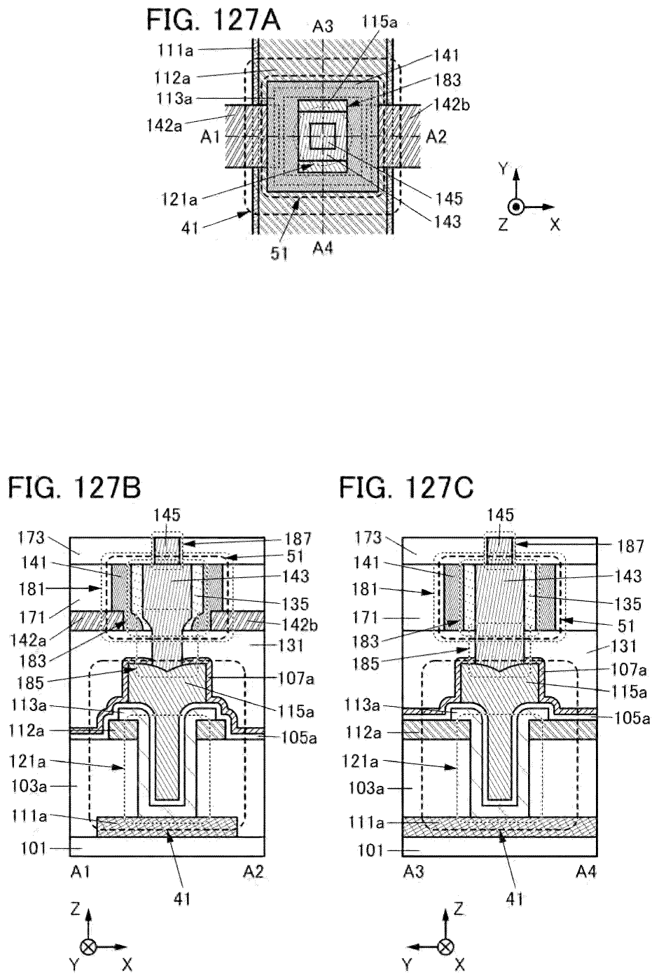

Next, part of the insulating layer 173 is processed, so that the opening portion 187 reaching the conductive layer 143 is formed (FIGS. 127A to 127C). Although the processing can be performed, for example, by a dry etching method or a wet etching method, processing by a dry etching method is preferable because it is suitable for microfabrication.

Next, the conductive layer 145 is formed inside the opening portion 187 (FIGS. 127A to 127C). For example, a conductive film to be the conductive layer 145 is formed so as to fill the opening portion 187, and the conductive film is subjected to planarization treatment such as CMP treatment until the top surface of the insulating layer 173 is exposed, whereby the conductive layer 145 is formed inside the opening portion 187. When the conductive layer 145 is formed inside the opening portion 187 reaching the conductive layer 143, the conductive layer 145 and the conductive layer 143 can be electrically connected to each other. For the conductive film to be the conductive layer 145, any of the above-described conductive materials that can be used for the conductive layer 145 can be appropriately used. The conductive film to be the conductive layer 145 can be formed by appropriately using a deposition method such as a sputtering method, a CVD method, an MBE method, a PLD method, or an ALD method.

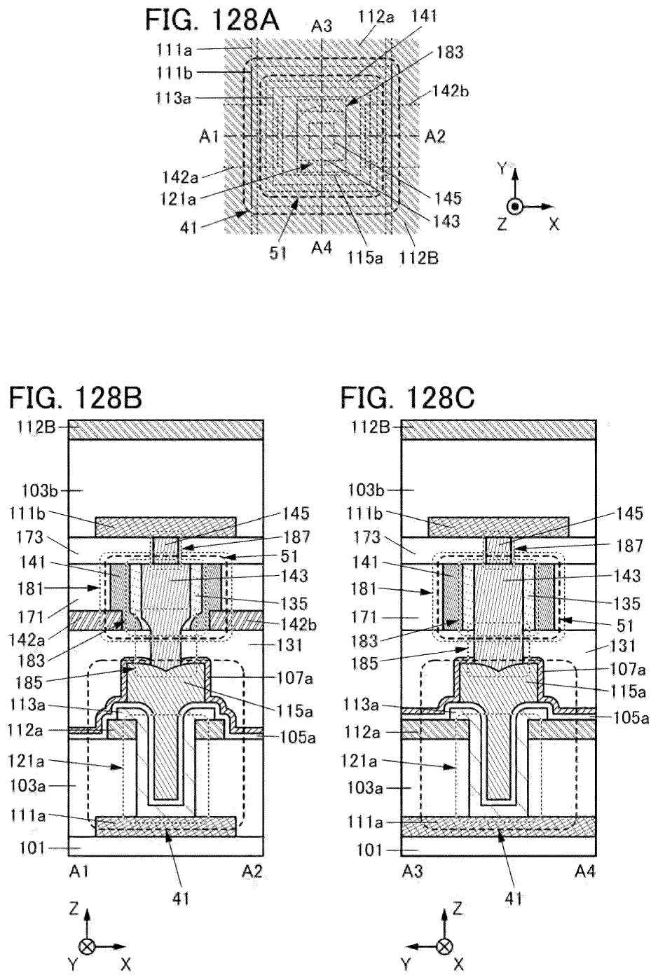

Next, the conductive layer 111b is formed over the conductive layer 145 and the insulating layer 173 (FIGS. 128A to 128C). For example, the conductive layer 111b is formed so as to include a region in contact with the top surface of the conductive layer 145. Thus, the conductive layer 111b and the conductive layer 145 can be electrically connected to each other. Furthermore, as described above, the conductive layer 145 can be electrically connected to the conductive layer 143, and the conductive layer 143 can be electrically connected to the conductive layer 115a. Therefore, the conductive layer 115a, the conductive layer 143, and the conductive layer 111b can be electrically connected to one another. The conductive layer 111b can be formed by a method similar to that for the conductive layer 111a.

Next, the insulating layer 103b is formed over the insulating layer 173 and the conductive layer 111b, and the conductive film 112B is formed over the insulating layer 103b (FIGS. 128A to 128C). For the formation of the insulating layer 103b and the conductive film 112B, the description of FIGS. 101A to 101C can be referred to.

Next, the conductive layer 112b, the opening portion 121b, the semiconductor layer 113b, the insulating layer 105b, the conductive layer 115b, and the insulating layer 107b are formed by methods similar to the methods for forming the conductive layer 112a, the opening portion 121a, the semiconductor layer 113a, the insulating layer 105a, the conductive layer 115a, and the insulating layer 107a (FIGS. 46A to 46C). In the above-described manner, the semiconductor device illustrated in FIGS. 46A to 46C including the memory cells 21 in each of which the transistor 41, the transistor 42, and the capacitor 51 are provided can be manufactured.

### <Example 6 of Method for Manufacturing Semiconductor Device>

As the method for manufacturing the semiconductor device of one embodiment of the present invention, an example of a method for manufacturing the semiconductor device illustrated in FIGS. 56A to 56C is described below.

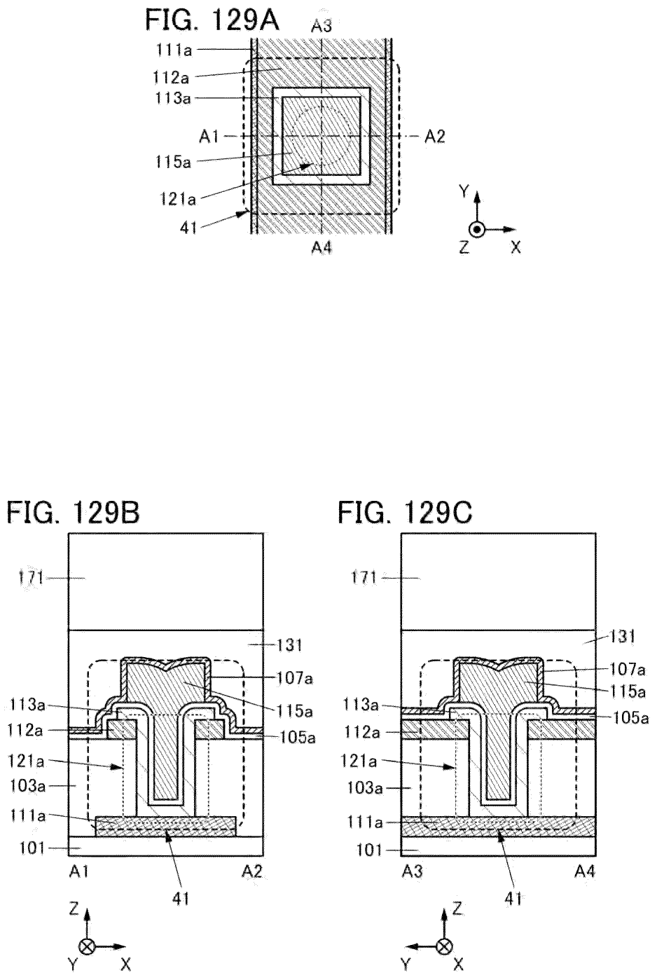

First, steps similar to those illustrated in FIG. 83A to FIG. 90C are performed. Next, the insulating layer 171 is formed over the insulating layer 131 (FIGS. 129A to 129C). For the formation of the insulating layer 171, the description of FIGS. 109A to 109C can be referred to.

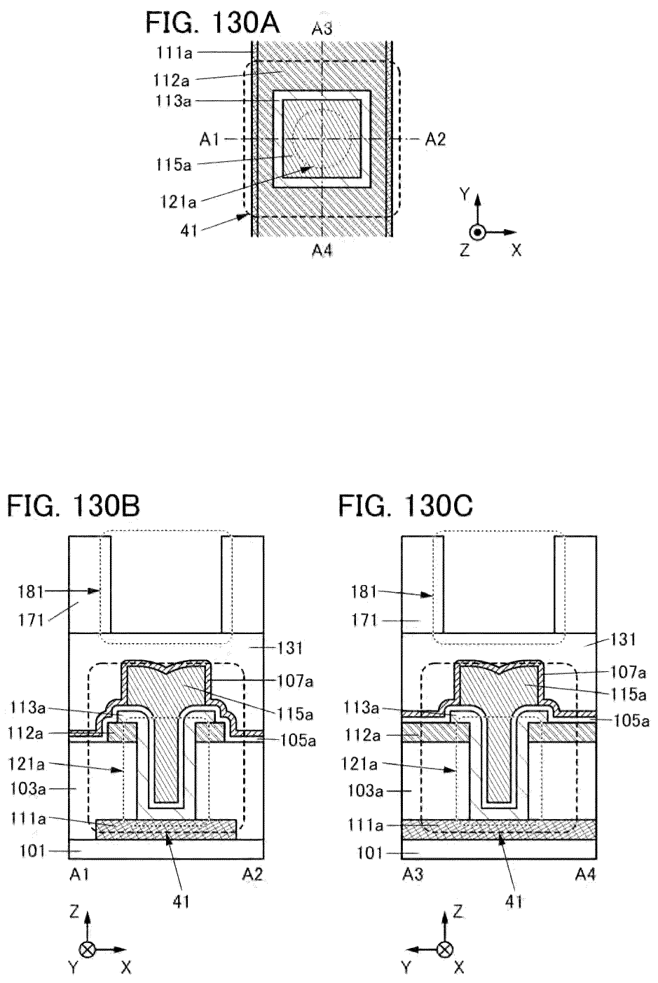

Next, part of the insulating layer 171 is processed, so that the opening portion 181 reaching the insulating layer 131 is formed so as to include a region overlapping with the conductive layer 115a (FIGS. 130A to 130C). For the formation of the opening portion 181, the description of FIGS. 110A to 110C can be referred to.

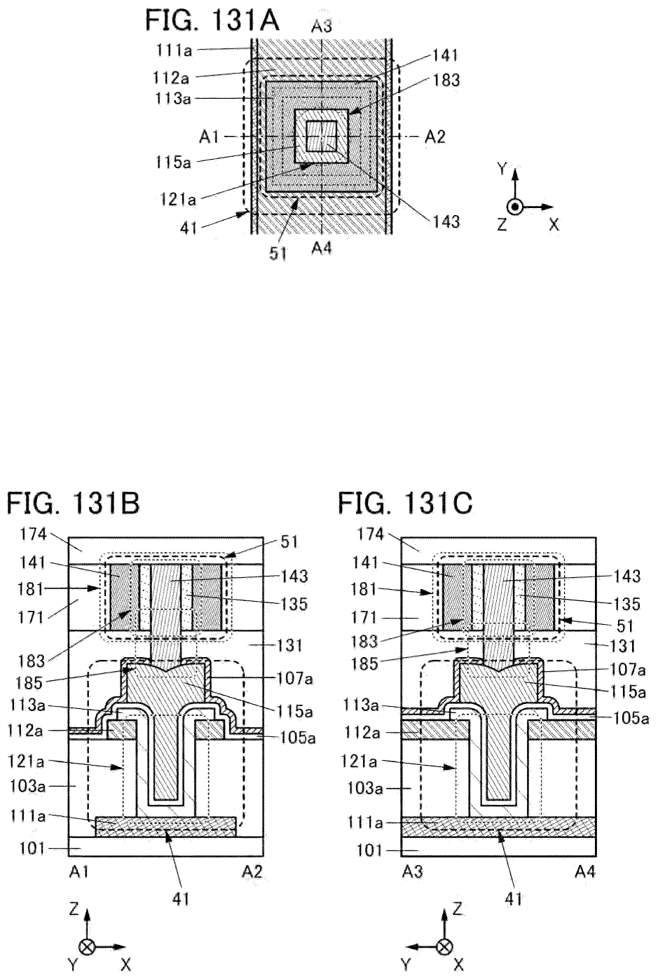

Next, steps similar to those illustrated in FIG. 111A to FIG. 113C and FIG. 122A to FIG. 125C are performed. Then, the insulating layer 174 is formed over the conductive layer 141, the conductive layer 143, the insulating layer 135, and the insulating layer 171 (FIGS. 131A to 131C). The insulating layer 174 can be formed by a method similar to that for the insulating layer 173 illustrated in FIGS. 126A to 126C.

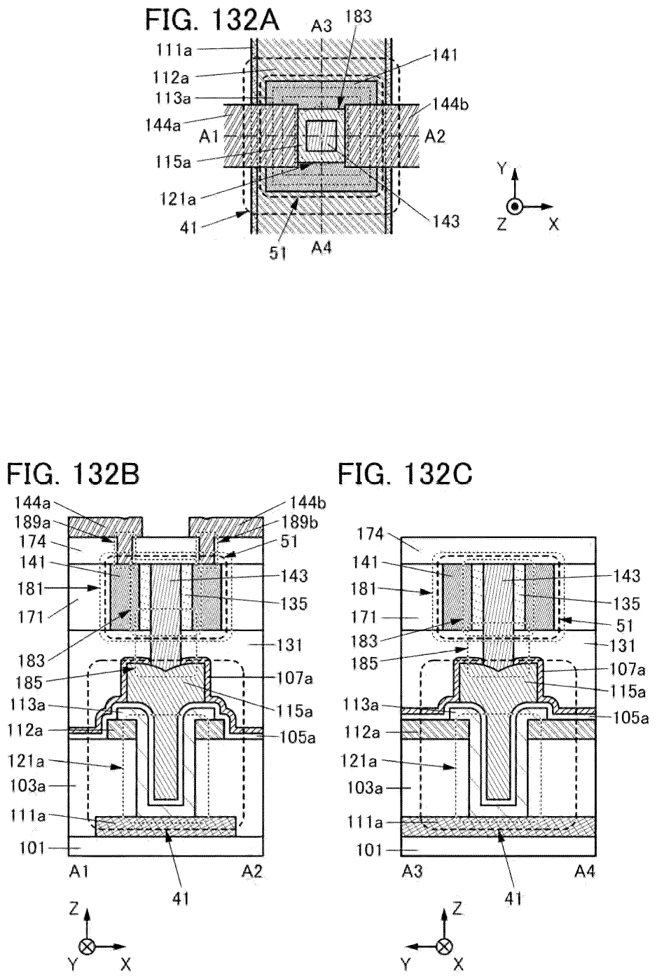

Next, part of the insulating layer 174 is processed, so that the opening portions 189a and 189b reaching the conductive layer 141 are formed (FIGS. 132A to 132C). Although the processing can be performed, for example, by a dry etching method or a wet etching method, processing by a dry etching method is preferable because it is suitable for microfabrication.

Next, the conductive layer 144a is formed over the conductive layer 141 and the insulating layer 174 so as to include a region positioned inside the opening portion 189a. Furthermore, the conductive layer 144b is formed over the conductive layer 141 and the insulating layer 174 so as to include a region positioned inside the opening portion 189b (FIGS. 132A to 132C). For example, the conductive layer 144a and the conductive layer 144b can be formed by forming and processing a conductive film to be the conductive layer 144a and the conductive layer 144b. For the conductive film to be the conductive layer 144a and the conductive layer 144b, any of the above-described conductive materials that can be used for the conductive layer 144a and the conductive layer 144b can be appropriately used.

The conductive film to be the conductive layers 144a and 144b can be formed by appropriately using a deposition method such as a sputtering method, a CVD method, an MBE method, a PLD method, or an ALD method. After the conductive film to be the conductive layers 144a and 144b is formed, formation of a pattern is performed by a lithography method, and the conductive film is processed by a dry etching method, a wet etching method, or the like using the pattern, whereby the conductive layers 144a and 144b can be formed. Here, for microfabrication, the conductive film is preferably processed by a dry etching method.

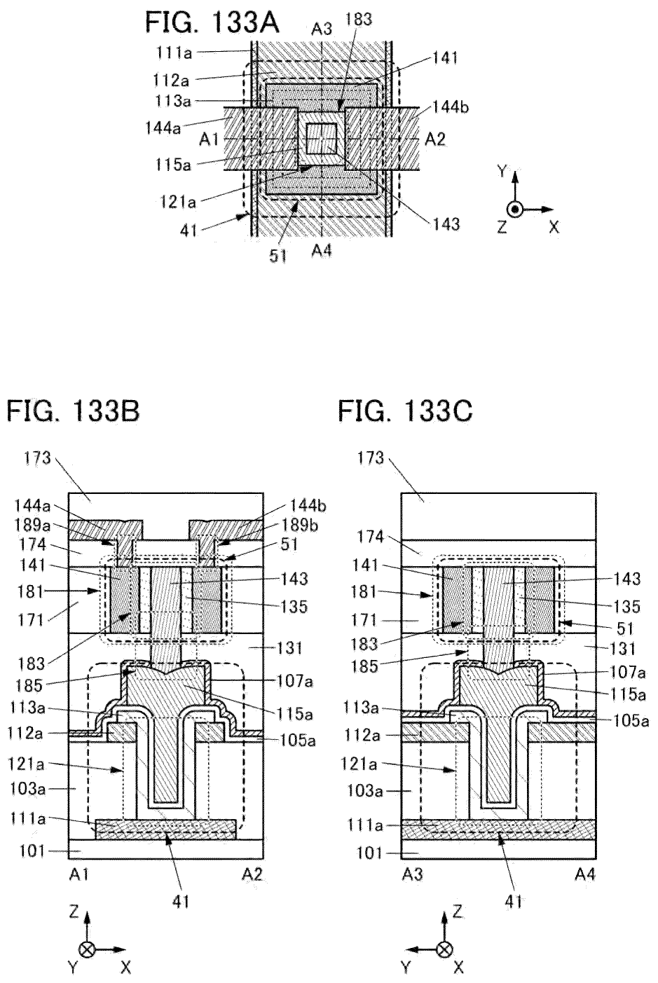

Next, the insulating layer 173 is formed over the insulating layer 174, the conductive layer 144a, and the conductive layer 144b (FIGS. 133A to 133C). For the formation of the insulating layer 173, the description of FIGS. 126A to 126C can be referred to.

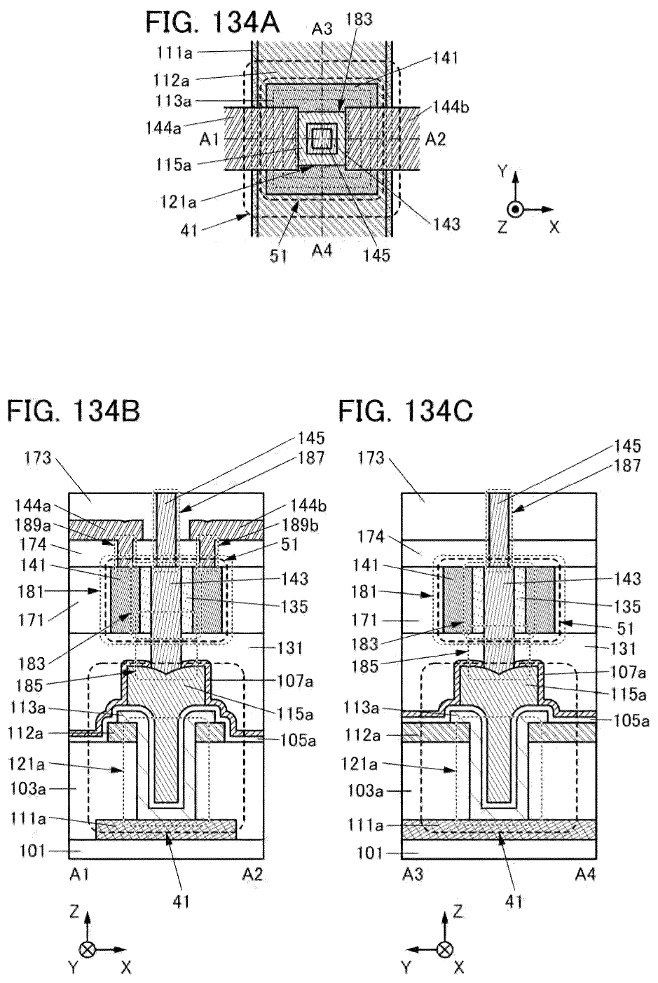

Next, part of the insulating layer 173 and part of the insulating layer 174 are processed to form the opening portion 187 reaching the conductive layer 143. Then, the conductive layer 145 is formed inside the opening portion 187 (FIGS. 134A to 134C). For the formation of the opening portion 187 and the conductive layer 145, the description of FIGS. 127A to 127C can be referred to.

Next, the step illustrated in FIGS. 128A to 128C and the subsequent steps are performed. In the above-described manner, the semiconductor device illustrated in FIGS. 56A to 56C including the memory cells 21 in each of which the transistor 41, the transistor 42, and the capacitor 51 are provided can be manufactured.

### <Example 7 of Method for Manufacturing Semiconductor Device>

As the method for manufacturing the semiconductor device of one embodiment of the present invention, an example of a method for manufacturing the semiconductor device illustrated in FIGS. 57A to 57C is described below.

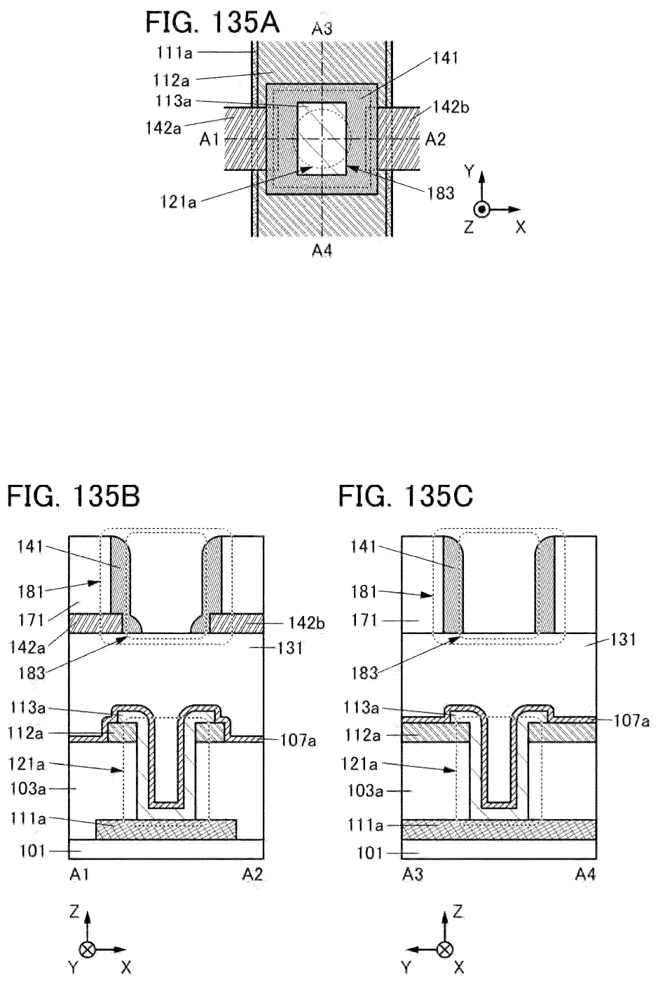

First, the steps of forming the components from the insulating layer 101 to the insulating layer 131 illustrated in FIGS. 102A to 102C are performed. Next, steps similar to those illustrated in FIG. 108A to FIG. 112C are performed, so that the conductive layer 142a, the conductive layer 142b, the insulating layer 171, and the conductive layer 141 are formed (FIGS. 135A to 135C).

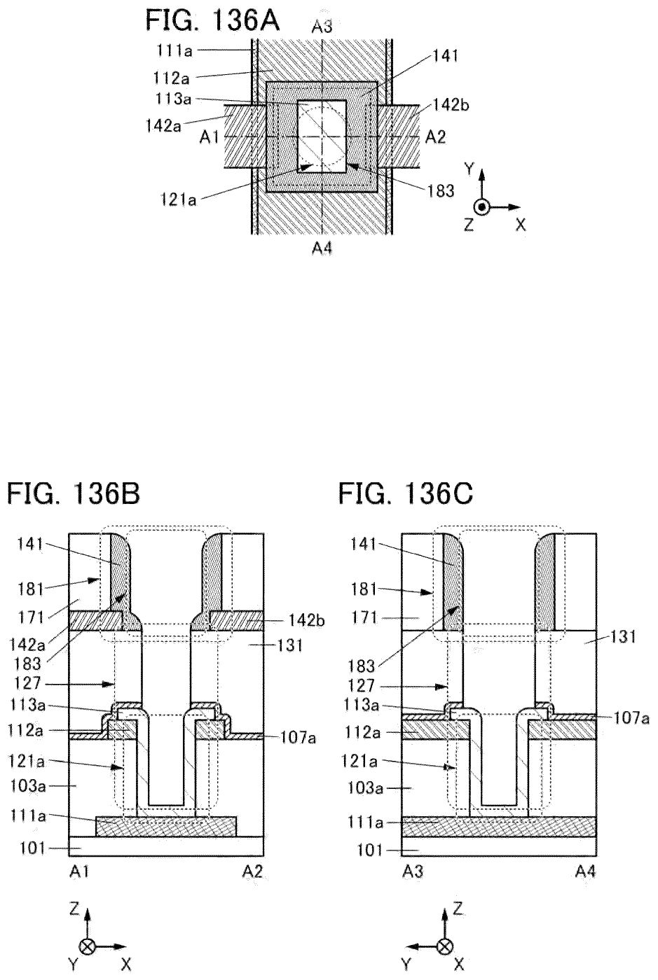

Next, part of the insulating layer 131 and part of the insulating layer 107a are processed, so that the opening portion 127 reaching the semiconductor layer 113a is formed so as to include a region overlapping with the opening portion 183 (FIGS. 136A to 136C). For the formation of the opening portion 127, the description of FIGS. 103A to 103C can be referred to.

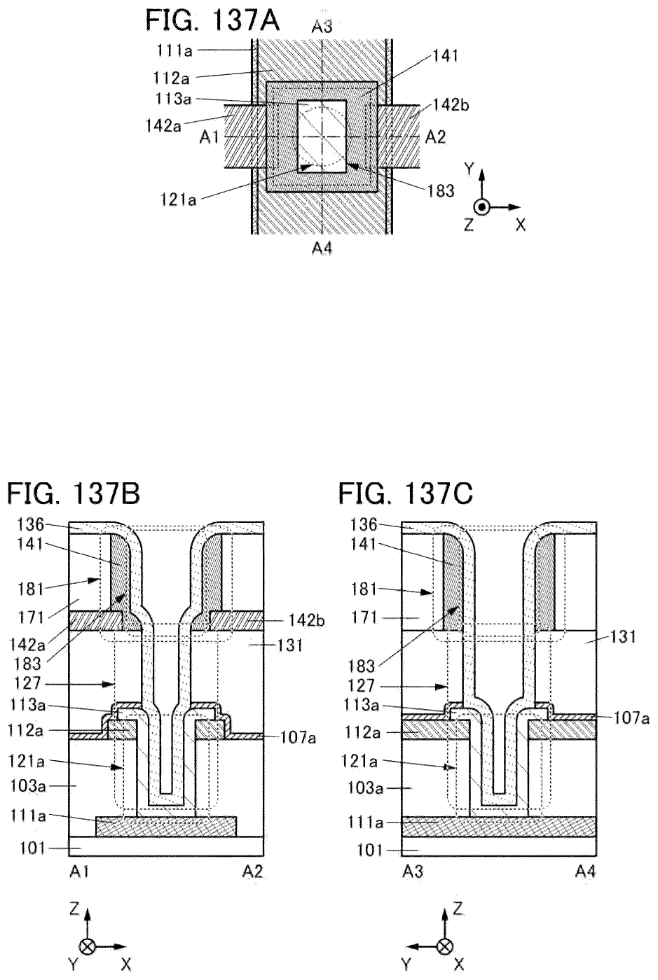

Next, the insulating layer 136 is formed over the semiconductor layer 113a, the conductive layer 141, and the insulating layer 171 (FIGS. 137A to 137C). For the formation of the insulating layer 136, the description of FIGS. 105A to 105C can be referred to.

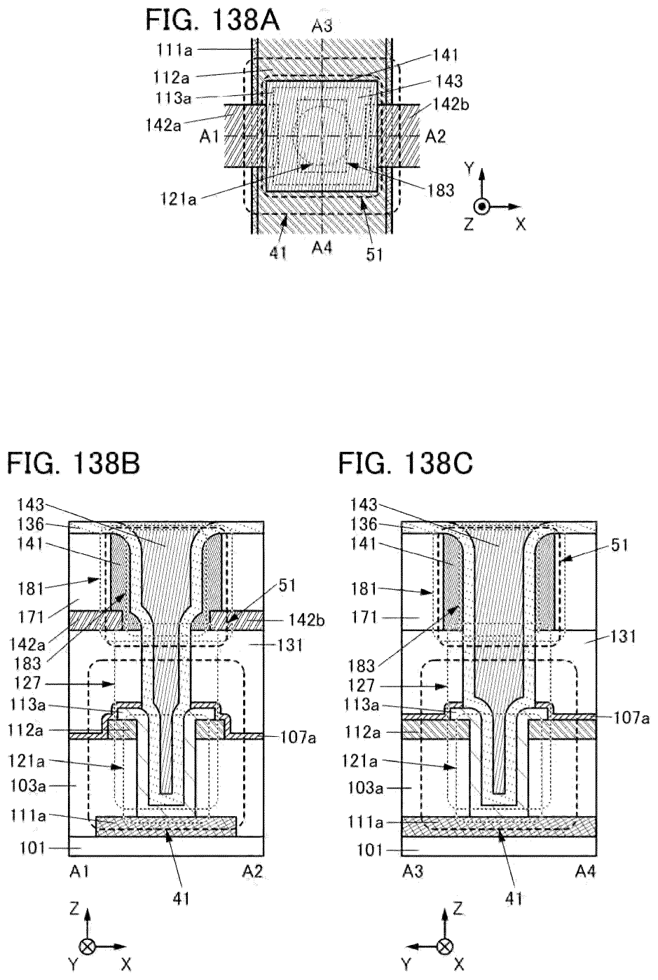

Next, the conductive layer 143 is formed so as to cover the insulating layer 136 inside the opening portion 127 and the opening portion 183 (FIGS. 138A to 138C). For the formation of the conductive layer 143, the description of FIG. 115A to FIG. 116C can be referred to.

Next, the step illustrated in FIGS. 117A to 117C and the subsequent steps are performed. In the above-described manner, the semiconductor device illustrated in FIGS. 57A to 57C including the memory cells 21 in each of which the transistor 41, the transistor 42, and the capacitor 51 are provided can be manufactured.

### <Example 8 of Method for Manufacturing Semiconductor Device>

As the method for manufacturing the semiconductor device of one embodiment of the present invention, an example of a method for manufacturing the semiconductor device illustrated in FIGS. 58A to 58C is described below.

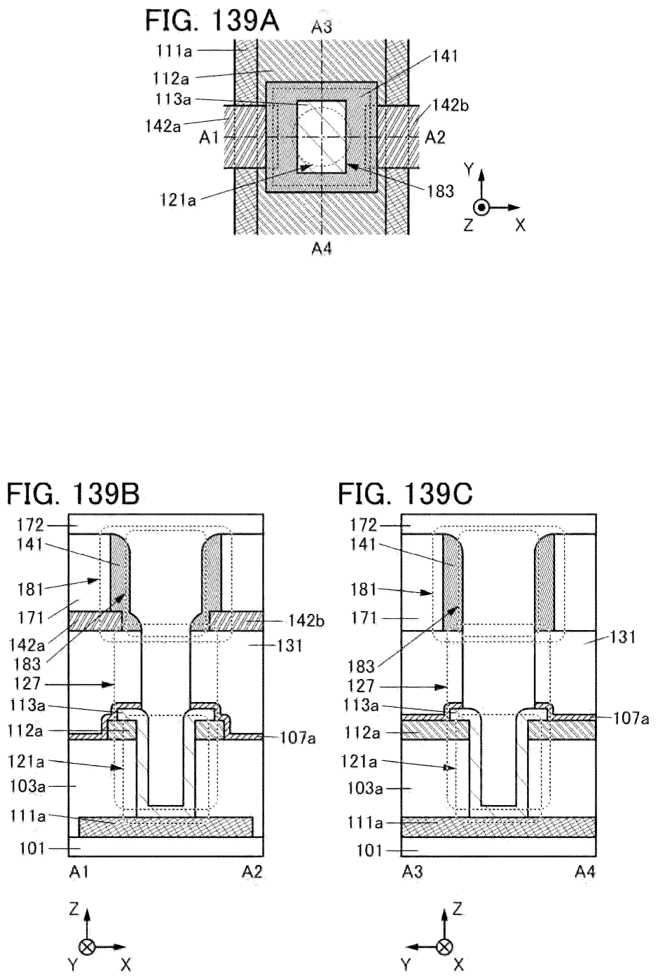

First, steps similar to those illustrated in FIG. 135A to FIG. 136C are performed. Next, the insulating layer 172 is formed so as to fill the opening portion 127 and the opening portion 183 and include a region positioned over the insulating layer 171 (FIGS. 139A to 139C). Any of the above-described insulating materials can be appropriately used for the insulating layer 172. The insulating layer 172 can be formed by appropriately using a deposition method such as a sputtering method, a CVD method, an MBE method, a PLD method, or an ALD method. The top surface of the deposited insulating layer 172 is preferably planarized by CMP treatment. Note that the CMP treatment is unnecessary in some cases. In such a case, the top surface of the insulating layer 172 has a convex shape. By not performing planarization treatment, manufacturing cost can be reduced and production yield can be increased.

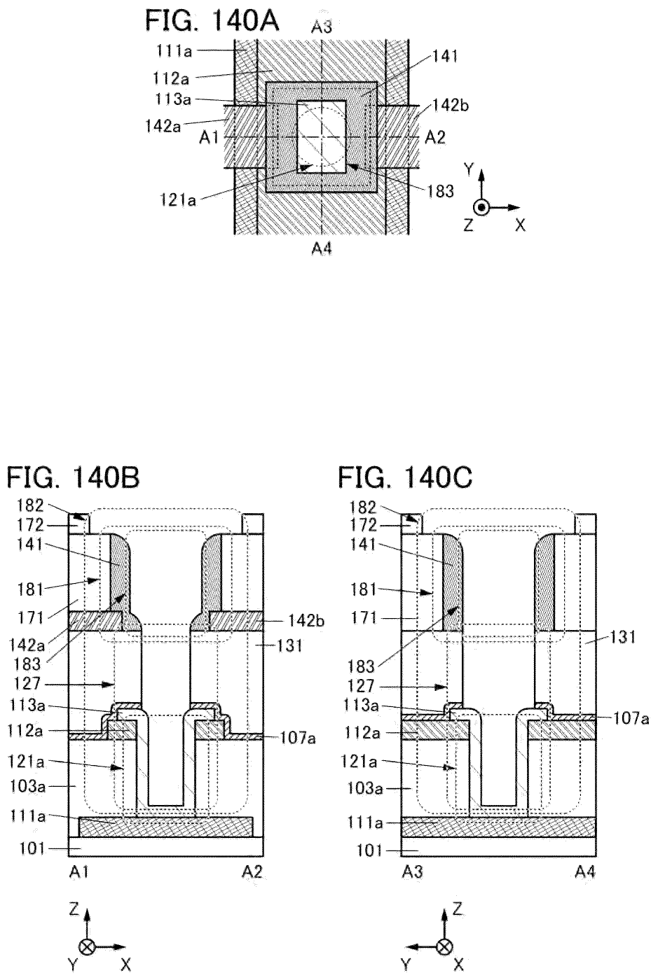

Next, the opening portion 182 reaching the insulating layer 171, the conductive layer 141, and the semiconductor layer 113a is formed in the insulating layer 172 so as to include a region overlapping with the opening portion 183 and the opening portion 127 (FIGS. 140A to 140C). The opening portion 182 can be formed by, for example, forming a pattern by a lithography method and processing the insulating layer 172 by an etching method using the pattern. Since the opening portion 182 formed in the insulating layer 172 has a high aspect ratio here, the insulating layer 172 is preferably processed by anisotropic etching. It is particularly preferable to use a dry etching method because it is suitable for microfabrication.

Here, part of the insulating layer 172 is preferably processed under conditions where the etching selectivity of the insulating layer 172 to the insulating layer 171 is high, that is, conditions where the insulating layer 172 is easily etched and the insulating layer 171 is not easily etched. Accordingly, formation of a depressed portion in the insulating layer 171 by unintentional processing of the insulating layer 171 at the time of processing the insulating layer 172 can be inhibited.

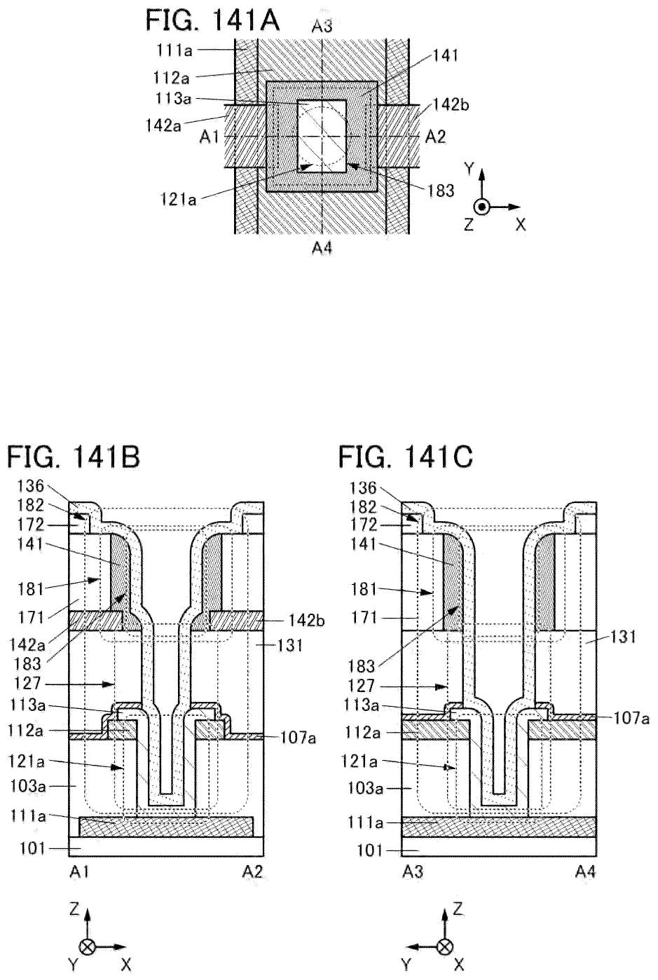

Next, the insulating layer 136 is formed over the semiconductor layer 113a, the conductive layer 141, the insulating layer 171, and the insulating layer 172 (FIGS. 141A to 141C). For the formation of the insulating layer 136, the description of FIGS. 105A to 105C can be referred to.

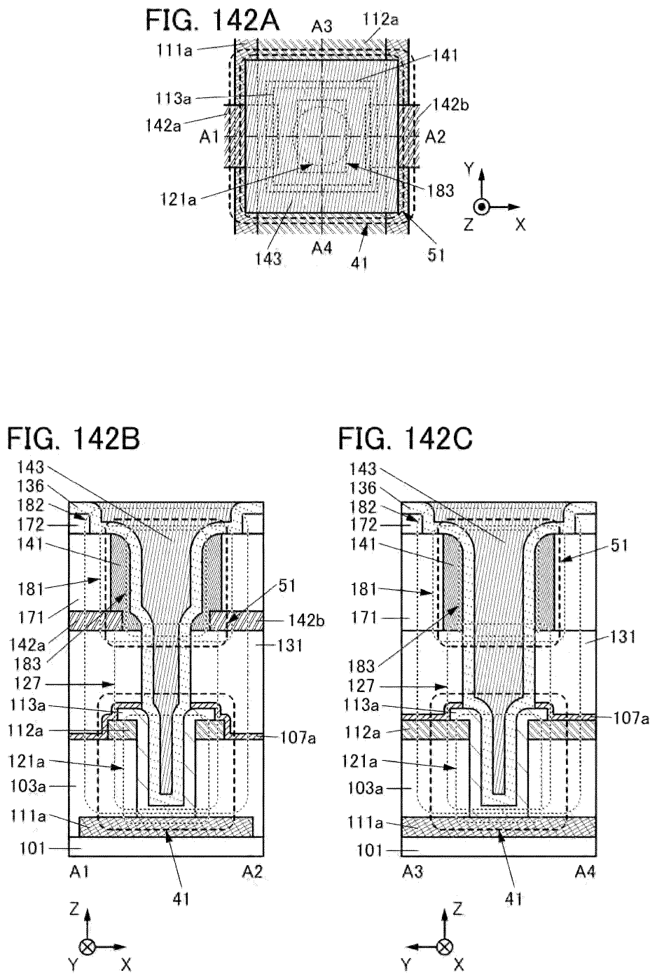

Next, the conductive layer 143 is formed so as to cover the insulating layer 136 inside the opening portion 182 (FIGS. 142A to 142C). For the formation of the conductive layer 143, the description of FIG. 115A to FIG. 116C can be referred to.

Next, the step illustrated in FIGS. 117A to 117C and the subsequent steps are performed. In the above-described manner, the semiconductor device illustrated in FIGS. 58A to 58C including the memory cells 21 in each of which the transistor 41, the transistor 42, and the capacitor 51 are provided can be manufactured.

### <Example 9 of Method for Manufacturing Semiconductor Device>

As the method for manufacturing the semiconductor device of one embodiment of the present invention, an example of a method for manufacturing the semiconductor device illustrated in FIGS. 59A to 59C is described below.

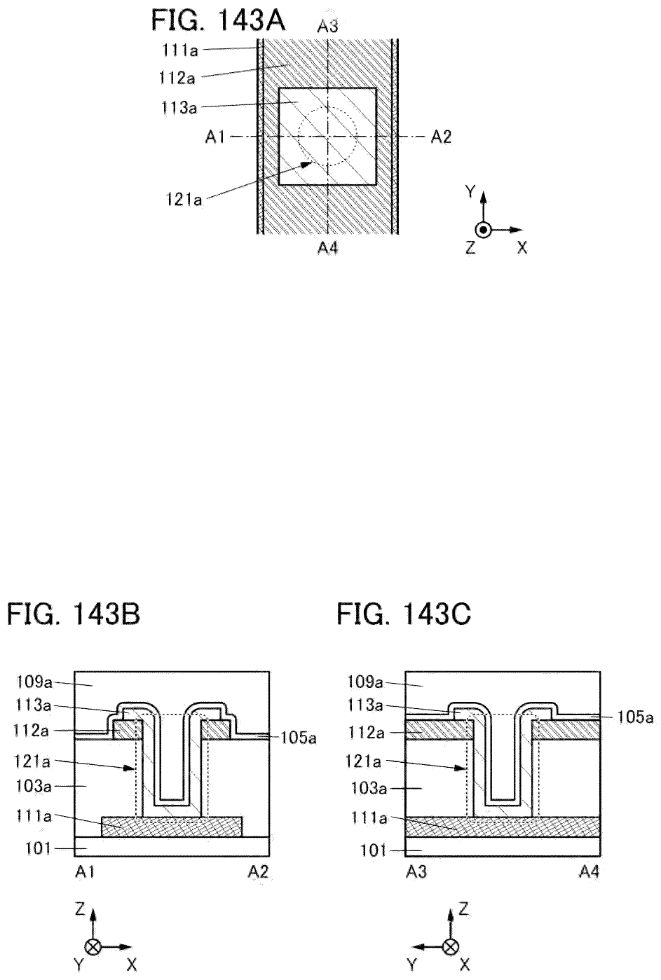

First, the steps of forming the components from the insulating layer 101 to the insulating layer 105a illustrated in FIG. 83A to FIG. 88C are performed. Next, the insulating layer 109a is formed over the insulating layer 105a (FIGS. 143A to 143C). The insulating layer 109a can be formed by appropriately using a deposition method such as a sputtering method, a CVD method, an MBE method, a PLD method, or an ALD method. The top surface of the deposited insulating layer 109a is preferably planarized by CMP treatment. Note that the CMP treatment is unnecessary in some cases. In such a case, the top surface of the insulating layer 109a has a convex shape. By not performing planarization treatment, manufacturing cost can be reduced and production yield can be increased.

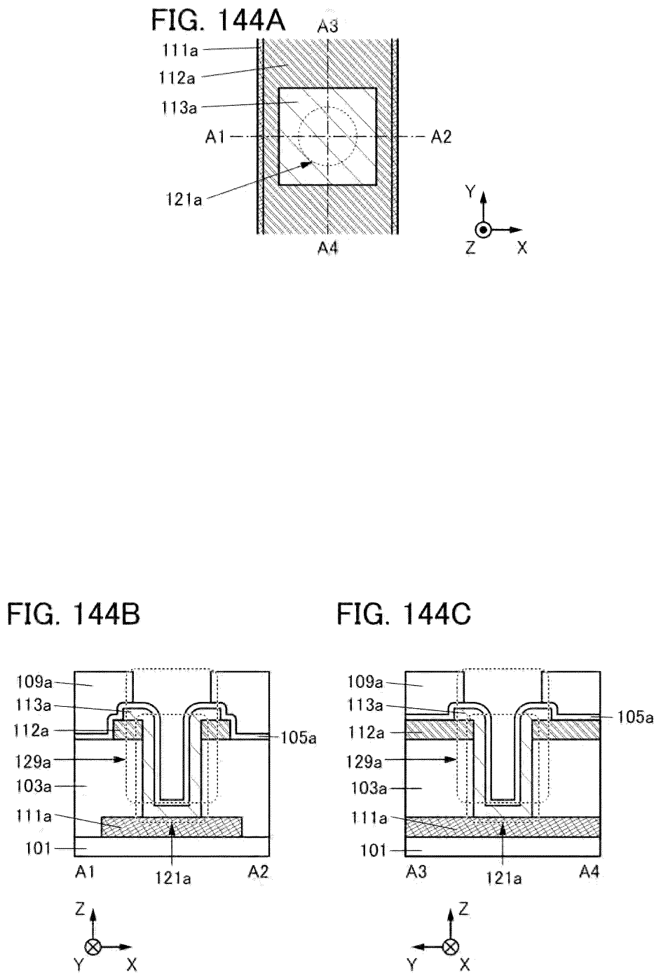

Next, part of the insulating layer 109a is processed, so that the opening portion 129a reaching the insulating layer 105a is formed so as to include a region overlapping with the opening portion 121a (FIGS. 144A to 144C). The opening portion 129a can be formed by a method similar to the method that can be used for forming the opening portion 121a.

In the formation of the opening portion 129a here, part of the insulating layer 109a is preferably processed under conditions where the etching selectivity of the insulating layer 109a to the insulating layer 105a is high, that is, conditions where the insulating layer 109a is easily etched and the insulating layer 105a is not easily etched. Accordingly, the insulating layer 105a can be inhibited from being processed unintentionally and reduced in thickness at the time of forming the opening portion 129a. Thus, a short circuit between the semiconductor layer 113a and the conductive layer 115a can be inhibited, for example. Note that the conductive layer 115a is formed in a later step.

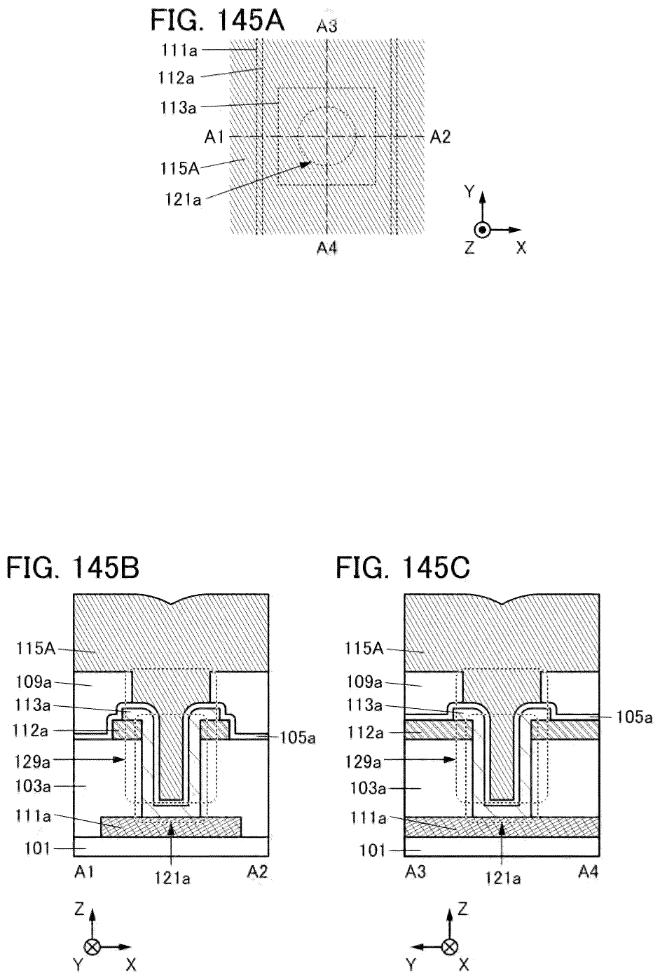

Next, the conductive film 115A is formed so as to fill the opening portion 129a (FIGS. 145A to 145C). For the formation of the conductive film 115A, the description of FIGS. 88A to 88C can be referred to.

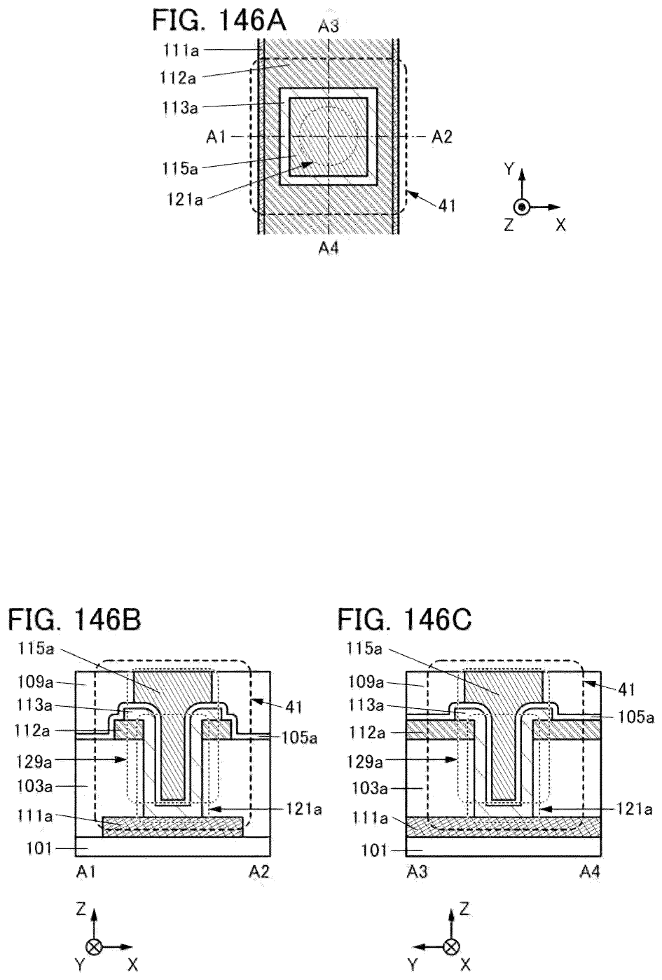

Next, the conductive film 115A is subjected to planarization treatment such as CMP treatment. For example, the planarization treatment is performed on the conductive film 115A until the top surface of the insulating layer 109a is exposed. Thus, the conductive film 115A over the insulating layer 109a is removed, and the conductive layer 115a is formed inside the opening portion 129a (FIGS. 146A to 146C). By the above-described CMP treatment, the insulating layer 109a is reduced in thickness, in some cases. The conductive layer 115a may include a region positioned over the insulating layer 109a. Furthermore, part of the conductive film 115A may remain over the insulating layer 109a.

In the above-described manner, the transistor 41 including the conductive layer 111a, the conductive layer 112a, the semiconductor layer 113a, the insulating layer 105a, and the conductive layer 115a can be formed. As described above, the conductive layer 111a functions as the one of the source electrode and the drain electrode of the transistor 41, the conductive layer 112a functions as the other of the source electrode and the drain electrode of the transistor 41, the insulating layer 105a functions as the gate insulating layer of the transistor 41, and the conductive layer 115a functions as the gate electrode of the transistor 41.

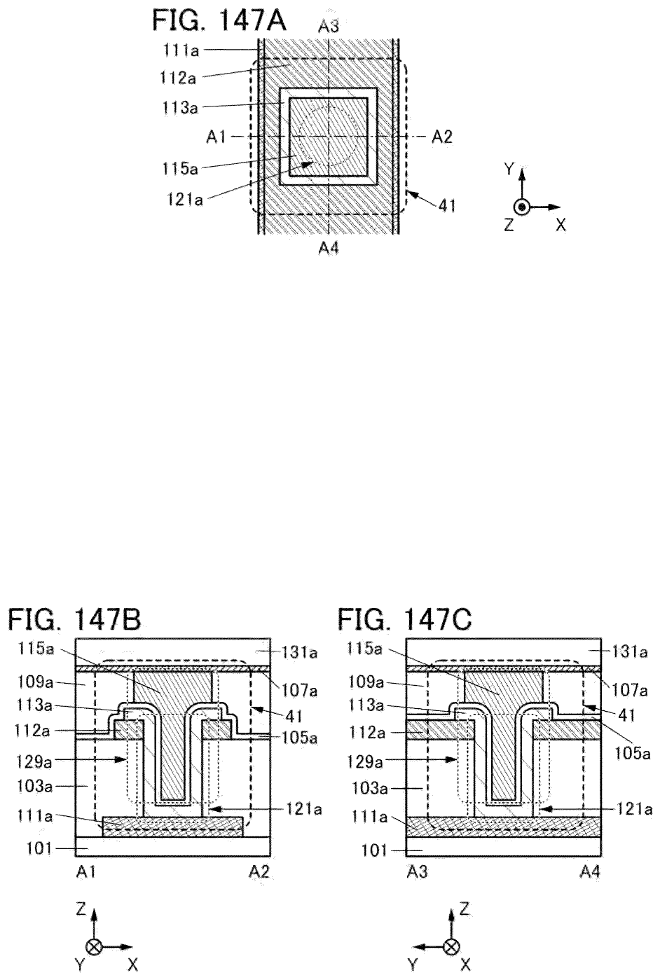

Next, the insulating layer 107a is formed over the conductive layer 115a and the insulating layer 109a, and the insulating layer 131a is formed over the insulating layer 107a (FIGS. 147A to 147C). For the formation of the insulating layer 107a and the insulating layer 131a, the description of FIGS. 90A to 90C can be referred to by reading the insulating layer 131 as the insulating layer 131a.

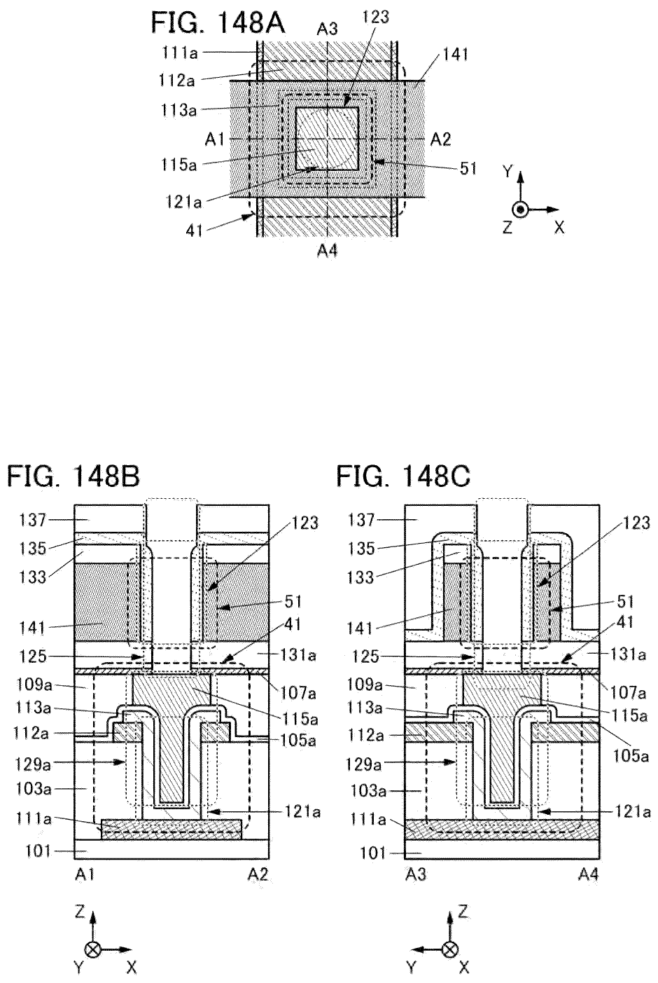

Next, steps similar to those illustrated in FIG. 91A to FIG. 96C are performed (FIGS. 148A to 148C). Here, at the time of forming the opening portion 125, the depressed portion 163 as illustrated in FIG. 60B might be formed in the conductive layer 115a.

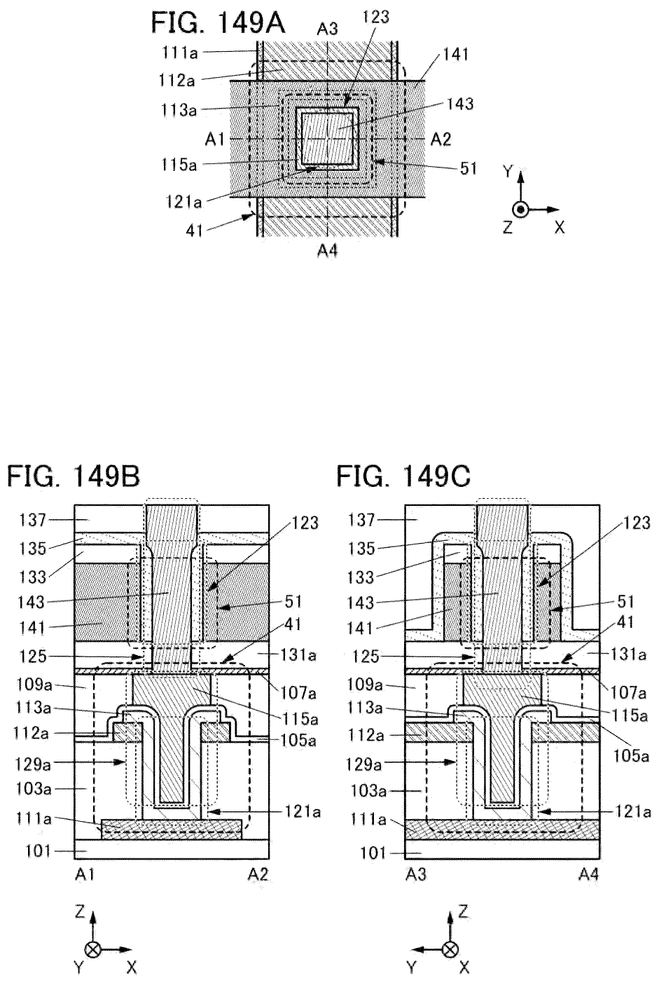

Next, steps similar to those illustrated in FIG. 97A to FIG. 98C are performed (FIGS. 149A to 149C). In the above-described manner, the capacitor 51 including the conductive layer 141, the insulating layer 135, and the conductive layer 143 can be formed.

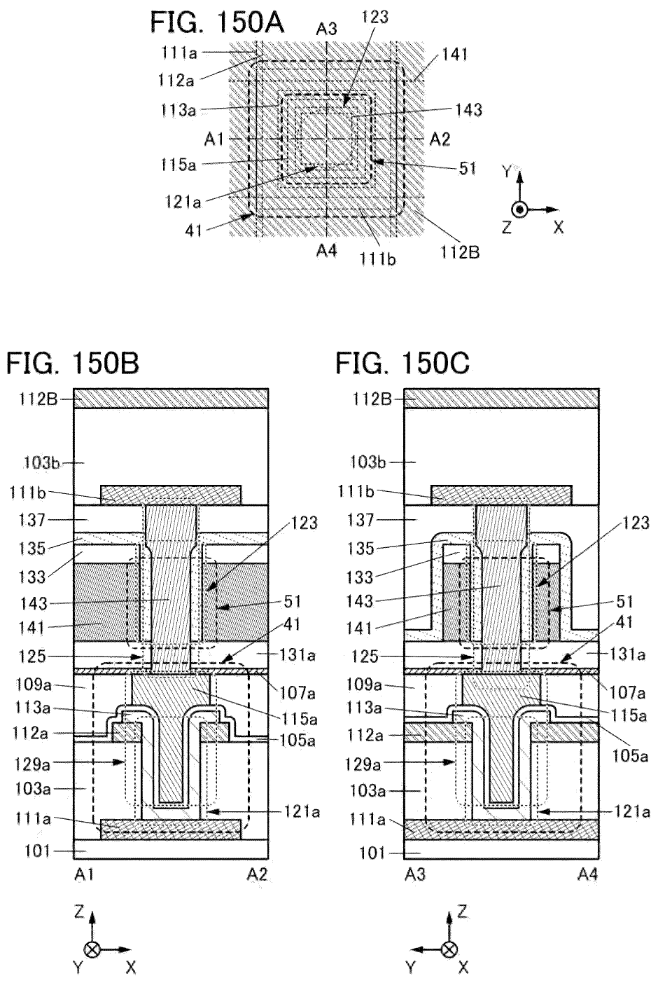

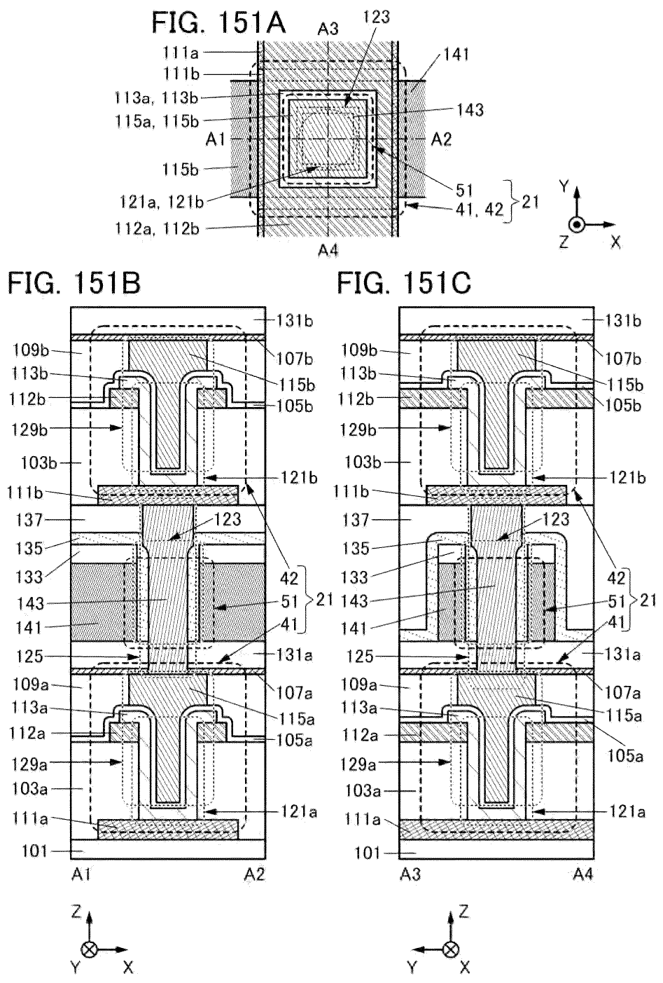

Next, steps similar to those illustrated in FIG. 100A to FIG. 101C are performed (FIGS. 150A to 150C). Then, the conductive layer 112b, the opening portion 121b, the semiconductor layer 113b, the insulating layer 105b, the insulating layer 109b, the opening portion 129b, the conductive layer 115b, the insulating layer 107b, and the insulating layer 131b are formed by methods similar to the methods for forming the conductive layer 112a, the opening portion 121a, the semiconductor layer 113a, the insulating layer 105a, the insulating layer 109a, the opening portion 129a, the conductive layer 115a, the insulating layer 107a, and the insulating layer 131a (FIGS. 151A to 151C).

In the above-described manner, the transistor 42 including the conductive layer 111b, the conductive layer 112b, the semiconductor layer 113b, the insulating layer 105b, and the conductive layer 115b can be formed. As described above, the conductive layer 111b functions as the one of the source electrode and the drain electrode of the transistor 42, the conductive layer 112b functions as the other of the source electrode and the drain electrode of the transistor 42, the insulating layer 105b functions as the gate insulating layer of the transistor 42, and the conductive layer 115b functions as the gate electrode of the transistor 42. Note that in the step illustrated in FIGS. 151A to 151C, the conductive layer 115b is not electrically connected to another circuit, for example.

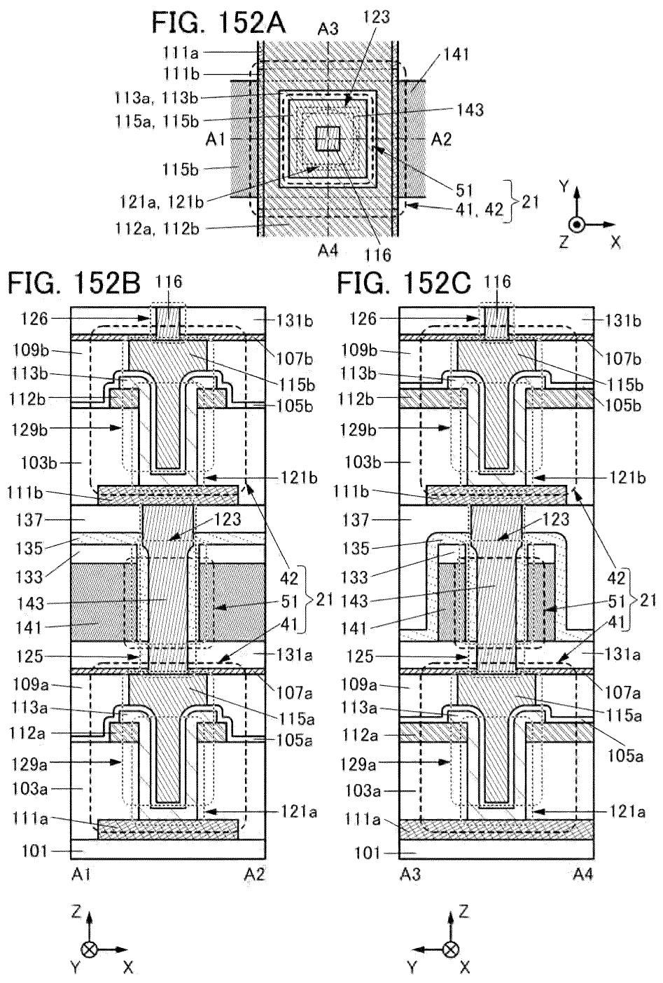

Next, part of the insulating layer 131b and part of the insulating layer 107b are processed, so that the opening portion 126 reaching the conductive layer 115b is formed (FIGS. 152A to 152C). Although the processing can be performed, for example, by a dry etching method or a wet etching method, processing by a dry etching method is preferable because it is suitable for microfabrication.

Next, the conductive layer 116 is formed inside the opening portion 126 (FIGS. 152A to 152C). For example, a conductive film to be the conductive layer 116 is formed so as to fill the opening portion 126, and the conductive film is subjected to planarization treatment such as CMP treatment until the top surface of the insulating layer 131b is exposed, whereby the conductive layer 116 is formed inside the opening portion 126. For the conductive film to be the conductive layer 116, any of the above-described conductive materials that can be used for the conductive layer 116 can be appropriately used. The conductive film to be the conductive layer 116 can be formed by appropriately using a deposition method such as a sputtering method, a CVD method, an MBE method, a PLD method, or an ALD method.

Next, the conductive layer 117 is formed over the conductive layer 116 and the insulating layer 131b (FIGS. 59A to 59C). For example, a conductive film to be the conductive layer 117 is formed and processed, so that the conductive layer 117 can be formed. As the conductive film to be the conductive layer 117, any of the above-described conductive materials that can be used for the conductive layer 117 can be appropriately used. The conductive film to be the conductive layer 117 can be formed by appropriately using a deposition method such as a sputtering method, a CVD method, an MBE method, a PLD method, or an ALD method. After the conductive film to be the conductive layer 117 is formed, formation of a pattern is performed by a lithography method, and the conductive film is processed by a dry etching method, a wet etching method, or the like using the pattern, whereby the conductive layer 117 can be formed. Here, for microfabrication, the conductive film is preferably processed by a dry etching method.

Next, the semiconductor device illustrated in FIGS. 59A to 59C including the memory cells 21 in each of which the transistor 41, the transistor 42, and the capacitor 51 are provided can be manufactured.

### <Example 10 of Method for Manufacturing Semiconductor Device>

As the method for manufacturing the semiconductor device of one embodiment of the present invention, an example of a method for manufacturing the semiconductor device illustrated in FIGS. 66A, 66C, and 66D is described below.

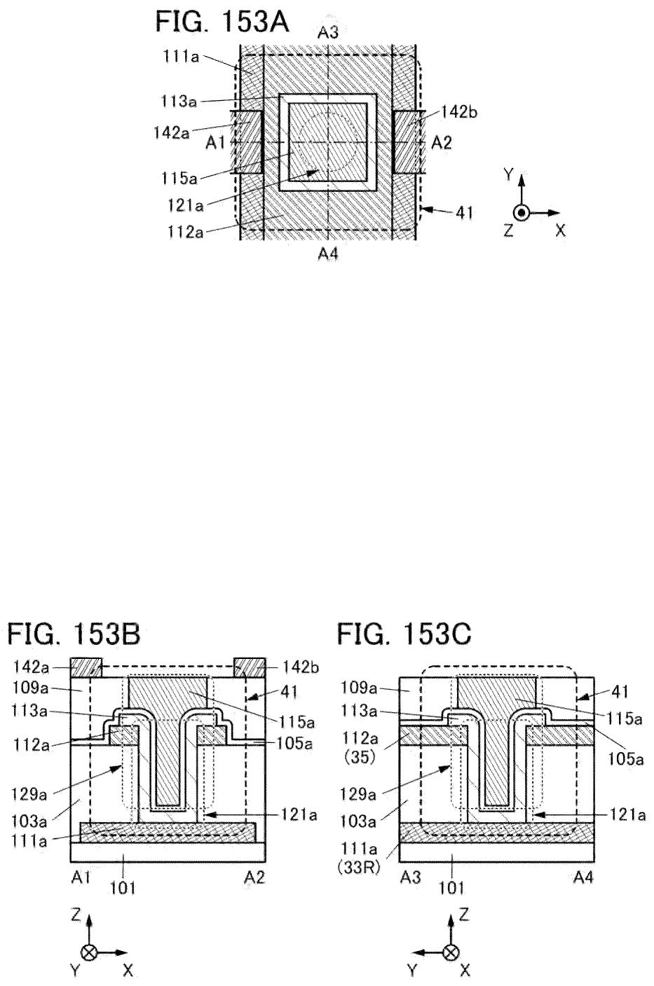

First, steps similar to those illustrated in FIG. 143A to FIG. 146C are performed. Next, the conductive layer 142a and the conductive layer 142b are formed over the insulating layer 109a (FIGS. 153A to 153C). For the formation of the conductive layers 142a and 142b, the description of FIGS. 108A to 108C can be referred to.

Here, part of the conductive film to be the conductive layers 142a and 142b is preferably processed under conditions where the etching selectivity of the conductive film to be the conductive layers 142a and 142b to the conductive layer 115a is high, that is, conditions where the conductive film is easily etched and the conductive layer 115a is not easily etched. Accordingly, for example, the top surface of the conductive layer 115a can be inhibited from being positioned below the top surface of the insulating layer 109a by unintentional processing of the conductive layer 115a at the time of processing the conductive film.

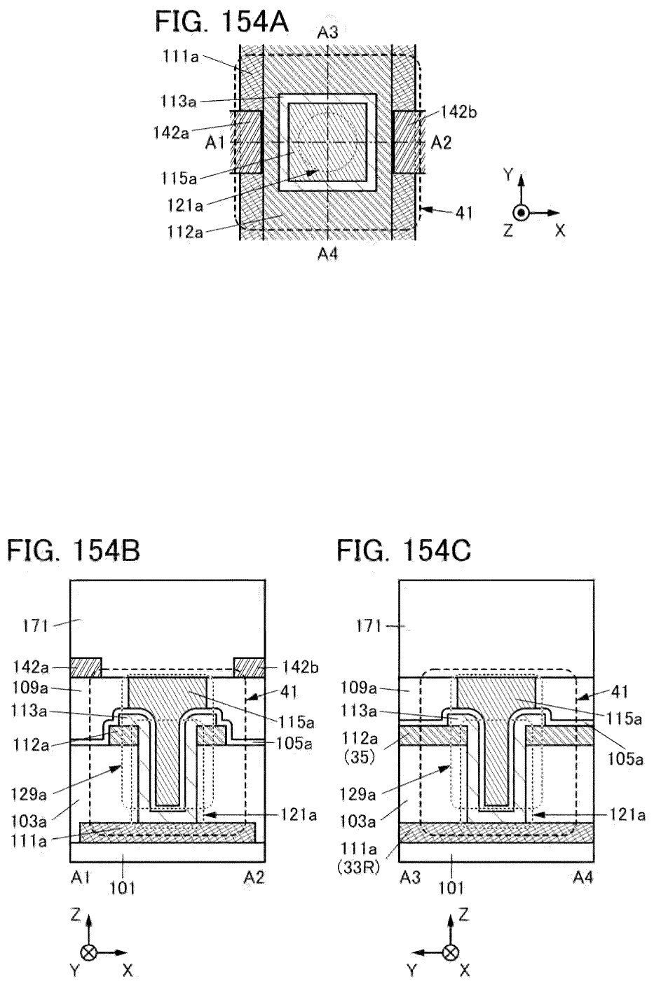

Next, the insulating layer 171 is formed over the insulating layer 109a, the conductive layer 115a, the conductive layer 142a, and the conductive layer 142b (FIGS. 154A to 154C). For the formation of the insulating layer 171, the description of FIGS. 109A to 109C can be referred to.

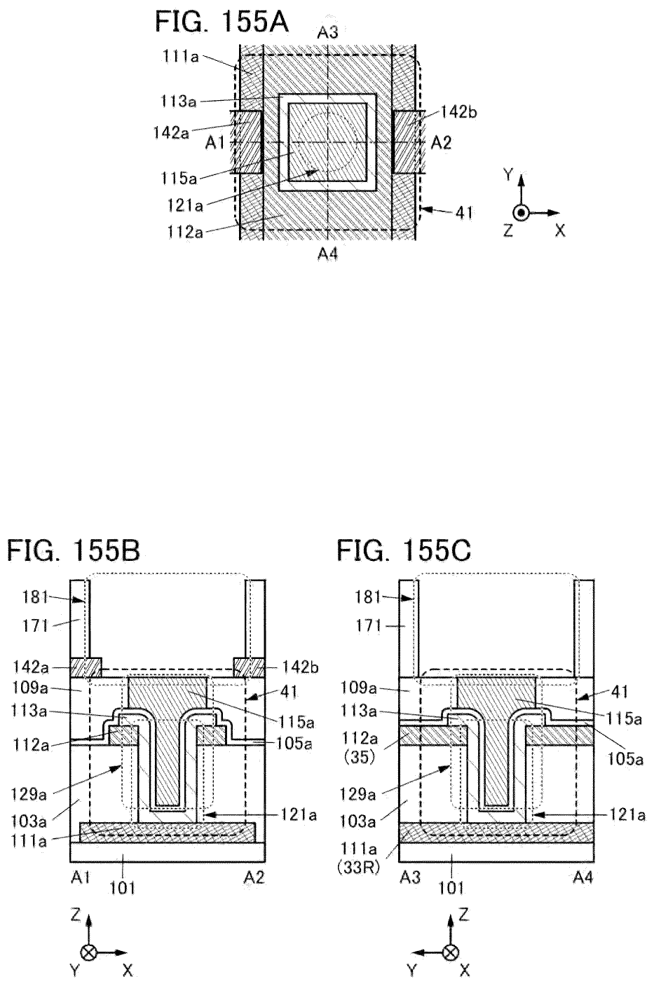

Next, part of the insulating layer 171 is processed to form the opening portion 181 reaching the insulating layer 109a, the conductive layer 115a, the conductive layer 142a, and the conductive layer 142b (FIGS. 155A to 155C). For the formation of the opening portion 181, the description of FIGS. 110A to 110C can be referred to.

Here, part of the insulating layer 171 is preferably processed under conditions where the etching selectivity of the insulating layer 171 to the insulating layer 109a is high, that is, conditions where the insulating layer 171 is easily etched and the insulating layer 109a is not easily etched. Accordingly, for example, formation of a depressed portion in the insulating layer 109a by unintentional processing of the insulating layer 109a at the time of processing the insulating layer 171 can be inhibited.

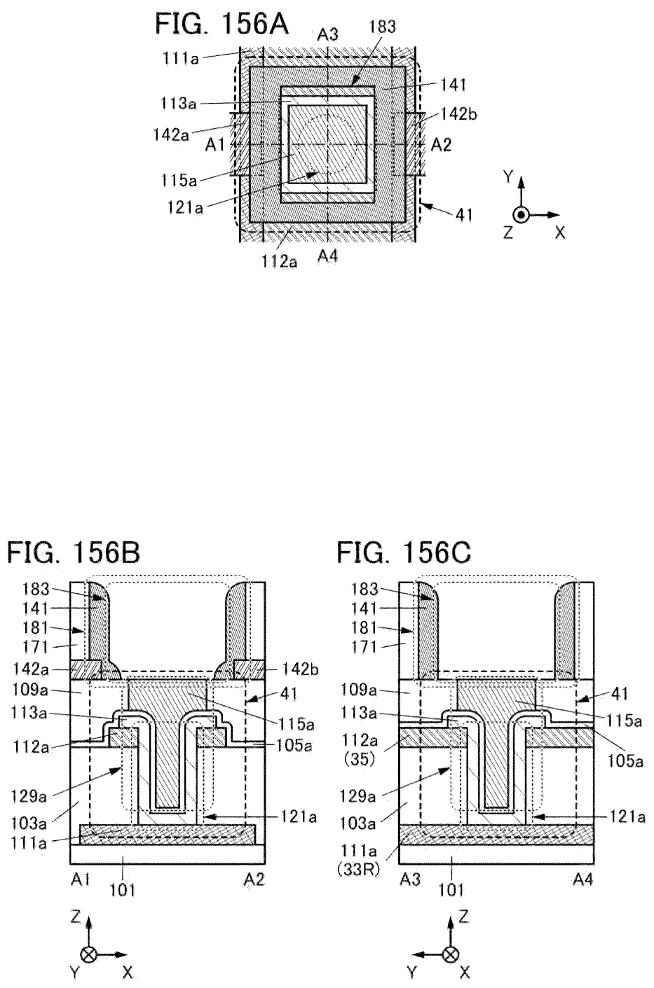

Next, the conductive layer 141 which includes the opening portion 183 including a region overlapping with the conductive layer 115a is formed inside the opening portion 181 (FIGS. 156A to 156C). For the formation of the conductive layer 141, the description of FIG. 111A to FIG. 112C can be referred to. Here, the conductive film 141A is processed so that the conductive layer 141 will not be in contact with the conductive layer 115a. The conductive layer 141 may be formed by etch-back treatment or a lithography method.

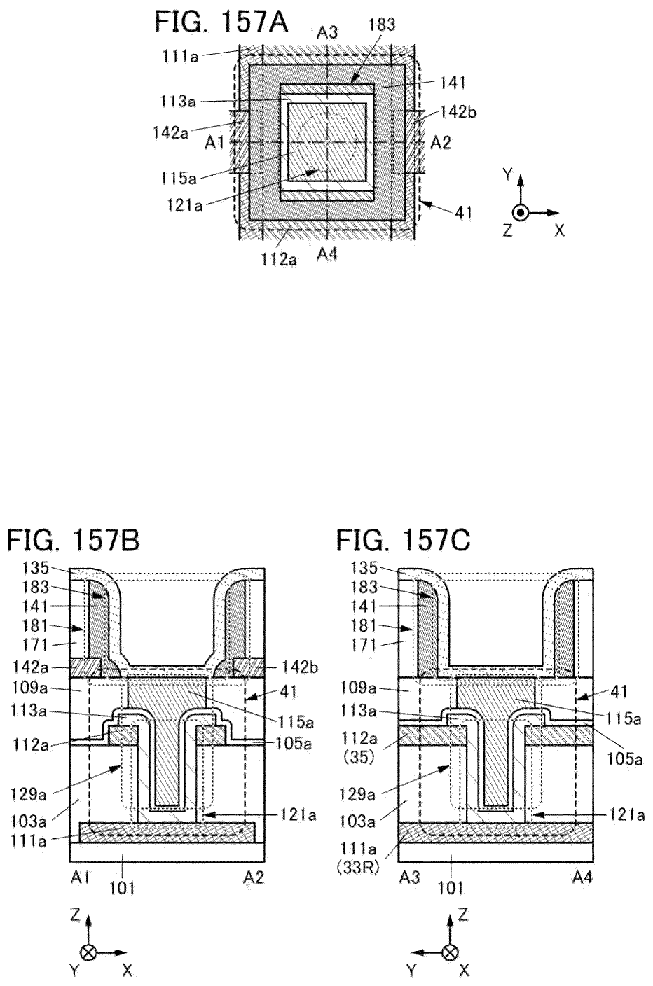

Next, the insulating layer 135 is formed so as to include a region positioned inside the opening portion 181, specifically, inside the opening portion 183 (FIGS. 157A to 157C). The insulating layer 135 is formed so as to cover at least part of the top surface of the insulating layer 171, at least part of the conductive layer 141, at least part of the top surface of the insulating layer 109a, and at least part of the top surface of the conductive layer 115a, for example. For the formation of the insulating layer 135, the description of FIGS. 113A to 113C can be referred to.

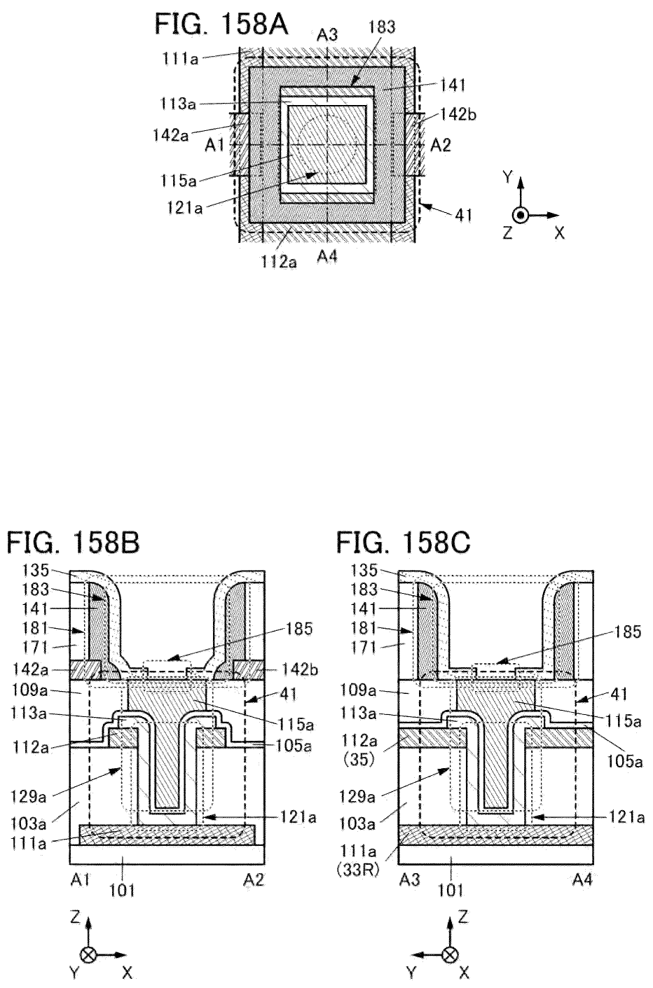

Next, part of the insulating layer 135 is processed to form the opening portion 185 reaching the conductive layer 115a (FIGS. 158A to 158C). For the formation of the opening portion 185, the description of FIGS. 114A to 114C can be referred to.

Next, steps similar to those illustrated in FIG. 115A to FIG. 117C are performed. Then, the insulating layer 103b, the conductive layer 112b, the opening portion 121b, the semiconductor layer 113b, the insulating layer 105b, the insulating layer 109b, the opening portion 129b, and the conductive layer 115b are formed by methods similar to the methods for forming the insulating layer 103a, the conductive layer 112a, the opening portion 121a, the semiconductor layer 113a, the insulating layer 105a, the insulating layer 109a, the opening portion 129a, and the conductive layer 115a.

Next, the conductive layer 117 is formed over the conductive layer 115b and the insulating layer 109b. As described above, the conductive layer 117 can be formed by forming and processing a conductive film to be the conductive layer 117.

Next, the semiconductor device illustrated in FIGS. 66A to 66C including the memory cells 21 in each of which the transistor 41, the transistor 42, and the capacitor 51 are provided can be manufactured.

### <Example 11 of Method for Manufacturing Semiconductor Device>

As the method for manufacturing the semiconductor device of one embodiment of the present invention, an example of a method for manufacturing the semiconductor device illustrated in FIGS. 67A to 67C is described below.

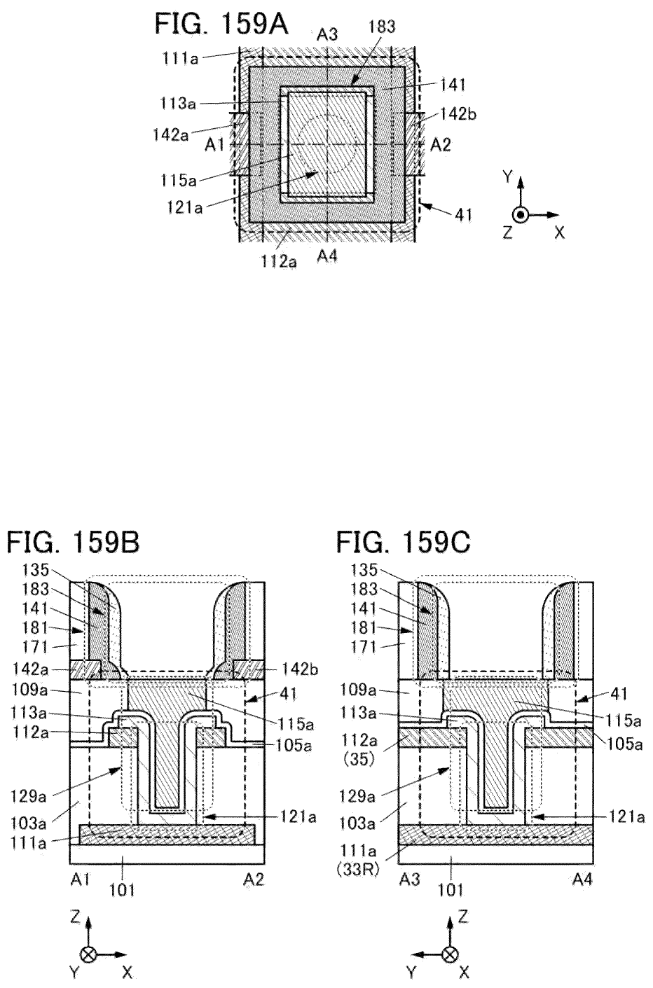

First, steps similar to those illustrated in FIG. 153A to FIG. 157C are performed. Next, the insulating layer 135 is subjected to etch-back treatment (FIGS. 159A to 159C). For the etch-back treatment performed on the insulating layer 135, the description of FIGS. 122A to 122C can be referred to.

Next, steps similar to those illustrated in FIG. 124A to FIG. 128C are performed. Then, the insulating layer 103b, the conductive layer 112b, the opening portion 121b, the semiconductor layer 113b, the insulating layer 105b, the insulating layer 109b, the opening portion 129b, and the conductive layer 115b are formed by methods similar to the methods for forming the insulating layer 103a, the conductive layer 112a, the opening portion 121a, the semiconductor layer 113a, the insulating layer 105a, the insulating layer 109a, the opening portion 129a, and the conductive layer 115a.

Next, the conductive layer 117 is formed over the conductive layer 115b and the insulating layer 109b. As described above, the conductive layer 117 can be formed by forming and processing a conductive film to be the conductive layer 117.

Next, the semiconductor device illustrated in FIGS. 67A to 67C including the memory cells 21 in each of which the transistor 41, the transistor 42, and the capacitor 51 are provided can be manufactured.

In the above-described manner, in the method for manufacturing the semiconductor device of one embodiment of the present invention, the transistor 41, the capacitor 51, and the transistor 42 are stacked in this order. In each of the transistor 41 and the transistor 42, the semiconductor layer, the gate insulating layer, and the gate electrode are provided inside the opening portion formed in the interlayer insulating layer, the one of the source electrode and the drain electrode is provided under the opening portion, and the other of the source electrode and the drain electrode is provided over the interlayer insulating layer. Thus, the area occupied by the memory cells 21 in a plan view can be made small as compared with, for example, the case where the transistor 41 and the transistor 42 are planar transistors and the transistor 41, the capacitor 51, and the transistor 42 are not stacked but provided in the same layer. Therefore, the memory cells can be miniaturized and highly integrated. Accordingly, with one embodiment of the present invention, a method for manufacturing a semiconductor device capable of being miniaturized and highly integrated can be provided.

This embodiment can be combined with any of the other embodiments and example as appropriate. In this specification, in the case where a plurality of structure examples are shown in one embodiment, the structure examples can be combined as appropriate.

### Embodiment 2

In this embodiment, a structure example of a semiconductor device in which a plurality of layers each including the memory cells 21 described in the above embodiment are stacked is described with reference to drawings.

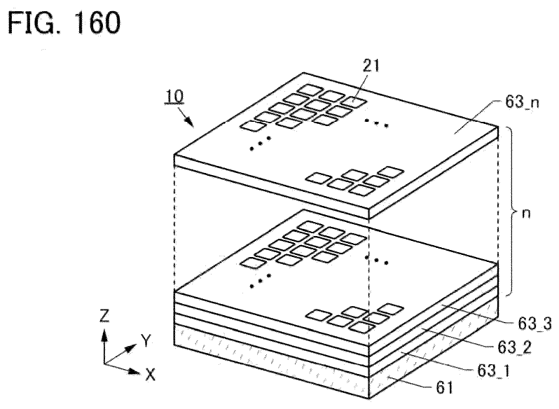

FIG. 160 is a perspective view illustrating a structural example of the semiconductor device 10. The semiconductor device 10 includes a driver circuit layer 61 and n memory layers 63 (n is an integer greater than or equal to 1). The driver circuit layer 61 is provided with the word line driver circuit 11 and the bit line driver circuit 13 described in the above embodiment. In addition, the driver circuit layer 61 may be provided with the power supply circuit 15 described in the above embodiment. In each of the memory layers 63, the memory cells 21 are arranged in a matrix. In this embodiment, the n memory layers 63 are differentiated by being expressed as a memory layer 63_1 to a memory layer 63_n. In FIG. 160, the memory layer 63_1, a memory layer 63_2, a memory layer 63_3, and the memory layer 63_n are illustrated as the memory layers 63.

In the semiconductor device 10 illustrated in FIG. 160, the n memory layers 63 are provided over the driver circuit layer 61. This can reduce the area occupied by the semiconductor device 10. Furthermore, the memory capacity per unit area can be increased.

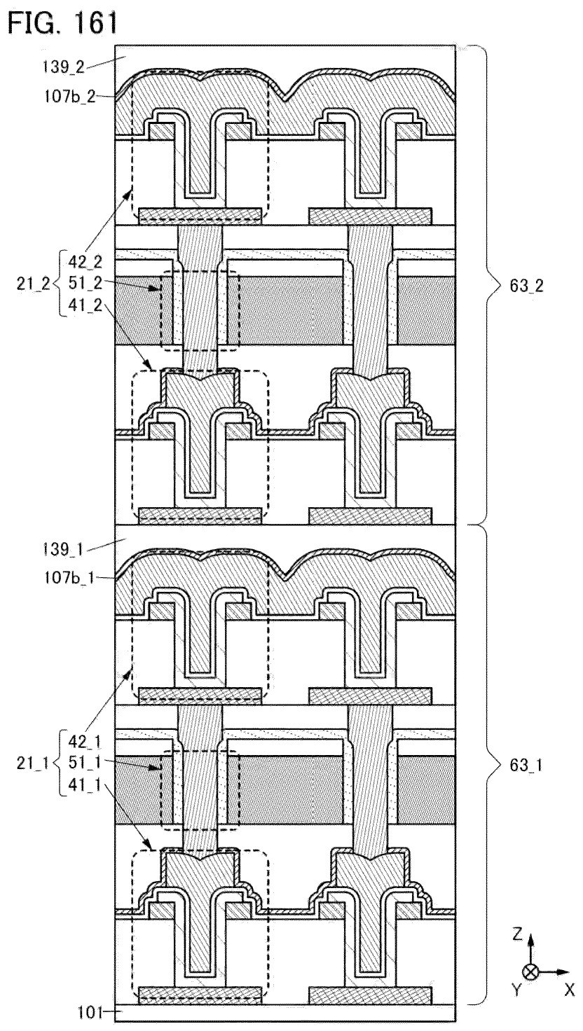

FIG. 161 is a cross-sectional view on the X-Z plane illustrating a structure example of the memory layer 63_1 and the memory layer 63_2 illustrated in FIG. 160. As illustrated in FIG. 161, the memory layer 63_1 is provided over the insulating layer 101, and the memory layer 63_2 is provided over the memory layer 63_1. As described above, the memory cells 21 are provided in the memory layers 63. FIG. 161 illustrates a structure example of the memory cells 21 in two rows and one column.

The memory cells 21 each include the transistor 41, the transistor 42, and the capacitor 51. In this embodiment, the memory cells 21 included in the memory layer 63_1 are referred to as memory cells 21_1, and the memory cells 21 included in the memory layer 63_2 are referred to as memory cells 21_2. Furthermore, the transistor 41, the transistor 42, and the capacitor 51 included in the memory cell 21_1 are respectively referred to as a transistor 41_1, a transistor 42_1, and a capacitor 51_1, and the transistor 41, the transistor 42, and the capacitor 51 included in the memory cell 21_2 are respectively referred to as a transistor 41_2, a transistor 42_2, and a capacitor 51_2. As described above, the insulating layer 107b is provided over the transistor 42. In this embodiment, the insulating layer 107b provided over the transistor 42_1 is referred to as an insulating layer 107b_1, and the insulating layer 107b provided over the transistor 42_2 is referred to as an insulating layer 107b_2.

Here, an insulating layer 139 functioning as an interlayer insulating layer is provided over the insulating layer 107b. In this embodiment, for example, the insulating layer 139 provided in the memory layer 63_1 is referred to as an insulating layer 139_1, and the insulating layer 139 provided in the memory layer 63_2 is referred to as an insulating layer 139_2. For example, the transistor 41_2 is provided over the insulating layer 139_1. For the insulating layer 139, a material similar to the material that can be used for the interlayer insulating layer described in the above embodiment can be used.

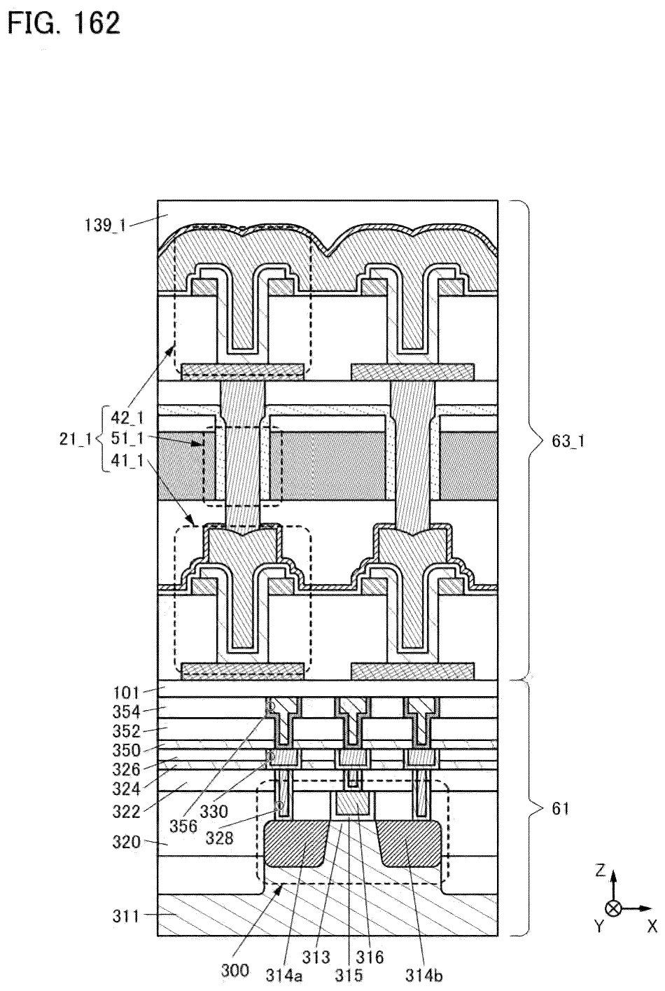

FIG. 162 is a cross-sectional view illustrating a structure example of the driver circuit layer 61 and the memory layer 63_1 over the driver circuit layer 61. FIG. 162 is a cross-sectional view obtained by eliminating the memory layer 63_2 from the structure in FIG. 161 and adding the driver circuit layer 61 thereto. In FIG. 162, a transistor 300 is illustrated as a transistor included in the driver circuit layer 61.

The transistor 300 is provided on a substrate 311 and includes a conductive layer 316 functioning as a gate electrode, an insulating layer 315 functioning as a gate insulating layer, a semiconductor region 313 including a part of the substrate 311, and a low-resistance region 314a and a low-resistance region 314b functioning as a source region and a drain region. The transistor 300 may be a p-channel transistor or an n-channel transistor. As the substrate 311, a single crystal silicon substrate can be used, for example.

In the transistor 300 illustrated in FIG. 162, the semiconductor region 313 (part of the substrate 311) in which a channel is formed has a projecting portion. Furthermore, the conductive layer 316 is provided so as to cover side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 162 is only an example and is not limited to having the structure shown therein; an appropriate transistor can be used in accordance with a circuit structure or a driving method.

Wiring layers including an interlayer insulating layer, a wiring, a plug, and the like may be provided between the structure bodies. A plurality of wiring layers can be provided in accordance with the design. Furthermore, in this specification and the like, a wiring and a plug electrically connected to the wiring may be a single component. That is, in some cases, part of a conductor functions as a wiring or part of a conductor functions as a plug.

For example, an insulating layer 320, an insulating layer 322, an insulating layer 324, and an insulating layer 326 are stacked over the transistor 300 in this order as interlayer insulating layers. For example, a conductive layer 328 is embedded in the insulating layer 320 and the insulating layer 322. For example, a conductive layer 330 is embedded in the insulating layer 324 and the insulating layer 326. Note that the conductive layer 328 and the conductive layer 330 function as contact plugs or wirings.

The insulating layer functioning as the interlayer insulating layer may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIG. 162, an insulating layer 350, an insulating layer 352, and an insulating layer 354 are stacked in this order over the insulating layer 326 and the conductive layer 330. A conductive layer 356 is provided in the insulating layer 350, the insulating layer 352, and the insulating layer 354. The conducting layer 356 functions as a contact plug or a wiring.

This embodiment can be combined with any of the other embodiments and the example as appropriate. In this specification, in the case where a plurality of structure examples are shown in one embodiment, the structure examples can be combined as appropriate.

### Embodiment 3

In this embodiment, application examples of the semiconductor device of one embodiment of the present invention are described with reference to the drawings. The semiconductor device of one embodiment of the present invention can be used for an electronic component, an electronic apparatus, a large computer, a device for space, and a data center (also referred to as DC), for example. An electronic component, an electronic apparatus, a large computer, a device for space, and a data center each employing the semiconductor device of one embodiment of the present invention are effective in improving performance, for example, reducing power consumption.

### [Electronic Component]

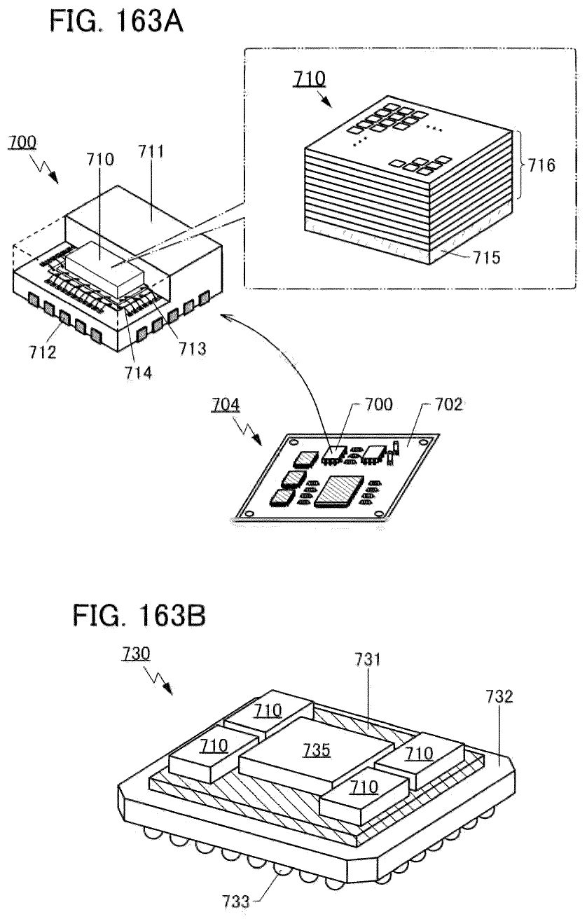

FIG. 163A is a perspective view of a substrate (a circuit board 704) provided with an electronic component 700. The electronic component 700 illustrated in FIG. 163A includes a semiconductor device 710 in a mold 711. Some components are omitted in FIG. 163A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit substrate 704.

The semiconductor device 710 includes a driver circuit layer 715 and a memory layer 716. The memory layer 716 has a structure where a plurality of memory cell arrays are stacked. The driver circuit layer 715 and the memory layer 716 can be stacked monolithically. In the monolithically stacked structure, layers can be connected without using through electrode technique such as through-silicon via (TSV) technique and bonding technique such as Cu—Cu direct bonding. Monolithically stacking the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, for example, the size of a connection wiring can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking memory cell arrays can improve the bandwidth of the memory and/or the access latency of the memory. Note that the bandwidth refers to the data transfer volume per unit time, and the access latency refers to a period of time from data access to the start of data transmission. Note that the memory layer 716 formed with Si transistors is more difficult to monolithically stack than the memory layer 716 formed with OS transistors. Therefore, an OS transistor is superior to a Si transistor in the monolithically stacked structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 163B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a central processing unit (CPU), a graphics processing unit (GPU), or an field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, TSV, and the like, a space for a width of the terminal pitch and the like is needed. Accordingly, in the case where the size of the electronic component 730 is to be reduced, the width of the terminal pitch is an issue and it is sometimes difficult to provide a large number of wirings for obtaining a wide memory bandwidth. For this reason, the above-described structure of monolithically stacking OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 163B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Electronic Apparatus]

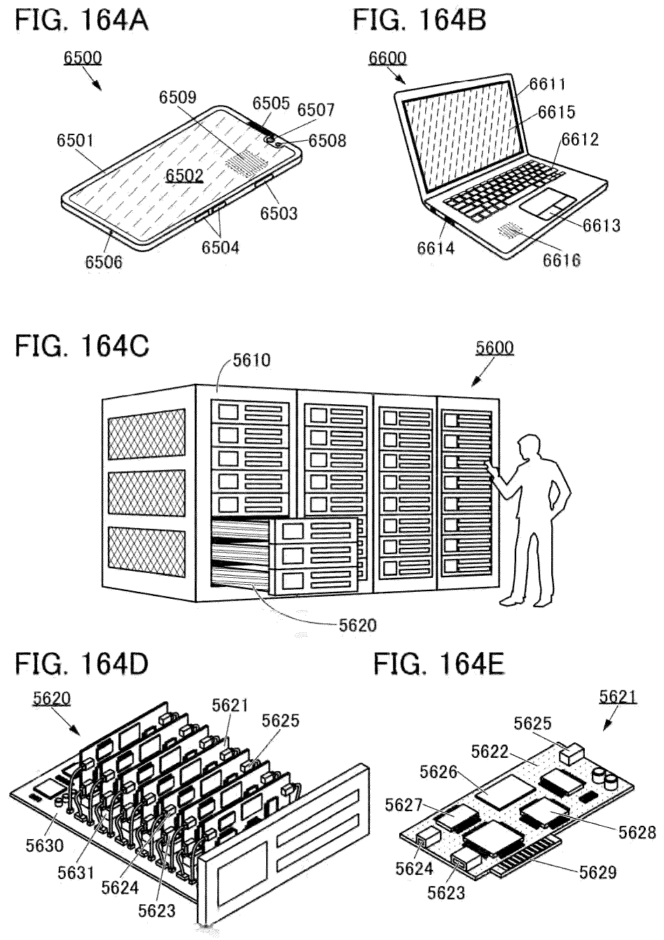

Next, FIG. 164A is a perspective view of an electronic apparatus 6500. The electronic apparatus 6500 in FIG. 164A is a portable information terminal that can be used as a smartphone. The electronic apparatus 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic apparatus 6600 illustrated in FIG. 164B is an information terminal that can be used as a laptop personal computer. The electronic apparatus 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 164C is a perspective view of a large computer 5600. In the large computer 5600 illustrated in FIG. 164C, a plurality of rack mount computers 5620 are stored in a rack 5610. Note that the large computer 5600 may be referred to as a supercomputer.

The computer 5620 can have a structure in a perspective view illustrated in FIG. 164D, for example. In FIG. 164D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 164E is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Although FIG. 164E also illustrates semiconductor devices other than the semiconductor devices 5626, 5627, and 5628, the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, and the like to the PC card 5621. As another example, they can serve as an interface for outputting a signal calculated by the PC card 5621. Examples of the standard for each of the connection terminal 5623, the connection terminal 5624, and the connection terminal 5625 include universal serial bus (USB), serial ATA (SATA), and small computer system interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of thermosphere, mesosphere, and stratosphere.

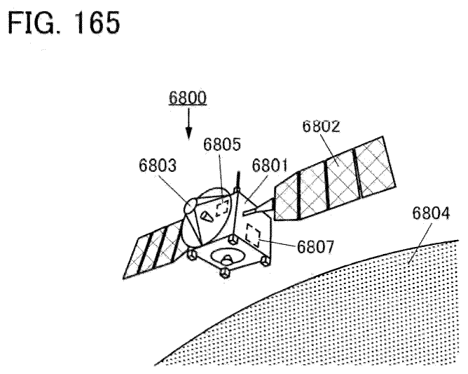

FIG. 165 illustrates an artificial satellite 6800 as an example of a device for space. The artificial satellite 6800 includes a body 6801, a solar panel 6802, an antenna 6803, a secondary battery 6805, and a control device 6807. In FIG. 165, a planet 6804 in outer space is illustrated.

Although not illustrated in FIG. 165, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center. Long-term management of data, such as guarantee of data immutability, is required for the data center. In the case where data is managed for a long term, increasing the scale of the data center is necessary for installation of storages and servers for storing an enormous amount of data, stable power supply for data retention, cooling equipment for data retention, and the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

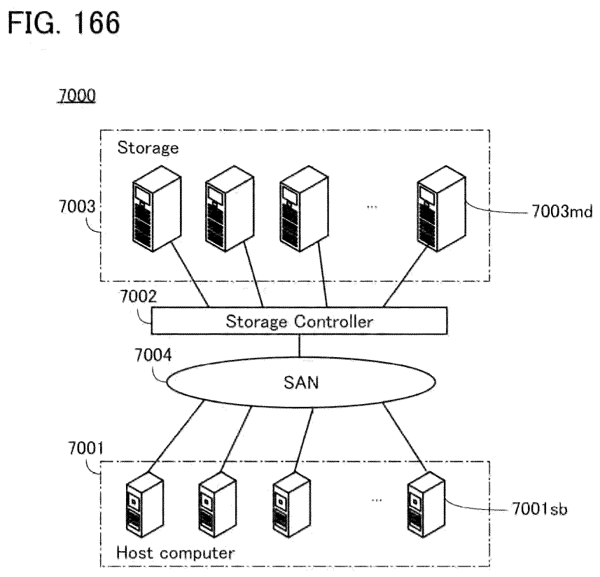

FIG. 166 illustrates a storage system that can be used in a data center. A storage system 7000 illustrated in FIG. 166 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in the storage. In the storage system, in order to solve the problem of low access speed of the storage 7003, a cache memory is normally provided in the storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, a device for space, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

This embodiment can be combined with any of the other embodiments and the example as appropriate.

### Example

In this example, a calculation result regarding a memory cell included in the semiconductor device of one embodiment of the present invention is described.

In this example, a difference in the potential of the node N in the memory cell 21 illustrated in FIG. 1B1 between the case of supplying a high potential to the other electrode of the capacitor 51 (the wiring 31R) and the case of supplying a low potential thereto was calculated. Here, the node N is a floating node. The potential difference was calculated with respect to the varying ratio between the capacitance of the capacitor 51 and the parasitic capacitance of the node N (the capacitance of the capacitor 51/the parasitic capacitance of the node N). The difference between the high potential and the low potential was 2.0 V. Note that the gate capacitance of the transistor 41, which is for example the capacitance formed by the conductive layer 112a, the insulating layer 105a, and the conductive layer 115a illustrated in FIGS. 2A to 2C, can be regarded as parasitic capacitance of the node N.

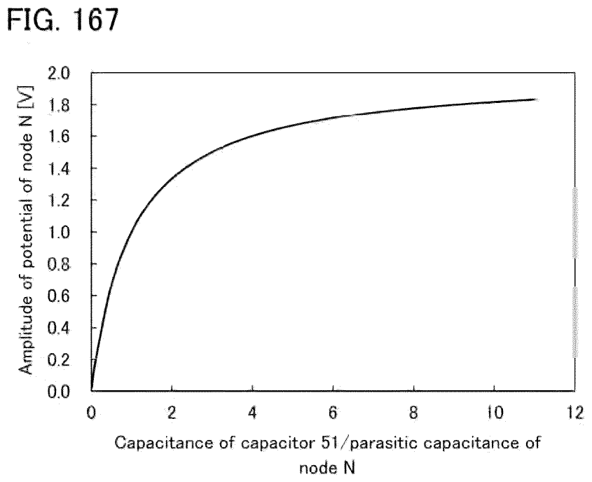

FIG. 167 is a graph showing the amplitude of the potential of the node N which was calculated with respect to the varying ratio between the capacitance of the capacitor 51 and the parasitic capacitance of the node N. Here, the amplitude of the potential of the node N refers to a difference between the potential of the node N of the case where a high potential is supplied to the other electrode of the capacitor 51 and the potential of the node N of the case where a low potential is supplied thereto. The amplitude of the potential of the node N is preferably as close to 2.0 V, which is the difference between the high potential and the low potential, as possible.

As illustrated in FIG. 167, it was confirmed that the amplitude of the potential of the node N was 1.3 V, 1.6 V, and 1.8 V when the capacitance of the capacitor 51 was double, quadruple, and octuple, respectively, the parasitic capacitance of the node N. Therefore, it was confirmed that the capacitance of the capacitor 51 is preferably more than or equal to double the parasitic capacitance of the node N, further preferably more than or equal to quadruple the parasitic capacitance of the node N.

This application is based on Japanese Patent Application Serial No. 2022-157803 filed with Japan Patent Office on Sep. 30, 2022 and Japanese Patent Application Serial No. 2022-165187 filed with Japan Patent Office on Oct. 14, 2022, the entire contents of which are hereby incorporated by reference.

What is claimed is:

1. A semiconductor device comprising:
a capacitor; a first transistor; and a first insulating layer,
wherein the capacitor comprises a first conductive layer, a second conductive layer, and a second insulating layer,
wherein the second insulating layer comprises a region in contact with a side surface of the first conductive layer,
wherein the second conductive layer covers at least part of the side surface of the first conductive layer with the second insulating layer therebetween,
wherein the first transistor comprises a third conductive layer, a fourth conductive layer, a fifth conductive layer, a first semiconductor layer, and a third insulating layer,
wherein the third conductive layer comprises a region in contact with a top surface of the first conductive layer,
wherein the first insulating layer is over the third conductive layer,
wherein the fourth conductive layer is over the first insulating layer,
wherein the first insulating layer and the fourth conductive layer comprise a first opening portion reaching the third conductive layer,
wherein the first semiconductor layer comprises a region in contact with the third conductive layer, a region in contact with the fourth conductive layer, and a region positioned inside the first opening portion,
wherein the third insulating layer is over the first semiconductor layer and comprises a region positioned inside the first opening portion, and
wherein the fifth conductive layer comprises a region facing the first semiconductor layer with the third insulating layer therebetween, inside the first opening portion.

2. The semiconductor device according to claim 1, further comprising a second transistor,
wherein the second transistor is under the capacitor, and
wherein the first conductive layer is electrically connected to a gate electrode of the second transistor.

3. The semiconductor device according to claim 1, further comprising a second transistor and a fourth insulating layer,
wherein the second transistor comprises a sixth conductive layer, a seventh conductive layer, an eighth conductive layer, a second semiconductor layer, and a fifth insulating layer,
wherein the fourth insulating layer is over the sixth conductive layer,
wherein the seventh conductive layer is over the fourth insulating layer,
wherein the fourth insulating layer and the seventh conductive layer comprise a second opening portion reaching the sixth conductive layer,
wherein the second semiconductor layer comprises a region in contact with the sixth conductive layer, a region in contact with the seventh conductive layer, and a region positioned inside the second opening portion,
wherein the fifth insulating layer is over the second semiconductor layer and comprises a region positioned inside the second opening portion,
wherein the eighth conductive layer comprises a region facing the second semiconductor layer with the fifth insulating layer therebetween, inside the second opening portion, and
wherein a top surface of the eighth conductive layer comprises a region in contact with the first conductive layer.

4. The semiconductor device according to claim 3, further comprising a memory portion,
wherein the memory portion comprises memory cells arranged in a matrix,
wherein each of the memory cells comprises the first transistor, the second transistor, and the capacitor, and
wherein the sixth conductive layer and the seventh conductive layer are shared by the memory cells arranged in a first direction.

5. The semiconductor device according to claim 4,
wherein a constant potential is supplied to the seventh conductive layer.

6. The semiconductor device according to claim 5, further comprising a first driver circuit,
wherein the first driver circuit is electrically connected to the sixth conductive layer, and
wherein the first driver circuit is configured to write data to the memory cells and read the data.

7. The semiconductor device according to claim 6,
wherein the second conductive layer is shared by the memory cells arranged in a second direction that is perpendicular to the first direction.

8. The semiconductor device according to claim 6, further comprising a second driver circuit,
wherein the second driver circuit is electrically connected to the second conductive layer, and
wherein the second driver circuit is configured to supply a signal to the second conductive layer and thereby control reading of the data.

9. The semiconductor device according to claim 1,
wherein the second conductive layer comprises a region extending in a first direction and a region extending in a second direction that is perpendicular to the first direction, and
wherein the second conductive layer comprises a third opening portion in a region where the region extending in the first direction and the region extending in the second direction intersect with each other.

10. The semiconductor device according to claim 9,
wherein a constant potential is supplied to the second conductive layer.

11. The semiconductor device according to claim 3, further comprising a memory portion, a first driver circuit, and a second driver circuit,
wherein the memory portion comprises memory cells arranged in a matrix,
wherein each of the memory cells comprises the first transistor, the second transistor, and the capacitor,
wherein the second conductive layer comprises a region extending in a first direction and a region extending in a second direction that is perpendicular to the first direction,
wherein the second conductive layer comprises a third opening portion in a region where the region extending in the first direction and the region extending in the second direction intersect with each other,
wherein a constant potential is supplied to the second conductive layer,
wherein the sixth conductive layer is electrically connected to the first driver circuit,
wherein the seventh conductive layer is electrically connected to the second driver circuit,
wherein the first driver circuit is configured to write data to the memory cells and read the data, and
wherein the second driver circuit is configured to supply a signal to the seventh conductive layer and thereby control reading of the data.

12. The semiconductor device according to claim 1,
wherein the first semiconductor layer comprises a metal oxide.

13. The semiconductor device according to claim 12,
wherein the metal oxide comprises one or more selected from indium, zinc, and an element M, and
wherein the element M is one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

14. The semiconductor device according to claim 3,
wherein the first semiconductor layer and the second semiconductor layer comprise a metal oxide.

15. The semiconductor device according to claim 14,
wherein the metal oxide comprises one or more selected from indium, zinc, and an element M, and
wherein the element M is one or more selected from aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony.

16. The semiconductor device according to claim 3,
wherein a capacitance of the capacitor is more than or equal to double a capacitance of a capacitor formed by the seventh conductive layer, the fifth insulating layer, and the eighth conductive layer.

17. An electronic apparatus comprising the semiconductor device according to claim 1 and a camera.

18. A method for manufacturing a semiconductor device, comprising the steps of:
forming a first conductive film;
processing part of the first conductive film to form a first conductive layer comprising a first opening portion;
forming a first insulating layer comprising a region in contact with, inside the first opening portion, a side surface of the first conductive layer;
forming, in the first insulating layer, a second opening portion comprising a region overlapping with the first opening portion;
forming a second conductive layer inside the second opening portion;
forming a third conductive layer comprising a region in contact with a top surface of the second conductive layer;
forming a second insulating layer over the third conductive layer;
forming a second conductive film over the second insulating layer;
forming a third opening portion in the second insulating layer and the second conductive film;
forming a first semiconductor layer so as to comprise a region in contact with the third conductive layer and a region in contact with the second conductive film and so as to comprise a region positioned inside the third opening portion;
processing part of the second conductive film to form a fourth conductive layer;
forming a third insulating layer over the first semiconductor layer and the fourth conductive layer; and
forming a fifth conductive layer so as to comprise a region facing the first semiconductor layer with the third insulating layer therebetween, inside the third opening portion,
wherein a capacitor comprises the first conductive layer, the second conductive layer, and the first insulating layer, and
wherein a first transistor comprises the third to fifth conductive layers and the third insulating layer.

19. The method for manufacturing a semiconductor device, according to claim 18, further comprising:
a step of forming a second transistor before the first conductive film is formed,
wherein the second conductive layer is formed so as to be electrically connected to a gate electrode of the second transistor.

20. The method for manufacturing a semiconductor device, according to claim 18, further comprising the steps of:
forming a sixth conductive layer before the first conductive film is formed;
forming a fourth insulating layer over the sixth conductive layer;
forming a third conductive film over the fourth insulating layer;
forming a fourth opening portion in the fourth insulating layer and the third conductive film;
forming a second semiconductor layer so as to comprise a region in contact with the sixth conductive layer and a region in contact with the third conductive film and so as to comprise a region positioned inside the fourth opening portion;
processing part of the third conductive film to form a seventh conductive layer;
forming a fifth insulating layer over the second semiconductor layer and the seventh conductive layer;
forming an eighth conductive layer so as to comprise a region facing the second semiconductor layer with the fifth insulating layer therebetween, inside the fourth opening portion;
forming a sixth insulating layer over the eighth conductive layer;
forming the first conductive film over the sixth insulating layer;
processing part of the first conductive film to form, over the sixth insulating layer, the first conductive layer comprising the first opening portion overlapping with at least part of the eighth conductive layer;
forming the second opening portion in the sixth insulating layer after the first insulating layer is formed; and
forming the second conductive layer comprising a region in contact with the eighth conductive layer,
wherein a second transistor comprises the sixth to eighth conductive layers and the fifth insulating layer.

21. The method for manufacturing a semiconductor device, according to claim 18, further comprising the steps of:
forming an insulating film over the first conductive film;
processing part of the insulating film to form a seventh insulating layer comprising the first opening portion; and
forming the first insulating layer so as to cover at least part of the seventh insulating layer.
